(19) United States
(12) Patent Application Publication
(10) Pub. No.: US 2025/0273560 A1
(43) Pub. Date: Aug. 28, 2025

(54) STAIRLESS THREE-DIMENSIONAL MEMORY DEVICE WITH WORD LINE CONTACT VIA STRUCTURES LOCATED OVER SUPPORT FEATURES AND METHODS OF FORMING THE SAME

(71) Applicant: SANDISK TECHNOLOGIES LLC, ADDISON, TX (US)

(72) Inventors: Tomohiro KUBO, Yokkaichi (JP); Takayuki MAEKURA, Yokkaichi (JP); Koichi MATSUNO, Fremont, CA (US)

(21) Appl. No.: 18/589,094

(22) Filed: Feb. 27, 2024

(51) Int. Cl. H01L 23/522; G11C 16/04; H01L 23/528; H10B 41/10; H10B 41/27; H10B 41/35; H10B 43/10; H10B 43/27; H10B 43/35

(52) U.S. Cl. CPC H01L 23/5226; G11C 16/0483; H01L 23/5283; H10B 41/10; H10B 41/27; H10B 41/35; H10B 43/10; H10B 43/27; H10B 43/35

(57) ABSTRACT

A three-dimensional memory device includes an alternating stack of insulating layers and electrically conductive layers, a memory opening vertically extending through the alternating stack, a memory opening fill structure located in memory opening and including a vertical stack of memory elements located at levels of the electrically conductive layers and a vertical semiconductor channel, and a layer contact via structure contacting a first electrically conductive layer. The layer contact via structure overlies one or more support features.

### FIELD

The present disclosure relates generally to the field of semiconductor devices, and particularly to stairless three-dimensional memory devices including word line contact via structures overlying support features and methods of forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: an alternating stack of insulating layers and electrically conductive layers, wherein the electrically conductive layers comprise a first electrically conductive layer, second electrically conductive layers that overlie the first electrically conductive layer, and third electrically conductive layers that underlie the first electrically conductive layer; a memory opening vertically extending through the alternating stack; a memory opening fill structure located in memory opening and comprising a vertical stack of memory elements located at levels of the electrically conductive layers and a vertical semiconductor channel; and a layer contact assembly comprising a layer contact via structure vertically extending through each layer within the alternating stack and laterally contacting a cylindrical surface of the first electrically conductive layer, and further comprising first annular insulating fins laterally surrounding the layer contact via structure and located at each level of the second electrically conductive layers.

According to another aspect of the present disclosure, a method of forming a three-dimensional memory device is provided. The method comprises: forming an alternating stack of insulating layers and sacrificial material layers over a substrate; forming a memory opening through the alternating stack; forming a memory opening fill structure in the memory opening, wherein the memory opening fill structure comprises a vertical stack of memory elements located at levels of the sacrificial material layers and a vertical semiconductor channel; forming a contact via cavity through a first subset of the sacrificial material layers; replacing portions of the first subset of the sacrificial material layers that are proximal to the contact via cavity with first annular insulating fins; performing a first via extension process that vertically extends the contact via cavity and replacing a portion of a first sacrificial material layer that underlies the first subset of the sacrificial material layers with a sacrificial fin structure; performing a second via extension process that vertically extends the contact via cavity and replacing portions of a second subset of the sacrificial material layers that underlies the sacrificial fin structure with second annular insulating fins; forming a sacrificial via fill material portion in the contact via cavity; replacing remaining portions of the sacrificial material layer in the alternating stack with electrically conductive layers; and replacing at least the sacrificial via fill material portion and the sacrificial fin structure with a layer contact via structure.

According to yet another aspect of the present disclosure, a three-dimensional memory device is provided, which comprises: a first alternating stack of first insulating layers and first electrically conductive layers; a memory opening vertically extending through the first alternating stack; a memory opening fill structure located in the memory opening and comprising a vertical stack of memory elements and a vertical semiconductor channel; a first layer contact via structure vertically extending through a first subset of the first electrically conductive layers and contacting a top surface of one of the first electrically conductive layers within a first horizontal plane; and a first finned dielectric support pillar structure located in proximity to the first layer contact via structure and comprising: a first tubular insulating liner vertically extending through each of the first subset of the first electrically conductive layers and through said one of the first electrically conductive layers, and a first finned dielectric material portion comprising a first dielectric pillar that vertically extends through each layer within the first alternating stack and further comprising first dielectric fins that are located below the first horizontal plane.

According to still another aspect of the present disclosure, a method of forming a three-dimensional memory device is provided, which comprises: forming a first alternating stack of first insulating layers and first sacrificial material layers over a substrate; forming a memory opening vertically extending through the first alternating stack; forming a memory opening fill structure comprising a vertical stack of memory elements in the memory opening and a vertical semiconductor channel; forming a contact via cavity and a support via cavity through a first subset of the first sacrificial material layers; performing a first via extension process which vertically extends the support via cavity while the contact via cavity is filled with a sacrificial via fill material portion; forming a first tubular insulating liner in a peripheral portion of the support via cavity; performing a second via extension process which vertically extends the support via cavity after formation of the first tubular insulating liner; forming annular cavities by removing proximal portions of a second subset of the first sacrificial material layers around the support via cavity selective to the first tubular insulating liner and the first insulating layers, wherein the second subset of the first sacrificial material layers underlies a horizontal plane including an annular bottom surface of the first tubular insulating liner; forming a first finned dielectric material portion in a combination of the support via cavity and the annular cavities to form a first finned dielectric support pillar structure comprising the first tubular insulating liner and the first finned dielectric material portion; replacing the sacrificial material layers with electrically conductive layers; and replacing the sacrificial contact via fill material portion a layer contact via structure that contacts a top surface of one of the electrically conductive layers within a first horizontal plane.

According to another aspect of the present disclosure, a three-dimensional memory device is provided, which comprises: an alternating stack of insulating layers and electrically conductive layers, wherein the electrically conductive layers comprise a first electrically conductive layer, second electrically conductive layers that overlie the first electrically conductive layer, and third electrically conductive layers that underlie the first electrically conductive layer; a memory opening vertically extending through the alternating stack; a memory opening fill structure located in memory opening and comprising a vertical stack of memory elements located at levels of the electrically conductive layers and a vertical semiconductor channel; and a layer contact assembly comprising a layer contact via structure vertically extending through each of the second electrically conductive layers and laterally contacting a cylindrical surface of the first electrically conductive layer, a dielectric support pillar structure vertically extending through each of the third electrically conductive layers and contacting a bottom surface of the layer contact via structure, first annular insulating fins laterally surrounding the layer contact via structure and located at each level of the second electrically conductive layers, and a second annular insulating fin having an inner cylindrical sidewall surface that contacts a first cylindrical surface segment of the dielectric support pillar structure.

According to still another aspect of the present disclosure, a method of forming a three-dimensional memory device is provided. The method comprises: forming an alternating stack of insulating layers and sacrificial material layers over a substrate; forming a memory opening through the alternating stack; forming a memory opening fill structure in the memory opening, wherein the memory opening fill structure comprises a vertical stack of memory elements located at levels of the sacrificial material layers and a vertical semiconductor channel; forming a dielectric support pillar structure through the alternating stack; forming a contact via cavity through a first subset of the sacrificial material layers by etching an upper portion of the dielectric support pillar structure, to reduce a height of the dielectric support pillar structure and to expose sidewalls of the first subset of the sacrificial material layers; replacing portions of the first subset of the sacrificial material layers that are proximal to the contact via cavity with first annular insulating fins; performing a first via extension process that vertically extends the contact via cavity; replacing a portion of a first sacrificial material layer that underlies the first subset of the sacrificial material layers with a sacrificial fin structure; forming a sacrificial via fill material portion in the contact via cavity; replacing remaining portions of the sacrificial material layer in the alternating stack with electrically conductive layers; and replacing at least the sacrificial via fill material portion and the sacrificial fin structure with an electrically conductive layer contact via structure.

### BRIEF DESCRIPTION OF THE DRAWINGS

FIGS. 1A and 1B are various views of a first exemplary structure after formation of in-process source-level material layers and etch-stop plates according to a first embodiment of the present disclosure. FIG. 1A is a vertical cross-sectional view. FIG. 1B is a top-down view. The vertical plane A-A′ in FIG. 1B is the cut plane of the vertical cross-sectional view of FIG. 1A.

FIG. 2 is a vertical cross-sectional view of the first exemplary structure after formation of an alternating stack of insulating layers and sacrificial material layers according to the first embodiment of the present disclosure.

FIGS. 3A-3C are various views of the first exemplary structure after formation of memory openings and support openings according to the first embodiment of the present disclosure. FIG. 3A is a vertical cross-sectional view. FIG. 3B is a top-down view. The vertical plane A-A′ in FIG. 3B is the cut plane of the vertical cross-sectional view of FIG. 3A. FIG. 3C is a vertical cross-sectional view along the vertical plane C-C′ in FIG. 3B.

FIGS. 4A-4E are sequential vertical cross-sectional views of a region of the first exemplary structure during formation of dielectric support pillar structures and memory opening fill structures according to the first embodiment of the present disclosure.

FIGS. 5A-5C are various views of the first exemplary structure after formation of contact via cavities according to the first embodiment of the present disclosure. FIG. 5A is a vertical cross-sectional view. FIG. 5B is a top-down view. The vertical plane A-A′ in FIG. 5B is the cut plane of the vertical cross-sectional view of FIG. 5A. FIG. 5C is a vertical cross-sectional view along the vertical plane C-C′ in FIG. 5B.

FIGS. 6A-6N are sequential vertical cross-sectional views of a region of the first exemplary structure during formation of an in-process layer contact assembly according to the first embodiment of the present disclosure.

FIGS. 7A-7C are various views of the first exemplary structure after formation of a contact-level dielectric layer and the lateral isolation trenches according to the first embodiment of the present disclosure. FIG. 7A is a vertical cross-sectional view. FIG. 7B is a top-down view. The vertical plane A-A′ in FIG. 7B is the cut plane of the vertical cross-sectional view of FIG. 7A. FIG. 7C is a vertical cross-sectional view along the vertical plane C-C′ in FIG. 7B.

FIGS. 8A-8E are sequential vertical cross-sectional views of the first exemplary structure during replacement of the in-process source-level material layers with source-level material layers, replacement of sacrificial material layers with electrically conductive layers, and formation of isolation trench fill structures according to the first embodiment of the present disclosure.

FIGS. 9A-9C are various views of the first exemplary structure after formation of isolation trench fill structures according to the first embodiment of the present disclosure. FIG. 9A is a vertical cross-sectional view. FIG. 9B is a top-down view. The vertical plane A-A′ in FIG. 9B is the cut plane of the vertical cross-sectional view of FIG. 9A. FIG. 9C is a vertical cross-sectional view along the vertical plane C-C′ in FIG. 9B.

FIGS. 10A-10D are sequential vertical cross-sectional views of a region of the first exemplary structure during formation of a replacement contact via cavity according to the first embodiment of the present disclosure. FIG. 10E is a magnified view of a portion of FIG. 10D.

FIGS. 11A-11D are various views of the first exemplary structure after formation of layer contact via structures and drain contact via structures according to the first embodiment of the present disclosure. FIG. 11A is a vertical cross-sectional view. FIG. 11B is a top-down view. The vertical plane A-A′ in FIG. 11B is the cut plane of the vertical cross-sectional view of FIG. 11A. FIG. 11C is a vertical cross-sectional view along the vertical plane C-C′ in FIG. 11B. FIG. 11D is a magnified view of a portion of the first exemplary structure illustrated in FIG. 11C.

FIG. 12 is a vertical cross-sectional view of a second exemplary structure after formation of an alternating stack of insulating layers and sacrificial material layers according to the second embodiment of the present disclosure.

FIGS. 13A-13C are various views of the second exemplary structure after formation of memory openings and support openings according to the second embodiment of the present disclosure. FIG. 13A is a vertical cross-sectional view. FIG. 13B is a top-down view. The vertical plane A-A′ in FIG. 13B is the cut plane of the vertical cross-sectional view of FIG. 13A. FIG. 13C is a vertical cross-sectional view along the vertical plane C-C′ in FIG. 13B.

FIG. 14 is a vertical cross-sectional view of a region of the second exemplary structure after formation of dielectric support pillar structures and memory opening fill structures according to the second embodiment of the present disclosure.

FIGS. 15A-15C are various views of the second exemplary structure after formation of contact via cavities according to the second embodiment of the present disclosure. FIG. 15A is a vertical cross-sectional view. FIG. 15B is a top-down view. The vertical plane A-A′ in FIG. 15B is the cut plane of the vertical cross-sectional view of FIG. 15A. FIG. 15C is a vertical cross-sectional view along the vertical plane C-C′ in FIG. 15B.

FIGS. 16A-16O are sequential vertical cross-sectional views of a region of the second exemplary structure during formation of an in-process layer contact assembly according to the second embodiment of the present disclosure.

FIGS. 17A-17C are various views of the second exemplary structure after formation of a contact-level dielectric layer and the lateral isolation trenches according to the second embodiment of the present disclosure. FIG. 17A is a vertical cross-sectional view. FIG. 17B is a top-down view. The vertical plane A-A′ in FIG. 17B is the cut plane of the vertical cross-sectional view of FIG. 17A. FIG. 17C is a vertical cross-sectional view along the vertical plane C-C′ in FIG. 17B.

FIGS. 18A-18E are sequential vertical cross-sectional views of the second exemplary structure during replacement of the in-process source-level material layers with source-level material layers, replacement of sacrificial material layers with electrically conductive layers, formation of isolation trench fill structures according to the second embodiment of the present disclosure.

FIGS. 19A-19C are various views of the second exemplary structure after formation of isolation trench fill structures according to the second embodiment of the present disclosure. FIG. 19A is a vertical cross-sectional view. FIG. 19B is a top-down view. The vertical plane A-A′in FIG. 19B is the cut plane of the vertical cross-sectional view of FIG. 19A. FIG. 19C is a vertical cross-sectional view along the vertical plane C-C′ in FIG. 19B.

FIGS. 20A-20C are sequential vertical cross-sectional views of a region of the second exemplary structure during formation of a replacement contact via cavity according to the second embodiment of the present disclosure. FIG. 20D is a magnified view of a portion of the second exemplary structure illustrated in FIG. 20C.

FIGS. 21A-21D are various views of the second exemplary structure after formation of layer contact via structures and drain contact via structures according to the second embodiment of the present disclosure. FIG. 21A is a vertical cross-sectional view. FIG. 21B is a top-down view. The vertical plane A-A′ in FIG. 21B is the cut plane of the vertical cross-sectional view of FIG. 21A. FIG. 21C is a vertical cross-sectional view along the vertical plane C-C′ in FIG. 21B. FIG. 21D is a magnified view of a portion of FIG. 21C.

FIGS. 22A and 22B are various views of a third exemplary structure after formation of in-process source-level material layers and first etch-stop plates according to a third embodiment of the present disclosure. FIG. 22A is a vertical cross-sectional view. FIG. 22B is a top-down view. The vertical plane A-A′ in FIG. 22B is the cut plane of the vertical cross-sectional view of FIG. 22A.

FIG. 23 is a vertical cross-sectional view of the third exemplary structure after formation of a first alternating stack of first insulating layers and first sacrificial material layers according to the third embodiment of the present disclosure.

FIGS. 24A and 24B are various views of the third exemplary structure after formation of first contact via cavities and first support via cavities according to the third embodiment of the present disclosure. FIG. 23A is a vertical cross-sectional view. FIG. 23B is a top-down view. The vertical plane A-A′ in FIG. 23B is the cut plane of the vertical cross-sectional view of FIG. 23A.

FIG. 25 is a vertical cross-sectional view of the third exemplary structure after formation of first sacrificial contact via fill material portions and first sacrificial support via fill material portions according to the third embodiment of the present disclosure.

FIG. 26 is a vertical cross-sectional view of the third exemplary structure after removal of the first sacrificial support via fill material portions according to the third embodiment of the present disclosure.

FIG. 27 is a vertical cross-sectional view of the third exemplary structure after performing a first via extension process that vertically extends the first support via cavities according to the third embodiment of the present disclosure.

FIG. 28 is a vertical cross-sectional view of the third exemplary structure after depositing a first insulating liner according to the third embodiment of the present disclosure.

FIG. 29 is a vertical cross-sectional view of the third exemplary structure after performing a second via extension process that vertically extends the first support via cavities according to the third embodiment of the present disclosure.

FIG. 30A is a vertical cross-sectional views of the third exemplary structure after formation of first finned dielectric support pillar structures according to the third embodiment of the present disclosure. FIG. 30B is a magnified view of a region of the third exemplary structure of FIG. 30A around a portion of a first finned dielectric support pillar structure.

FIGS. 31A and 31B are various views of the third exemplary structure after formation of first-tier sacrificial memory opening fill structures according to the third embodiment of the present disclosure. FIG. 31A is a vertical cross-sectional view. FIG. 31B is a top-down view. The vertical plane A-A′ in FIG. 31B is the cut plane of the vertical cross-sectional view of FIG. 31A.

FIG. 32 is a vertical cross-sectional view of the third exemplary structure after formation of an inter-tier dielectric layer, second etch-stop plates, and a second alternating stack of second insulating layers and second sacrificial material layers according to the third embodiment of the present disclosure.

FIGS. 33A and 33B are various views of the third exemplary structure after formation of second contact via cavities and second support via cavities according to the third embodiment of the present disclosure. FIG. 33A is a vertical cross-sectional view. FIG. 33B is a top-down view. The vertical plane A-A′ in FIG. 33B is the cut plane of the vertical cross-sectional view of FIG. 33A.

FIG. 34A is a vertical cross-sectional view of the third exemplary structure after formation of second sacrificial contact via fill material portions and second sacrificial support via fill material portions according to the third embodiment of the present disclosure.

FIG. 34B is a vertical cross-sectional view of the third exemplary structure after vertical extension of a subset of the second contact via cavities pillars according to the third embodiment of the present disclosure.

FIG. 35 is a vertical cross-sectional view of the third exemplary structure after reformation of second sacrificial contact via fill material portions according to the third embodiment of the present disclosure.

FIG. 36 is a vertical cross-sectional view of the third exemplary structure after removal of the second sacrificial support via fill material portions according to the third embodiment of the present disclosure.

FIG. 37 is a vertical cross-sectional view of the third exemplary structure after performing a first via extension process that vertically extends the second support via cavities and after formation of second insulating liners according to the third embodiment of the present disclosure.

FIG. 38 is a vertical cross-sectional view of the third exemplary structure after performing a second via extension process that vertically extends the second support via cavities and after formation of second finned dielectric support pillar structures according to the third embodiment of the present disclosure.

FIGS. 39A and 39B are various views of the third exemplary structure after formation of memory openings according to the third embodiment of the present disclosure. FIG. 39A is a vertical cross-sectional view. FIG. 39B is a top-down view. The vertical plane A-A′ in FIG. 39B is the cut plane of the vertical cross-sectional view of FIG. 39A.

FIG. 40 is a vertical cross-sectional views of the third exemplary structure after formation of memory opening fill structures according to the third embodiment of the present disclosure.

FIGS. 41A and 41B are various views of the third exemplary structure after formation of a contact-level dielectric layer and lateral isolation trenches according to the third embodiment of the present disclosure. FIG. 41A is a vertical cross-sectional view. FIG. 41B is a top-down view. The vertical plane A-A′ in FIG. 41B is the cut plane of the vertical cross-sectional view of FIG. 41A.

FIG. 42 is a vertical cross-sectional view of the third exemplary structure after replacement of the in-process source-level material layers with source-level material layers according to the third embodiment of the present disclosure.

FIG. 43A is a vertical cross-sectional view of the third exemplary structure after replacement of sacrificial material layers with electrically conductive layers and formation of isolation trench fill structures according to the third embodiment of the present disclosure. FIG. 43B is a magnified view of a region of the third exemplary structure of FIG. 43A around a portion of a first finned dielectric support pillar structure.

FIG. 44 is a vertical cross-sectional views of the third exemplary structure after formation of replacement contact via cavities according to the third embodiment of the present disclosure.

FIG. 45 is a vertical cross-sectional views of the third exemplary structure after formation of insulating spacers according to the third embodiment of the present disclosure.

FIGS. 46A-46D are various views of the third exemplary structure after formation of layer contact via structures and drain contact via structures according to the third embodiment of the present disclosure. FIGS. 46A and 46D are vertical cross-sectional views of alternative configurations of the third exemplary structure. FIG. 46B is a top-down view. The vertical plane A-A′ in FIG. 46B is the cut plane of the vertical cross-sectional view of FIG. 46A. FIG. 46C is a magnified view of a portion of the third exemplary structure illustrated in FIG. 46B.

### DETAILED DESCRIPTION

As discussed above, the embodiments of the present disclosure are directed to stairless three-dimensional memory devices including layer contact via structures (e.g., word line contact via structures) overlying various support features and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many a number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

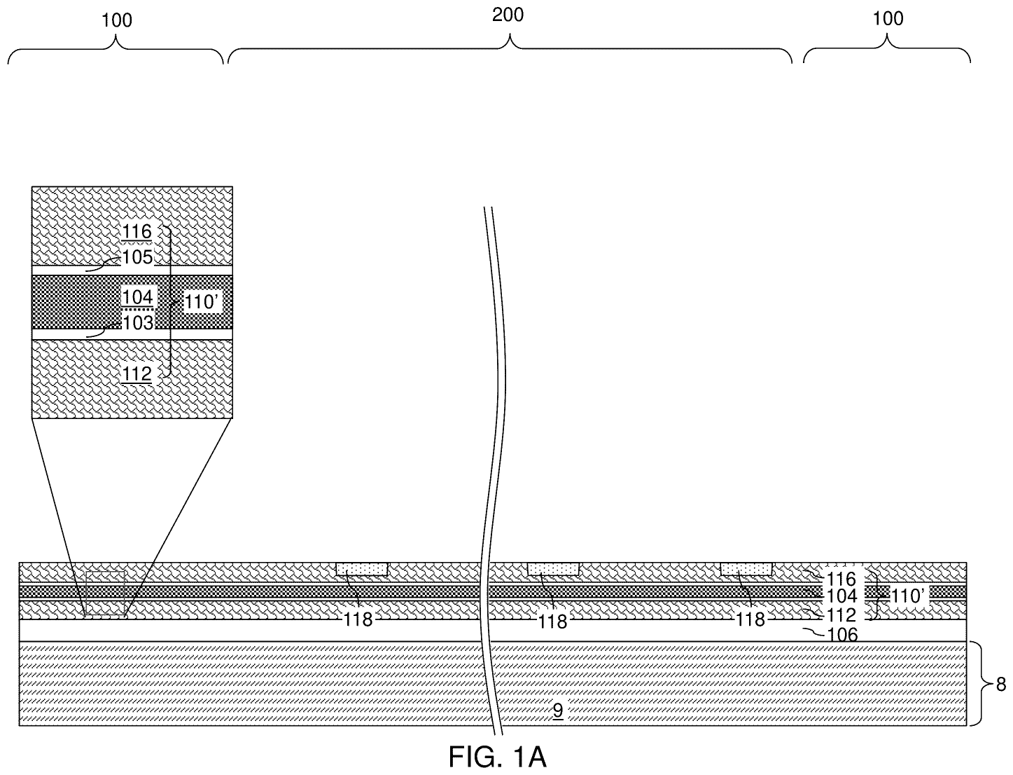

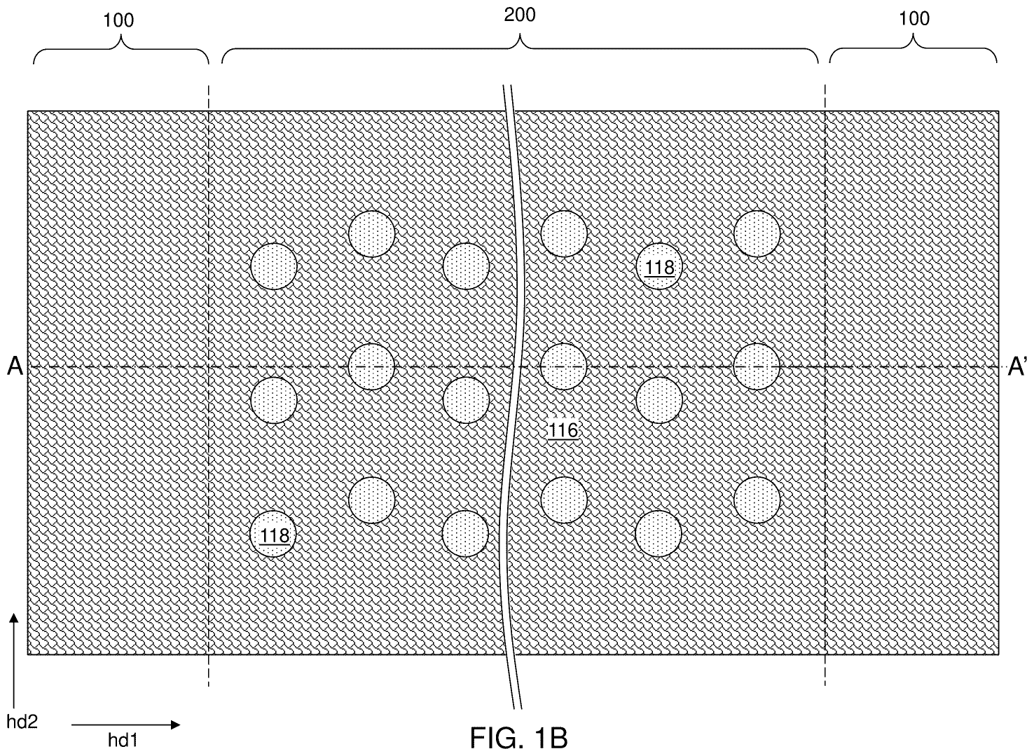

Referring to FIGS. 1A and 1B, a first exemplary structure according to a first embodiment of the present disclosure includes a substrate 8. The substrate 8 may be a carrier substrate that is subsequently removed. The substrate 8 may comprise a semiconductor material (e.g., a silicon wafer), an insulating material, a conductive material, or a combination thereof. The substrate 8 comprises a material that can provide structural support to material portions that are subsequently formed thereupon. The substrate 8 comprises a substrate material layer 9 at least at an upper portion thereof. In one embodiment, the substrate material layer 9 may be a semiconductor material layer, such as a silicon layer or a doped well in a silicon wafer. In another embodiment, the substrate material layer 9 may be an insulating layer, such as silicon oxide. An optional driver circuit (not shown) may be formed on the substrate 8. The driver circuit may be used to drive memory device to be subsequently formed over the substrate 8, as will be described below.

An optional insulating material layer can be formed on a top surface of the substrate 8. The insulating material layer can be subsequently employed as a stopping material layer for a process that removes the substrate 8, and is herein referred to as a planar insulating layer 106. If a polishing process, such as a chemical mechanical polishing process is employed to subsequently remove the substrate 8, the planar insulating layer 106 may be subsequently employed as a polishing planar insulating layer. If an etch process such as a wet etch process is employed to subsequently remove the substrate 8, the planar insulating layer 106 may be subsequently employed as an etch stop material layer. In one embodiment, the planar insulating layer 106 comprises a dielectric material such as undoped silicate glass, a doped silicate glass, or silicon nitride. The thickness of the planar insulating layer 106 may be in a range from 50 nm to 600 nm, such as from 100 nm to 300 nm, although lesser and greater thicknesses may also be employed.

Optional in-process source-level material layers 110′ can be formed over the substrate 8 (and over the planar insulating layer 106, if present). The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116. In an alternative embodiment, the in-process source-level material layers 110′ may be omitted. In the alternative embodiment, the substrate 8 may be removed after forming a memory device, and a top source contact may be formed on exposed portions of the vertical semiconductor channels of the memory device.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

The first exemplary structure comprises a pair of memory array regions 100 in which a three-dimensional array of memory elements is to be subsequently formed, and a contact region 200 in which layer contact via structures contacting word lines are to be subsequently formed. In one embodiment, a pair of memory array regions 100 can be laterally spaced from each other along a first horizontal direction (e.g., word line direction) hd1, and the contact region 200 can be provided between the pair of memory array regions 100.

Optional etch-stop plates 118 can be formed in an upper portion of the in-process source-level material layers 110′. For example, a photoresist layer (not shown) can be applied over the top surface of the upper source-level semiconductor layer 116, and can be lithographically patterned to form a two-dimensional array of openings in the contact region 200. The openings in the photoresist layer can be formed at locations at which layer contact via structures are to be subsequently formed. The lateral extent of each opening in the photoresist layer in a plan view (such as a top-down view) may be greater in the size of a respective layer contact via structure to be subsequently formed at the same location. In an illustrative example, the maximum lateral extent (such as a diameter) of each opening in the photoresist layer may be in the range from 200 nm to 1,000 nm, such as from 300 nm to 600 nm, although lesser and greater dimensions may also be employed.

An anisotropic etch process can be performed to transfer the pattern of the openings into an upper portion of the upper source-level semiconductor layer 116. A two-dimensional array of recess regions can be formed in the upper portion of the upper source-level semiconductor layer 116. The depth of the two-dimensional array of recess regions may be in the range from 5% to 90%, such as from 10% to 50%, of the thickness of the upper source-level semiconductor layer 116. The photoresist layer can be subsequently removed, for example, by ashing. A sacrificial fill material can be deposited in the two-dimensional array of recess regions. The sacrificial fill material comprise a material that can be subsequently removed selective to the material of the upper source-level semiconductor layer 116. For example, the sacrificial fill material may comprise amorphous carbon, diamond-like carbon, or silicon carbide. Excess portions of the sacrificial fill material may be removed from above the horizontal plane including the top surface of the upper source-level semiconductor layer 116 by performing a planarization process. The planarization process may comprise a chemical mechanical polishing process and/or a recess etch process. Each remaining portion of the sacrificial fill material that remains in a respective recess region constitutes an etch-stop plate 118. The top surfaces of the etch-stop plates 118 may be formed within the horizontal plane including the top surface of the upper source-level semiconductor layer 116.

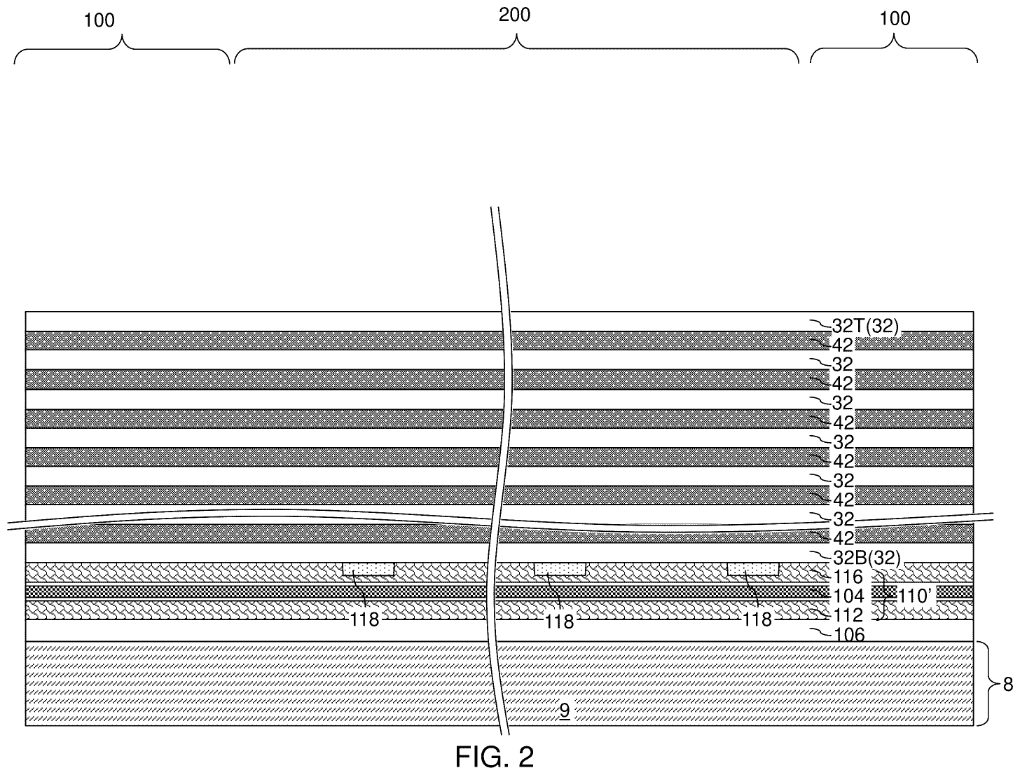

Referring to FIG. 2, an alternating stack of first material layers and second material layers can be formed over substrate 8 (and over the in-process source-level material layers 110′ if present). The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the substrate 8 (and over the in-process source-level material layers 110′, if present). The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the substrate 8 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness that is different from that of the other insulating layers 32. In one embodiment, each of the insulating layers 32 may have a first thickness, and each of the sacrificial material layers 42 may have a second thickness.

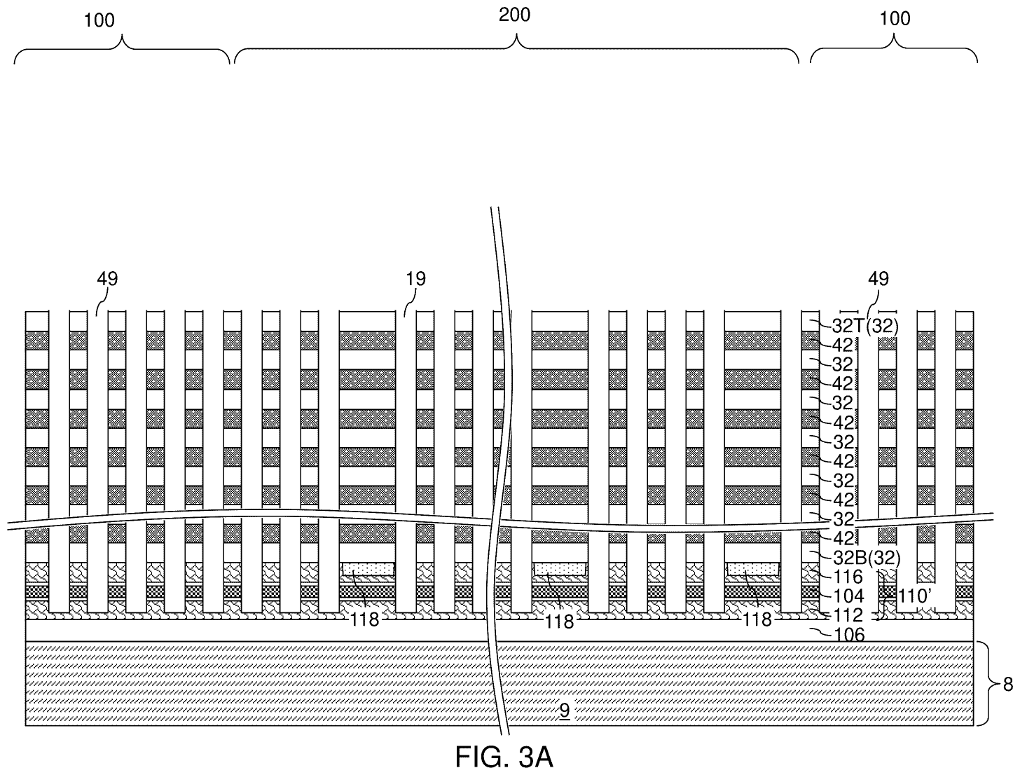

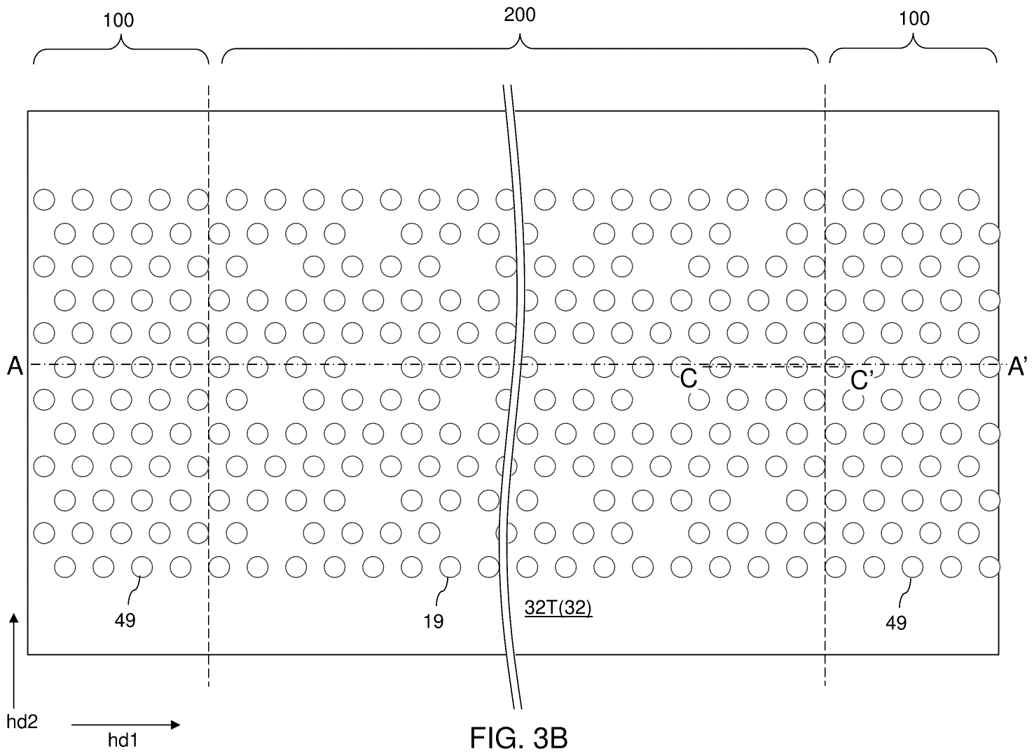

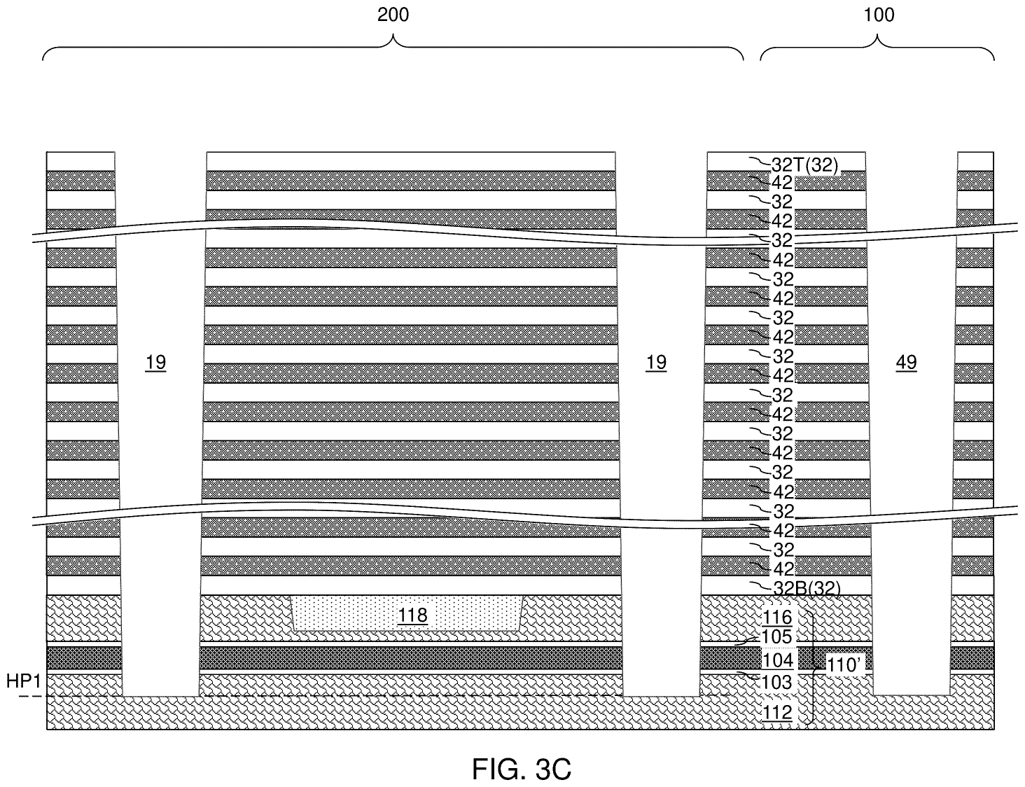

Referring to FIGS. 3A-3C, a lithographic material stack (not shown) including at least a photoresist layer can be formed over the topmost insulating layer 32T, and can be lithographically patterned to form discrete openings therein. The discrete openings in the photoresist layer can be formed in the memory array regions 100 and in the contact region 200. In one embodiment, the memory array regions 100 are laterally spaced apart from each other along the first horizontal direction (e.g., word line direction) hd1, and the contact region 200 can be located between the memory array regions 100. In an alternative embodiment, contact regions 200 may be located on opposite lateral ends of one memory array region 100 along the first horizontal direction hd1. The discrete openings in the photoresist layer can be formed within rectangular areas (e.g., memory block areas) that are laterally spaced apart from each other along a second horizontal direction (e.g., bit line direction) hd2 that is perpendicular to the first horizontal direction hd1. Elongated strip-shaped areas that are free of any opening can be provided between each neighboring pair of rectangular areas (e.g., between memory block areas) in which the openings are patterned in the photoresist layer.

The pattern in the lithographic material stack can be transferred through the alternating stack (32, 42) by at least one anisotropic etch that employs the patterned lithographic material stack as an etch mask. Portions of the alternating stack (32, 42) underlying the openings in the patterned lithographic material stack are etched to form memory openings 49 and support openings 19. As used herein, a “memory opening” refers to a structure in which memory elements, such as a memory stack structure, is subsequently formed. As used herein, a “support opening” refers to a structure in which a support structure (such as a dielectric support pillar structure) that mechanically supports other elements is subsequently formed. The memory openings 49 are formed in the memory array regions 100, and the support openings 19 are formed in the contact region 200.

The chemistry of the anisotropic etch process employed to etch through the materials of the alternating stack (32, 42) can alternate to optimize etching of the first and second materials in the alternating stack (32, 42). The anisotropic etch can be, for example, a series of reactive ion etches. The sidewalls of the memory openings 49 and the support openings 19 can be substantially vertical, or can be tapered. The patterned lithographic material stack can be subsequently removed, for example, by ashing.

Each of the memory openings 49 can vertically extend through the alternating stack (32, 42) and into the in-process source-level material layers 110′ (if present) or into the substrate 8 (in case the in-process source-level material layers 110′ are not employed). In one embodiment, bottom surfaces of the memory openings 49 may be formed within the lower source-level semiconductor layer 112 or at an interface between the lower source-level semiconductor layer and the planar insulating layer 106. In this case, the memory openings 49 and the support openings 19 may vertically extend through the upper source-level semiconductor layer 116, the upper sacrificial liner 105, the source-level sacrificial layer 104, the lower sacrificial liner 103, and an upper portion of the lower source-level semiconductor layer 112.

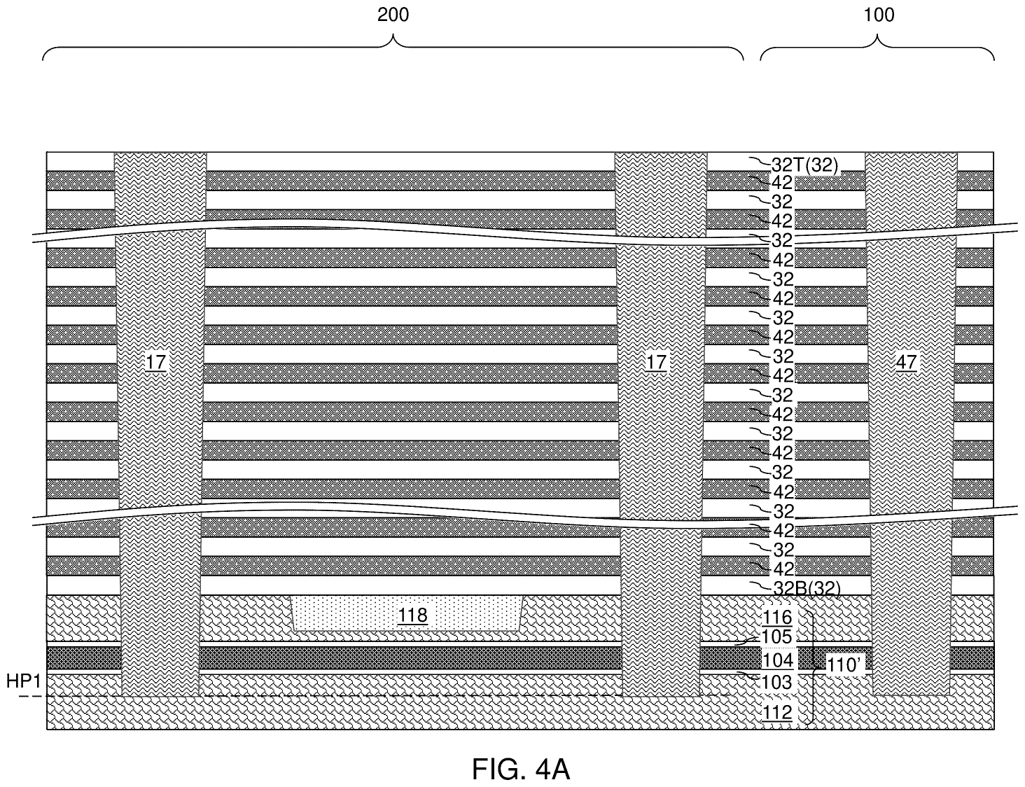

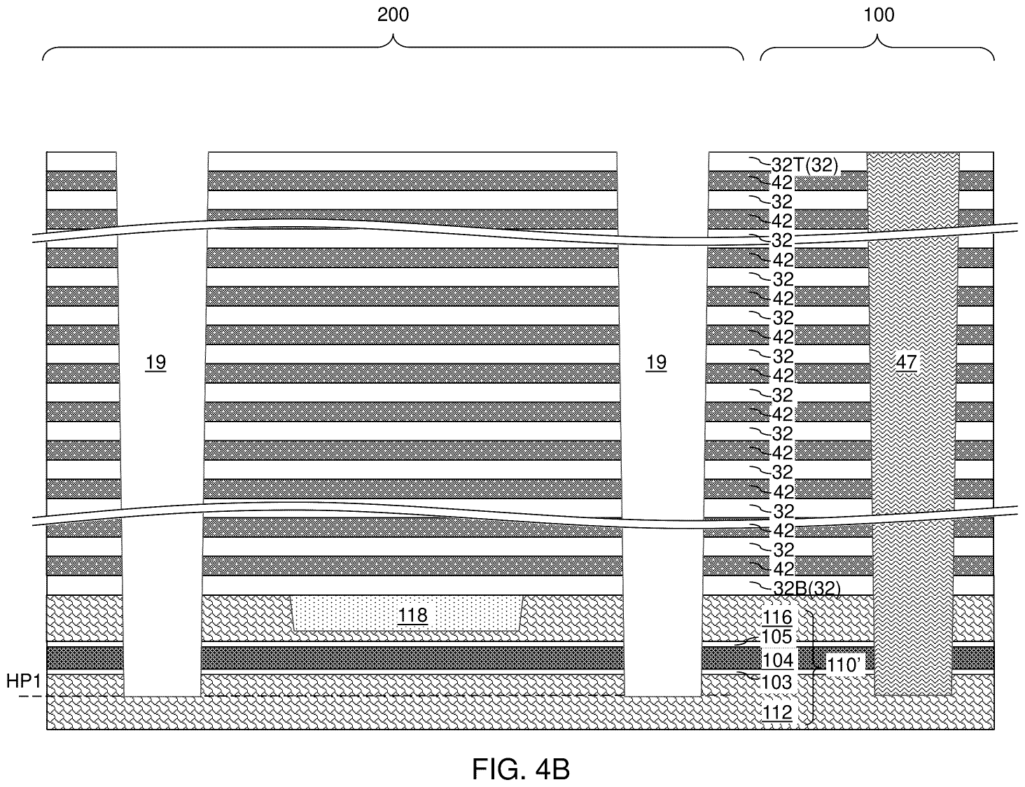

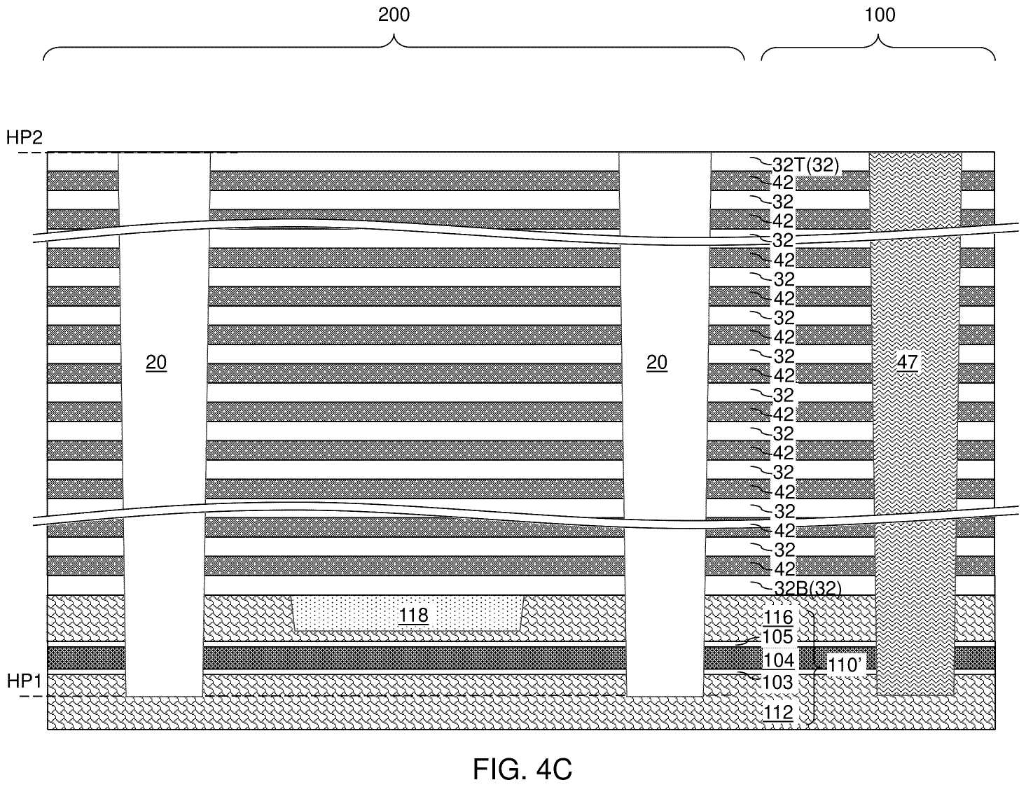

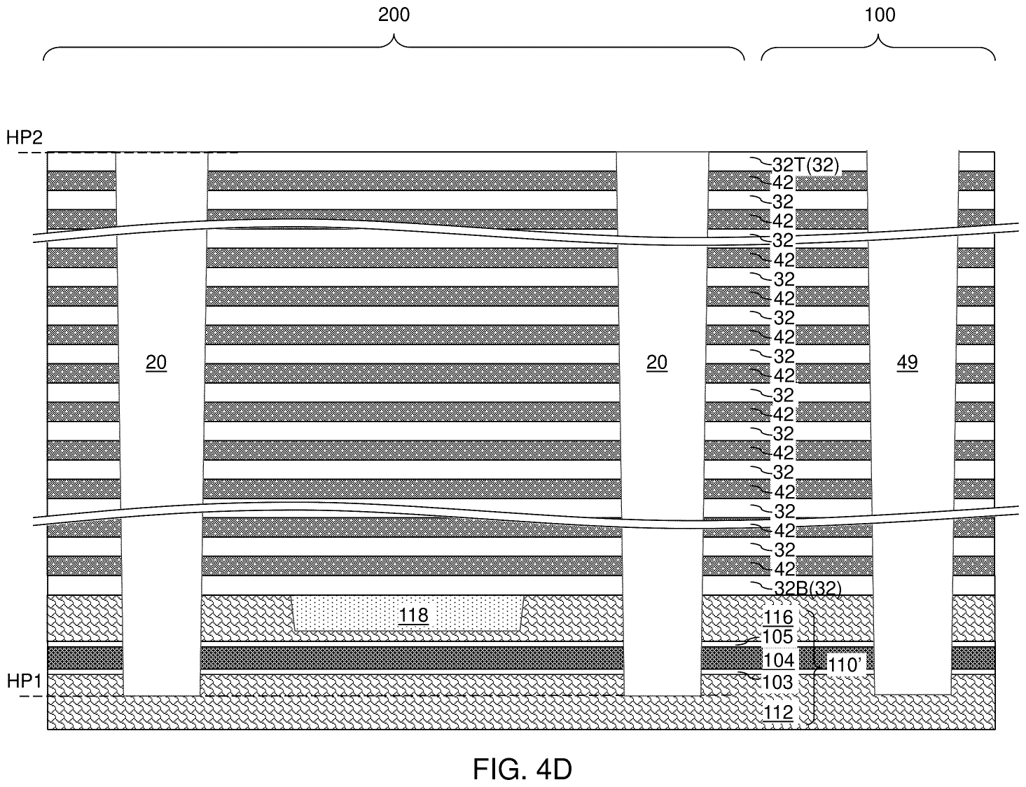

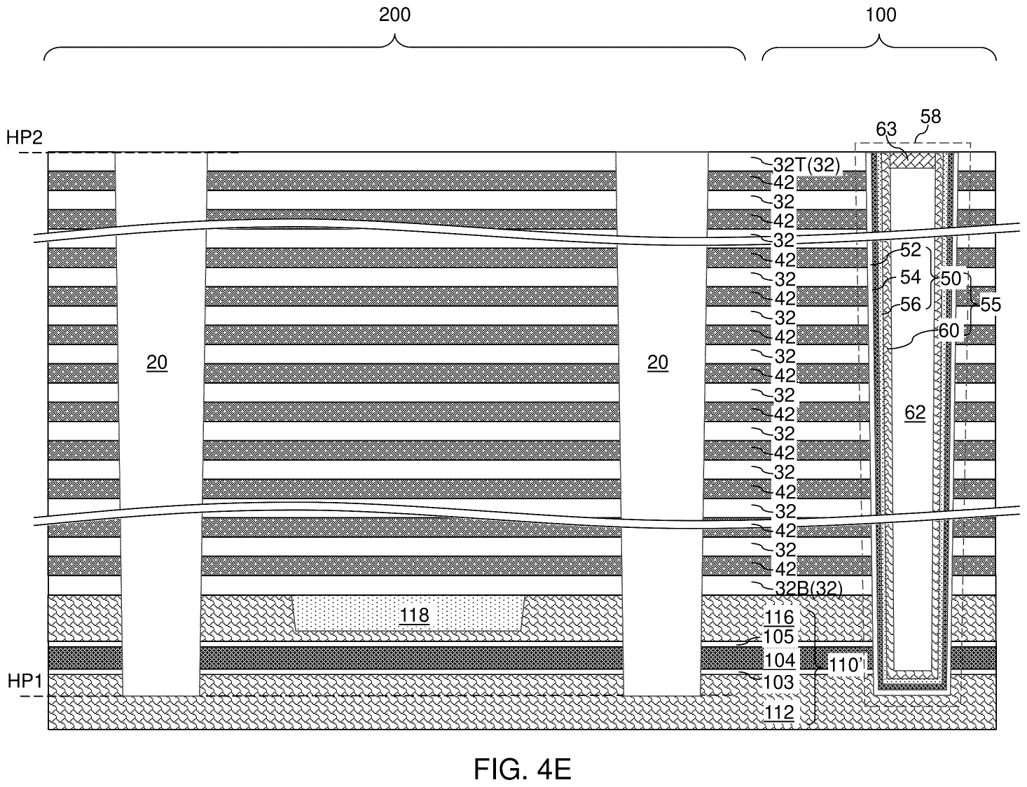

FIGS. 4A-4E are sequential vertical cross-sectional views of a region of the first exemplary structure during formation of dielectric support pillar structures 20 and memory opening fill structures 58 according to the first embodiment of the present disclosure.

Referring to FIG. 4A, a sacrificial fill material can be deposited in the memory openings 49 and the support openings 19. The sacrificial fill material may be any material that may be removed selective to the materials of the insulating layers 32, the sacrificial material layers 42, and the materials of the in-process source-level material layers 110′. For example, the sacrificial fill material may comprise a carbon-based material such as amorphous carbon or diamond-like carbon, a semiconductor material such as a silicon-germanium alloy, polysilicon or amorphous silicon, or a dielectric material such as borosilicate glass or organosilicate glass. Optionally, a thin etch stop liner (not shown) may be employed to facilitate subsequent selective removal of the sacrificial fill material. Excess portions of the sacrificial fill material may be removed from above the horizontal plane including the top surface of the topmost insulating layer 32T. Each remaining portion of the sacrificial fill material filling a memory opening 49 constitutes a sacrificial memory opening fill structure 47. Each remaining portion of the sacrificial fill material filling a support opening 19 constitutes a sacrificial support opening fill structure 17.

Referring to FIG. 4B, a photoresist layer (not shown) can be applied over the alternating stack (32, 42), and can be lithographically patterned to cover the sacrificial memory opening fill structures 47 while not covering the sacrificial support opening fill structures 17. The sacrificial support opening fill structures 17 can be removed by removing the sacrificial fill material within the areas that are not covered by the photoresist layer. The sacrificial fill material may be removed, for example, by ashing or by performing an etch process such as a wet etch process. Cavities are formed in the support openings 19. The photoresist layer can be removed, for example, by ashing.

Referring to FIG. 4C, a dielectric fill material such as undoped silicate glass (i.e., silicon oxide) or a doped silicate glass can be deposited in the support openings 19 employing a conformal deposition process such as a chemical vapor deposition process. Portions of the dielectric fill material that overlie the topmost insulating layer 32T may be removed, for example, by chemical mechanical polishing or by an etch back process, such as a wet etch process employing dilute hydrofluoric acid. Remaining portions of the dielectric fill material that fill the support openings 19 comprise dielectric support pillar structures 20, which provide structural support to the first exemplary structure during a subsequent processing step in which the sacrificial material layers 42 are removed.

In one embodiment, each of the dielectric support pillar structures 20 consists essentially of a dielectric fill material, such as silicon oxide. In one embodiment, bottom surfaces of the dielectric support pillar structures 20 may be formed within a first horizontal plane HP1 located between a top surface and a bottom surface of the lower source-level semiconductor layer 112. In one embodiment, top surfaces of the dielectric support pillar structures 20 may be formed within a second horizontal plane HP2 that contains the top surface of the topmost insulating layer 32T.

Referring to FIG. 4D, the sacrificial fill material of the sacrificial memory opening fill structures 47 can be removed selective to the materials of the insulating layers 32, the sacrificial material layers 42, the dielectric support pillar structures 20, and the in-process source-level material layers 110′. The sacrificial memory opening fill structures 47 may be removed by ashing or by performing an etch process such as a wet etch process. Cavities are formed in volumes of the memory openings 49 from the which the sacrificial memory opening fill structures 47 are removed.

Referring to FIG. 4E, memory opening fill structures 58 are formed in the memory openings 49. For example, a layer stack including a continuous blocking dielectric layer, a continuous memory material layer and a continuous semiconductor channel material layer can be formed in the memory openings 49 and over the topmost insulating layer 32T.

The continuous blocking dielectric layer can include a single dielectric material layer or a stack of a plurality of dielectric material layers. In one embodiment, the continuous blocking dielectric layer can include a dielectric metal oxide layer consisting essentially of a dielectric metal oxide. In one embodiment, the continuous blocking dielectric layer includes aluminum oxide. In one embodiment, the continuous blocking dielectric layer can include multiple dielectric metal oxide layers having different material compositions. Alternatively or additionally, the continuous blocking dielectric layer can include a dielectric semiconductor compound such as silicon oxide, silicon oxynitride, silicon nitride, or a combination thereof. In one embodiment, the continuous blocking dielectric layer can include silicon oxide. The thickness of the continuous blocking dielectric layer can be in a range from 3 nm to 20 nm, although lesser and greater thicknesses can also be employed. Alternatively, the continuous blocking dielectric layer can be omitted, and a backside blocking dielectric layer can be formed after formation of backside recesses on surfaces of memory films to be subsequently formed.

The continuous memory material layer may comprise any memory material that can store a data bit. The data bit may be stored in the form of electrical charges trapped therein, in the form of a resistive state of a material due to changes in the material phase, resistivity or ferroelectric property. In one embodiment, continuous memory material layer may comprise a charge storage layer including a dielectric charge trapping material, which can be, for example, silicon nitride. Alternatively, the continuous memory material layer can include a conductive material such as doped polysilicon or a metallic material that is patterned into multiple electrically isolated portions (e.g., floating gates), for example, by being formed within lateral recesses into sacrificial material layers 42. In one embodiment, the continuous memory material layer includes a silicon nitride layer. In one embodiment, the sacrificial material layers 42 and the insulating layers 32 can have vertically coincident sidewalls, and the continuous memory material layer can be formed as a single continuous layer.

The continuous tunneling dielectric layer may comprise a charge-tunneling dielectric material through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The continuous tunneling dielectric layer can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the continuous tunneling dielectric layer can include a stack of a first silicon oxide layer, a silicon oxynitride layer, and a second silicon oxide layer, which is commonly known as an ONO stack. In one embodiment, the continuous tunneling dielectric layer can include a silicon oxide layer or a silicon oxynitride layer. The thickness of the continuous tunneling dielectric layer can be in a range from 2 nm to 20 nm, although lesser and greater thicknesses can also be employed.

The continuous semiconductor channel material layer includes a semiconductor material such as at least one elemental semiconductor material, at least one III-V compound semiconductor material, at least one II-VI compound semiconductor material, at least one organic semiconductor material, or other semiconductor materials known in the art. In one embodiment, the continuous semiconductor channel material layer includes amorphous silicon or polysilicon. The continuous semiconductor channel material layer can have a doping of a first conductivity type. The continuous semiconductor channel material layer can be formed by a conformal deposition method such as low pressure chemical vapor deposition (LPCVD). The thickness of continuous semiconductor channel material layer can be in a range from 2 nm to 10 nm, although lesser and greater thicknesses can also be employed.

A dielectric fill material such as silicon oxide can be deposited in remaining cavities in the memory openings 49, and can be vertically recessed such that top surfaces of remaining portions of the dielectric fill material are formed at, or about, the horizontal plane including a bottom surface of the topmost insulating layer 32T. Each remaining portion of the dielectric fill material constitutes a dielectric core 62.

A doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Portions of the deposited semiconductor material having a doping of the second conductivity type, the continuous semiconductor channel material layer, the continuous tunneling dielectric layer, the continuous memory material layer, and the continuous blocking dielectric layer that overlie the second horizontal plane HP2 can be removed by a planarization process. The planarization process may employ, for example, a chemical mechanical polishing (CMP) process and/or a recess etch process.

Each remaining portion of the doped semiconductor material having a doping of the second conductivity type constitutes a drain region 63. Each remaining portion of the continuous semiconductor channel material layer (which has a doping of the first conductivity type) constitutes a vertical semiconductor channel 60. Each remaining portion of the continuous tunneling dielectric layer constitutes a tunneling dielectric layer 56. Each remaining portion of the continuous memory material layer constitutes a memory material layer 54. Each remaining portion of the continuous blocking dielectric layer constitutes a blocking dielectric layer 52. Each contiguous set of a blocking dielectric layer 52, a memory material layer 54, and a tunneling dielectric layer 56 collectively constitutes a memory film 50, which can store electrical charges or ferroelectric polarization with a macroscopic retention time. As used herein, a macroscopic retention time refers to a retention time suitable for operation of a memory device as a permanent memory device such as a retention time in excess of 24 hours. In some embodiments, a blocking dielectric layer 52 may not be present in the memory film 50 at this step, and a backside blocking dielectric layer may be subsequently formed after formation of backside recesses.

Each combination of a memory film 50 and a vertical semiconductor channel 60 within a memory opening 49 constitutes a memory stack structure 55. The memory stack structure 55 is a combination of a vertical semiconductor channel 60, a tunneling dielectric layer 56, a plurality of memory elements as embodied as portions of the memory material layer 54, and an optional blocking dielectric layer 52. An entire set of material portions that fills a memory opening 49 is herein referred to as a memory opening fill structure 58.

Generally, a memory opening fill structure 58 can be formed in each memory opening 49. The memory opening fill structure 58 comprises a vertical stack of memory elements (such as portions of a memory material layer 54) located at levels of the sacrificial material layers 42. The memory opening fill structure 58 comprises an optional blocking dielectric layer 52, a memory material layer 54, an optional tunneling dielectric layer 56, and a vertical semiconductor channel 60. A tunneling dielectric layer 56 may laterally surround the vertical semiconductor channel 60. The memory material layer 54 can laterally surround the tunneling dielectric layer 56. In case a blocking dielectric layer 52 is present in each memory opening fill structure 58, the blocking dielectric layer 52 may be formed on a sidewall of a memory opening 49, and the vertical stack of memory elements (which may comprise portions of the memory material layer 54) may be formed on the blocking dielectric layer 52. In one embodiment, the vertical stack of memory elements comprises portions of a charge storage layer (comprising the memory material layer 54) located at the levels of the sacrificial material layers 42.

While an embodiment is described in which a single tier of insulating layers 32 and sacrificial material layers 42 is formed over the substrate 8, in other embodiments two or more tiers of insulating layers 32 and sacrificial material layers 42 may be formed over the substrate 8. Furthermore, while an embodiment is described in which the memory opening fill structures 58 are formed after formation of the dielectric support pillar structures 20, the order of the set of processing steps described with reference to FIGS. 4B and 4C and the set of processing steps described with reference to FIGS. 4D and 4E may be reversed. In this case, the memory opening fill structures 58 may be formed prior to formation of the dielectric support pillar structures 20. Generally, the dielectric support pillar structures 20 may be formed prior to or after formation of the memory opening fill structure 58.

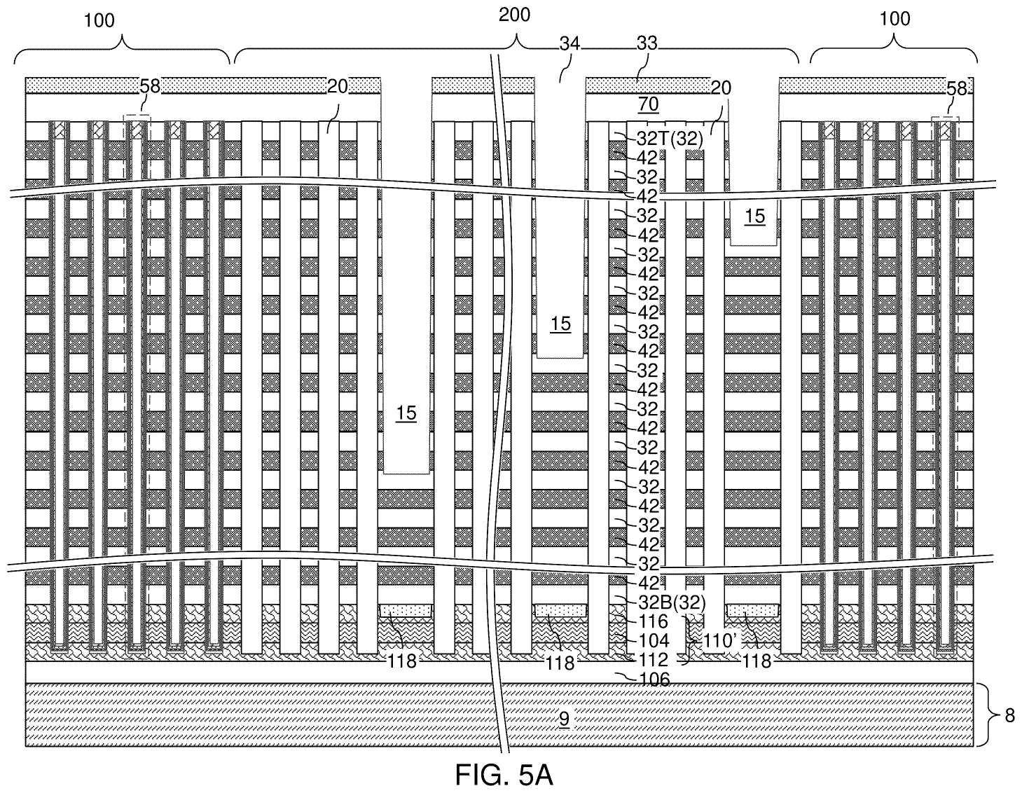

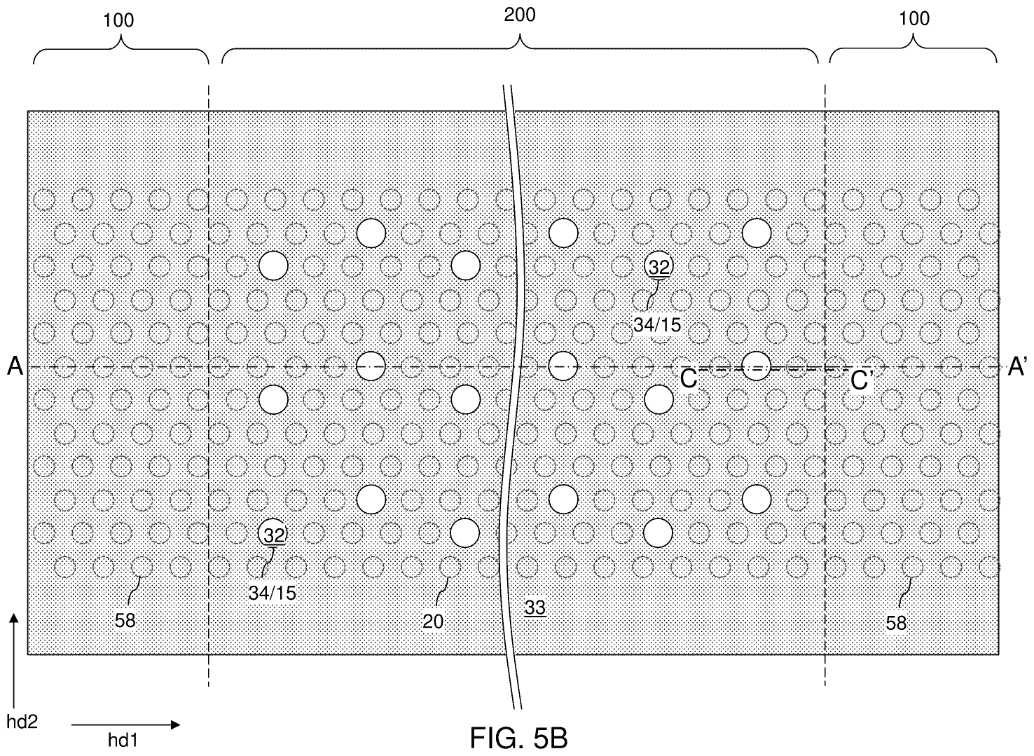

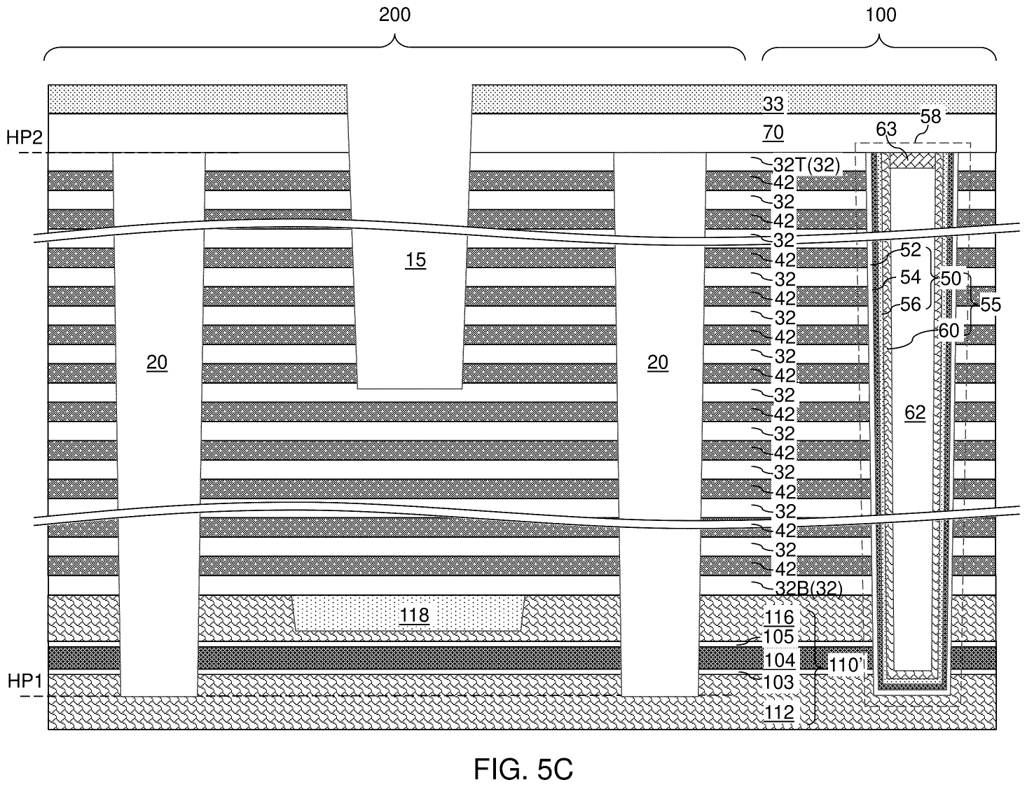

Referring to FIGS. 5A-5C, an insulating cap layer 70 can be formed over the alternating stack (32, 42), the memory opening fill structures 58, and the dielectric support pillar structures 20. The insulating cap layer 70 comprises an insulating material, such as silicon oxide, and may have a thickness in a range from 20 nm to 300 nm, although lesser and greater thicknesses may also be employed.

Subsequently, contact via cavities 15 having different depths can be formed in the contact region 200 through the insulating cap layer 70 and a respective subset of layers within the alternating stack (32, 42). Each of the contact via cavities 15 may be formed in an area that is not occupied by any dielectric support pillar structure 20, but is laterally surrounded by a set of neighboring dielectric support pillar structures 20 in a plan view (such as a top-down view). In one embodiment, the support pillar structures 20 may be formed at a first subset of the lattice sites (e.g., rectangular lattice sites) of a two-dimensional periodic array, and the contact via cavities 15 may be formed at a second subset of the lattice sites of the two-dimensional periodic array. In one embodiment, each contact via cavity 15 may be laterally surrounded by a set of neighboring dielectric support pillar structures 20. For example, each contact via cavity 15 may be laterally surrounded by six of neighboring dielectric support pillar structures 20 located at vertices of a hexagonal lattice centered on the respective contact via cavity 15. Each of the contact via cavities 15 vertically extends through a respective subset of the layers within the alternating stack (32, 42). Bottom surfaces of the contact via cavities 15 may comprise physically exposed to horizontal surface segments of the insulating layers 32. In one embodiment, each insulating layer 32 within the alternating stack (32, 42) other than the bottommost insulating layer 32B may have a respective horizontal surface segment that is exposed to a respective overlying contact via cavity 15.

The contact via cavities 15 may be formed using any suitable methods. One embodiment method of forming the contact via cavities 15 is described below. In this embodiment, a patterned hard mask layer 33 may be formed over the alternating stack (32, 42). The patterned hard mask layer 33 may comprise any etch mask material that can withstand ashing processes that are subsequently employed to remove patterned photoresist material layers. The patterned hard mask layer 33 may comprise a metallic material (such as TiN), a dielectric metal oxide material, or a semiconductor material, such as amorphous silicon or silicon carbide. The patterned hard mask layer 33 may be formed by depositing a blanket (unpatterned) hard mask material layer, by forming a photoresist material layer (not illustrated) over the blanket hard mask material layer, by lithographically patterning the photoresist material layer to form openings in areas in which contact via cavities 15 are to be subsequently formed, and by transferring the pattern in the patterned photoresist layer through the blanket hard mask material layer by performing an anisotropic etch process. An array of openings 34 is formed through the patterned hard mask layer 33. The photoresist material can be subsequently removed.

A series photoresist layers, in combination with a series of anisotropic etch processes can be subsequently employed to sequentially cover a respective subset of the openings 34 in the patterned hard mask layer 33 and to extend the pattern of the openings 34 in the patterned hard mask layer 33 through a respective number of pairs of an insulating layer 32 and a sacrificial material layer 42. For example, about one half of all of the openings 34 through the patterned hard mask layer 33 can be covered by a first photoresist layer, and one insulating layer 32 and one sacrificial material layer 42 can be etched by performing an anisotropic etch process underneath the openings through the unmasked portions of the sacrificial material layer. The first photoresist layer can be subsequently removed.

About one half of all of the openings 34 through the patterned hard mask layer 33 can be covered by a second photoresist layer. About one half of the unmasked openings 34 are among the openings 34 previously covered by the first photoresist layer, and the remainder of the unmasked openings 34 are among the openings 34 previously unmasked by the first photoresist layer. Two pairs of an insulating layer 32 and a sacrificial material layer 42 (i.e., two insulating layers 32 and two sacrificial material layers 42) can be etched by performing an anisotropic etch process underneath the openings 34 through the unmasked portions of the second sacrificial material layer 42. The second photoresist layer can be subsequently removed.

The above steps can be repeated up to the N-th photoresist layer and an N-th anisotropic etch process etching 2^{(N-1)} pairs of an insulating layer 32 and a sacrificial material layer 42. N may be any suitable integer, such as an integer from 4 to 32. Contact via cavities 15 that may have up to 2^{N} different depths can be formed in the contact region 200. In an illustrative example, if N is 8, the total number of sacrificial material layers 42 may be 28, i.e., 256. A plurality of contact via cavities 15 may vertically extend through a respective subset of the sacrificial material layers 42. In one embodiment, each insulating layer 32 other than the bottommost insulating layer 32B may have a respective top surface segment that is physically exposed to a respective one of the contact via cavities 15.

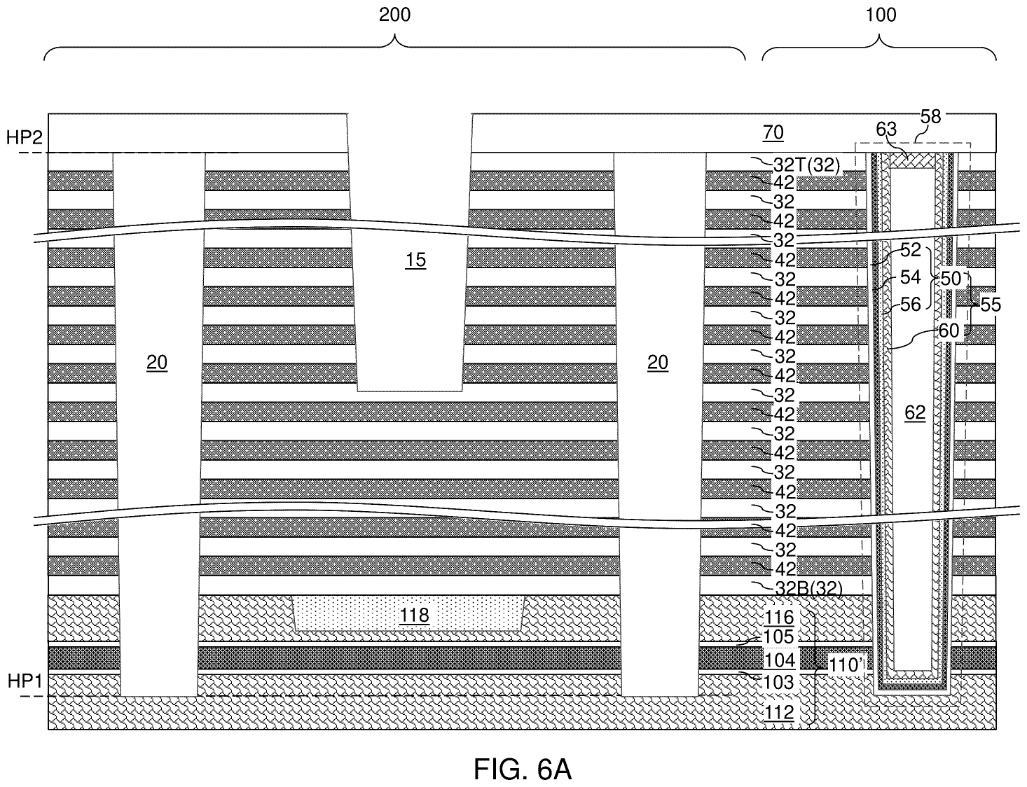

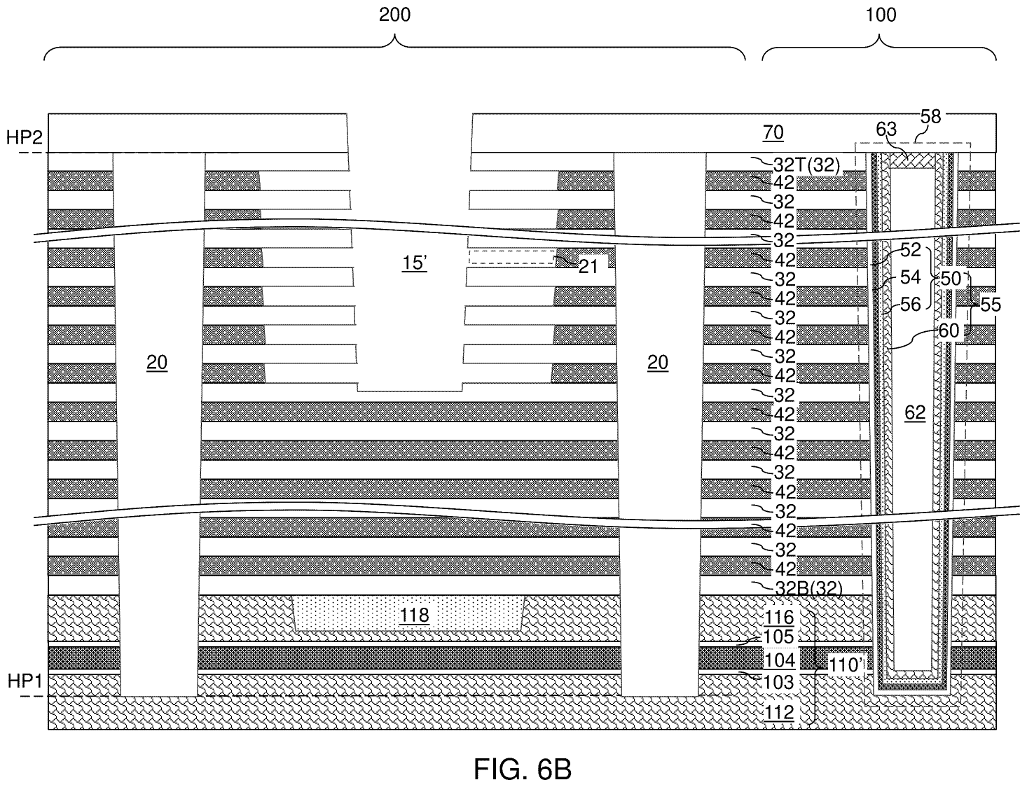

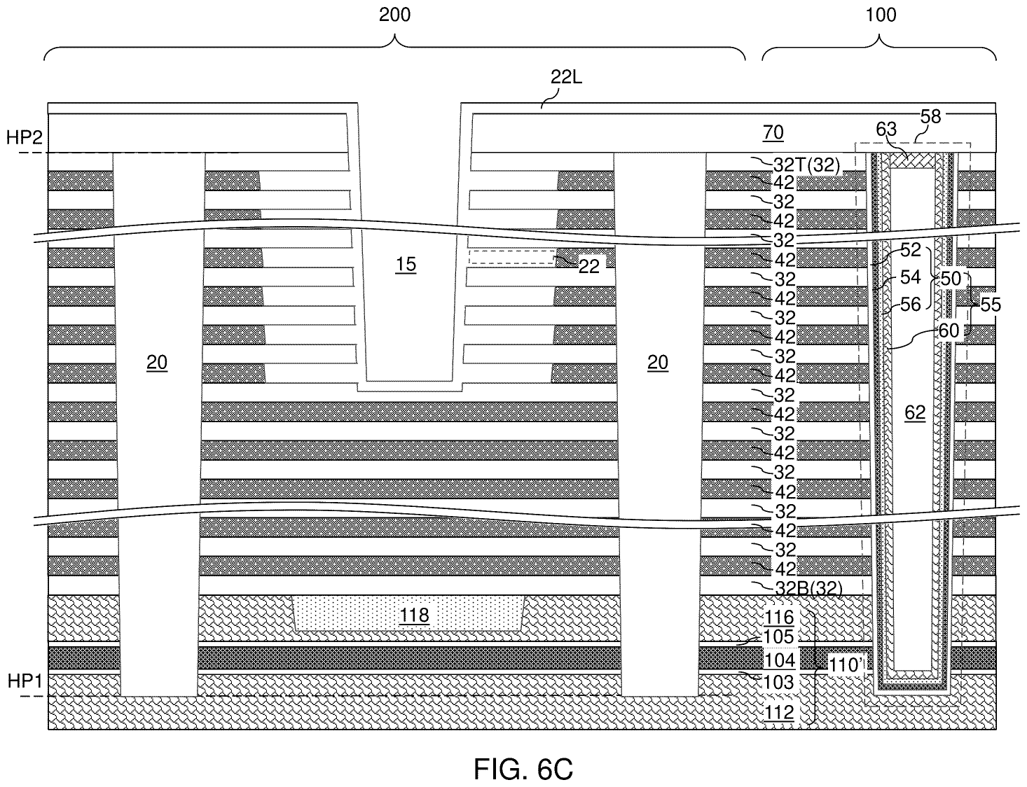

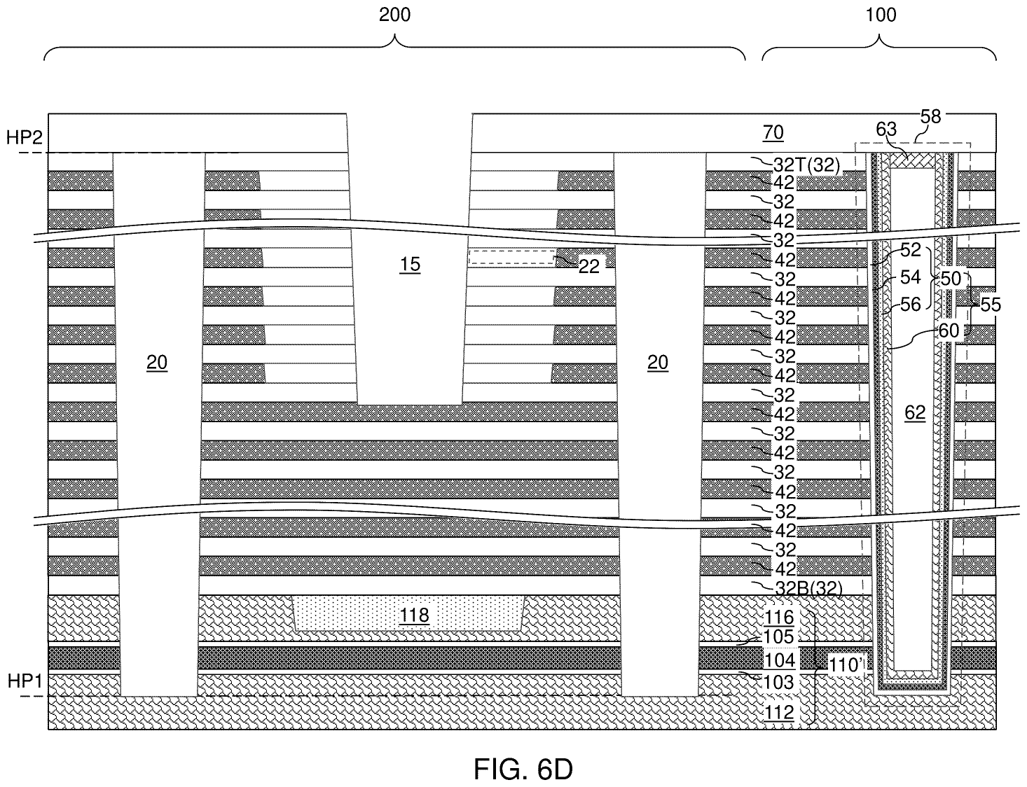

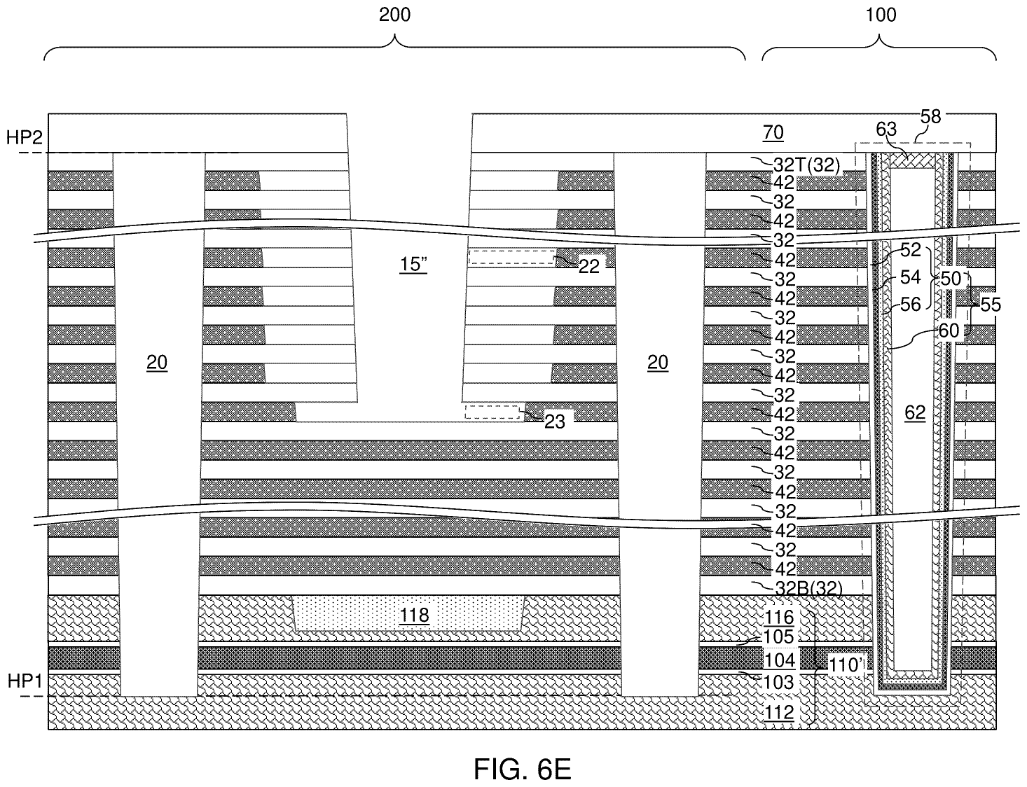

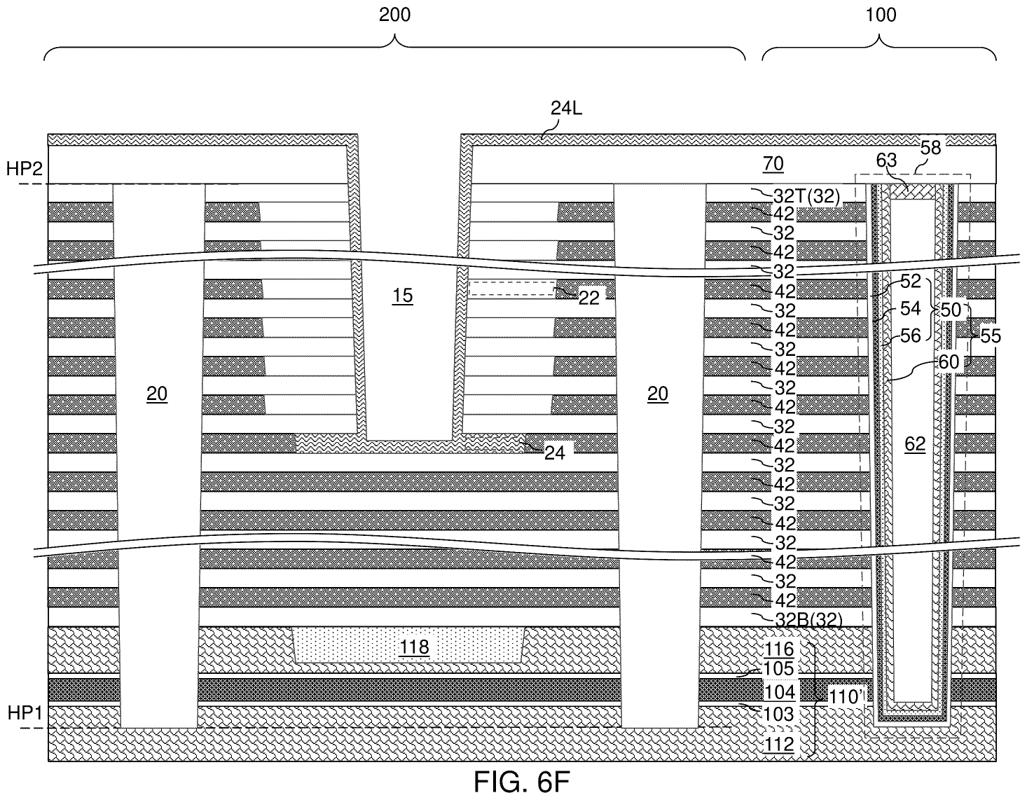

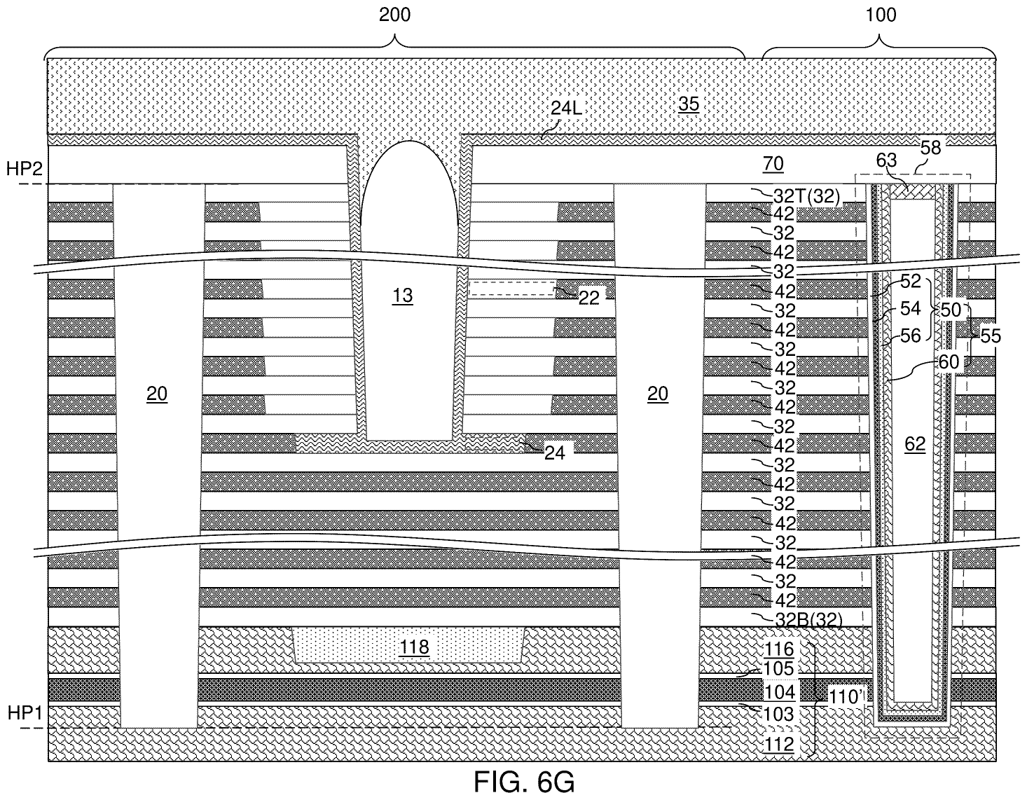

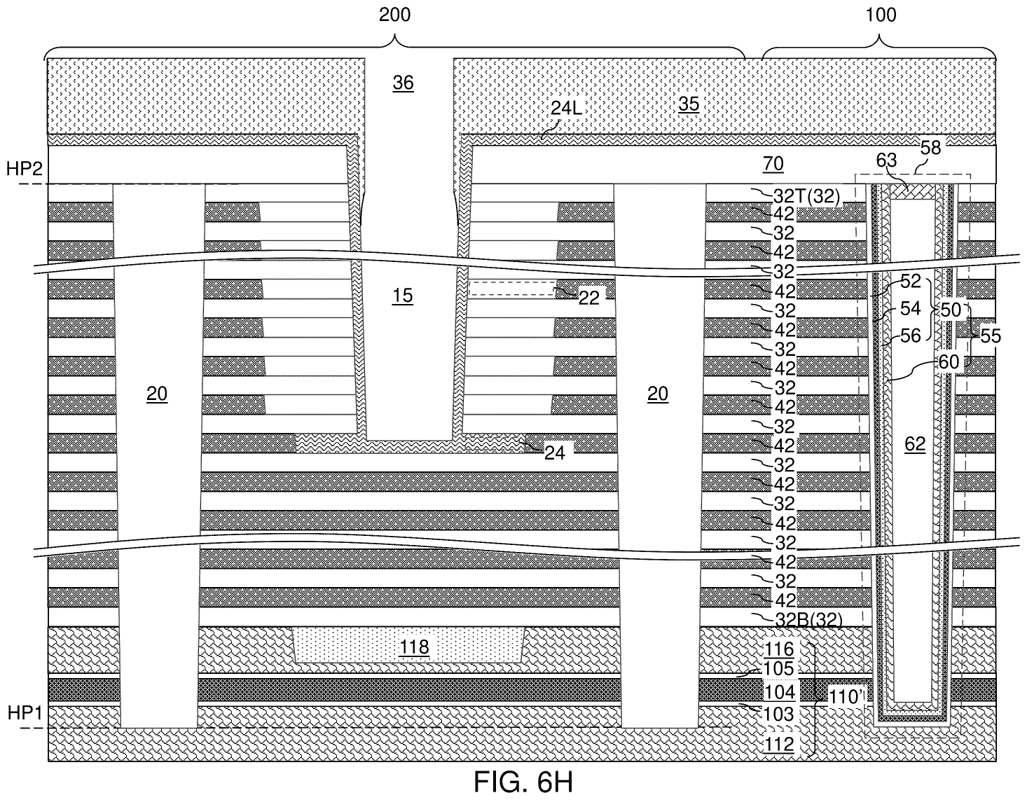

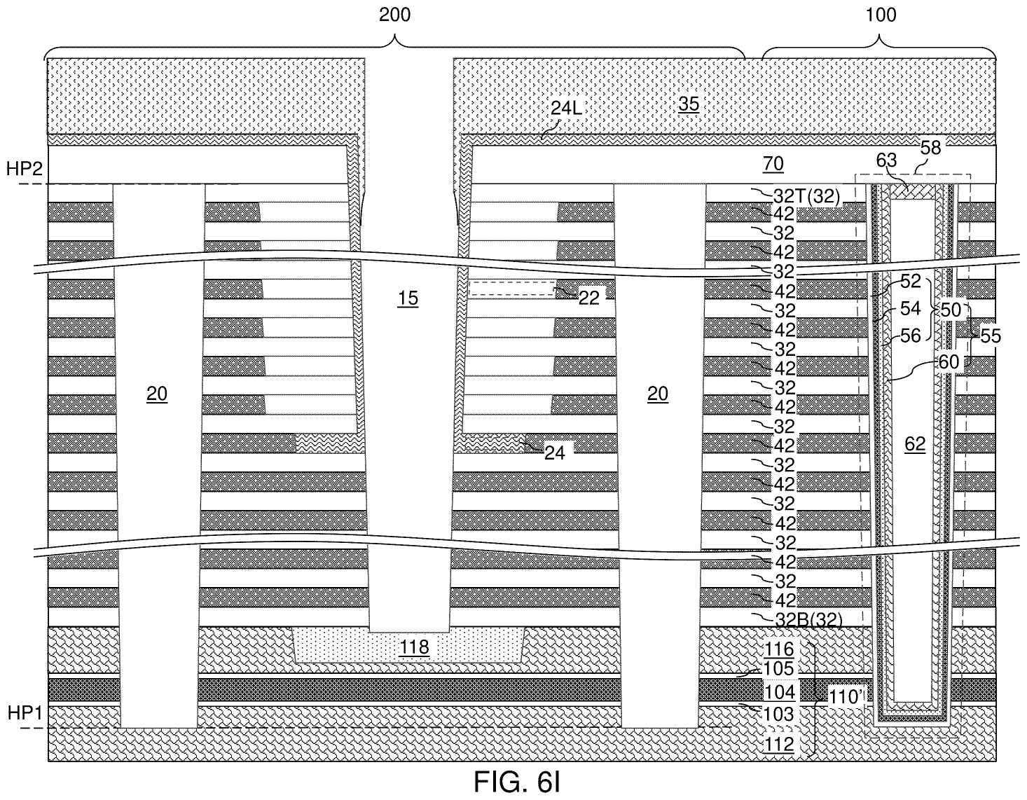

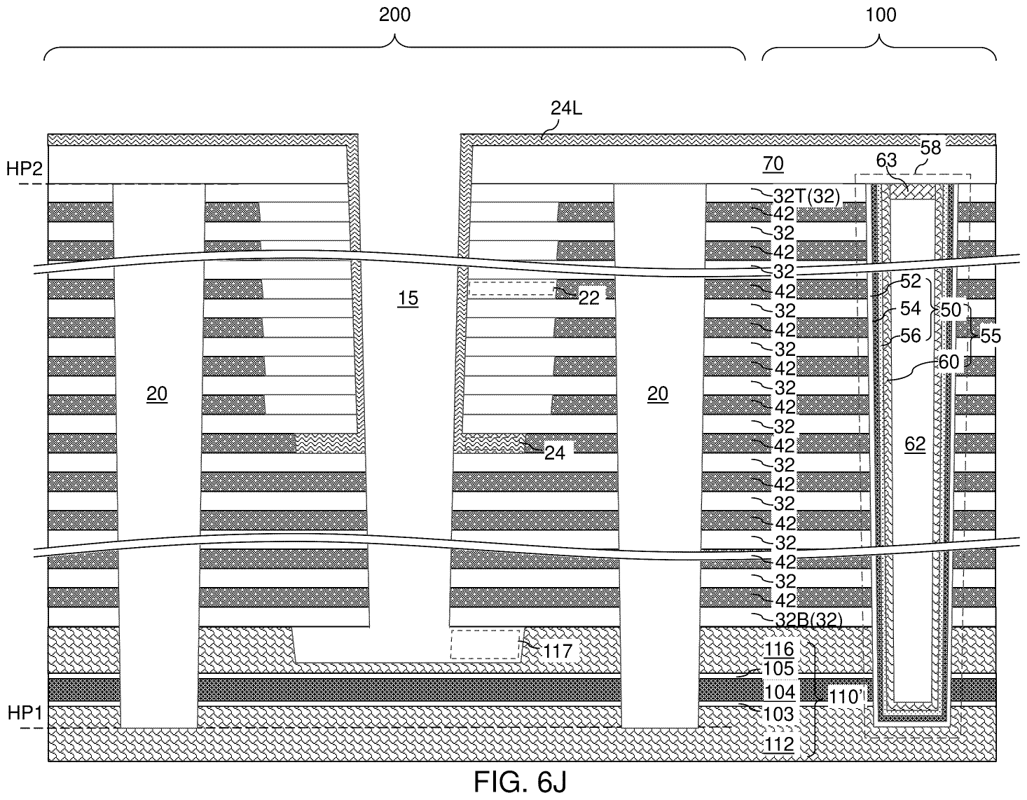

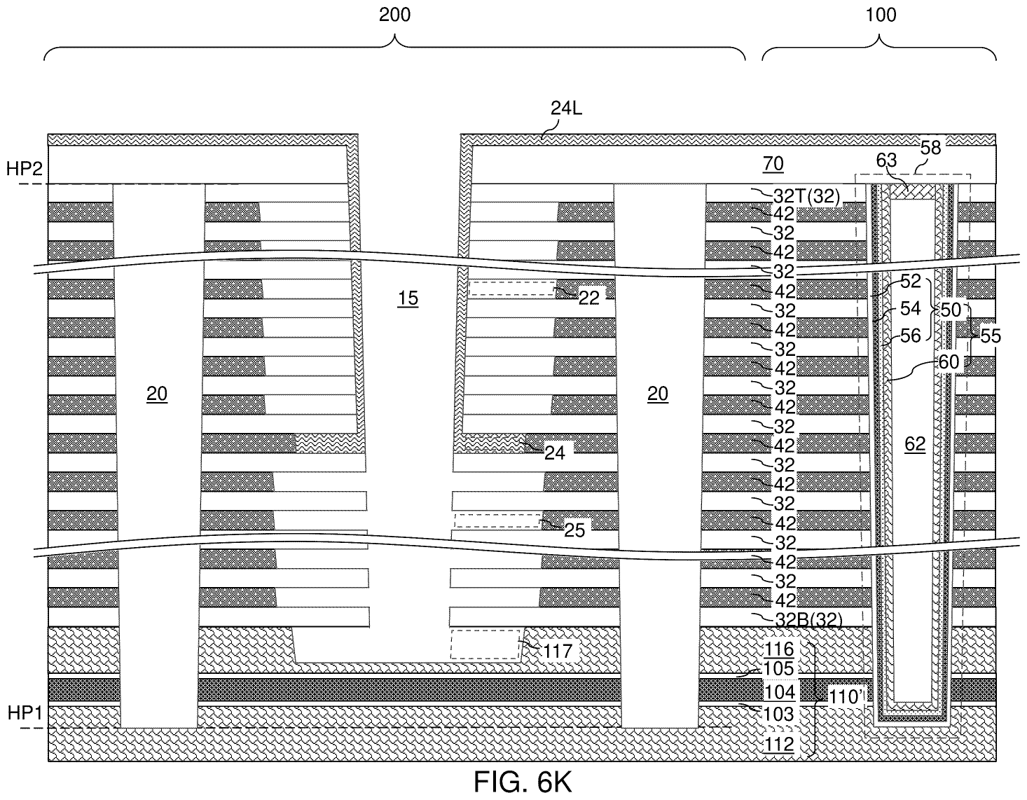

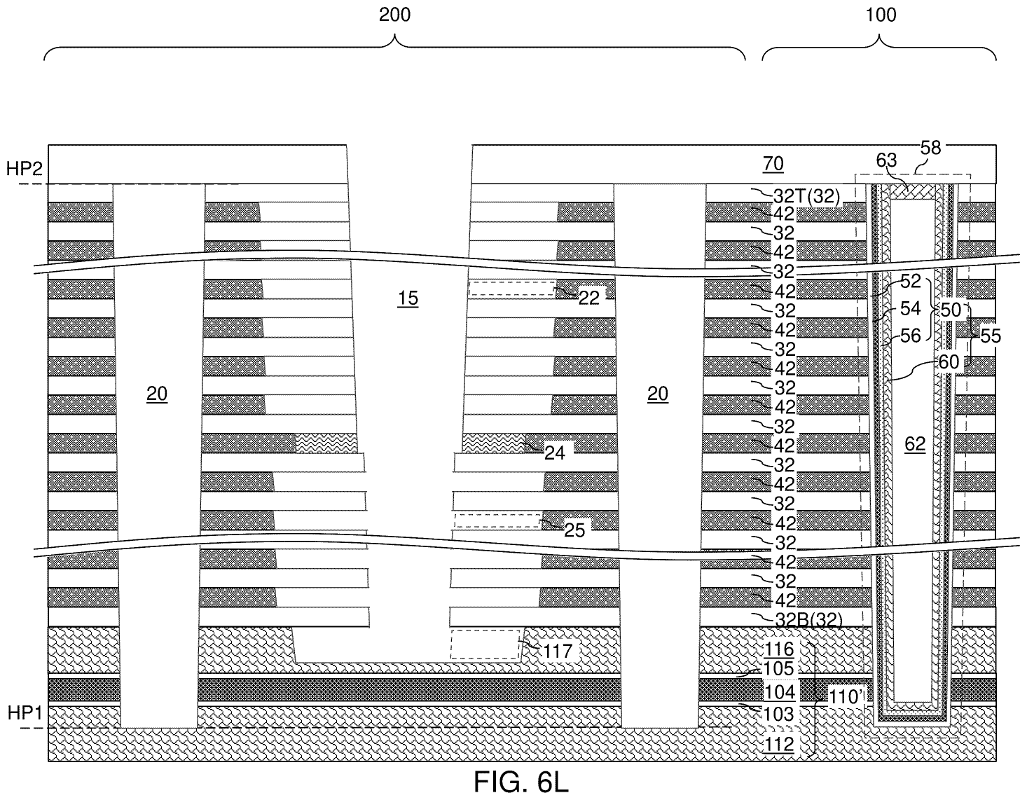

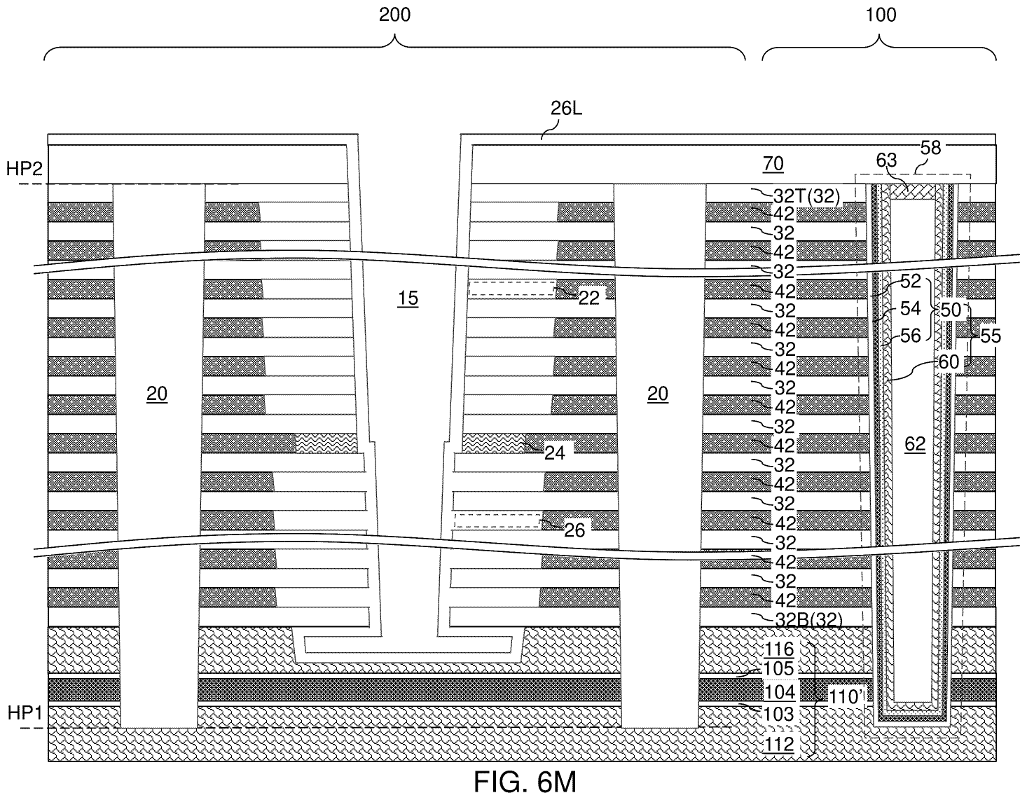

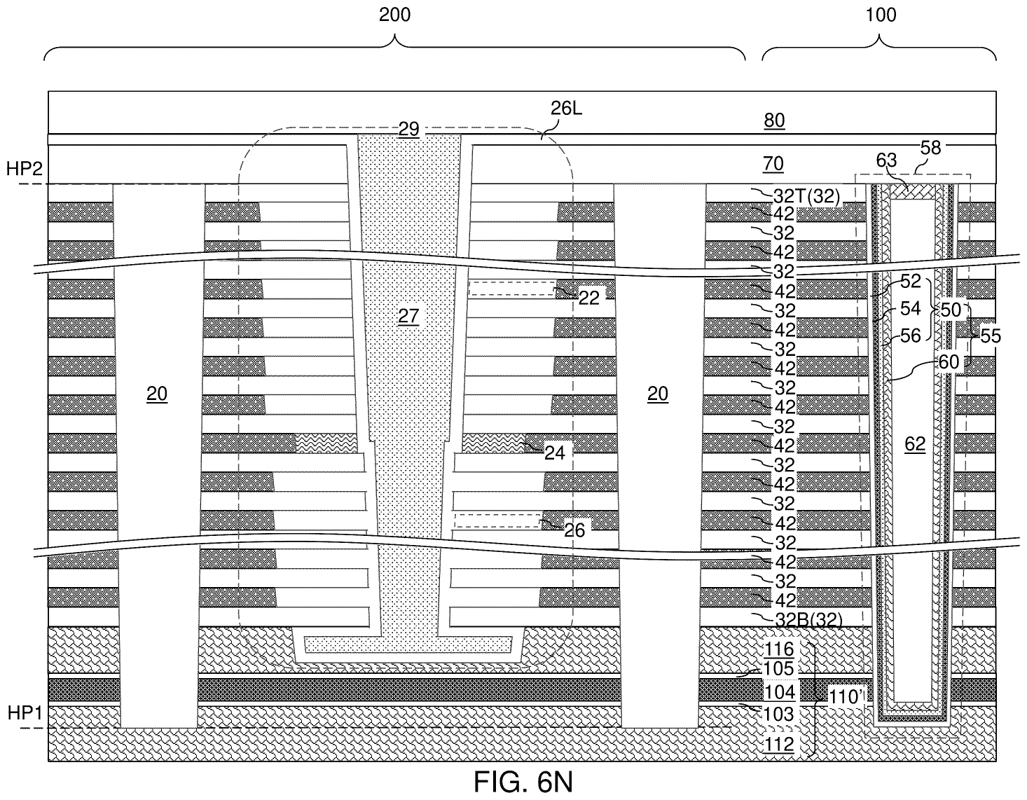

FIGS. 6A-6N are sequential vertical cross-sectional views of a region of the first exemplary structure during formation of an in-process layer contact assembly 29 according to the first embodiment of the present disclosure.

Referring to FIG. 6A, the patterned hard mask layer 33 can be subsequently removed, for example, by performing a selective etch process that removes the material of the patterned hard mask layer 33 selective to the materials of the alternating stack (32, 42). For example, if the insulating layers 32 comprise silicon oxide, the sacrificial material layers 42 comprises silicon nitride, and the patterned hard mask layer 33 comprises titanium nitride, a wet etch process employing a mixture of ammonium hydroxide and hydrogen peroxide may be employed to remove the patterned hard mask layer 33 selective to the alternating stack (32, 42).

Referring to FIG. 6B, a first selective isotropic etch process can be performed. For each contact via cavity 15, a respective first subset of the sacrificial material layers 42 that is exposed to the contact via cavity 15 can be laterally recessed around the contact via cavity 15. The first selective isotropic etch process etches the material of the sacrificial material layers 42 selective to the material of the insulating layers 32. In an illustrative example, if the sacrificial material layers 42 comprise silicon nitride and if the insulating layers 32 comprise silicon oxide, the first selective isotropic etch process may comprise a wet etch process employing hot phosphoric acid.

The sacrificial material layers 42 can be isotropically recessed around the contact via cavities 15 to form annular voids in volumes from which the material of the sacrificial material layers 42 are etched. The contact via cavities 15 are converted into finned contact via cavities 15′. Each finned contact via cavity 15′ comprises at least one first fin cavity 21, which comprises voids from which the material of the sacrificial material layers 42 is removed. Each first fin cavity 21 may have a shape of an annulus having a uniform thickness. The lateral recess distance of the first selective isotropic etch process may be selected such that surfaces of the dielectric support pillar structures 20 are not exposed around the first fin cavities 21. For example, the lateral recess distance of the first selective isotropic etch process may be in a range from 20 nm to 300 nm, such as from 40 nm to 200 nm, although lesser and greater lateral recess distances may also be employed. In one embodiment, each insulating layer 32 other than the bottommost insulating layer 32B may have a respective top surface segment that is physically exposed to a respective one of the finned contact via cavities 15′.

Referring to FIG. 6C, a first insulating fill material, such as silicon oxide, can be conformally deposited in the first fin cavities 21, in peripheral portions of the contact via cavities 15, and over the insulating cap layer 70 to form a first insulating liner 22L. The thickness of the first insulating liner 22L is greater than one half of the thickness of a sacrificial material layer 42. In one embodiment, the thickness of the first insulating liner 22L may be in a range from 15 nm to 50 nm, although lesser and greater thicknesses may also be employed. The first insulating liner 22L comprises first annular insulating fins 22 that fill the volumes of the first fin cavities 21.

Referring to FIG. 6D, a first vertical extension etch process can be performed to vertically extend the contact via cavities 15. In one embodiment, the first vertical extension etch process may comprise a first anisotropic etch process which etches horizontally-extending portions of the first insulating liner 22L and the material of the insulating layers 32. The etch chemistry of the anisotropic etch process can be selective to the material of the sacrificial material layers 42. The duration of the anisotropic etch process can be selected such that the exposed portions of the first insulating liner 22L are removed, while the first annular insulating fins 22 that fill the volumes of the first fin cavities 21 remain. In some embodiments, vertically-extending portions of the first insulating liner 22L may be collaterally removed during the anisotropic etch process. Alternatively, a wet etch process may be performed to remove vertically-extending portions of the first insulating liner 22L. Each contact via cavity 15 is vertically extended through a respective underlying insulating layer 32.

A top surface of an underlying sacrificial material layer 42 can be physically exposed at the bottom of each contact via cavity 15. For each contact via cavity 15 that vertically extends through a respective first subset of the sacrificial material layers 42, portions of a first subset of the sacrificial material layers 42 that are proximal to the contact via cavity 15 are replaced with first annular insulating fins 22.

Referring to FIG. 6E, a second selective isotropic etch process can be performed to remove portions of the sacrificial material layers 42 that are exposed at the bottom of the contact via cavities 15. For each contact via cavity 15, a respective first sacrificial material layer 42 that is exposed to the contact via cavity 15 can be partially etched underneath the contact via cavity 15. The second selective isotropic etch process etches the material of the sacrificial material layers 42 selective to the material of the insulating layers 32. In an illustrative example, if the sacrificial material layers 42 comprise silicon nitride and if the insulating layers 32 comprise silicon oxide, the second selective isotropic etch process may comprise a wet etch process employing hot phosphoric acid.

Portions of the sacrificial material layers 42 that underlie the contact via cavities 15 can be isotropically recessed to form circular plate-shaped volumes from which the material of the sacrificial material layers 42 are etched. The contact via cavities 15 are converted into finned contact via cavities 15″ each comprising a respective second fin cavity 23. Each finned contact via cavity 15″ comprises a second fin cavity 23, which comprises voids between adjacent insulating layers 32 from which the material of the sacrificial material layers 42 is removed. Each second fin cavity 23 may have a shape of an annulus having a uniform thickness. The lateral distance between an inner periphery and an outer periphery of an annular top surface of a second fin cavity 23 may be in a range from 20 nm to 300 nm, such as from 40 nm to 200 nm, although lesser and greater lateral recess distances may also be employed. In one embodiment, each insulating layer 32 may have a respective top surface segment that is physically exposed to a respective one of the finned contact via cavities 15″.

Referring to FIG. 6F, a sacrificial fill material different from the material of the first insulating liner 22L can be conformally deposited in the second fin cavities 23, in peripheral portions of the contact via cavities 15, and over the insulating cap layer 70 to form a sacrificial fill material liner 24L. In one embodiment, the sacrificial fill material liner 24L comprises amorphous silicon, polysilicon or silicon-germanium. The sacrificial fill material comprises a material that may be subsequently removed selective to the materials of the insulating layers 32 and the sacrificial material layers 42. The thickness of the sacrificial fill material liner 24L is greater than one half of the thickness of a sacrificial material layer 42. In one embodiment, the thickness of the sacrificial fill material liner 24L may be in a range from 15 nm to 50 nm, although lesser and greater thicknesses may also be employed. The sacrificial fill material liner 24L comprises sacrificial fin structures 24 that fill the volumes of the second fin cavities 23.

Referring collectively to FIGS. 6D-6F, a first via extension process can be performed to vertically extend the contact via cavities 15 through a respective underlying insulating layer 32, and to replace a portion of each sacrificial material layer 42 that underlies a respective overlying first subset of the sacrificial material layers 42 with a respective sacrificial fin structure 24.

Referring to FIG. 6G, a patterning film 35 may be anisotropically deposited over the sacrificial fill material liner 24L such that an encapsulated cavity 13 that is covered by the patterning film 35 is formed within the volumes of the contact via cavities 15. The patterning film 35 may comprise a carbon-based material that includes amorphous carbon as a principal component and may additionally include dopants, such as boron, silicon, oxygen, fluorine, etc.

Referring to FIG. 6H, a photoresist layer (not shown) can be applied over the patterning film 35, and can be lithographically patterned to form openings over the encapsulated cavities 13. An anisotropic etch process can be performed to transfer the pattern of the openings in the photoresist layer through the patterning film 35. An opening 36 is formed through the patterning film 35 over each of the encapsulated cavities 13 to expose the contact via cavities 15.

Referring to FIG. 6I, a second via extension process can be performed to vertically extend the contact via cavities 15 to the etch-stop plates 118. The second via extension process may comprise a second anisotropic etch process that etches each horizontally-extending portion of the sacrificial fill material liner 24L underneath the contact via cavities 15 and subsequently etches underlying portions of the alternating stack (32, 42). The duration of the second anisotropic etch process can be selected such that each contact via cavity 15 is vertically extended through the entirety of the alternating stack (32, 42) to a top surface of a respective underlying one of the etch-stop plates 118. Thus, each contact via cavity 15 can vertically extend through each layer in the alternating stack (32, 42) after performing the second via extension process. The photoresist layer overlying the patterning film 35 may be removed prior to performing the second anisotropic etch process, or may be consumed collaterally during the second anisotropic etch process.

Referring to FIG. 6J, an ashing or a selective etch process can be performed to remove the etch-stop plates 118 selective to the materials of the upper source-level semiconductor layer 116, the alternating stack (32, 42), and the sacrificial fill material liner 24L. In one embodiment, if the etch-stop plates 118 comprise a carbon material, then they can be removed together with the patterning film 35 utilizing the same ashing process. The contact via cavities 15 vertically extend through the insulating cap layer 70, the alternating stack (32, 42), and an upper portion of the upper source-level semiconductor layer 116. An annular base cavity 117 can be formed around the bottom portion of each contact via cavity 15. A sacrificial fin structure 24 is present around each contact via cavity 15. The sacrificial fin structure 24 has a shape of an annular plate. For each sacrificial fin structure 24 that is formed below the level of the topmost sacrificial material layer 42, a respective set at least one first annular insulating fin 22 can be provided above the sacrificial fin structure 24. The respective set of at least one first annular insulating fin 22 can be laterally surrounded by and can be contacted by a respective first subset of the sacrificial material layers 42 including the topmost sacrificial material layer 42. For each sacrificial fin structure 24 that is formed above the level of the bottommost sacrificial material layer 42, a respective second subset of the sacrificial material layers 42 can be present below the sacrificial fin structure 24. Generally, a material portion (such as an etch-stop plate 118) embedded within a substrate (which may comprise the in-process source-level material layers 110′ or a silicon wafer 8) may be removed after the second via extension process.

Referring to FIG. 6K, a third selective isotropic etch process can be performed. For each sacrificial fin structure 24 that is formed above the level of the bottommost sacrificial material layer 42, a respective second subset of the sacrificial material layers 42 that underlies the sacrificial fin structure 24 can be laterally recessed around a respective contact via cavity 15. The third selective isotropic etch process etches the material of the sacrificial material layers 42 selective to the material of the insulating layers 32, the sacrificial fill material liner 24L and the sacrificial fin structure 24, and the upper source-level semiconductor layer 116. In an illustrative example, if the sacrificial material layers 42 comprise silicon nitride, the sacrificial fin structure 24 comprises silicon, and the insulating layers 32 comprise silicon oxide, the third selective isotropic etch process may comprise a wet etch process employing hot phosphoric acid.

The physically exposed sacrificial material layers 42 can be isotropically recessed around the contact via cavities 15 to form annular voids in volumes from which the material of the sacrificial material layers 42 are etched. Each void that is formed by removal of an annular portion of the sacrificial material layers 42 is herein referred to as a third fin cavity 25. Each third fin cavity 25 may have a shape of an annulus having a uniform thickness. The lateral recess distance of the selective isotropic etch process may be selected such that surfaces of the dielectric support pillar structures 20 are not exposed around the third fin cavities 25. For example, the lateral recess distance of the third selective isotropic etch process may be in a range from 20 nm to 300 nm, such as from 40 nm to 200 nm, although lesser and greater lateral recess distances may also be employed.

Referring to FIG. 6L, an isotropic etch process can be performed to remove portions of the sacrificial fill material liner 24L that are located outside the volumes of the second fin cavities 23, i.e., to remove portions of the sacrificial fill material liner 24L other than the sacrificial fin structures 24. For example, if the sacrificial fill material liner 24L comprises amorphous silicon, a wet etch process employing hot trimethyl-2 hydroxyethyl ammonium hydroxide (“hot TMY”) or tetramethyl ammonium hydroxide (TMAH) may be performed to remove the portions of the sacrificial fill material liner 24L that are located outside the volumes of the second fin cavities 23. The duration of the isotropic etch process can be selected such that the etch distance of the material of the sacrificial fill material liner 24L is in a range from 100% to 150% of the thickness of vertically-extending portions of the sacrificial fill material liner 24L. The sacrificial fin structures 24 remain in the volumes of the second fin cavities 23.

The sacrificial fin structure 24 laterally surrounds and has an inner cylindrical sidewall that is exposed to the contact via cavity 15. The total number of contact via cavities 15 may be the same as or greater than the total number of the sacrificial material layers 42 in each portion of the contact region 200 in which an array of layer contact via structures is to be subsequently formed. For each sacrificial material layer 42 in the alternating stack (32, 42), at least one contact via cavity 15 is provided, to which an inner cylindrical sidewall of a respective sacrificial fin structure 24 is exposed.

Referring to FIG. 6M, a second insulating fill material, such as silicon oxide, can be conformally deposited in the third fin cavities 25, in peripheral portions of the contact via cavities 15, and over the insulating cap layer 70 to form a second insulating liner 26L. The thickness of the second insulating liner 26L is greater than one half of the thickness of a sacrificial material layer 42. In one embodiment, the thickness of the second insulating liner 26L may be in a range from 15 nm to 50 nm, although lesser and greater thicknesses may also be employed. The second insulating liner 26L comprises second annular insulating fins 26 that fill the volumes of the third fin cavities 25.

Referring collectively to FIGS. 6K-6M, for each sacrificial fin structure 24 that laterally surrounds a respective contact via cavity 15 and may underlie a respective first subset of the sacrificial material layers 42, portions of a respective second subset of the sacrificial material layers 42 that underlie the sacrificial fin structure 24 can be replaced with a set of at least one second annular insulating fins 26. Generally, an insulating surface can be provided around a portion of the contact via cavity 15 that underlies a horizontal plane including a bottommost surface of the alternating stack (32, 42) such that the entirety of all physically exposed surfaces that are exposed to the contact via cavities 15 and underlie the horizontal plane are insulating surfaces. For example, the insulating surfaces may comprise physically exposed surfaces of the second insulating liner 26L, and the entirety of all physically exposed surfaces that are exposed to the contact via cavities 15 and underlie the horizontal plane is insulating surfaces of the second insulating liner 26L.

Referring to FIG. 6N, a sacrificial fill material can be deposited in the voids within the contact via cavities 15. The sacrificial fill material comprises a material that can be subsequently removed selective to material of the second insulating liner 26L. For example, the sacrificial fill material may comprise a carbon-based material, such as amorphous carbon or diamond-like carbon, a semiconductor material, such as amorphous silicon, polysilicon, or silicon-germanium, or a dielectric material, such as borosilicate glass or organosilicate glass.

Excess portions of the sacrificial fill material may be removed from above the horizontal plane including the top surface of a horizontally-extending portion of the second insulating liner 26L that overlies the insulating cap layer 70 employing a planarization process. The planarization process may comprise a recess etch process or a chemical mechanical polishing process. Each remaining portion of the sacrificial fill material constitutes a sacrificial via fill material portion 27. Each sacrificial via fill material portion 27 is formed directly on the insulating surfaces of the second insulating liner 26L in a respective contact via cavity 15.

Referring collectively to FIGS. 6M and 6N, an insulating liner (such as the second insulating liner 26L) can be formed within a volume of a contact via cavity 15 on at least one inner sidewall of at least one first annular insulating fin 22, on an inner sidewall of a sacrificial fin structure 24, and on at least one inner sidewall of at least one second annular insulating fin 26. The sacrificial via fill material portion 27 is formed within the insulating liner (such as the second insulating liner 26L).

A contact-level dielectric layer 80 can be formed above the horizontally-extending portion of the second insulating liner 26L that overlies the insulating cap layer 70. The contact-level dielectric layer 80 comprises a dielectric material, such as undoped silicate glass or a doped silicate glass, and may have a thickness in a range from 100 nm to 800 nm, such as from 200 nm to 500 nm, although lesser and greater thicknesses may also be employed.

An array of in-process layer contact assemblies 29 can be formed in the contact region 200. Each in-process layer contact assembly 29 comprises a sacrificial via fill material portion 27, optionally at least one first annular insulating fin 22 laterally surrounding and contacting the sacrificial via fill material portion 27, a sacrificial fin structure 24 having a shape of an annular plate, optionally at least one second annular insulating fin 26 laterally surrounding and contacting the sacrificial via fill material portion 27, and a respective portion of the second insulating liner 26L that is in contact with the sacrificial via fill material portion 27. Each sacrificial fin structure 24 laterally contacts a cylindrical surface of a respective first sacrificial material layer 42. If the sacrificial fin structure 24 is formed at any level other than the level of the topmost sacrificial material layer 42, the in-process layer contact assembly 29 comprises at least one first annular insulating fin 22. If the sacrificial fin structure is formed at any level other than the level of the bottommost sacrificial material layer 42, the in-process layer contact assembly 29 comprises at least one second annular insulating fin 26.

Each sacrificial fin structure 24 located at a level other than the level of the topmost sacrificial material layer 42 or the level of the bottommost sacrificial material layer 42 is contacted by a cylindrical sidewall of a respective first sacrificial material layer 42, underlies at least one first annular insulating fin 22, and overlies at least one second annular insulating fin 26. For each sacrificial fin structure 24 located at a level other than the level of the topmost sacrificial material layer 42 or the level of the bottommost sacrificial material layer 42, each overlying first annular insulating fin 22 is contacted by and is laterally surrounded by a respective second sacrificial material layer 42 that overlies the first sacrificial material layer 42, and each underlying second annular insulating fin 26 is contacted by and is laterally surrounded by a respective third sacrificial material layer 42 that underlies the first sacrificial material layer 42.

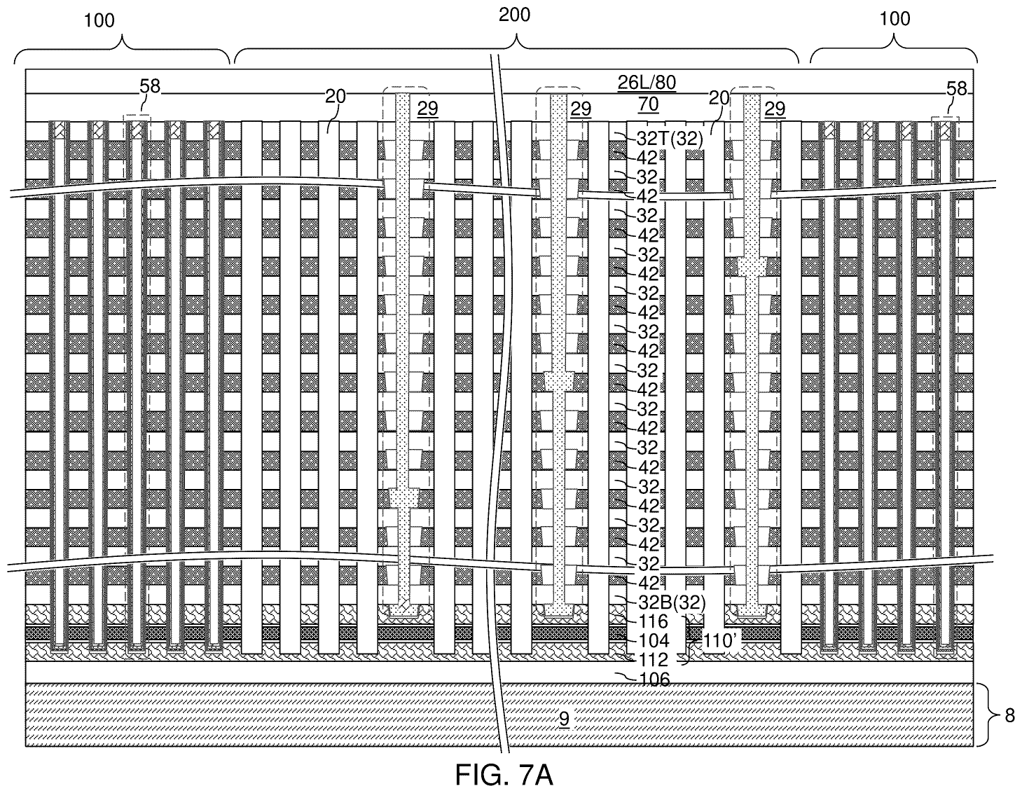

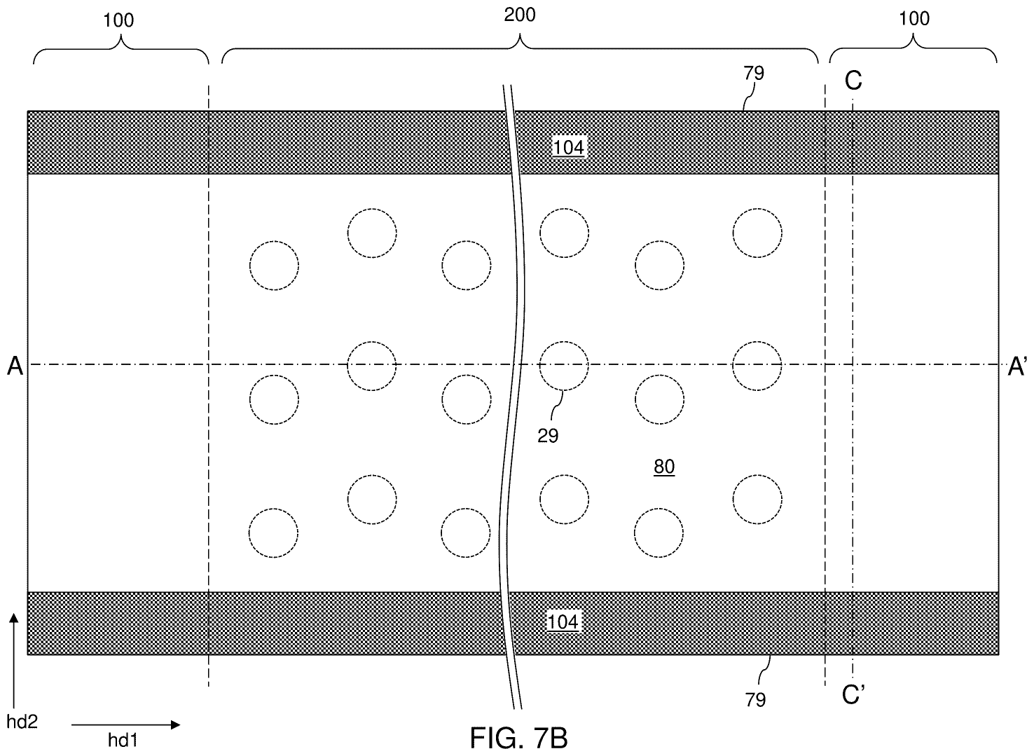

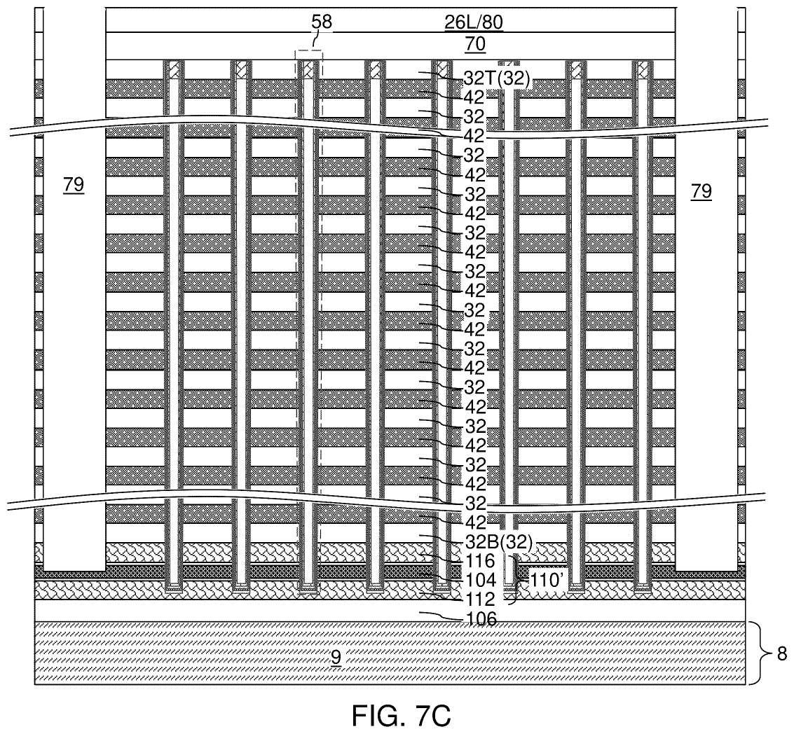

Referring to FIGS. 7A-7C, a photoresist layer (not shown) can be applied over the contact-level dielectric layer 80, and is lithographically patterned to form elongated openings in areas between clusters of memory opening fill structures 58. The elongated openings can be formed over areas that are free of any memory opening fill structures 58, any dielectric support pillar structures 20, and any sacrificial via fill material portions 27. The pattern in the photoresist layer can be transferred through the contact-level dielectric layer 80, a horizontally-extending portion of the second insulating liner 26L, the insulating cap layer 70, and the alternating stack (32, 42) employing an anisotropic etch process. Lateral isolation trenches 79 are formed in the volumes from which materials of the contact-level dielectric layer 80, a horizontally-extending portion of the second insulating liner 26L, the insulating cap layer 70, and the alternating stack (32, 42) are etched. The lateral isolation trenches 79 vertically extend from the top surface of the contact-level dielectric layer 80 to the source-level sacrificial layer 104 (if present) or to the top surface of the substrate 8 (if the in-process source-level material layers 110′ are omitted). The lateral isolation trenches 79 laterally extend along the first horizontal direction hd1 between neighboring memory blocks of memory opening fill structures 58.

In one embodiment, the lateral isolation trenches 79 can laterally extend along the first horizontal direction (e.g., word line direction) hd1 and can be laterally spaced apart from each other along the second horizontal direction hd2 (which may be a bit line direction) that is perpendicular to the first horizontal direction hd1. The memory opening fill structures 58 can be arranged in rows that extend along the first horizontal direction hd1. Multiple rows of memory opening fill structures 58 can be located between each neighboring pair of lateral isolation trenches 79 in a respective memory block. Thus, the lateral isolation trenches 79 separate adjacent memory blocks along the second horizontal direction hd2. Generally, lateral isolation trenches 79 laterally extending along the first horizontal direction hd1 can be formed through the vertically alternating sequence of insulating layers 32 and sacrificial material layers 42. The lateral isolation trenches 79 are laterally spaced apart along the second horizontal direction hd2.

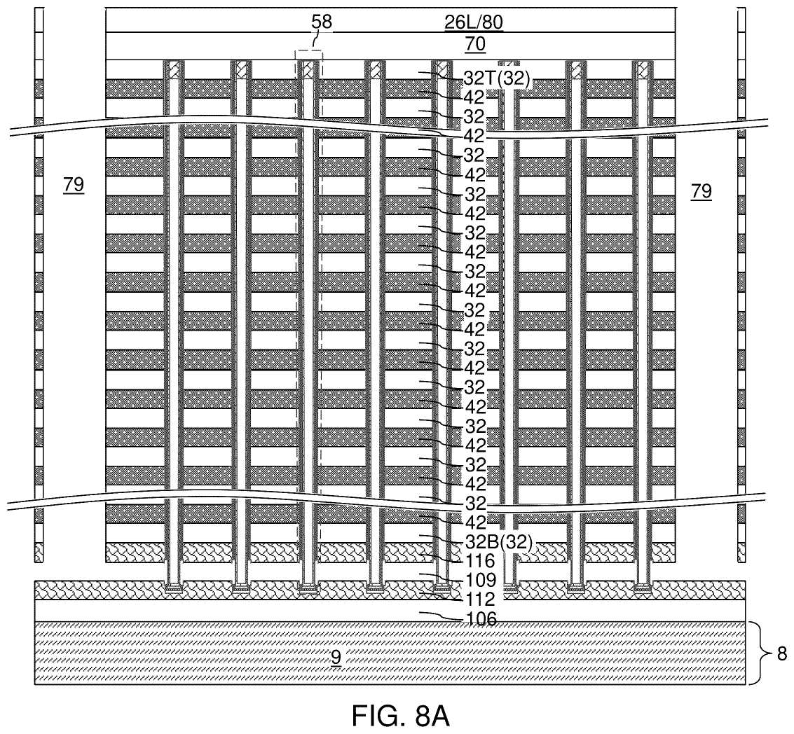

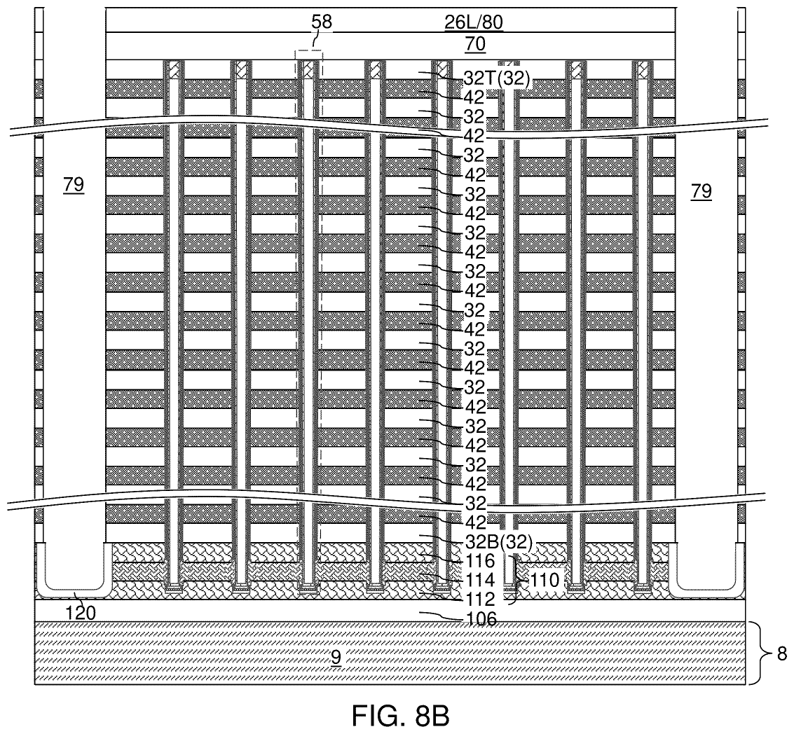

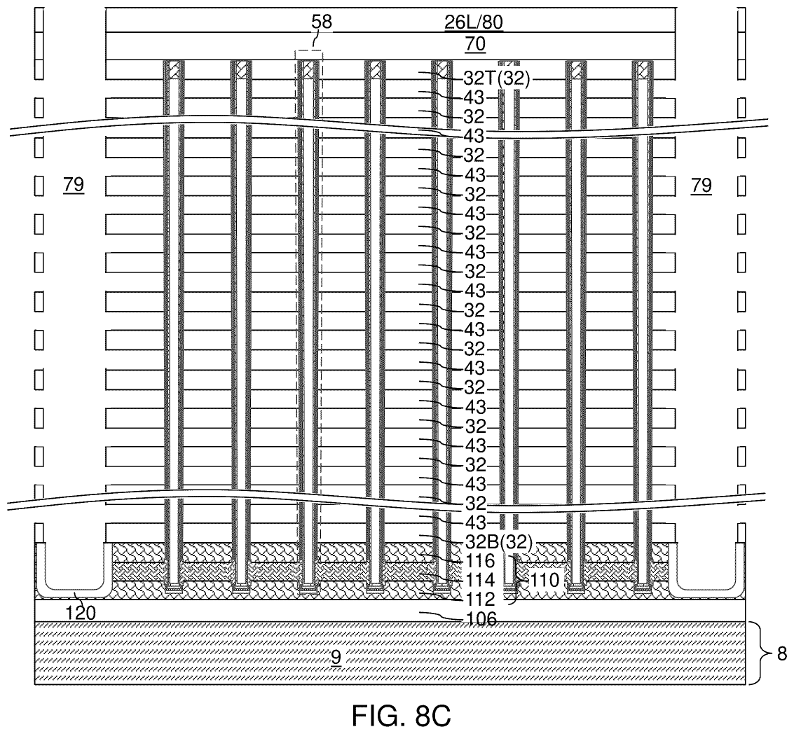

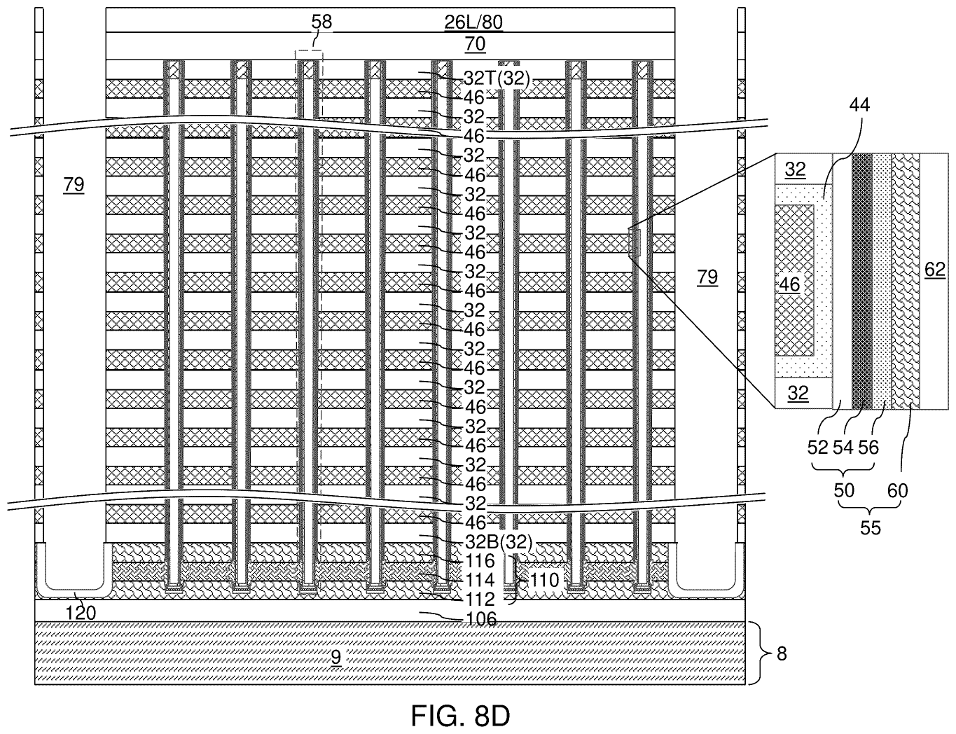

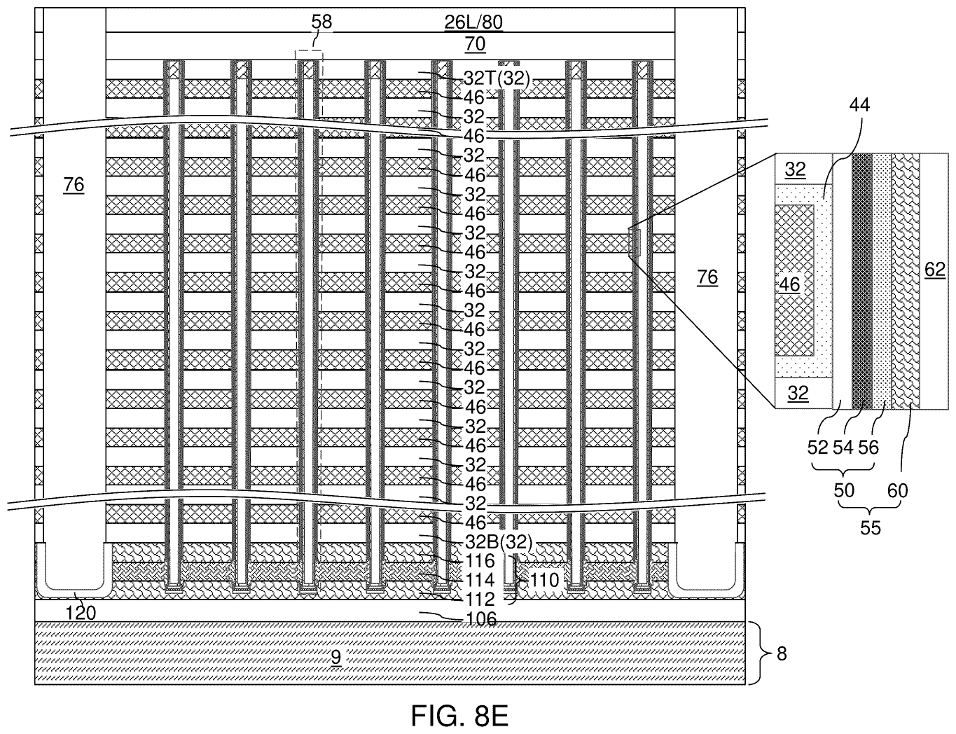

FIGS. 8A-8E are sequential vertical cross-sectional views of the first exemplary structure during replacement of the in-process source-level material layers with source-level material layers, replacement of sacrificial material layers 42 with electrically conductive layers 46, and formation of isolation trench fill structures 76 according to the first embodiment of the present disclosure.

Referring to FIG. 8A, an etchant that etches the material of the source-level sacrificial layer 104 selective to the materials of the alternating stack (32, 42), the contact-level dielectric layer 80, the insulating cap layer 70, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact-level dielectric layer 80, the insulating cap layer 70, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the first exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

Referring to FIG. 8B, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the first exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes source-level material layers 110, which replaces the in-process source-level material layers 110′. The source contact layer 114 contacts an end portion of each of the vertical semiconductor channels 60.

Optionally, a dielectric surface conversion process, such as an oxidation process or a nitridation process, may be performed to convert physically exposed edge surface portions of the source-level material layers 110 exposed in each lateral isolation trench 79 to form trench bottom dielectric liners 120. The source-level material layers 110 include semiconductor material layers such as a stack of a lower source-level semiconductor layer 112, a source contact layer 114, and an upper source-level semiconductor layer 116, which may be converted to semiconductor oxide or nitride edge portions, such as silicon oxide, silicon nitride or silicon oxynitride edge portions exposed to the lateral isolation trenches 79. Alternatively, if the top source contact or another source layer to vertical semiconductor scheme is used, then the source-level material layers 110 and the steps shown in FIGS. 8A and 8B may be omitted.

Referring to FIG. 8C, an isotropic etch process can be performed to remove the sacrificial material layers 42 selective to the sacrificial fin structure 24, the insulating fins (22, 26), the insulating layers 32, the planar insulating layer 106, the memory opening fill structures 58, the contact-level dielectric layer 80, the insulating cap layer 70, the source-level material layers 110, and the trench bottom dielectric liners 120. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid.

Referring to FIG. 8D, a backside blocking dielectric layer 44 can be optionally formed in the laterally-extending cavities 43 by a conformal deposition process. The backside blocking dielectric layer 44 comprises a dielectric metal oxide material, such as aluminum oxide, hafnium oxide, tantalum oxide, etc. The thickness of the backside blocking dielectric layer 44 may be in a range from 2 nm to 12 nm, such as from 4 nm to 8 nm, although lesser and greater thicknesses may also be employed.

At least one conductive material, such as at least one metallic material, can be conformally deposited in remaining volumes of the laterally-extending cavities 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. An alternating stack of insulating layers 32 and electrically conductive layers 46 can be formed between each neighboring pair of lateral isolation trenches 79 over the substrate 8. A plurality of alternating stacks of insulating layers 32 and electrically conductive layers 46 can be laterally spaced apart among one another by the lateral isolation trenches 79.

Referring to FIG. 8E, a dielectric fill material, such as silicon oxide, may be conformally deposited in the lateral isolation trenches 79. Excess portions of the dielectric fill material may be removed from above the contact-level dielectric layer 80 by performing a planarization process, which may comprise a recess etch process or a chemical mechanical polishing process. Each remaining portion of the dielectric fill material that remains in a respective lateral isolation trench 79 constitutes an isolation trench fill structure 76, which may be a dielectric wall structure.

Referring collectively to FIGS. 8A-8E, lateral isolation trenches 79 can be formed through the alternating stack (32, 42), and laterally-extending cavities 43 can be formed by etching the sacrificial material layers 42 selective to the insulating layers 32 and the sacrificial fin structure 24. A combination of a respective backside blocking dielectric layer 44 and a respective electrically conductive layer 46 can be formed within each of the laterally-extending cavities 43.

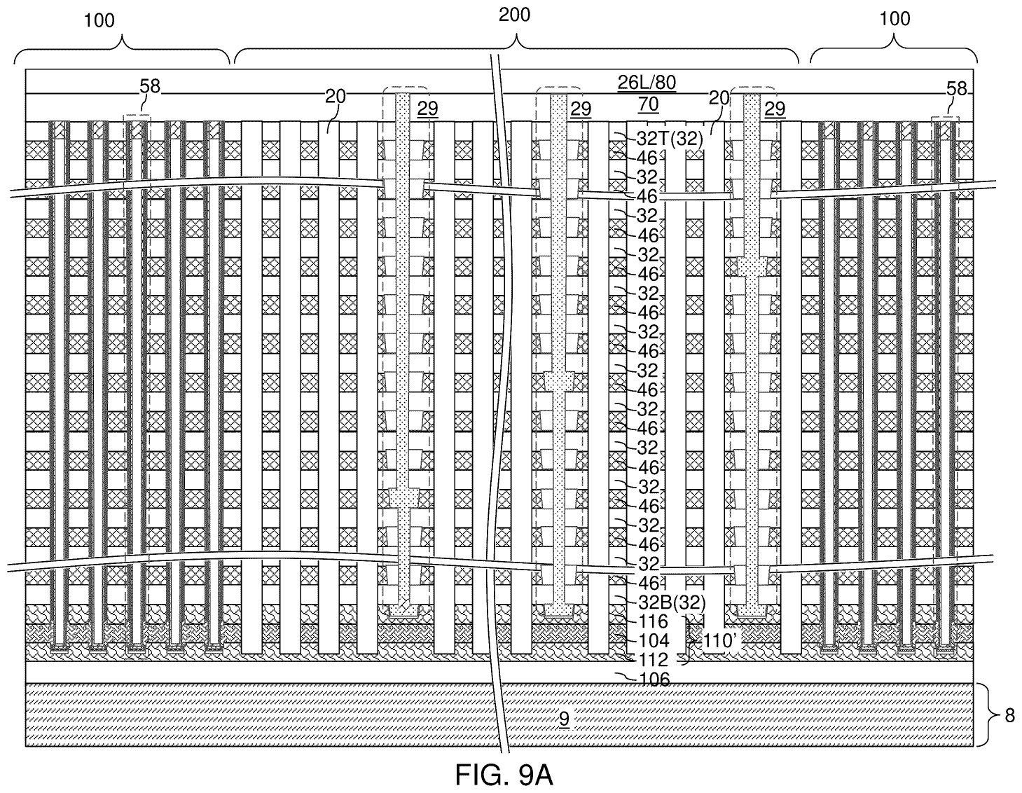

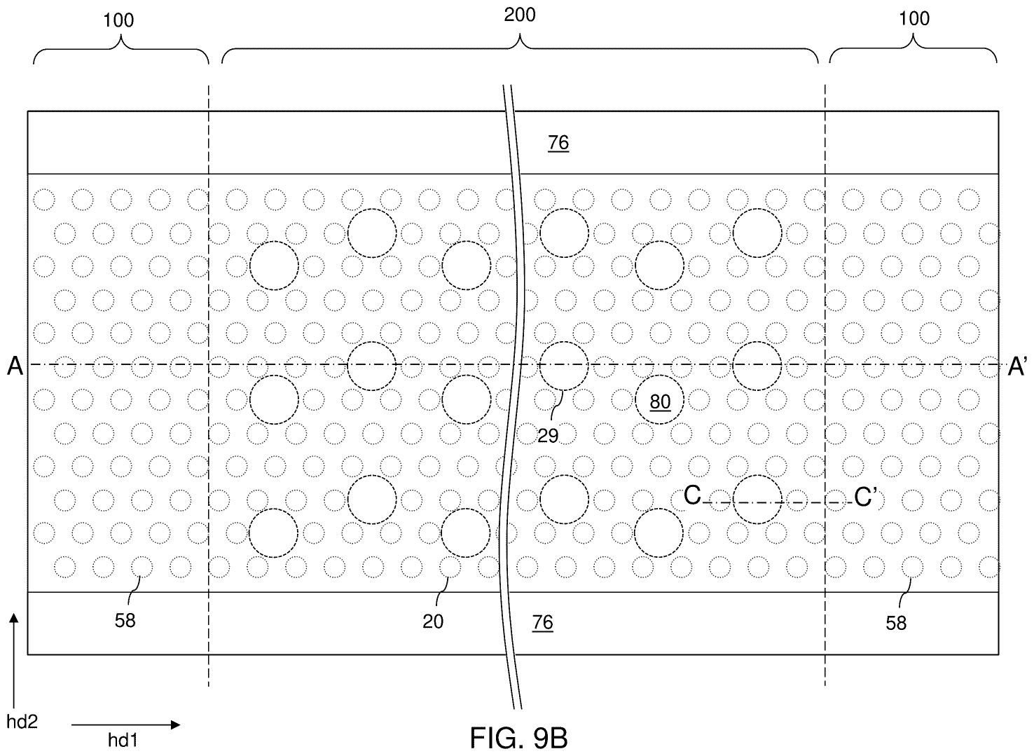

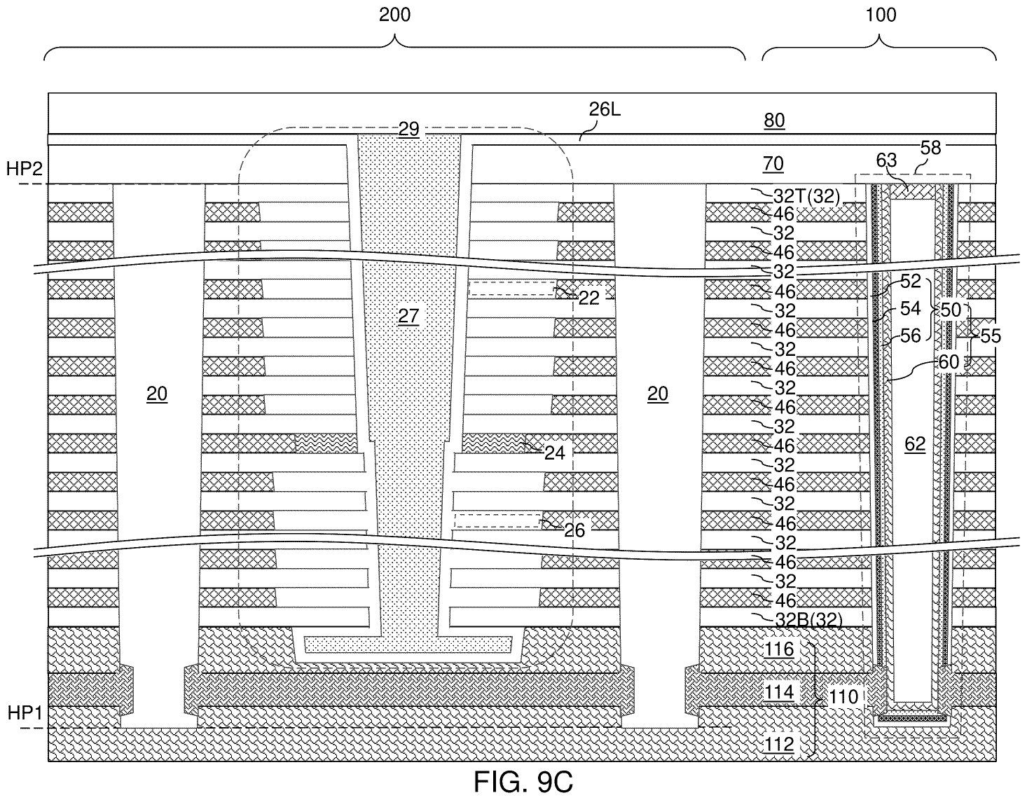

Referring to FIGS. 9A-9C, the first exemplary structure is illustrated after formation of the isolation trench fill structures 76.

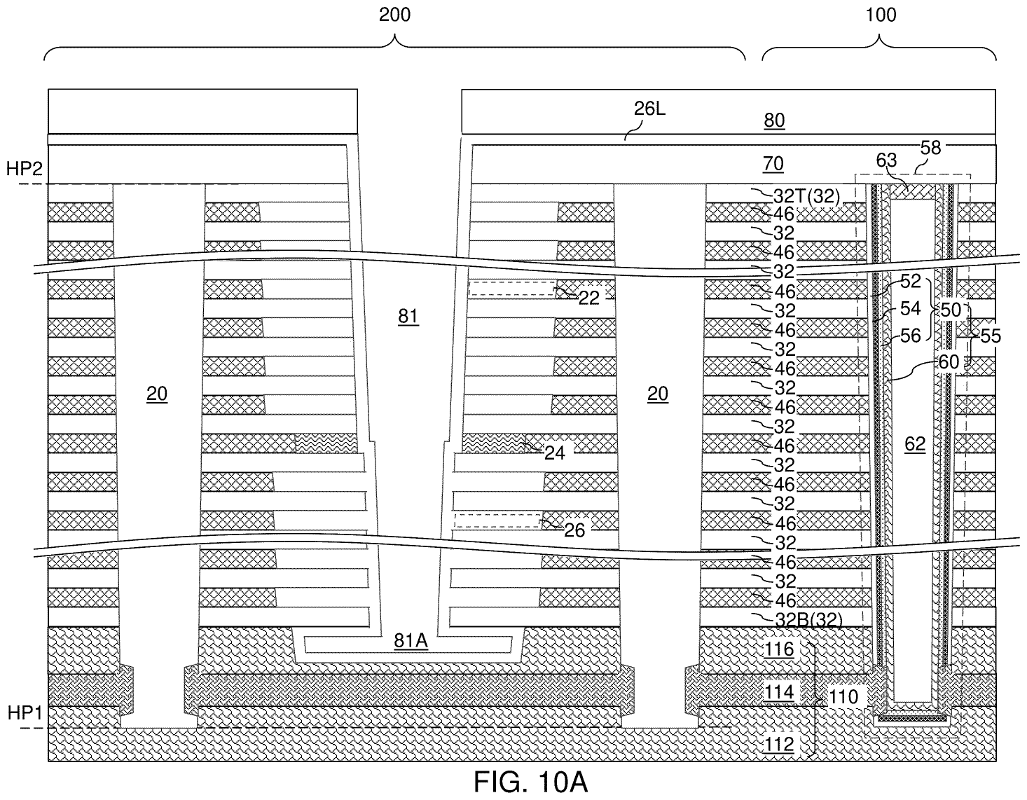

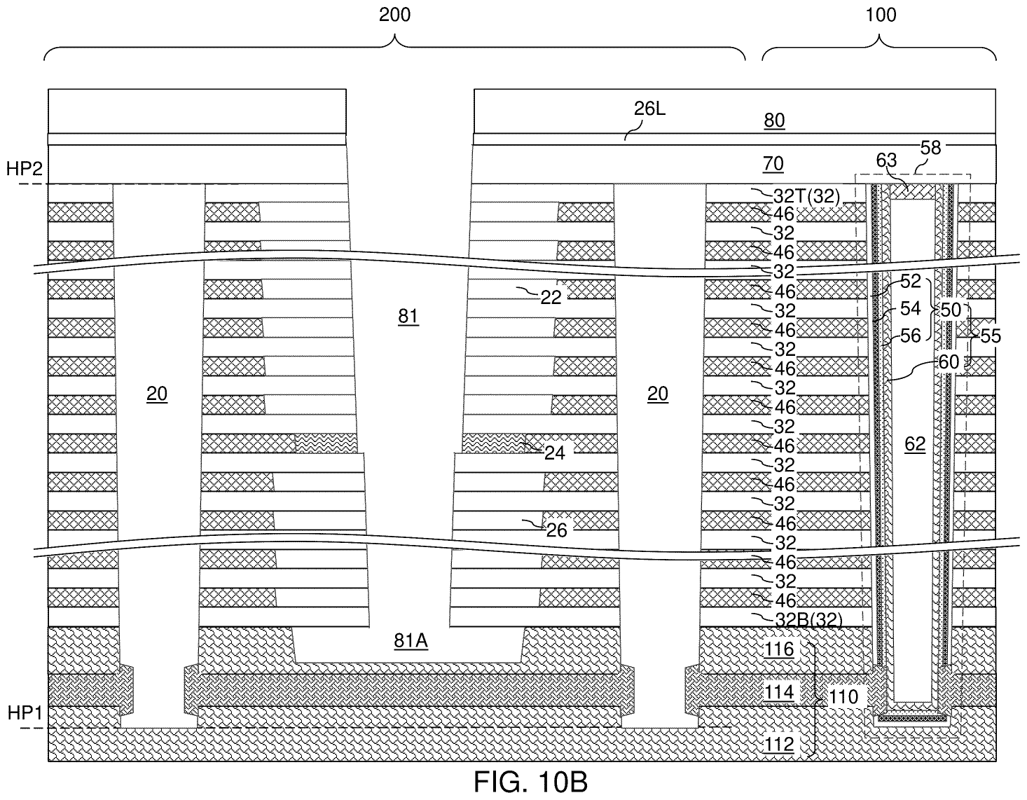

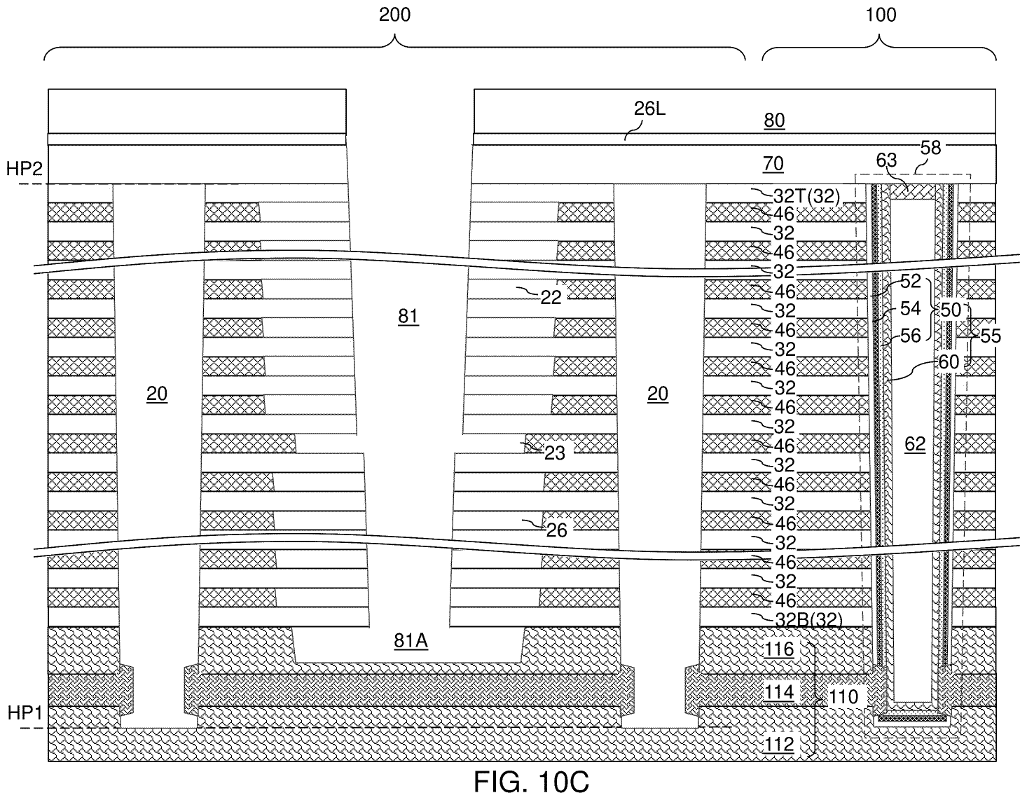

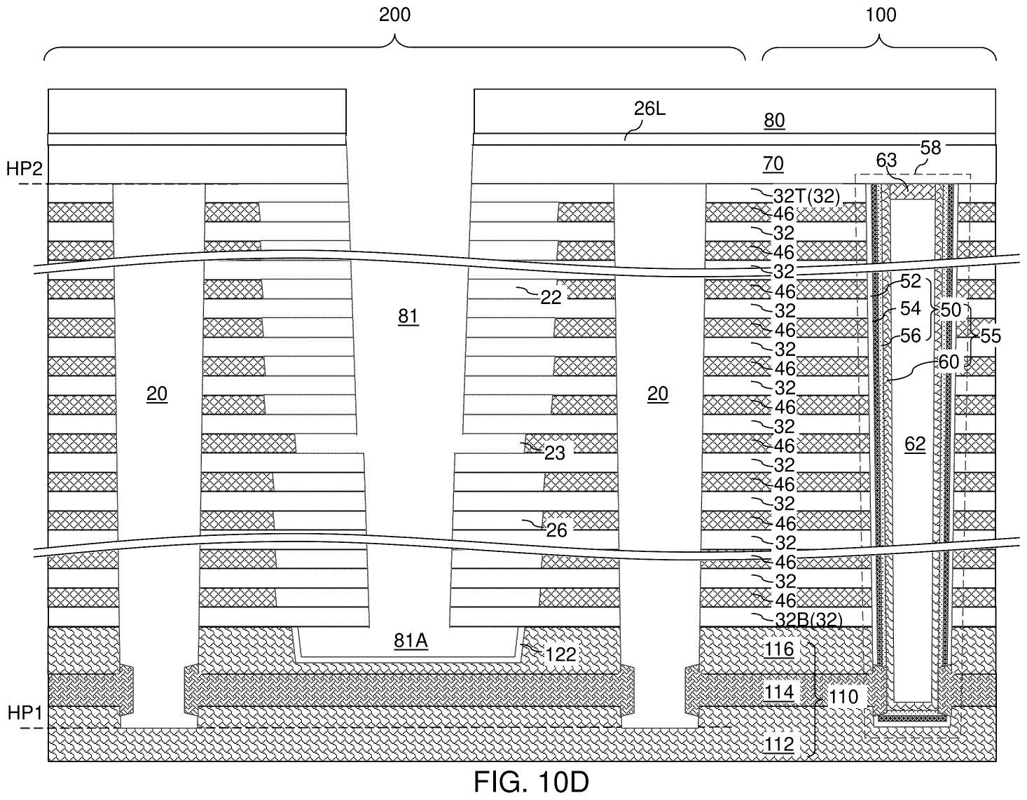

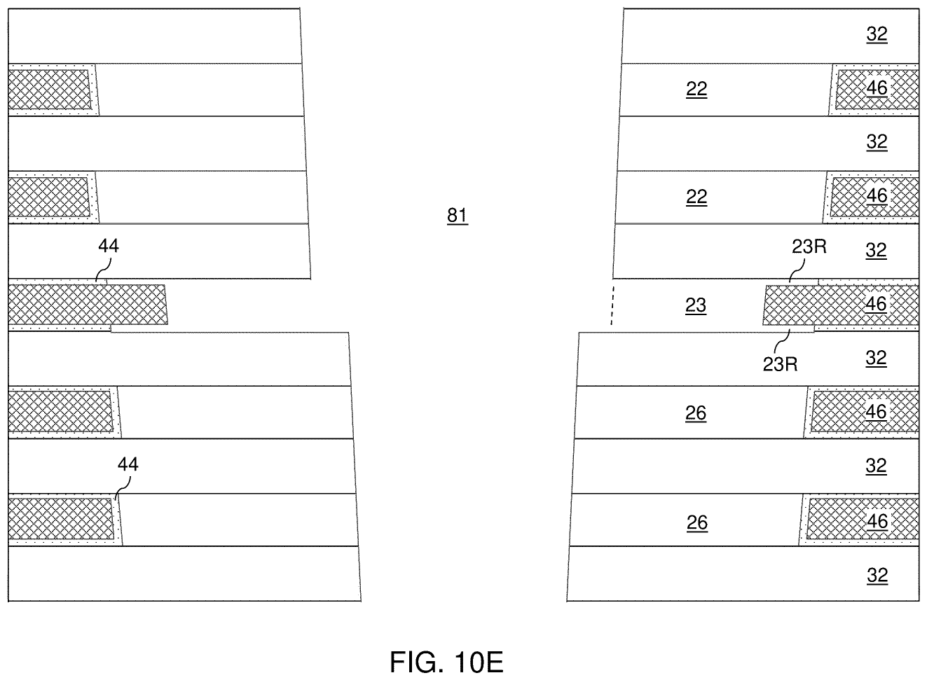

FIGS. 10A-10D are sequential vertical cross-sectional views of a region of the first exemplary structure during formation of a replacement contact via cavity 81 according to the first embodiment of the present disclosure. FIG. 10E is a magnified view of a portion of FIG. 10D.

Referring to FIG. 10A, a photoresist layer (not shown) can be applied over the contact-level dielectric layer 80, and can be lithographically patterned to form openings within the areas of the in-process layer contact assemblies 29. In one embodiment, areas of the openings in the photoresist layer may be the same as the areas of the sacrificial via fill material portions 27 in a plan view, such as a see-through top-down view. An anisotropic etch process can be performed to remove portions of the contact-level dielectric layer 80 that are not covered by the photoresist layer. Top surfaces of the sacrificial via fill material portions 27 can be exposed underneath the openings in the contact-level dielectric layer 80.

Subsequently, the sacrificial via fill material portions 27 can be removed selective to the materials of the contact-level dielectric layer 80 and the second insulating liner 26L. For example, a selective etch process or an ashing process (if the sacrificial via fill material portions 27 comprise a carbon-based material) may be employed to remove the sacrificial via fill material portions 27. If a selective etch process is employed, the selective etch process may comprise an isotropic etch process or an anisotropic etch process. A replacement contact via cavity 81 is formed in each combination of a volume from which a sacrificial via fill material portion 27 is removed and a volume of an overlying opening through the contact-level dielectric layer 80. In one embodiment, each replacement contact via cavity 81 may comprise an annular cavity 81A having a wider diameter than the replacement via cavity 81 and underlying the horizontal plane including the bottommost surface of the alternating stack (32, 46) and laterally surrounded by the upper source-level semiconductor layer 116.

Referring to FIG. 10B, any insulating liner, such as the second insulating liner 26L, that is the present around the replacement contact via cavity 81 can be removed by performing an isotropic etch process. For example, if the second insulating liner 26L comprises a silicon oxide material, a wet etch process employing dilute hydrofluoric acid may be performed to isotropically etch physically exposed portions of the second insulating liner 26L around the replacement contact via cavities 81. Inner cylindrical surfaces of the first annular insulating fins 22, inner cylindrical surfaces of the sacrificial fin structures 24, inner cylindrical surfaces of the second annular insulating fins 26, and surfaces of the upper source-level semiconductor layer 116 can be exposed around the replacement contact via cavities 81. As used herein, a “cylindrical surface” refers to a surface having a closed top periphery in the first horizontal plane, having a close to bottom periphery in the second horizontal plane, and vertically extending along a vertical direction without any taper angle relative to a vertical direction or without taper angle less than 15 degrees.

Referring to FIG. 10C, the sacrificial fin structures 24 can be removed selective to the materials of the insulating layers 32, the first annular insulating fins 22, the second annular insulating fins 26, the insulating cap layer 70, and the contact-level dielectric layer 80. If the sacrificial fin structures 24 comprise amorphous silicon or polysilicon, a wet etch process employing hot trimethyl-2 hydroxyethyl ammonium hydroxide (“hot TMY”) or tetramethyl ammonium hydroxide (TMAH) may be performed to remove the sacrificial fin structures 24. In this case, physically-exposed surface portions of the upper source-level semiconductor layer 116 may be collaterally recessed. Generally, the upper source-level semiconductor layer 116 may be sufficiently thick so that the source contact layer 114 is not exposed to the replacement contact via cavities 81 after removal of the sacrificial fin structures 24.

In summary, the replacement contact via cavity 81 may be formed by sequentially removing the sacrificial via fill material portions 27, portions of an insulating liner (such as the second insulating liner 26L) located around the voids formed by removal of the sacrificial via fill material portions 27, and the sacrificial fin structures 24 to reopen the second fin cavities 23. Voids are formed in each volume of the second fin cavities 23. In one embodiment, a cylindrical surface of a backside blocking dielectric layer can be physically exposed around the each second fin cavity 23.

Referring to FIGS. 10D and 10E, an oxidation process can be performed to convert physically exposed to surface portions of the upper source-level semiconductor layer 116 in the annular cavity 81A to semiconductor oxide liners 122, such as silicon oxide liners. The thickness of the semiconductor oxide liners 122 may be in the range from 20 nm to 40 nm, although lesser and greater thicknesses may also be employed.

Subsequently, a selective isotropic etch process may be performed to remove portions of the backside blocking dielectric layers 44 that are proximal to the second fin cavities 23, as shown in FIG. 10E. The selective isotropic etch process and etches the material of the backside blocking dielectric layers 44 selective to the materials of the electrically conductive layers 46, the insulating layers 32, the first annular insulating fins 22, the second annular insulating fins 26, the insulating cap layer 70, and the contact-level dielectric layer 80. For example, if the backside blocking dielectric layers 44 comprise aluminum oxide, a wet etch process employing hot phosphoric acid may be employed as the selective isotropic etch process. The isotropic etch process etches portions of the backside blocking dielectric layers 44 that are proximal to the replacement contact via cavities 81. For each backside blocking dielectric layer 44 that is exposed to a respective second fin cavity 23, the selective isotropic etch process may remove a cylindrical portion of the backside blocking dielectric layer 44, a top annular portion of the backside blocking dielectric layer 44 that is joined to a top periphery of the cylindrical portion, and the bottom annular portion of the backside blocking dielectric layer 44 that is adjoined to a bottom periphery of the cylindrical portion.

Each second fin cavity 23 can be expanded to include volumes of a pair of annular rim-shaped voids (e.g., flange-shaped voids) 23R having a respective height that is the same as the thickness of a backside blocking dielectric layer 44. Each replacement contact via cavity 81 comprises a respective second fin cavity 23 to which a respective first electrically conductive layer 46 is physically exposed. For each replacement contact via cavity 81 including a respective second fin cavity 23 located at a level other than the level of the topmost electrically conductive layer 46 or the level of the bottommost electrically conductive layer 46, at least one first annular insulating fin 22 overlies the respective second fin cavity 23 and at least one second annular insulating fin 26 underlies the respective second fin cavity 23. Each first annular insulating fin 22 is laterally surrounded by a respective second electrically conductive layer 46, and is laterally spaced from the respective second electrically conductive layer 46 by a respective backside blocking dielectric layer 44. Each second annular insulating fin 26 is laterally surrounded by a respective third electrically conductive layer 46, and is laterally spaced from the respective third electrically conductive layer 46 by a respective backside blocking dielectric layer 44.

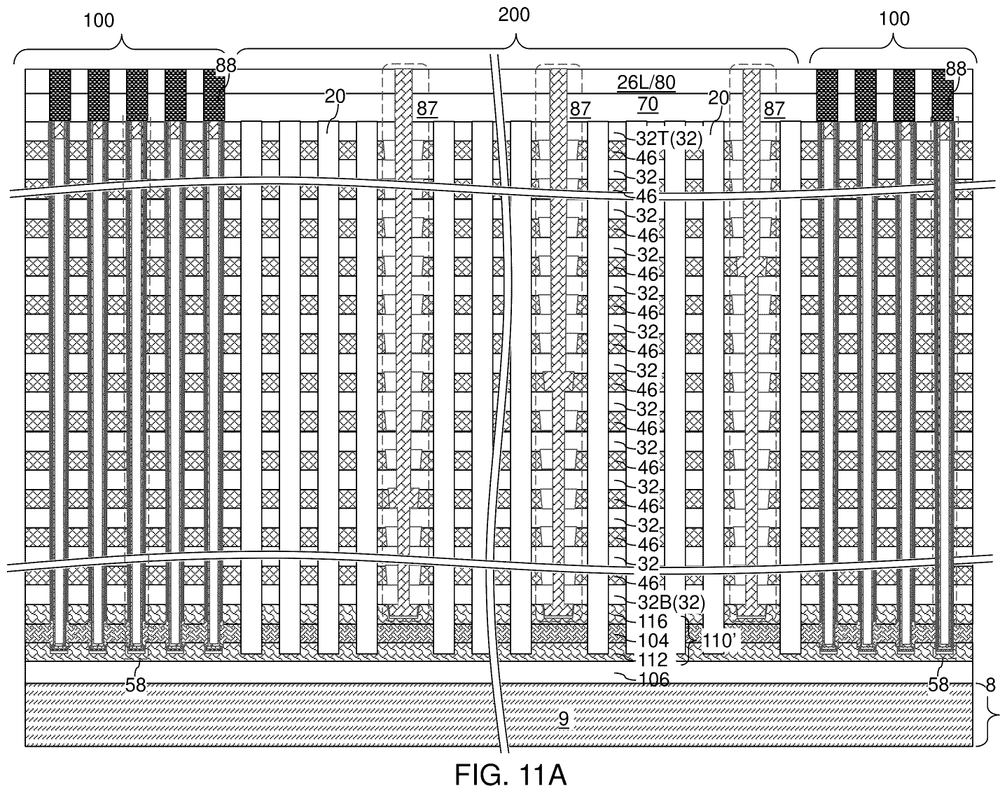

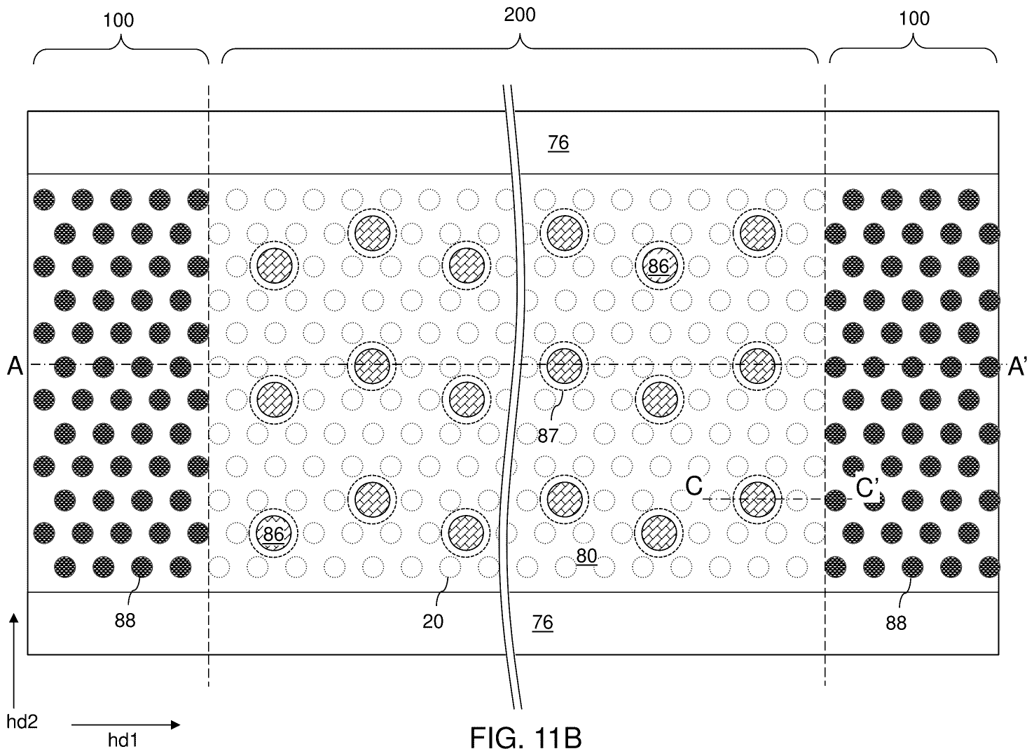

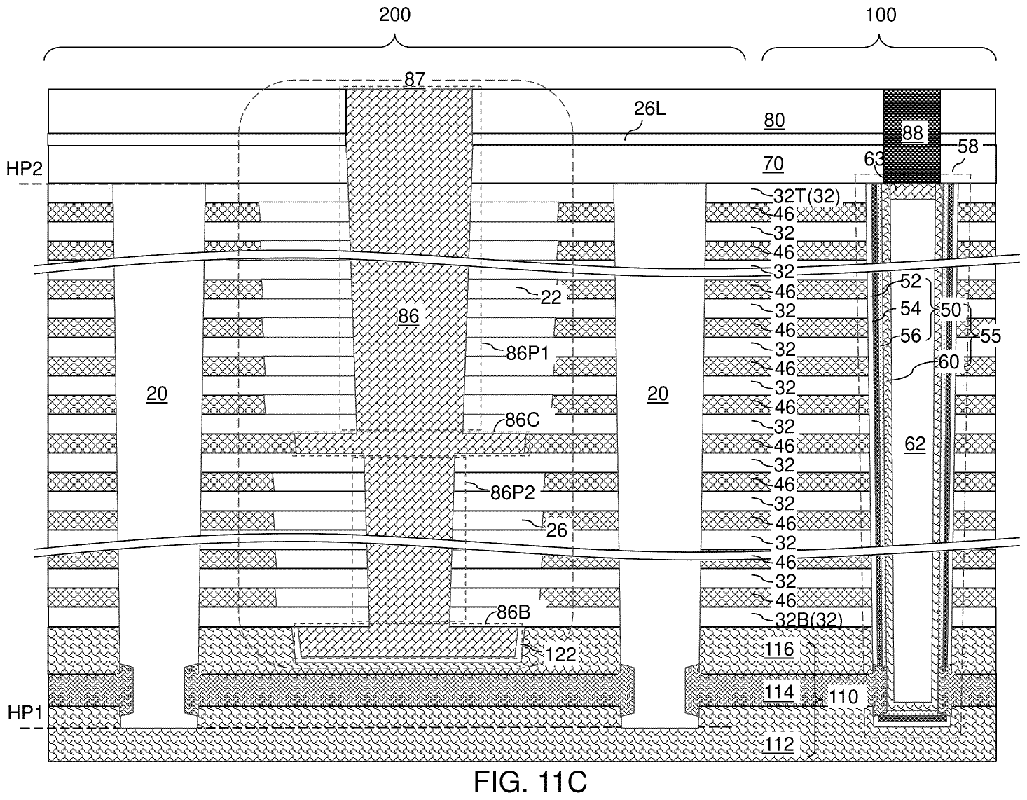

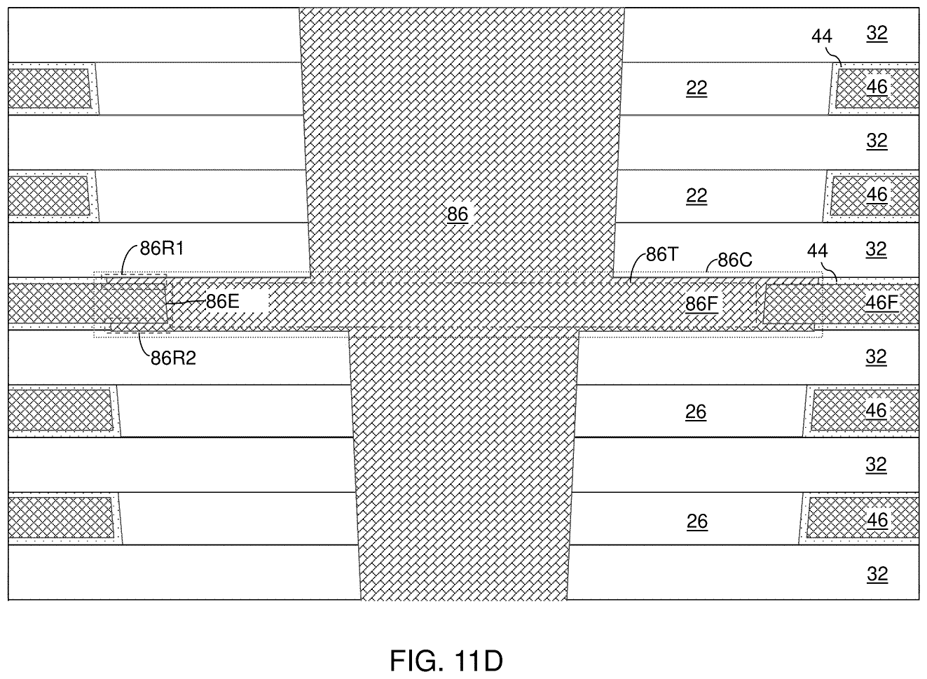

Referring to FIGS. 11A-11D, a photoresist layer (not shown) can be applied to over the contact-level dielectric layer 80, and can be lithographically patterned to form openings over the memory opening fill structures 58. An anisotropic etch process can be performed to transfer the pattern of the openings in the photoresist layer through the contact-level dielectric layer 80, the second insulating liner 26L, and the insulating cap layer 70. Drain contact via cavities are formed through the contact-level dielectric layer 80. The photoresist layer can be subsequently removed, for example, by ashing.

At least one conductive material can be deposited in the replacement contact via cavities 81 and the drain contact via cavities. The at least one conductive material may comprise a metallic barrier material and a metallic fill material. The metallic barrier material may comprise a metallic nitride material such as TiN, TaN, MoN and/or WN and/or a metallic carbide material such as TiC, TaC, and/or WC. The metallic fill material may comprise W, Ti, Ta, Ru, Co, Mo, Cu, etc. The at least one conductive material may be deposited by chemical vapor deposition, physical vapor deposition, electroplating, electroless plating, or combinations thereof. Excess portions of the at least one conductive material can be removed from above the horizontal plane including the top surface of the contact-level dielectric layer 80 by performing a planarization process, which may employ a chemical mechanical polishing (CMP) process or a recess etch process. Each remaining portion of the at least one conductive material filling a respective replacement contact via cavity 81 constitutes a layer contact via structure 86 that contacts top surface a respective first electrically conductive layer 46. Each remaining portion of the at least one conductive material filling a respective drain contact via cavity constitutes a drain contact via structure 88 that contacts top surface a respective drain region 63.

Each layer contact via structure 86 is formed directly on an edge of respective one of the first electrically conductive layer 46 exposed in the respective second fin cavity 23 (including in the annular rim-shaped voids 23R, if present). Each electrically conductive layer 46 within the alternating stack (32, 46) may be contacted by a respective layer contact via structure 86. Generally, each combination of a sacrificial via fill material portion 27 and a sacrificial fin structure 24 can be replaced with a layer contact via structure 86.

An array of layer contact assemblies 87 can be formed in the contact region 200 between each neighboring pair of isolation trench fill structures 76 that are spaced along the second horizontal direction hd2. Each layer contact assembly 87 comprises a layer contact via structure 86 vertically extending through each layer within the alternating stack (32, 46) and laterally contacting a cylindrical (e.g., edge) surface of the first electrically conductive layer 46.

In the first embodiment illustrated in FIGS. 11A-11D, a three-dimensional memory device comprises: an alternating stack (32, 46) of insulating layers 32 and electrically conductive layers 46 wherein the electrically conductive layers 46 comprise a first electrically conductive layer 46F (shown in FIG. 11D), second electrically conductive layers 46 that overlie the first electrically conductive layer 46F, and third electrically conductive layers 46 that underlie the first electrically conductive layer 46F; a memory opening 49 vertically extending through the alternating stack (32, 46); a memory opening fill structure 58 located in memory opening 49 and comprising a vertical stack of memory elements (e.g., portions of the memory film 50) located at levels of the electrically conductive layers 46 and vertical semiconductor channel 60; and a layer contact assembly 87 comprising a layer contact via structure 86 vertically extending through each layer within the alternating stack (32, 46) and laterally contacting a cylindrical surface of the first electrically conductive layer 46F, and further comprising first annular insulating fins 22 laterally surrounding the layer contact via structure 86 and located at each level of the second electrically conductive layers 46.

In one embodiment, the layer contact assembly 87 further comprises second annular insulating fins 26 laterally surrounding the layer contact via structure 86 and located at each level of the third electrically conductive layers 46. In one embodiment, each of the second annular insulating fins 26 is in direct contact with a respective cylindrical surface segment of the layer contact via structure 86. In one embodiment, each of the second annular insulating fins 26 is laterally spaced from a respective most proximal one of the third electrically conductive layers 46 by a respective backside blocking dielectric layer 44.

In one embodiment shown in FIG. 11C, the layer contact via structure 86 further comprises: a first pillar portion 86P1 that vertically extends through each of the second electrically conductive layers 46 and overlies the first electrically conductive layer 46F; a second pillar portion 86P2 that vertically extends through each of the third electrically conductive layers 46 and underlies the first electrically conductive layer 46F; and a connector portion 86C located at a level of the first electrically conductive layer 46F and having a greater lateral extent than the first pillar portion 86P1 and than the second pillar portion 86P2, and connecting the first pillar portion 86P1 and the second pillar portion 86P2.

In one embodiment shown in FIG. 11D, the connector portion 86C comprises a dual-rimmed annular connector portion (86T, 86R1, 86R2) which comprises: a connector plate 86T having a uniform thickness between an annular top surface and an annular bottom surface; a first annular rim 86R1 extending outward from the connector plate 86T and having a top surface within a horizontal plane including the annular top surface of the connector plate 86T; and a second annular rim 86R2 extending outward from the connector plate 86T and having a bottom surface within a horizontal plane including the annular bottom surface of the connector plate 86T.

In one embodiment shown in FIG. 11D, the first electrically conductive layer 46F (which is in direct contact with the layer contact via structure 86) is embedded within a backside blocking dielectric layer 44 that contacts a cylindrical surface segment of the memory opening fill structure 58; and each of the first annular rim 86R1 and the second annular rim 86R2 has a thickness that equals a thickness of the backside blocking dielectric layer 44. In one embodiment, the uniform thickness of the connector plate 86T equals a sum of a thickness of the first electrically conductive layer 46 and twice a thickness of the backside blocking dielectric layer 44.

In one embodiment shown in FIG. 11D, an annular bottom surface segment of the first annular rim 86R1 contacts an annular top surface segment of the first electrically conductive layer 46; and an annular top surface segment of the second annular rim 86R2 contacts an annular bottom surface segment of the first electrically conductive layer 46. In one embodiment, a cylindrical edge surface 86E of the connector plate 86T vertically extends between the first annular rim 86R1 and the second annular rim 86R2; and an entirety of the cylindrical edge surface 86E of the connector plate 86T is in contact with a cylindrical edge surface segment of the first electrically conductive layer 46.

In one embodiment shown in FIG. 11C, a bottom periphery of the first pillar portion 86P1 is wider than a top periphery of the second pillar portion 86P2, and is vertically spaced from the top periphery of the second pillar portion 86P2 by a vertical spacing that equals a thickness of the connector plate 86T.

In one embodiment shown in FIG. 11C, the layer contact assembly 87 comprises a base portion 86B underlying the second pillar portion 86P2 and embedded within the substrate 8, wherein the base portion is wider than the second pillar portion. In one embodiment, an entirety of the base portion 86B of the layer contact via structure 86 underlies a horizontal plane including a bottommost surface of the alternating stack (32, 46), and is in contact with an insulating surface, such as a surface of a semiconductor oxide liner 122.

In one embodiment shown in FIG. 11D, each of the first annular insulating fins 22 contacts or is laterally spaced by a respective backside blocking dielectric layer 44 from a respective one of the second electrically conductive layers 46.

The device of the first embodiment provides compact lengths of portions of the insulating layers 32 that extend between the support pillar structures 20 and the layer contact assembly 87 in the contact region 200. This prevents or reduces buckling of the portions of the insulating layers 32 located in the contact region 200 into the laterally-extending cavities 43 during replacement of the sacrificial material layers 42 with the electrically conductive layers 46. Furthermore, the layer contact via structure 86 is electrically isolated from the electrically conductive layers 46 by the fins (22, 26) except at its respective first electrically conductive layer 46F. This reduces or eliminates unintended short circuits and leakage current between the layer contact via structure 86 and the second and third electrically conductive layers 46.

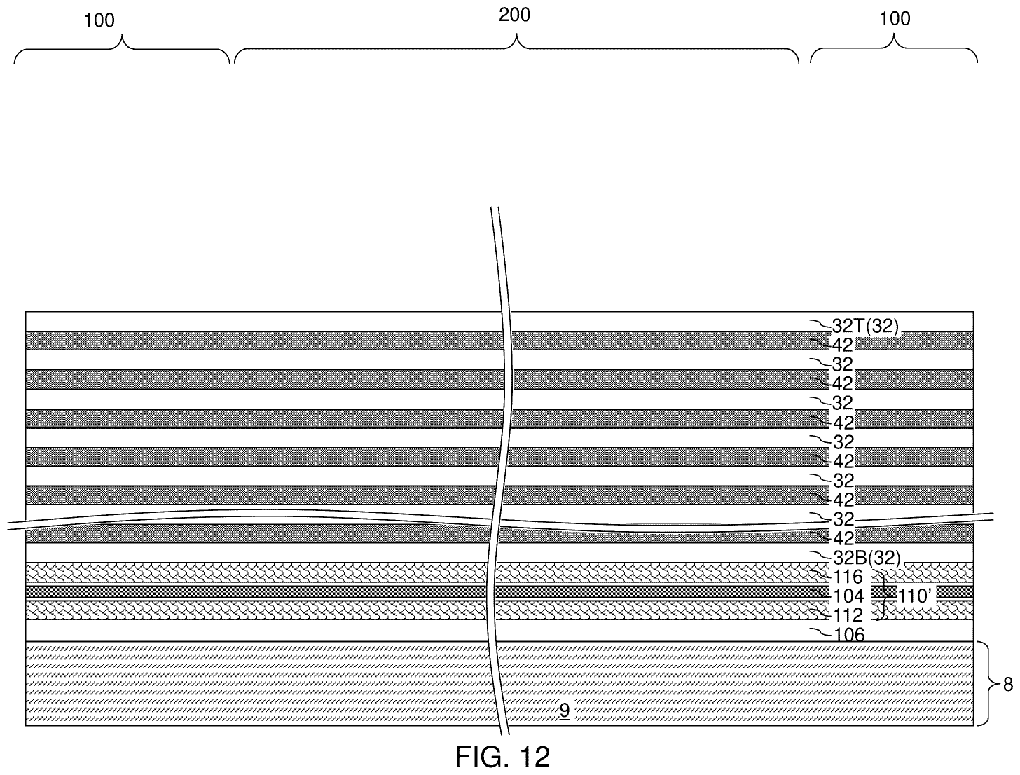

Referring to FIG. 12, a second exemplary structure according to the second embodiment of the present disclosure can be derived from the first exemplary structure illustrated in FIG. 2, up to the formation of etch-stop plates 118. The etch-stop plates 118 may be excluded in the second embodiment.

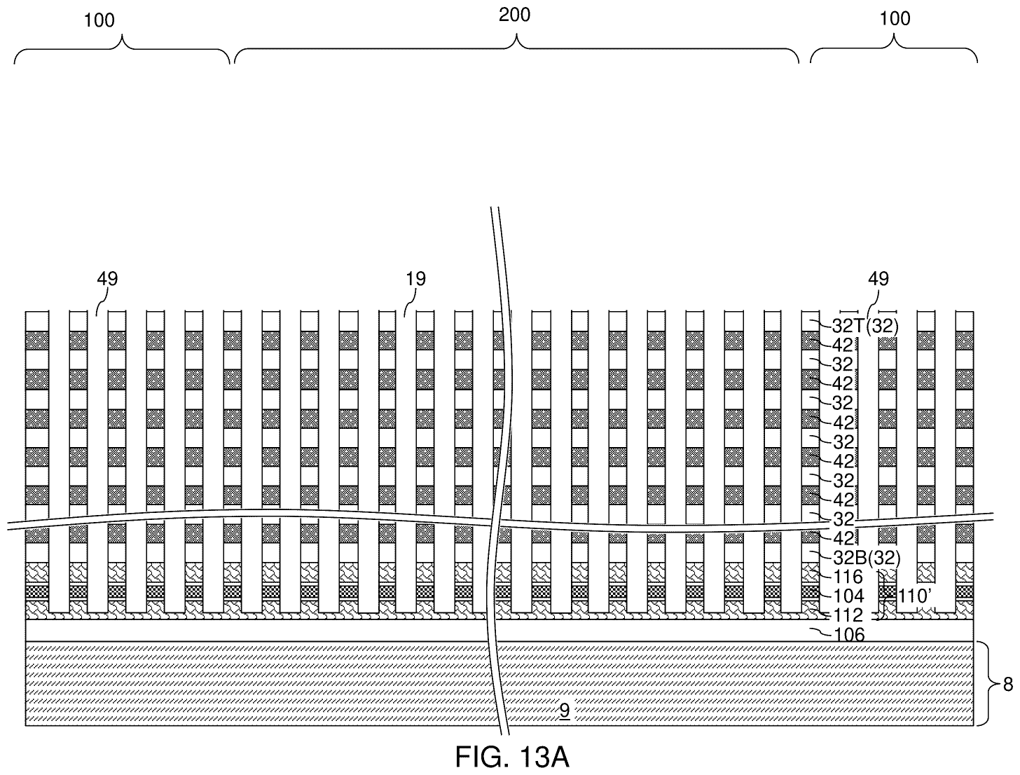

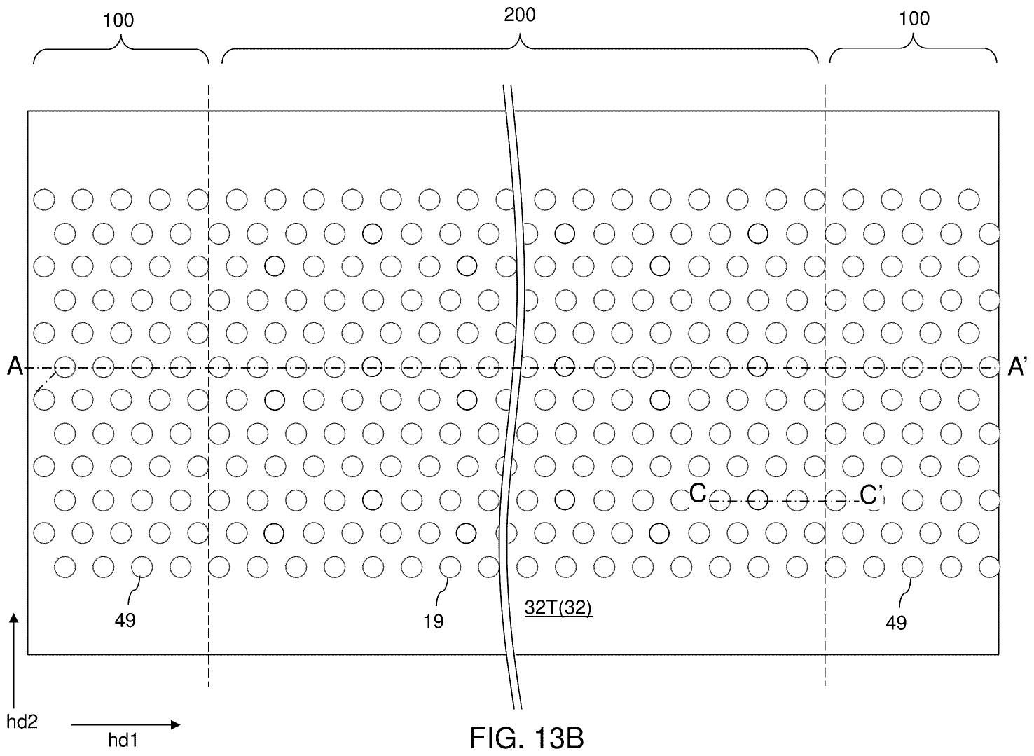

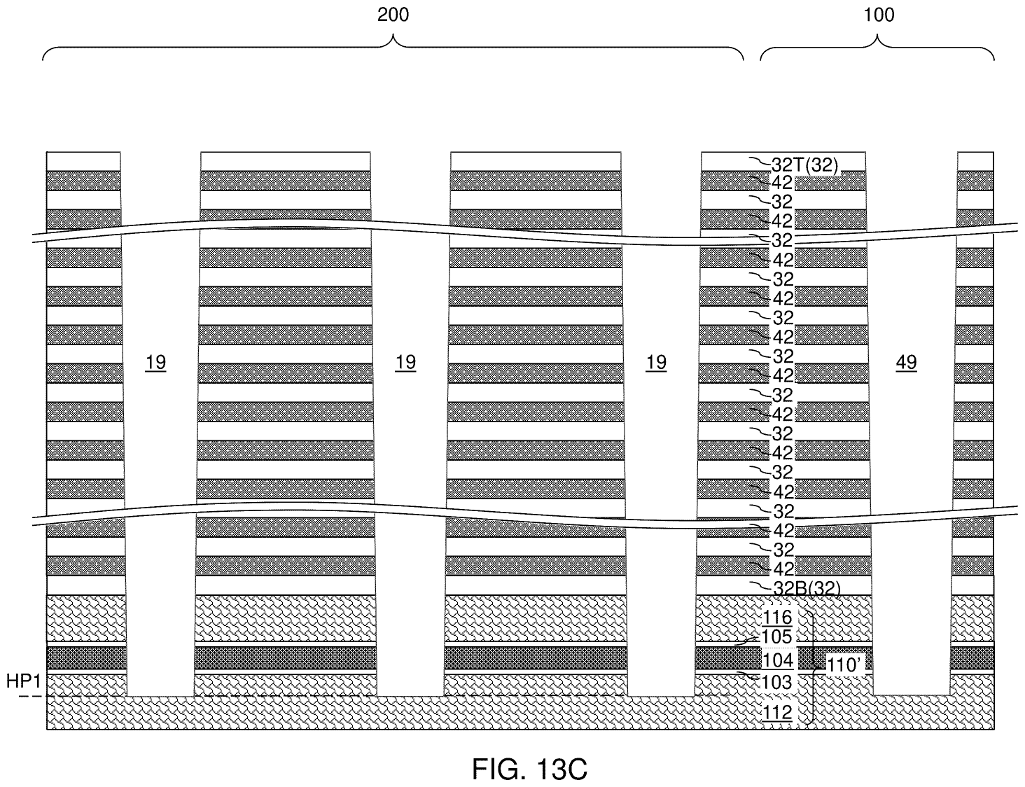

Referring to FIGS. 13A-13C, the processing steps described with reference to FIGS. 3A-3C can be performed to form support openings 19 and memory openings 49. In the second exemplary structure, the pattern of the support openings 19 may be modified relative to the pattern of the support openings 19 in the first exemplary structure such that the support openings are formed as periodic arrays. In this case, a support opening 19 can be formed at each lattice site of a two-dimensional periodic array, which may be a hexagonal array or a rectangular array. In the second exemplary structure, support opening 19 is formed at each location at which a layer contact via structure is to be subsequently formed. Thus, support openings 19 may be formed at the center and vertices of the hexagonal array.

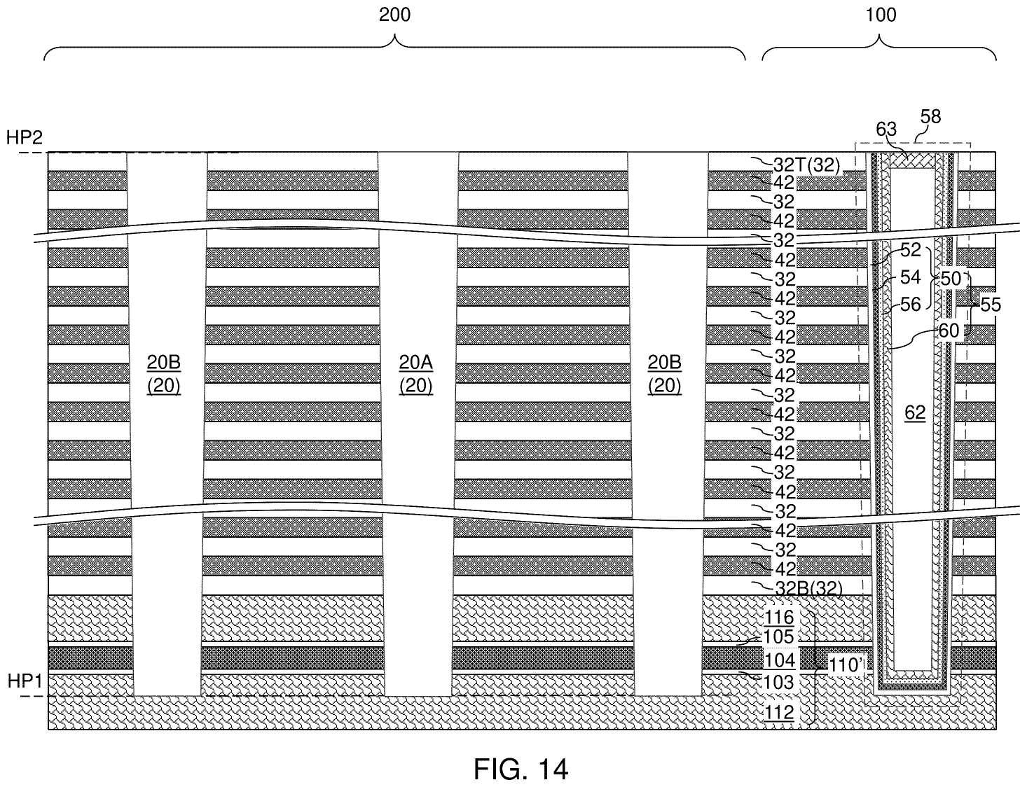

Referring to FIG. 14, the processing steps described with reference to FIGS. 4A-4E can be performed to form a dielectric support pillar structure 20 in each support opening 19, and to form a memory opening fill structure 58 in each memory opening 49.

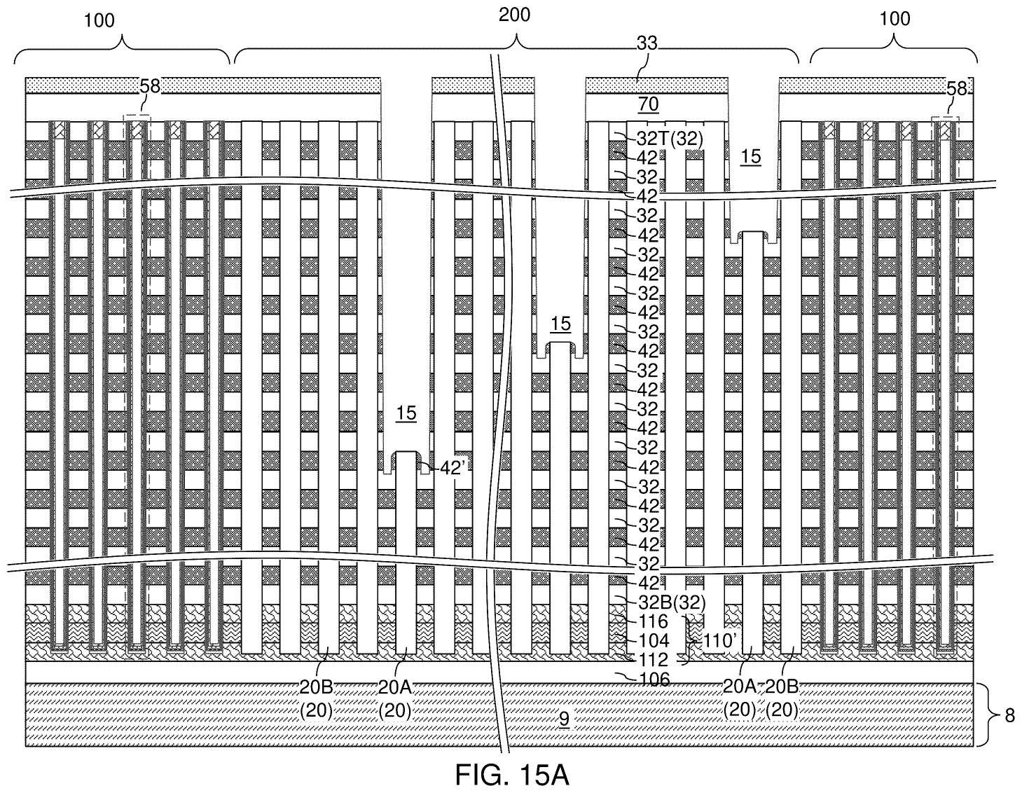

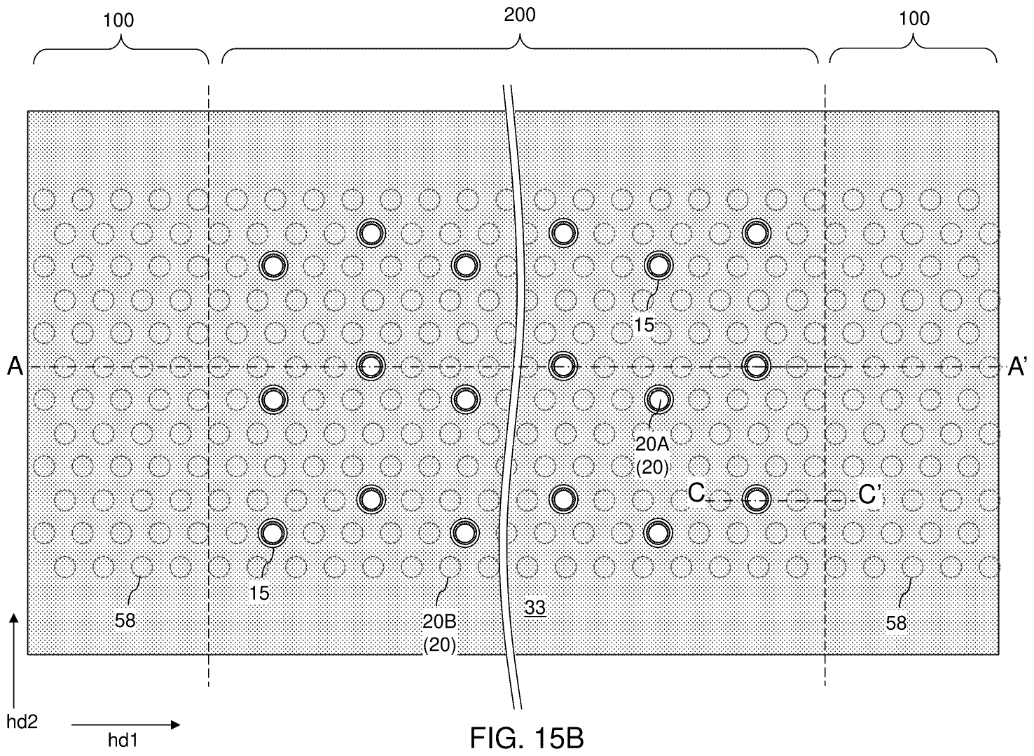

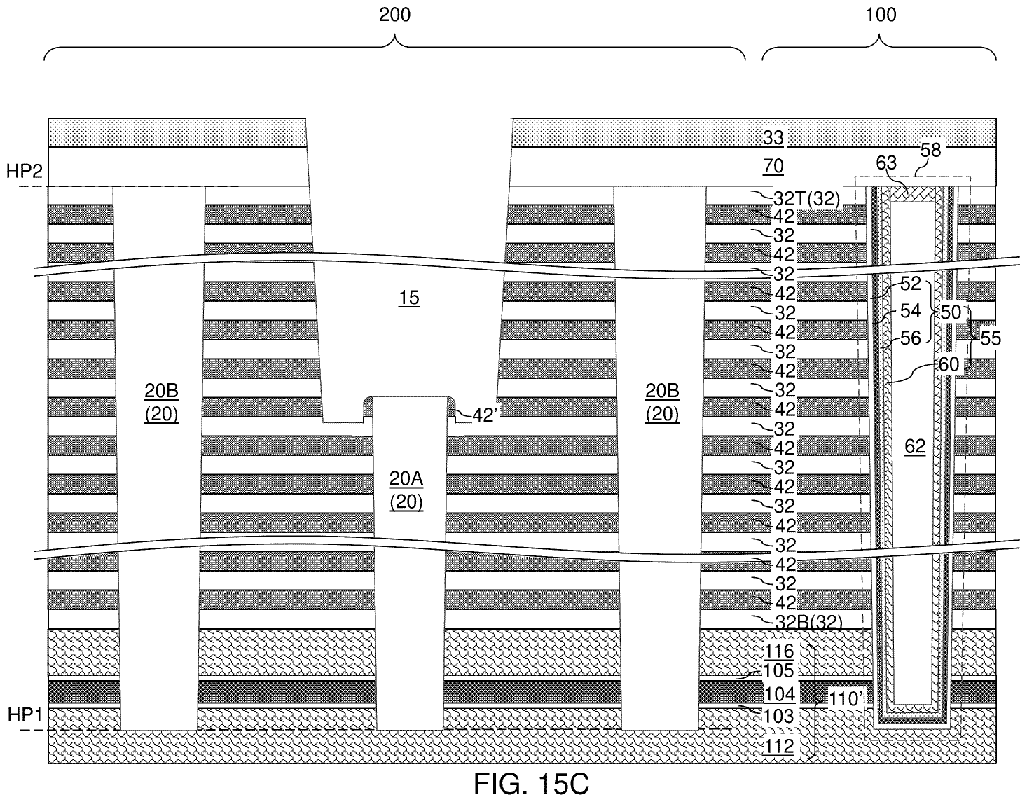

Referring to FIGS. 15A-15C, an insulating cap layer 70 can be formed over the alternating stack (32, 42), the memory opening fill structures 58, and the dielectric support pillar structures 20. The insulating cap layer 70 comprises an insulating material, such as silicon oxide, and may have a thickness in a range from 20 nm to 300 nm, although lesser and greater thicknesses may also be employed.

Subsequently, contact via cavities 15 having different depths can be formed in the contact region 200 through the insulating cap layer 70 and a respective subset of layers within the alternating stack (32, 42). Each of the contact via cavities 15 may be formed by etching an upper portion of a respective dielectric support pillar structure 20 that is laterally surrounded by a set of neighboring dielectric support pillar structures 20, and by etching a portion of the alternating stack (32, 42) that is proximal to the etched portion of the respective dielectric support pillar structure 20. In one embodiment, each of the contact via cavities 15 may be centered over a respective dielectric support pillar structure 20 that is laterally surrounded by a set of neighboring dielectric support pillar structures 20. Each contact via cavity 15 can have a respective area in a plan view, such as a top-down view, which includes an entirety of the respective dielectric support pillar structure 20, and does not have any areal overlay with the set of neighboring dielectric support pillar structures 20. Thus, a first subset of the dielectric support pillar structures 20 having an areal overlap with a respective one of the contact via cavities 15 are vertically recessed during formation of the contact via cavities 15, while a second subset of the dielectric support pillar structures 20 that do not have any areal overlap within the contact via cavities 15 are not vertically recessed during formation of the contact via cavities 15.

The first subset of the dielectric support pillar structures 20 is herein referred to as first-type dielectric support pillar structures 20A, and the second subset of the dielectric support pillar structures 20 is herein referred to as second-type dielectric support pillar structures 20B. The contact via cavities 15 vertically extend through a respective subset of the layers within the alternating stack (32, 42), and overlie a respective first-type dielectric support pillar structure 20A. Each of the contact via cavities 15 has a respective bottom surface that includes a top surface of a respective first-type dielectric support pillar structure 20A and an annular top segment of a respective insulating layer 32.

The contact via cavities 15 can be formed using any suitable methods, as the method described above with respect to FIGS. 5A-5C which utilizes the patterned hard mask layer 33 formed over the alternating stack (32, 42). Any unmasked portion of the first-type dielectric support pillar structures 20A may be collaterally etched by selecting the etch chemistry of the various etch steps of an anisotropic etch process such that the overall etch rate for the material of the dielectric support pillar structures 20 matches the overall etch rate for a combination of an insulating layers 32 and a sacrificial material layer 42.

Each contact via cavity 15 can be formed by vertically recessing the first-type dielectric support pillar structure 20A and a neighboring portion of the alternating stack (32, 42) such that a remaining portion of the first-type dielectric support pillar structure 20A is present underneath the contact via cavity 15. The first-type dielectric support pillar structure 20A comprises a top surface that is physically exposed to an overlying contact via cavity 15. An annular horizontal surface segment of an insulating layer 32 may be physically exposed at the bottom of each contact via cavity 15. The second-type dielectric support pillar structures 20B are not recessed during formation of the contact via cavities 15. In one embodiment, each first-type dielectric support pillar structure 20A can be laterally surrounded by a set (e.g., four to six) of second-type dielectric support pillar structures 20B having a greater vertical extent than the first-type dielectric support pillar structure 20A.

In one embodiment shown in FIG. 15C, bottom surfaces of the first-type dielectric support pillar structure 20A and the second-type dielectric support pillar structures 20B are located within the same first horizontal plane HP1 that underlies the alternating stack (32, 42). However, the top surfaces of the second-type dielectric support pillar structures 20B are located within a second horizontal plane HP2 including a topmost surface of the alternating stack (32, 42), while the top surfaces of the first-type dielectric support pillar structures 20A are located below the second horizontal plane HP2.

Each contact via cavity 15 may be formed through a respective first subset of the sacrificial material layers 42 by etching an upper portion of a respective first-type dielectric support pillar structure 20A. The respective first-type dielectric support pillar structure 20A has a reduced height and sidewalls of the first subset of the sacrificial material layers 42 are exposed. In one embodiment, each insulating layer 32 other than the bottommost insulating layer 32B may have a respective annular surface segment that is exposed to a respective contact via cavity 15.

In some embodiments, the anisotropic etch process that etches the contact via cavities 15 may etch the first-type dielectric support pillar structures 20A at a lower average etch rate than the average etch rate for the materials of the alternating stack (32, 42). In this case, a physically exposed top surface of a first-type dielectric support pillar structure 20A may be formed above a physically exposed annular surface of an insulating layer 32 at bottom portions of a subset of the contact via cavities 15. In this case, an etched remaining portion of a sacrificial material layer 42 may form an annular sacrificial material spacer 42′ having a generally tubular configuration surrounding the respective first-type dielectric support pillar structure 20A at the bottoms of the contact via cavities 15.

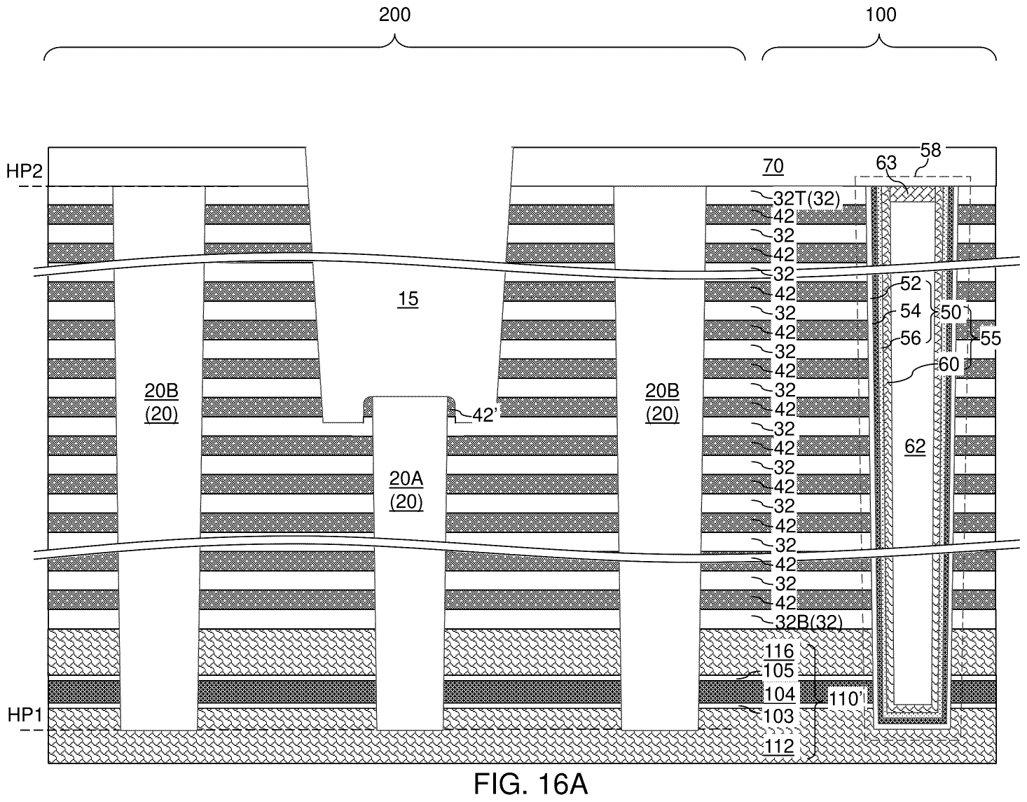

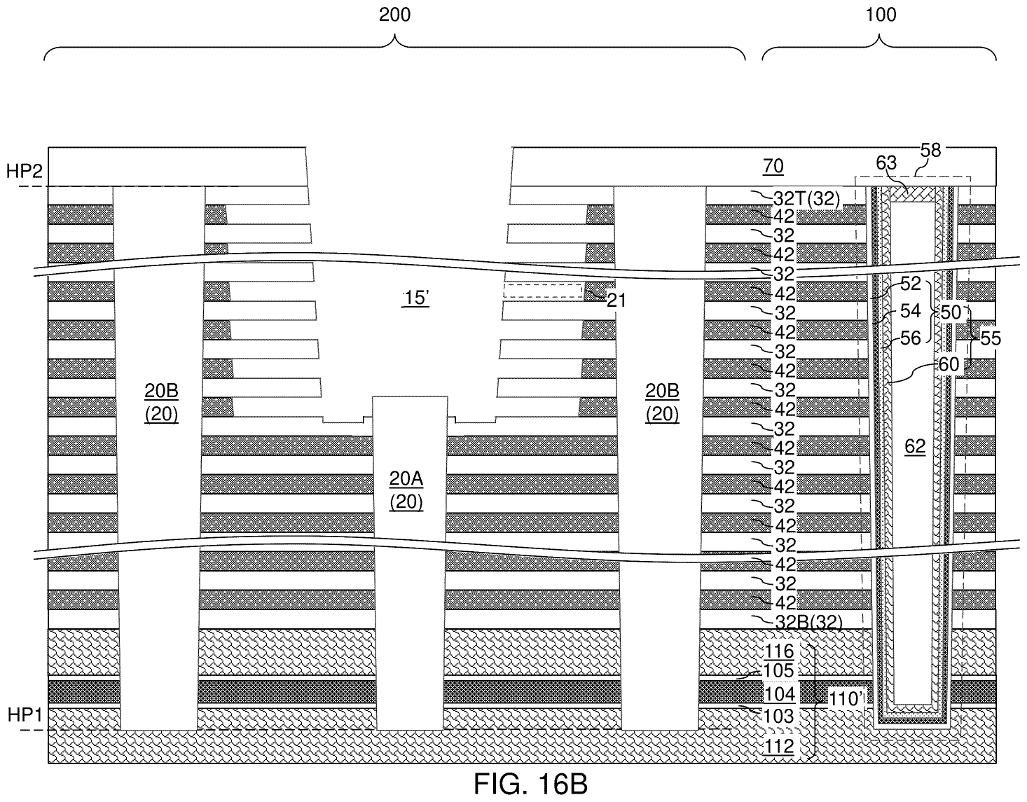

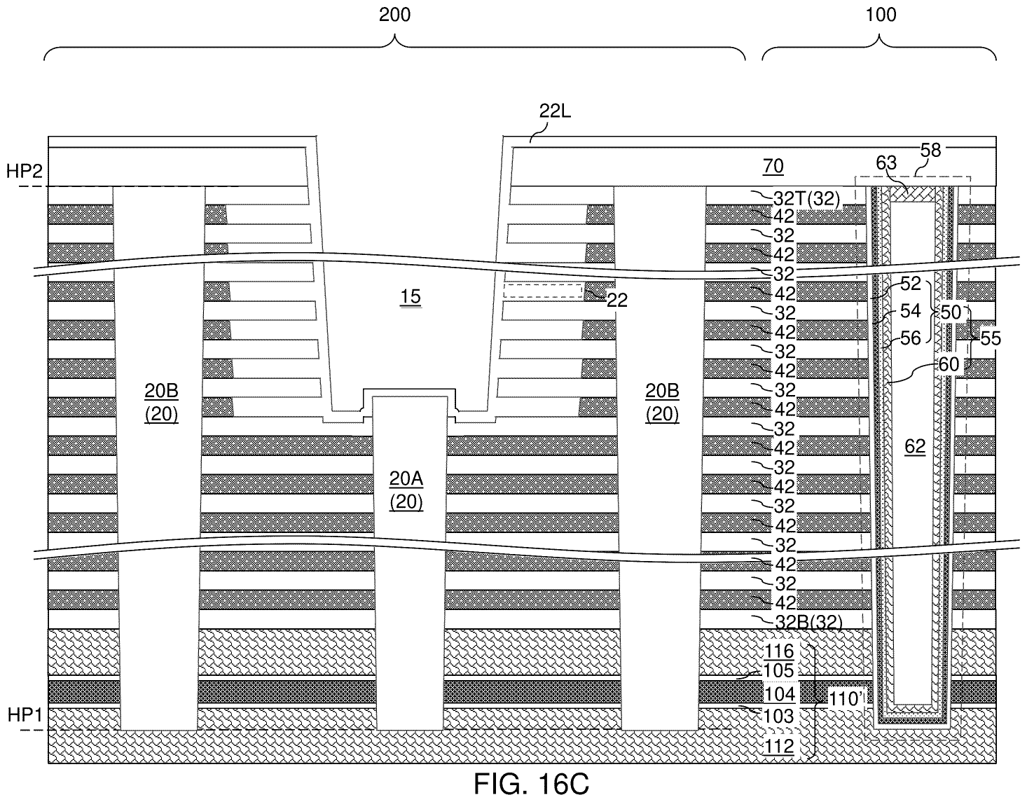

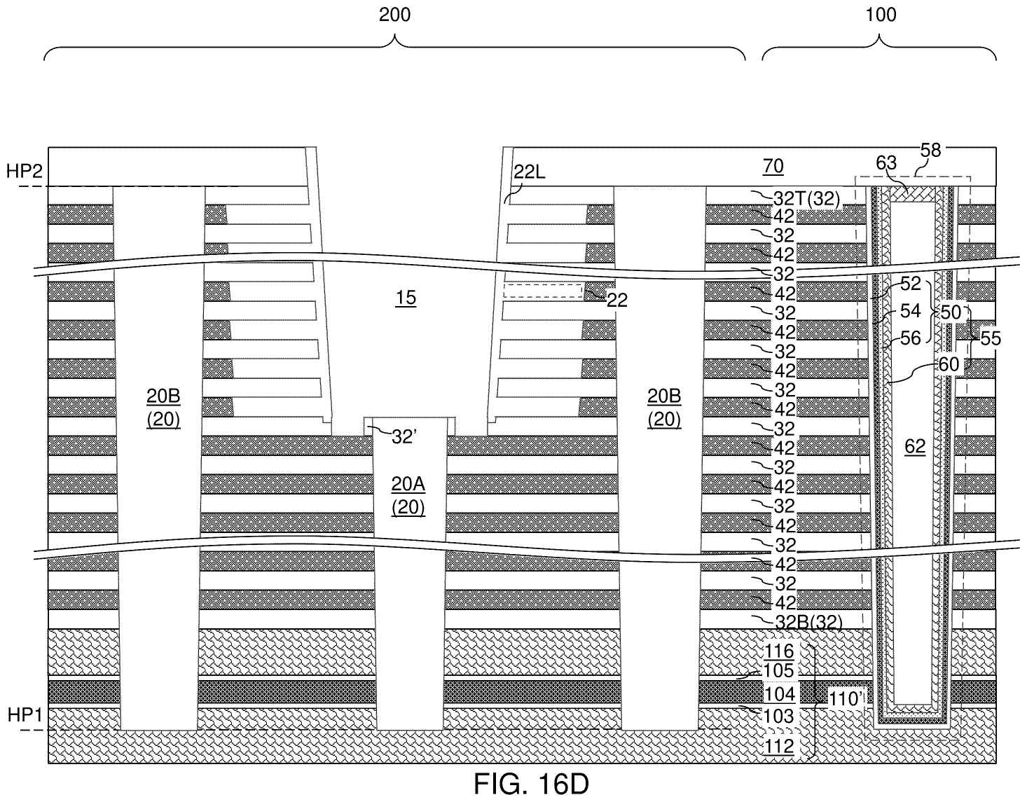

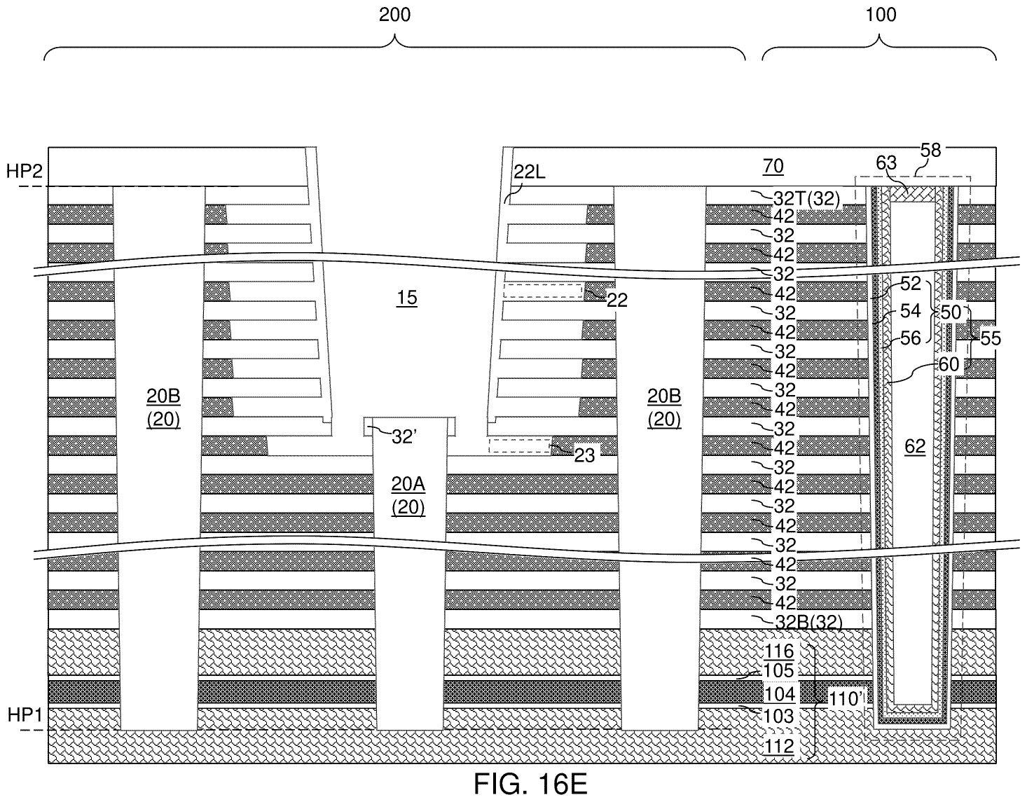

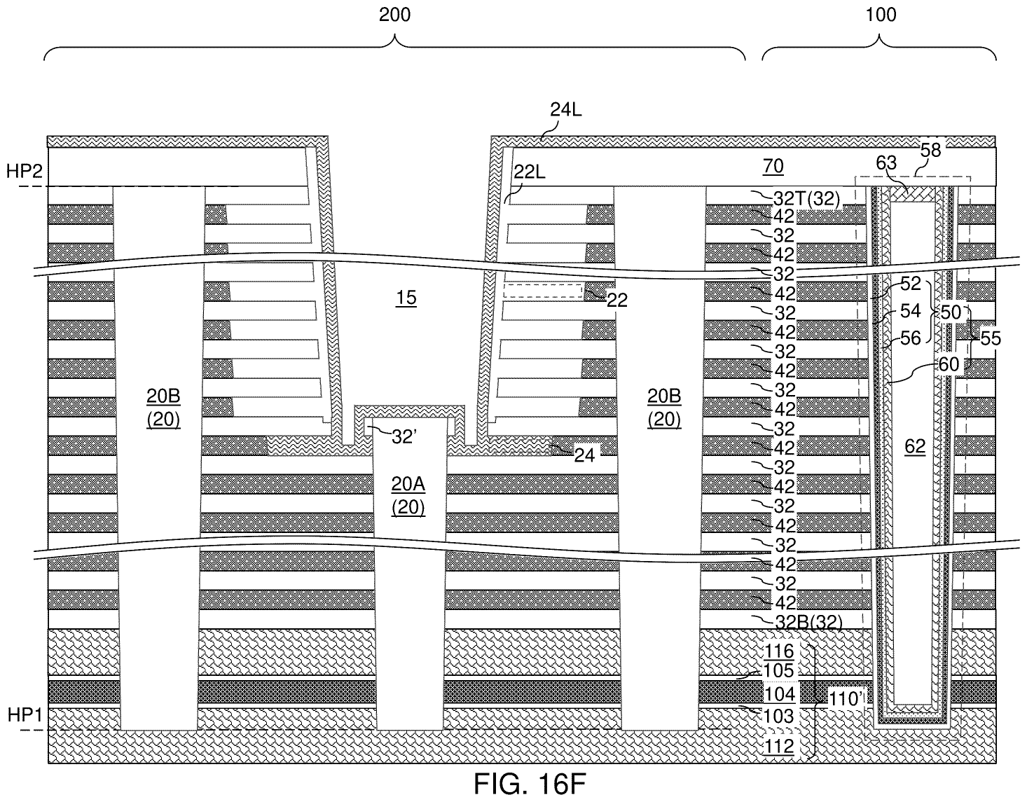

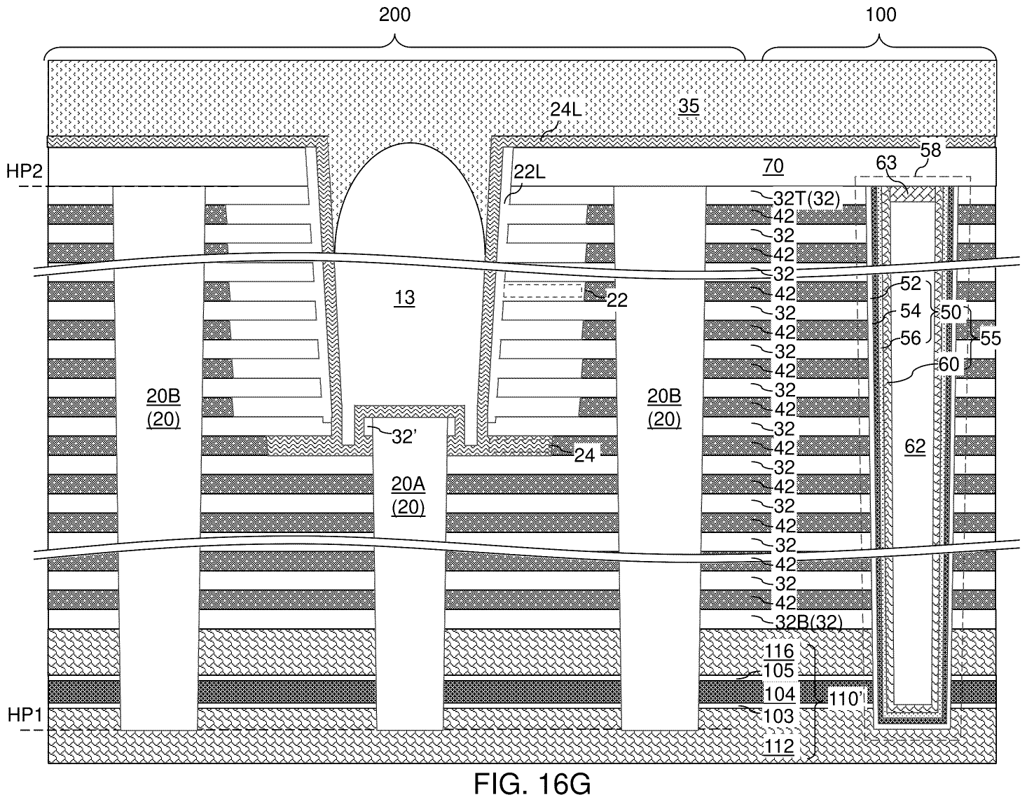

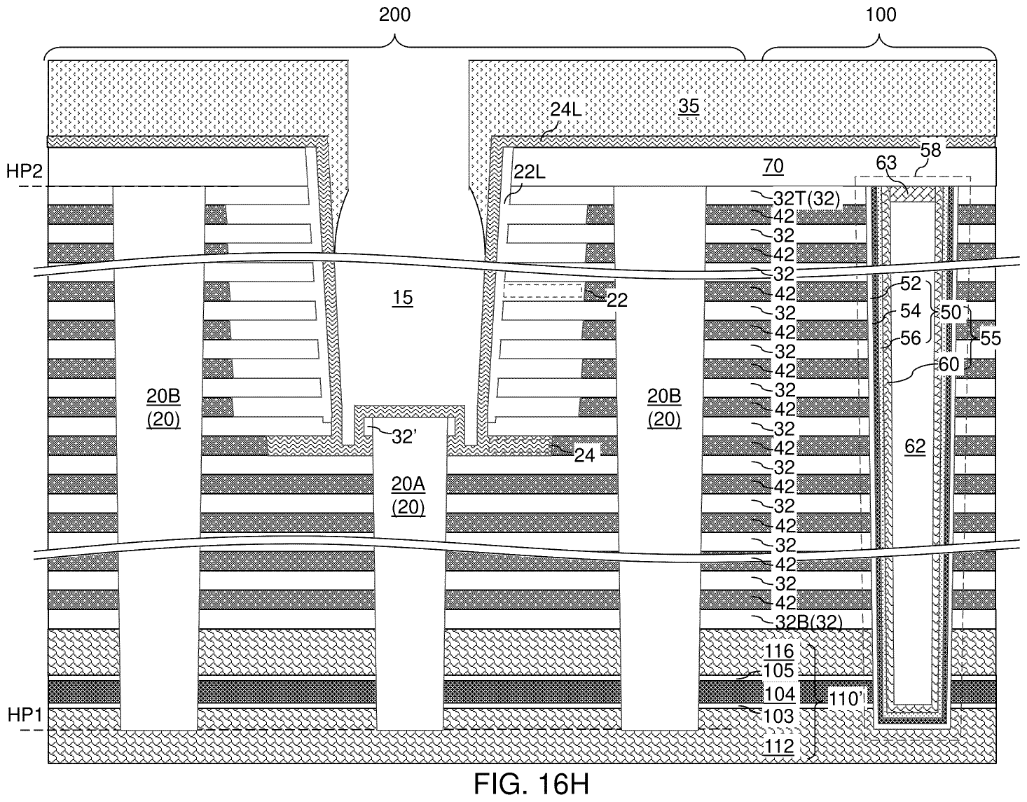

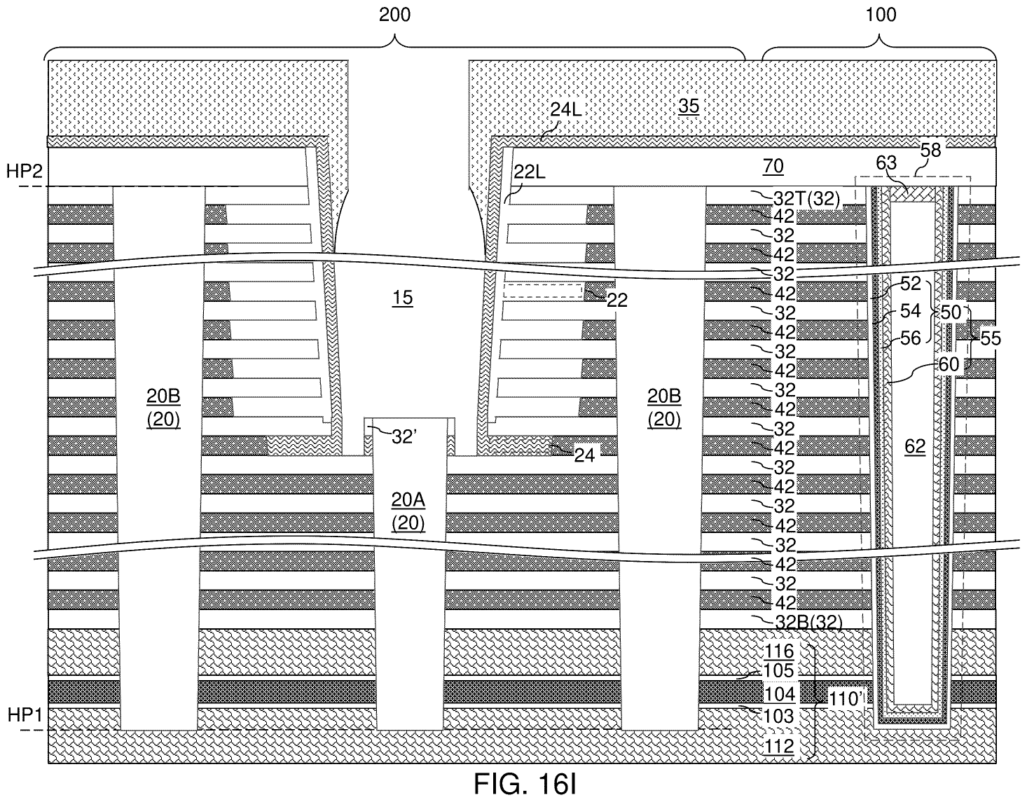

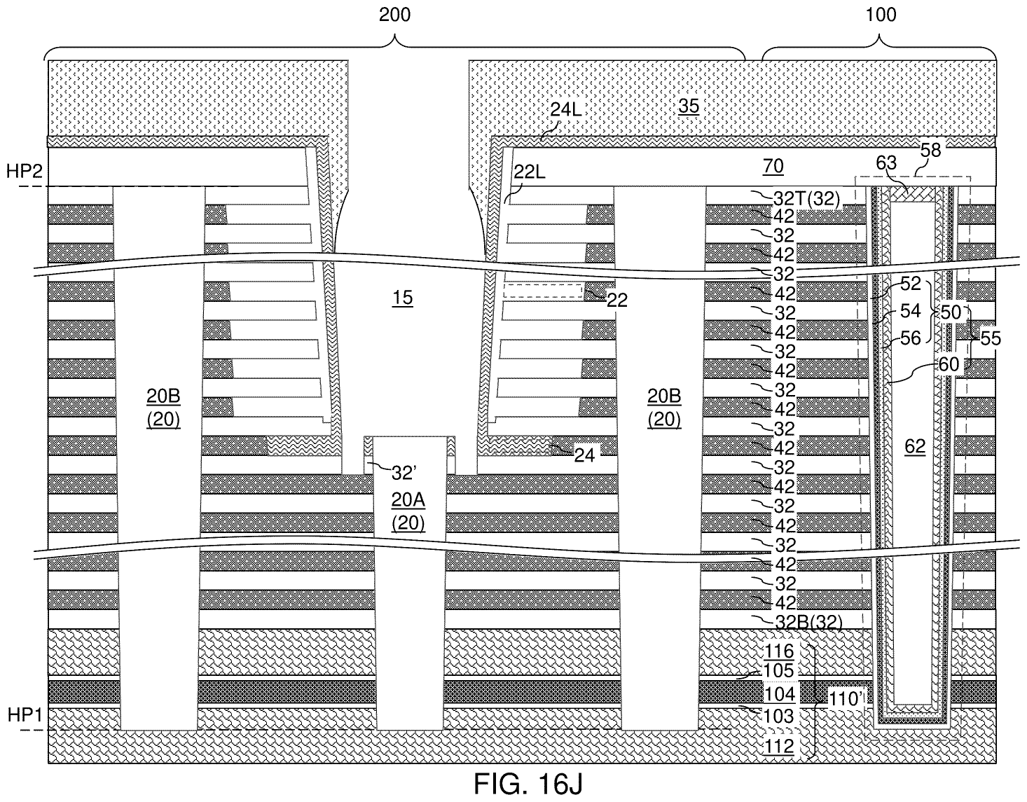

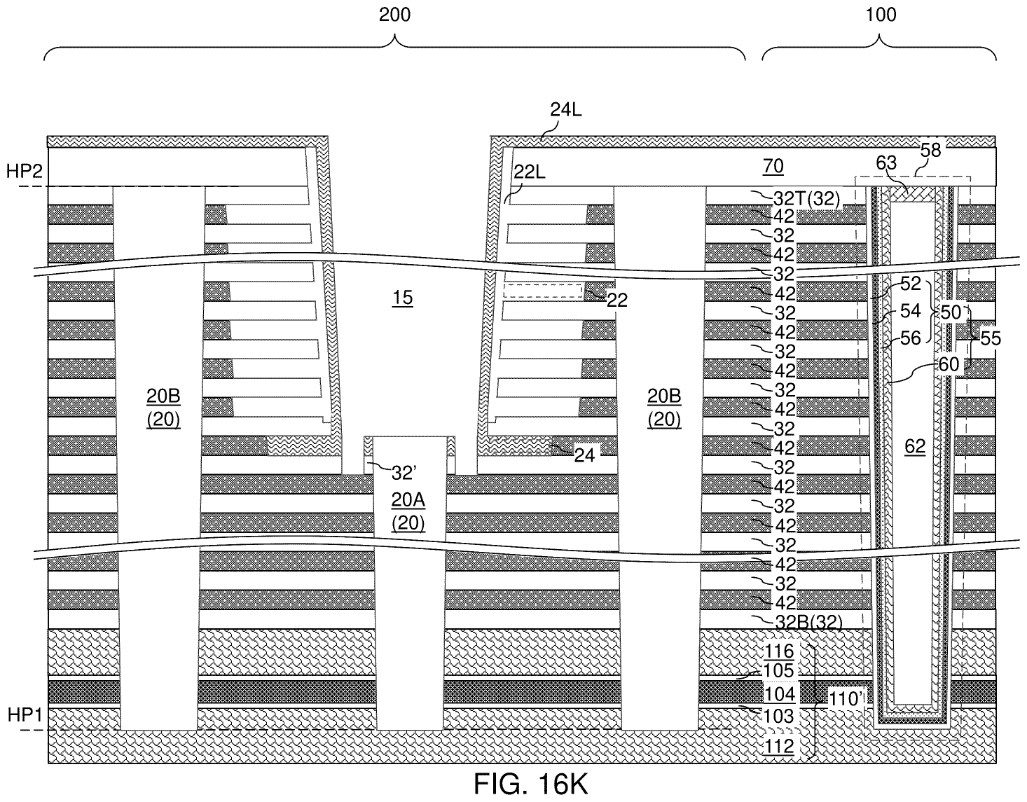

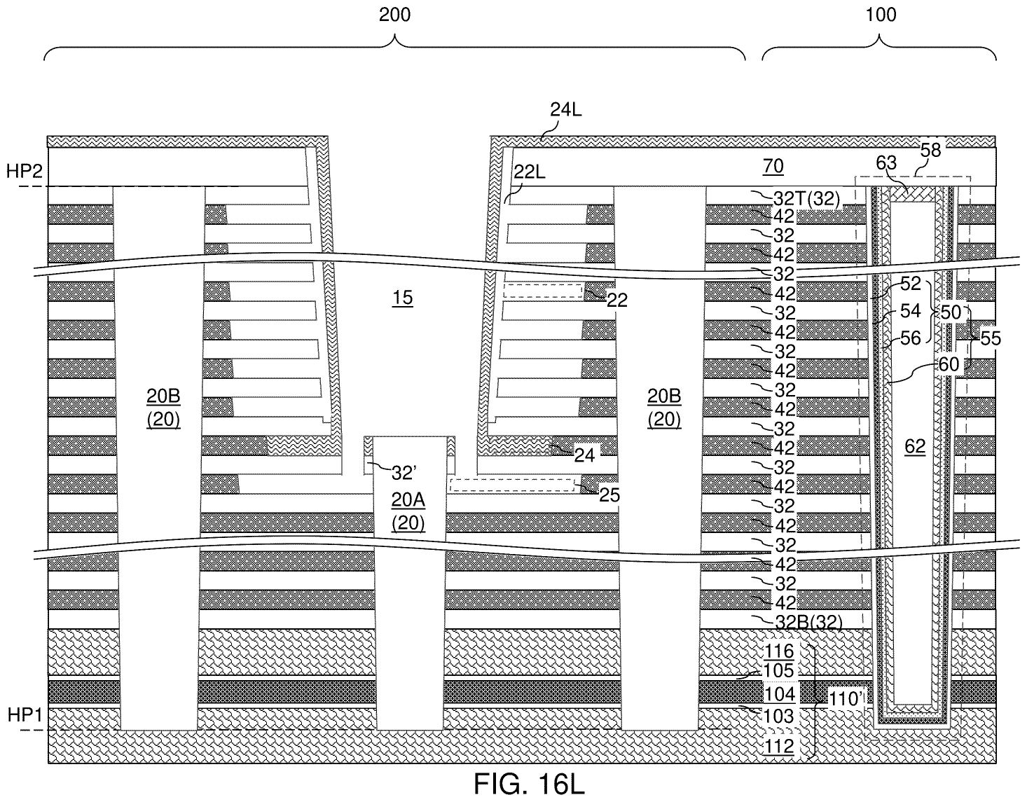

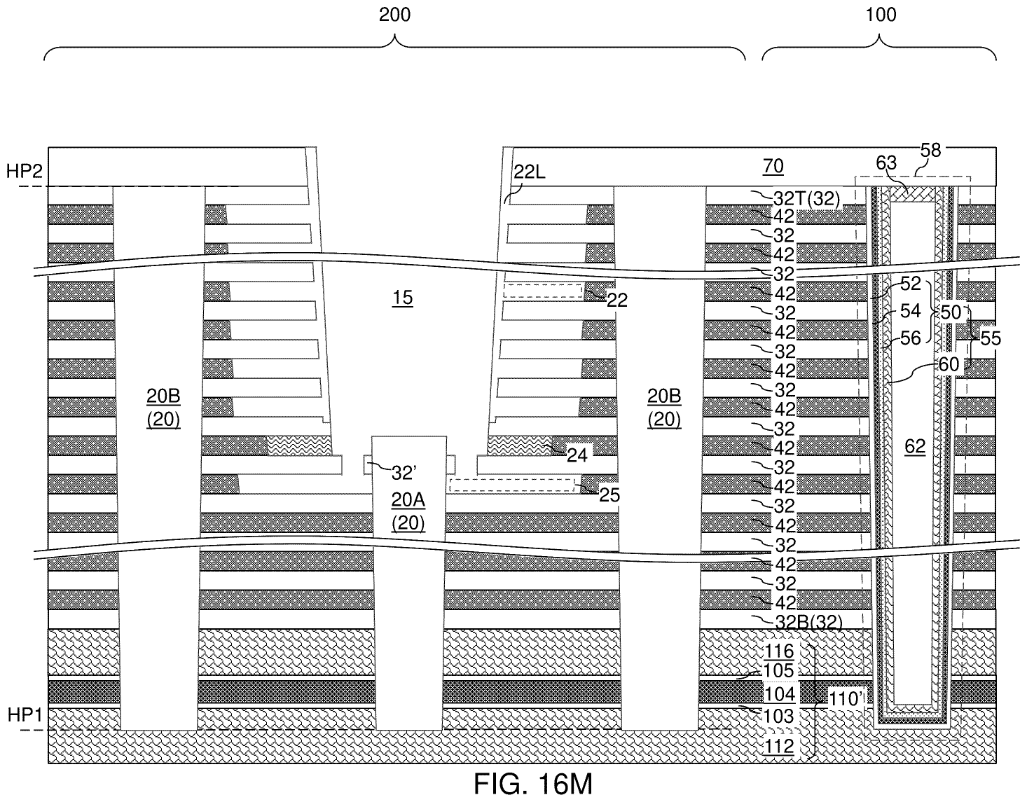

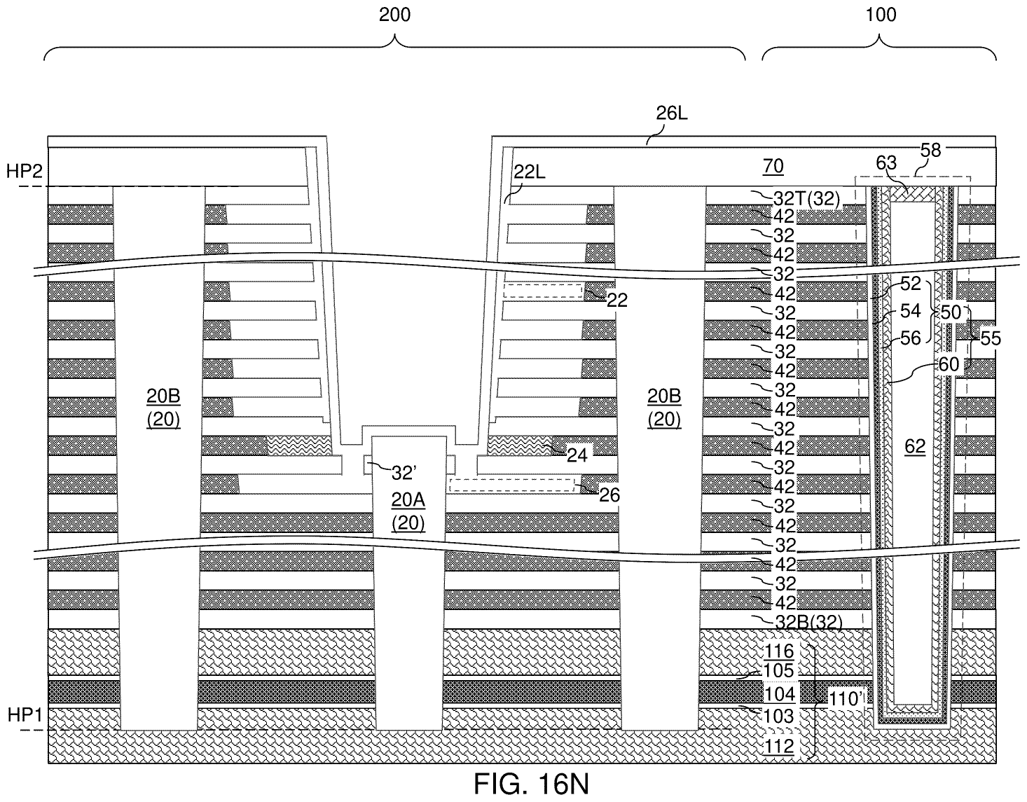

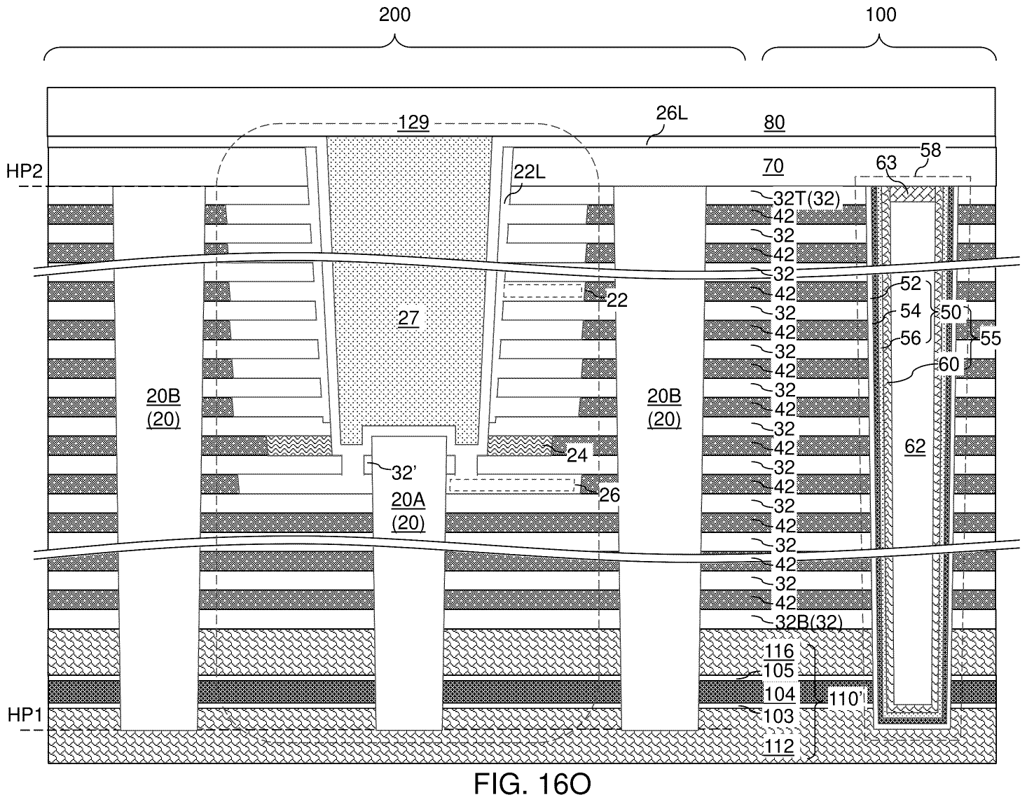

FIGS. 16A-16O are sequential vertical cross-sectional views of a region of the second exemplary structure during formation of an in-process layer contact assembly 129 according to the second embodiment of the present disclosure.

Referring to FIG. 16A, the patterned hard mask layer 33 can be subsequently removed, for example, by performing an etch process that removes the material of the patterned hard mask layer 33 selective to the materials of the alternating stack (32, 42). For example, if the insulating layers 32 comprise silicon oxide, the sacrificial material layers 42 comprises silicon nitride, and the patterned hard mask layer 33 comprises titanium nitride, a wet etch process employing a mixture of ammonium hydroxide and hydrogen peroxide may be employed to remove the patterned hard mask layer 33 selective to the alternating stack (32, 42).

Referring to FIG. 16B, a first selective isotropic etch process can be performed. For each contact via cavity 15, a respective first subset of the sacrificial material layers 42 that is exposed to the contact via cavity 15 can be laterally recessed around the contact via cavity 15. The first selective isotropic etch process etches the material of the sacrificial material layers 42 selective to the material of the insulating layers 32. In an illustrative example, if the sacrificial material layers 42 comprise silicon nitride and if the insulating layers 32 comprise silicon oxide, the first selective isotropic etch process may comprise a wet etch process employing hot phosphoric acid.

The sacrificial material layers 42 can be isotropically recessed around the contact via cavities 15 to form annular voids (e.g., first fin cavities 21) in volumes from which the material of the sacrificial material layers 42 are etched. The contact via cavities 15 are converted into finned contact via cavities 15′. Each finned contact via cavity 15′ comprises at least one first fin cavity 21, which comprises voids from which the material of the sacrificial material layers 42 is removed. Each first fin cavity 21 may have a shape of an annulus having a uniform thickness. The lateral recess distance of the first selective isotropic etch process may be selected such that surfaces of the second-type dielectric support pillar structures 20B are not exposed around the first fin cavities 21. For example, the lateral recess distance of the first selective isotropic etch process may be in a range from 20 nm to 300 nm, such as from 40 nm to 200 nm, although lesser and greater lateral recess distances may also be employed. In one embodiment, each insulating layer 32 other than the bottommost insulating layer 32B may have a respective top surface segment that is physically exposed to a respective one of the finned contact via cavities 15′. The annular sacrificial material spacer 42′ can be collaterally removed during the first selective isotropic etch process.

Referring to FIG. 16C, a first insulating fill material, such as silicon oxide, can be conformally deposited in the first fin cavities 21, in peripheral portions of the contact via cavities 15, and over the insulating cap layer 70 to form a first insulating liner 22L. The thickness of the first insulating liner 22L is greater than one half of the thickness of a sacrificial material layer 42. In one embodiment, the thickness of the first insulating liner 22L may be in a range from 15 nm to 50 nm, although lesser and greater thicknesses may also be employed. The first insulating liner 22L comprises first annular insulating fins 22 that fill the volumes of the first fin cavities 21.

Referring to FIG. 16D, a first vertical extension etch process can be performed to vertically extend the contact via cavities 15. In one embodiment, the first vertical extension etch process may comprise a first anisotropic etch process which etches horizontally-extending portions of the first insulating liner 22L and the material of the insulating layers 32. The etch chemistry of the anisotropic etch process can be selective to the material of the sacrificial material layers 42. The duration of the anisotropic etch process can be selected such that the horizontally-extending portions of the first insulating liner 22L are removed, and each contact via cavity 15 is vertically extends through a respective underlying insulating layer 32.

A top surface of an underlying sacrificial material layer 42 can be physically exposed at the bottom of each contact via cavity 15. A cylindrical vertically-extending portion of the first insulating liner 22L may remain around each contact via cavity 15 after the anisotropic etch process. In one embodiment, each sacrificial material layer 42 may have a respective top surface that is physically exposed to a respective overlying contact via cavity 15. For each contact via cavity 15 that vertically extends through a respective first subset of the sacrificial material layers 42, portions of a first subset of the sacrificial material layers 42 that are proximal to the contact via cavity 15 are replaced with first annular insulating fins 22. In one embodiment, a tubular patterned portion of an insulating layer 32 may remain around a top portion of one or more of the first-type dielectric support pillar structures 20A. Such tubular patterned portions of the insulating spacers 32 are herein referred to as insulating spacers 32′.

Referring to FIG. 16E, a second selective isotropic etch process can be performed to remove portions of the sacrificial material layers 42 that are proximal to the contact via cavities 15. For each contact via cavity 15, a respective first sacrificial material layer 42 that is exposed to the contact via cavity 15 can be partially etched underneath the contact via cavity 15. The second selective isotropic etch process etches the material of the sacrificial material layers 42 selective to the material of the insulating layers 32. In an illustrative example, if the sacrificial material layers 42 comprise silicon nitride and if the insulating layers 32 comprise silicon oxide, the second selective isotropic etch process may comprise a wet etch process employing hot phosphoric acid.

Portions of the sacrificial material layers 42 that underlie the contact via cavities 15 can be isotropically recessed to form circular plate-shaped voids in volumes from which the material of the sacrificial material layers 42 are etched. The contact via cavities 15 are converted into finned contact via cavities 15″ each comprising a respective second fin cavity 23. Each finned contact via cavity 15″ comprises a second fin cavity 23, which comprises voids from which the material of the sacrificial material layers 42 is removed. Each second fin cavity 23 may have a shape of an annulus having a uniform thickness. The second fin cavity 23 may have a lateral length that is less than the lateral length of the first fin cavities 21, by decreasing a duration of the second recess etch (i.e., the second selective isotropic etch) relative to a duration of the first recess etch (i.e., the first selective isotropic etch). The lateral distance between an inner periphery and an outer periphery of an annular top surface of a second fin cavity 23 may be in a range from 15 nm to 200 nm, such as from 30 nm to 150 nm, although lesser and greater lateral recess distances may also be employed. In one embodiment, each insulating layer 32 may have a respective top surface segment that is physically exposed to a respective one of the finned contact via cavities 15″.

Referring to FIG. 16F, a sacrificial fill material can be conformally deposited in the second fin cavities 23, in peripheral portions of the contact via cavities 15, and over the insulating cap layer 70 to form a sacrificial fill material liner 24L. In one embodiment, the sacrificial fill material liner 24L comprises amorphous silicon, polysilicon or silicon-germanium. The sacrificial fill material comprises a material that may be subsequently removed selective to the materials of the insulating layers 32 and the sacrificial material layers 42. The thickness of the sacrificial fill material liner 24L is greater than one half of the thickness of a sacrificial material layer 42. In one embodiment, the thickness of the sacrificial fill material liner 24L may be in a range from 15 nm to 50 nm, although lesser and greater thicknesses may also be employed. The sacrificial fill material liner 24L comprises sacrificial fin structures 24 that fill the volumes of the second fin cavities 23.

Referring collectively to FIGS. 16D-16F, a first via extension process can be performed to vertically extend the contact via cavities 15 through a respective underlying insulating layer 32, and to replace a portion of each sacrificial material layer 42 that underlies a respective overlying first subset of the sacrificial material layers 42 with a respective sacrificial fin structure 24.

Referring to FIG. 16G, a patterning film 35 may be anisotropically deposited over the sacrificial fill material liner 24L such that an encapsulated cavity 13 that is covered by the patterning film 35 is formed within the volumes of the contact via cavities 15. The patterning film 35 comprises a carbon-based material that includes amorphous carbon as a principal component and may additionally include dopants, such as boron, silicon, oxygen, fluorine, etc.

Referring to FIG. 16H, a photoresist layer (not shown) can be applied over the patterning film 35, and can be lithographically patterned to form openings over the encapsulated cavities 13. An anisotropic etch process can be performed to transfer the pattern of the openings in the photoresist layer through the patterning film 35. An opening is formed through the patterning film 35 over each of the encapsulated cavities 13, and the contact via cavities 15 are exposed through the openings in the patterning film 35.

Referring to FIG. 16I, a first etch step of a second via extension process can be performed to vertically extend the contact via cavities 15 through horizontally-extending portions of the sacrificial fill material liner 24L. The first etch step of the second via extension process may comprise an anisotropic etch process that etches each horizontally-extending portion of the sacrificial fill material liner 24L underneath the contact via cavities 15. An annular top surface of an underlying insulating layer 32 can be exposed underneath each contact via cavity 15.

Referring to FIG. 16J, a second step of the second via extension process can be performed to vertically extend each of the contact via cavities 15 through an annular portion of a respective underlying insulating layer 32. In some embodiments, tubular portions of the insulating layers 32 that are masked by a tubular remaining portion of the sacrificial fill material liner 24L may remain after formation of tubular cavities through the insulating layers 32. Such tubular remaining portions of the insulating layers 32 comprise insulating spacers 32′. An annular top surface of a respective underlying sacrificial material layer 42 can be physically exposed underneath each contact via cavity 15. In one embodiment, each of the sacrificial material layers 42 may comprise a respective physically exposed annular top surface segment that is exposed to a respective overlying contact via cavity 15. In one embodiment, each of the sacrificial material layers 42 may comprise a respective cylindrical surface that contacts an outer cylindrical sidewall of a respective sacrificial fin structure 24. In one embodiment, each of the sacrificial material layers 42 other than the topmost sacrificial material layer 42 may underlie a respective sacrificial fin structure 24.

Referring to FIG. 16K, the photoresist layer overlying the patterning film 35 and the patterning film 35 may be removed, for example, by ashing.

Referring to FIG. 16L, a third selective isotropic etch process can be subsequently performed. For each sacrificial fin structure 24 that is formed above the level of the bottommost sacrificial material layer 42, a respective underlying sacrificial material layer 42 that immediately underlies the sacrificial fin structure 24 can be laterally recessed around a respective contact via cavity 15. The third selective isotropic etch process etches the material of the sacrificial material layers 42 selective to the material of the insulating layers 32, the sacrificial fill material liner 24L, and the first-type dielectric support pillar structures 20A. In an illustrative example, if the sacrificial material layers 42 comprise silicon nitride and if the insulating layers 32 comprise silicon oxide, the third selective isotropic etch process may comprise a wet etch process employing hot phosphoric acid.

Each physically exposed sacrificial material layer 42 that underlies a respective contact via cavity 15 can be isotropically etched to form a respective annular void in the volume from which the material of the sacrificial material layers 42 is etched. Each void that is formed by removal of an annular portion of the sacrificial material layers 42 is herein referred to as a third fin cavity 25. Each third fin cavity 25 may have a shape of an annulus having a uniform thickness. The lateral recess distance of the selective isotropic etch process may be selected such that surfaces of the second-type dielectric support pillar structures 20B are not exposed around the second fin cavities 23. The second fin cavity 23 may have a lateral length that is less than the lateral length of the third fin cavities 25, by increasing a duration of the third recess etch (i.e., the third selective isotropic etch) relative to a duration of the second recess etch (i.e., the second selective isotropic etch). For example, the lateral recess distance of the third selective isotropic etch process may be in a range from 20 nm to 300 nm, such as from 40 nm to 200 nm, although lesser and greater lateral recess distances may also be employed.

Referring to FIG. 16M, an isotropic etch process can be performed to remove portions of the sacrificial fill material liner 24L that are located outside the volumes of the second fin cavities 23, i.e., to remove portions of the sacrificial fill material liner 24L other than the sacrificial fin structures 24. For example, if the sacrificial fill material liner 24L comprises amorphous silicon, a wet etch process employing hot trimethyl-2 hydroxyethyl ammonium hydroxide (“hot TMY”) or tetramethyl ammonium hydroxide (TMAH) may be performed to remove the portions of the sacrificial fill material liner 24L that are located outside the volumes of the second fin cavities 23. The duration of the isotropic etch process can be selected such that the etch distance of the material of the sacrificial fill material liner 24L is in a range from 100% to 150% of the thickness of vertically-extending portions of the sacrificial fill material liner 24L. The sacrificial fin structures 24 remain in the volumes of the second fin cavities 23.

Each contact via cavity 15 includes a respective sacrificial fin structure 24. The sacrificial fin structure 24 laterally surrounds and has an inner cylindrical sidewall that is exposed to the contact via cavity 15. The total number of contact via cavities 15 may be the same as or greater than the total number of the sacrificial material layers 42 in each portion of the contact region 200 in which an array of layer contact via structures is to be subsequently formed. For each sacrificial material layer 42 in the alternating stack (32, 42), at least one contact via cavity 15 is provided, to which an inner cylindrical sidewall of a respective sacrificial fin structure 24 is exposed.

Referring to FIG. 16N, a second insulating fill material, such as silicon oxide, can be conformally deposited in the third fin cavities 25, in peripheral portions of the contact via cavities 15, and over the insulating cap layer 70 to form a second insulating liner 26L. The thickness of the second insulating liner 26L is greater than one half of the thickness of a sacrificial material layer 42. In one embodiment, the thickness of the second insulating liner 26L may be in a range from 15 nm to 50 nm, although lesser and greater thicknesses may also be employed. The second insulating liner 26L comprises second annular insulating fins 26 that fill the volumes of the third fin cavities 25.

Referring collectively to FIGS. 16L-16N, for each sacrificial fin structure 24 that laterally surrounds a respective contact via cavity 15 and may underlie a respective first subset of the sacrificial material layers 42, portions of a respective underlying sacrificial material layer 42 that underlies the sacrificial fin structure 24 can be replaced with a second annular insulating fin 26.

Referring to FIG. 16O, a sacrificial fill material can be deposited in the voids within the contact via cavities 15. The sacrificial fill material comprises a material that can be subsequently removed selective to material of the second insulating liner 26L. For example, the sacrificial fill material may comprise a carbon-based material, such as amorphous carbon or diamond-like carbon, a semiconductor material, such as amorphous silicon, polysilicon, or silicon-germanium, or a dielectric material, such as borosilicate glass or organosilicate glass.

Excess portions of the sacrificial fill material may be removed from above the horizontal plane including the top surface of a horizontally-extending portion of the second insulating liner 26L that overlies the insulating cap layer 70 employing a planarization process. The planarization process may comprise a recess etch process or a chemical mechanical polishing process. Each remaining portion of the sacrificial fill material constitutes a sacrificial via fill material portion 27. Each sacrificial via fill material portion 27 is formed directly on the insulating surfaces of the second insulating liner 26L in a respective contact via cavity 15.

Referring collectively to FIGS. 16N and 16O, an insulating liner (such as the second insulating liner 26L) can be formed within a volume of the contact via cavity 15 on at least one inner sidewall of at least one first annular insulating fin 22, on an inner sidewall of a sacrificial fin structure 24, on an inner sidewall of a second annular insulating fin 26, and on a top surface and optionally a cylindrical surface segment of a sidewall of an underlying first-type dielectric support pillar structure 20A. The sacrificial via fill material portion 27 is formed within the the second insulating liner 26L.

A contact-level dielectric layer 80 can be formed above the horizontally-extending portion of the second insulating liner 26L that overlies the insulating cap layer 70. The contact-level dielectric layer 80 comprises a dielectric material, such as undoped silicate glass or a doped silicate glass, and may have a thickness in a range from 100 nm to 800 nm, such as from 200 nm to 500 nm, although lesser and greater thicknesses may also be employed.

An array of in-process layer contact assemblies 129 can be formed in the contact region 200. Each in-process layer contact assembly 129 comprises a sacrificial via fill material portion 27, optionally at least one first annular insulating fin 22 laterally surrounding and contacting the sacrificial via fill material portion 27, a sacrificial fin structure 24 having a shape of an annular plate, optionally a second annular insulating fin 26 laterally surrounding and contacting the sacrificial via fill material portion 27 (in case the sacrificial fin structure 24 is formed above the level of the bottommost sacrificial material layer 42), and a respective portion of the second insulating liner 26L that is in contact with the sacrificial via fill material portion 27. Each sacrificial fin structure 24 laterally contacts a cylindrical (e.g., edge) surface of a respective first sacrificial material layer 42. If the sacrificial fin structure 24 is formed at any level other than the level of the topmost sacrificial material layer 42, the in-process layer contact assembly 129 comprises at least one first annular insulating fin 22. If the sacrificial fin structure is formed at any level other than the level of the bottommost sacrificial material layer 42, the in-process layer contact assembly 129 comprises a respective second annular insulating fin 26.

Each sacrificial fin structure 24 located at a level other than the level of the topmost sacrificial material layer 42 or the level of the bottommost sacrificial material layer 42 is contacted by a cylindrical sidewall of a respective first sacrificial material layer 42, underlies at least one first annular insulating fin 22, and overlies a second annular insulating fin 26. For each sacrificial fin structure 24 located at a level other than the level of the topmost sacrificial material layer 42 or the level of the bottommost sacrificial material layer 42, each overlying first annular insulating fin 22 is contacted by and is laterally surrounded by a respective second sacrificial material layer 42 that overlies the first sacrificial material layer 42, and a respective underlying second annular insulating fin 26 is contacted by and is laterally surrounded by a respective third sacrificial material layer 42 that underlies the first sacrificial material layer 42.

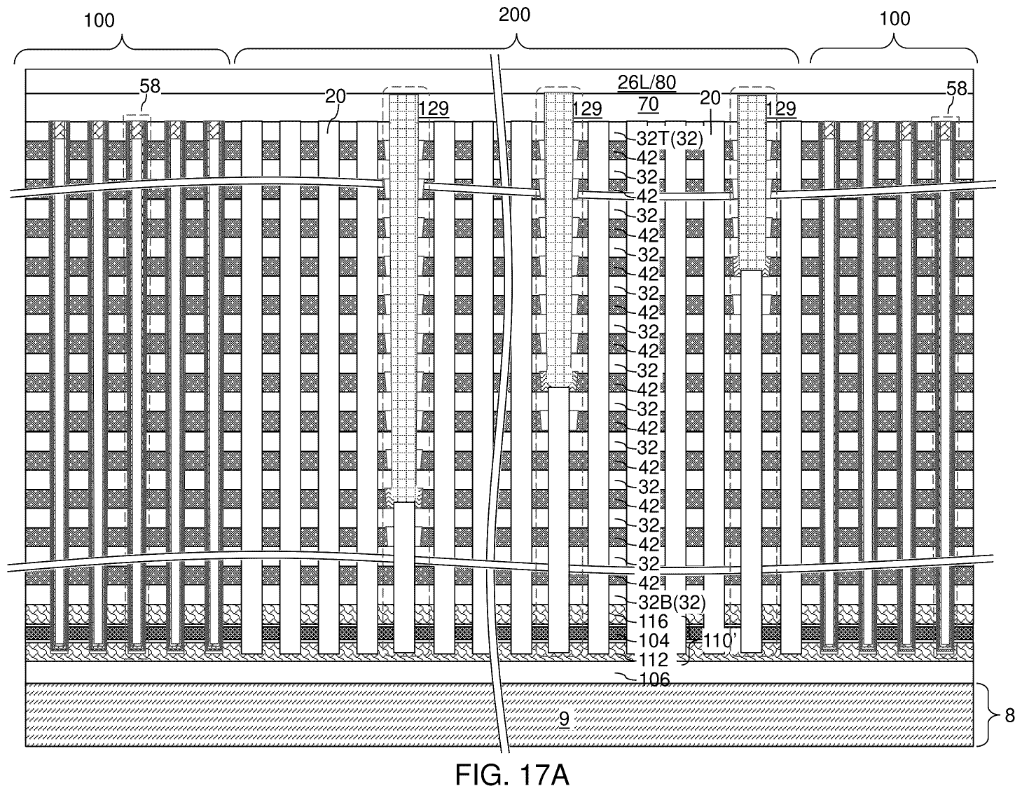

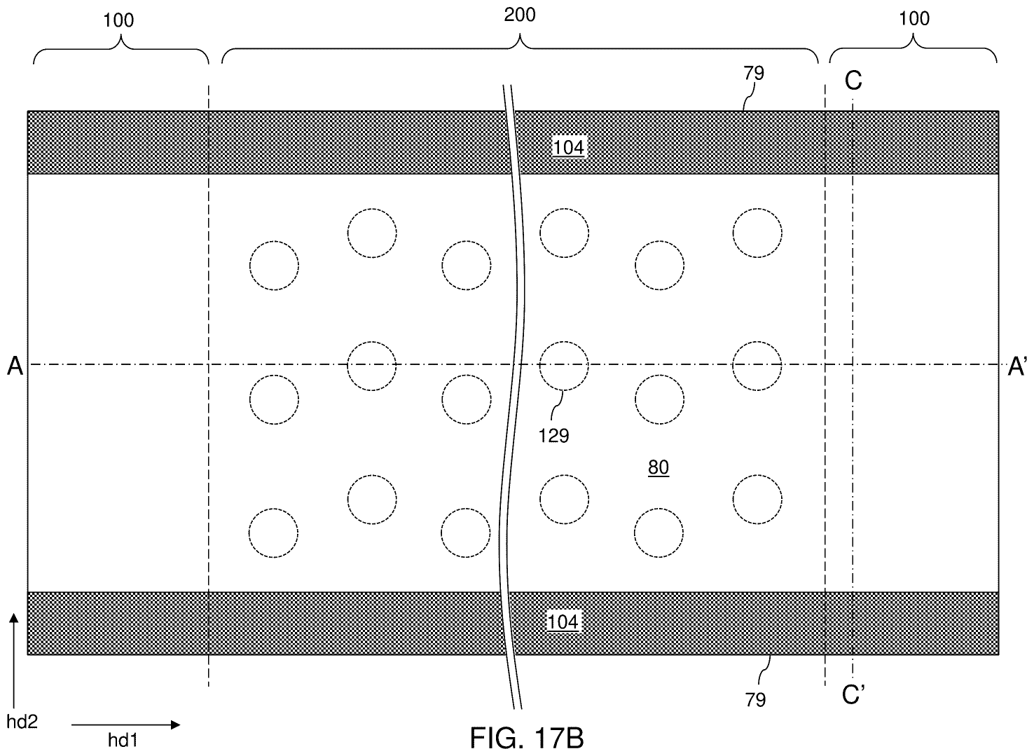

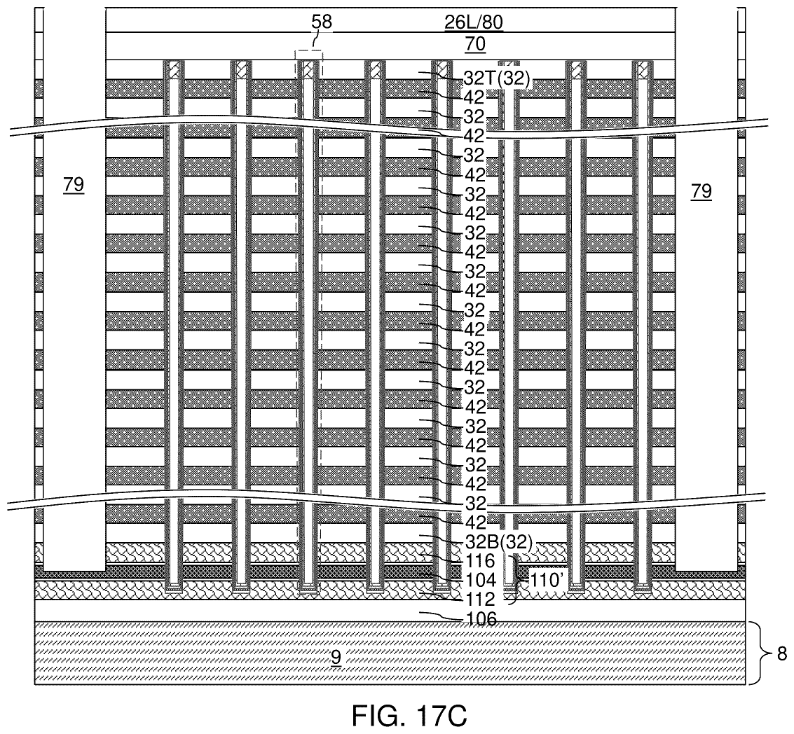

Referring to FIGS. 17A-17C, a photoresist layer (not shown) can be applied over the contact-level dielectric layer 80, and is lithographically patterned to form elongated openings in areas between clusters of memory opening fill structures 58. The pattern of the elongated openings in the photoresist layer may be the same as described with reference to FIGS. 7A-7C. The pattern in the photoresist layer can be transferred through the contact-level dielectric layer 80, a horizontally-extending portion of the second insulating liner 26L, the insulating cap layer 70, and the alternating stack (32, 42) employing an anisotropic etch process. Lateral isolation trenches 79 are formed in the volumes from which materials of the contact-level dielectric layer 80, a horizontally-extending portion of the second insulating liner 26L, the insulating cap layer 70, and the alternating stack (32, 42) are etched. The lateral isolation trenches 79 vertically extend from the top surface of the contact-level dielectric layer 80 to the source-level sacrificial layer 104 (if present) or to the top surface of the substrate 8 (if the in-process source-level material layers 110′ are omitted). The lateral isolation trenches 79 laterally extend along the first horizontal direction hd1 between neighboring memory blocks of memory opening fill structures 58.

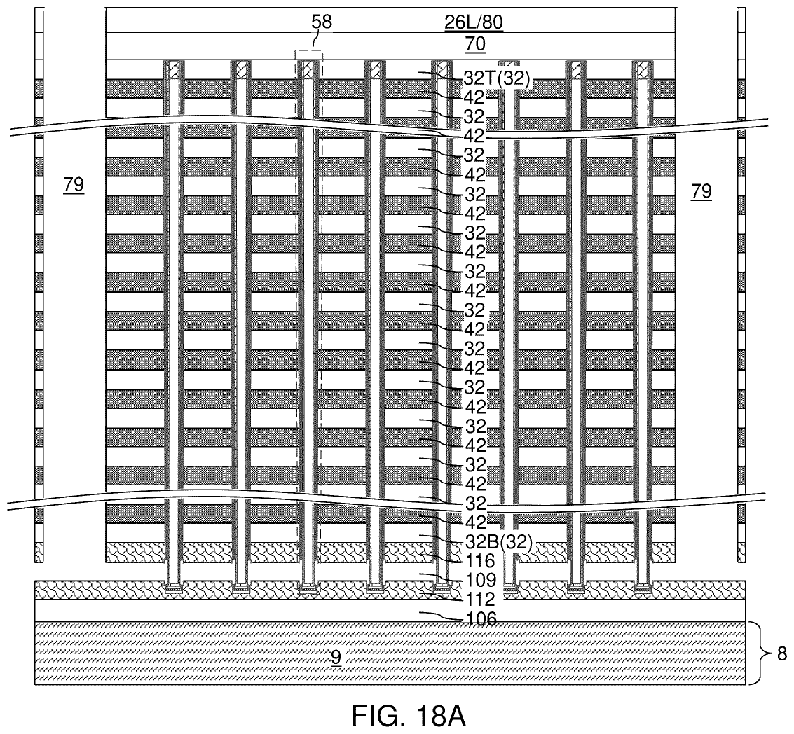

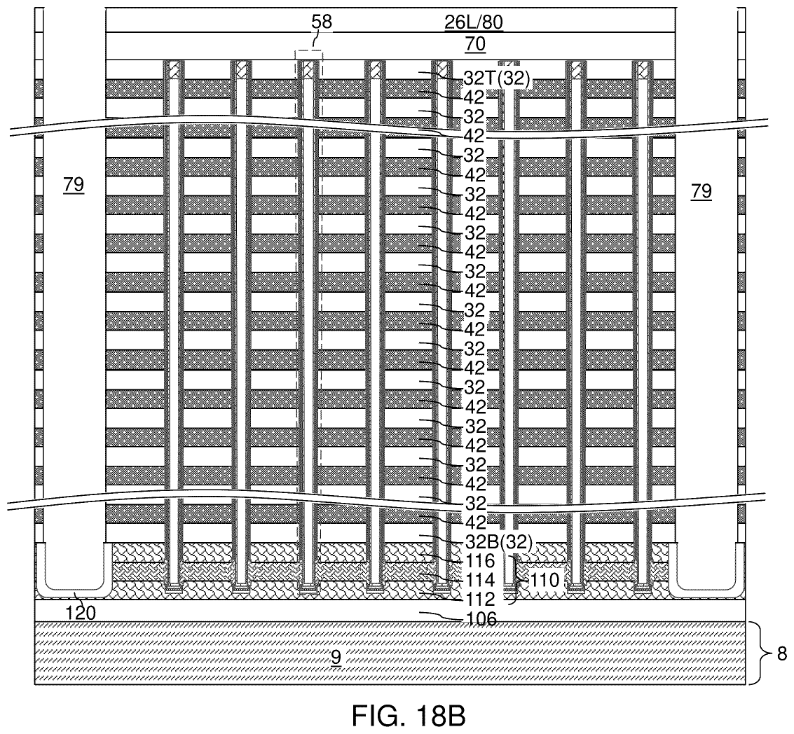

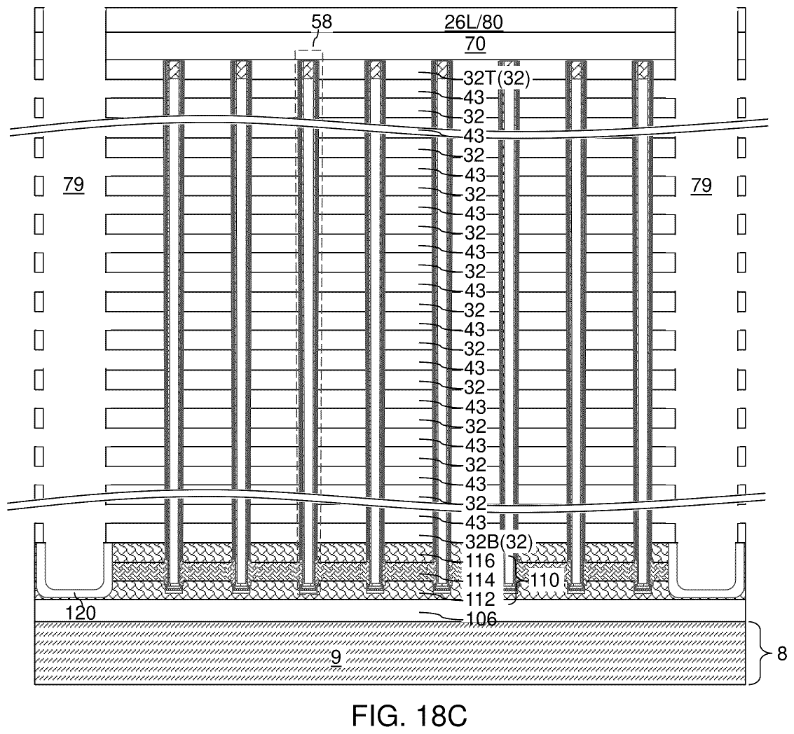

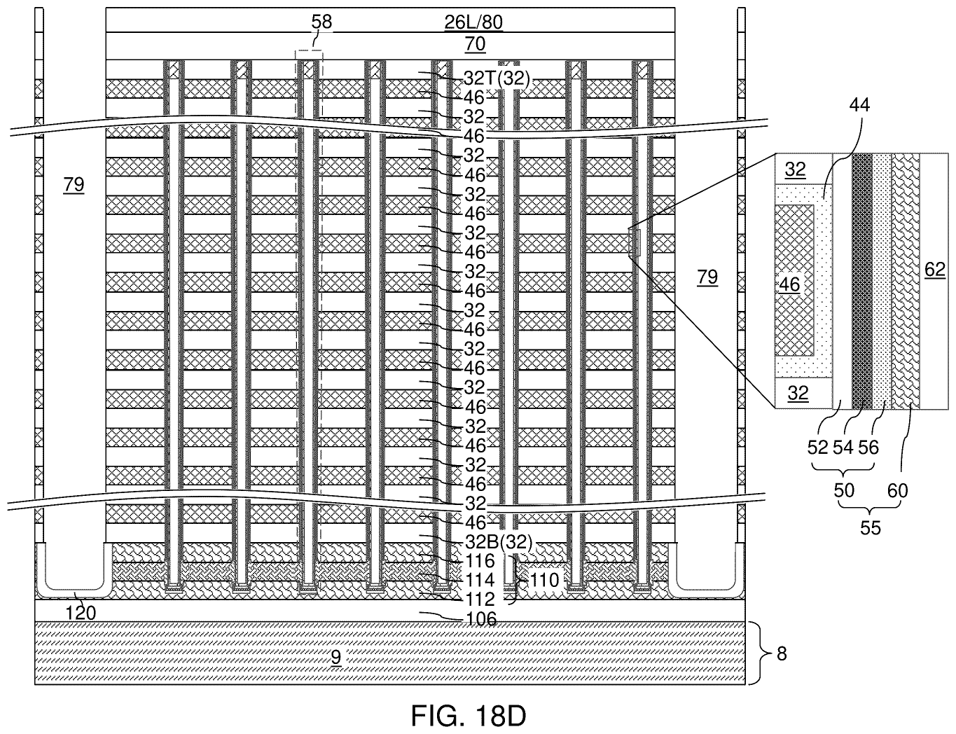

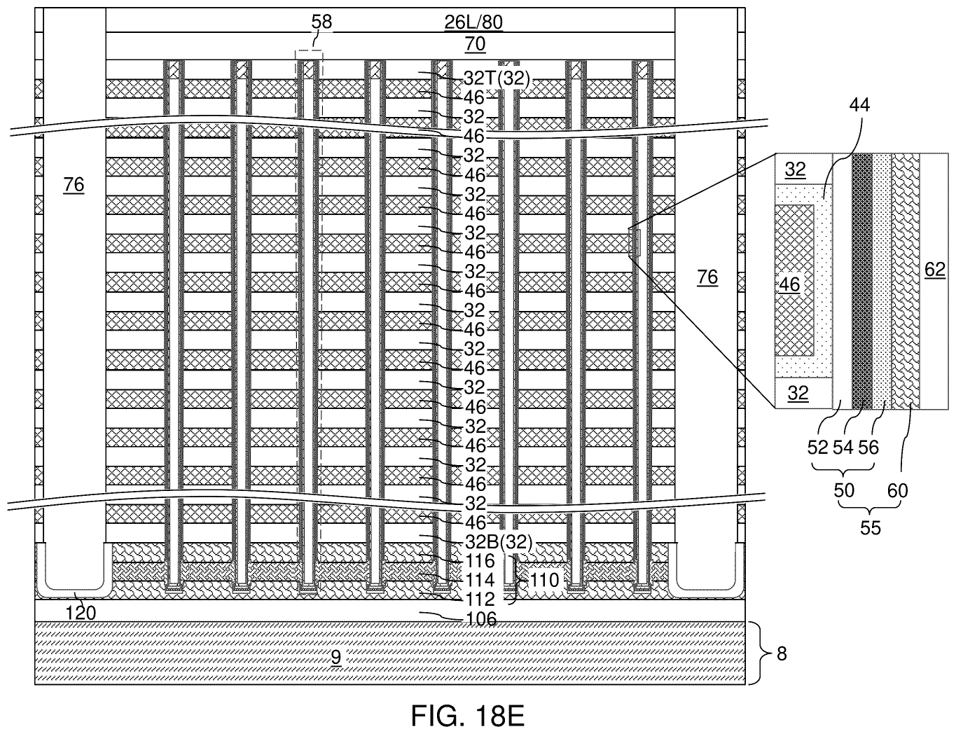

FIGS. 18A-18E are sequential vertical cross-sectional views of the second exemplary structure during replacement of the in-process source-level material layers 110′ with source-level material layers 110, replacement of sacrificial material layers 42 with electrically conductive layers 46, and formation of isolation trench fill structures 76 according to the second embodiment of the present disclosure. The processing steps of FIGS. 18A-18E may be the same as the processing steps described with reference to FIGS. 8A-8E.

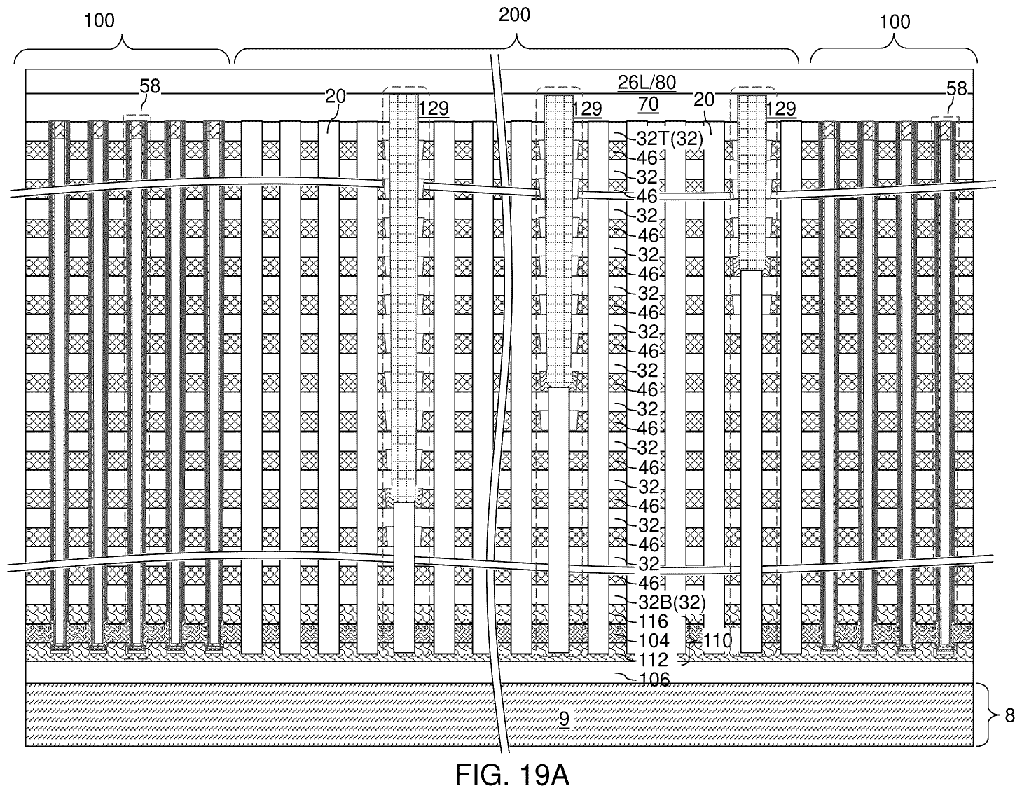

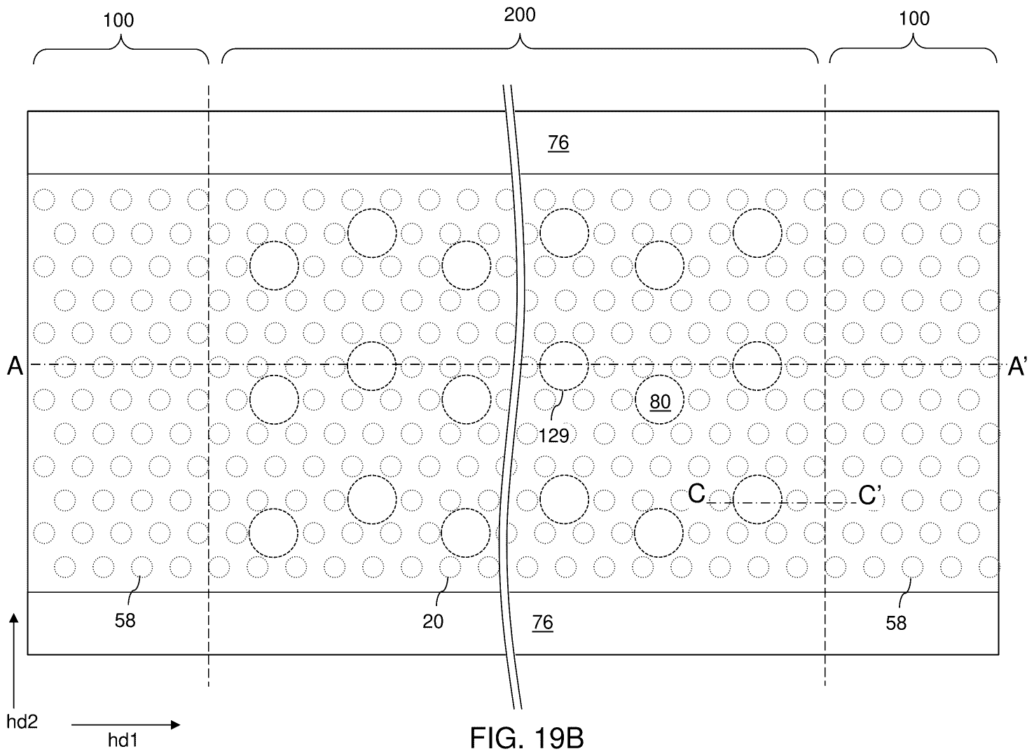

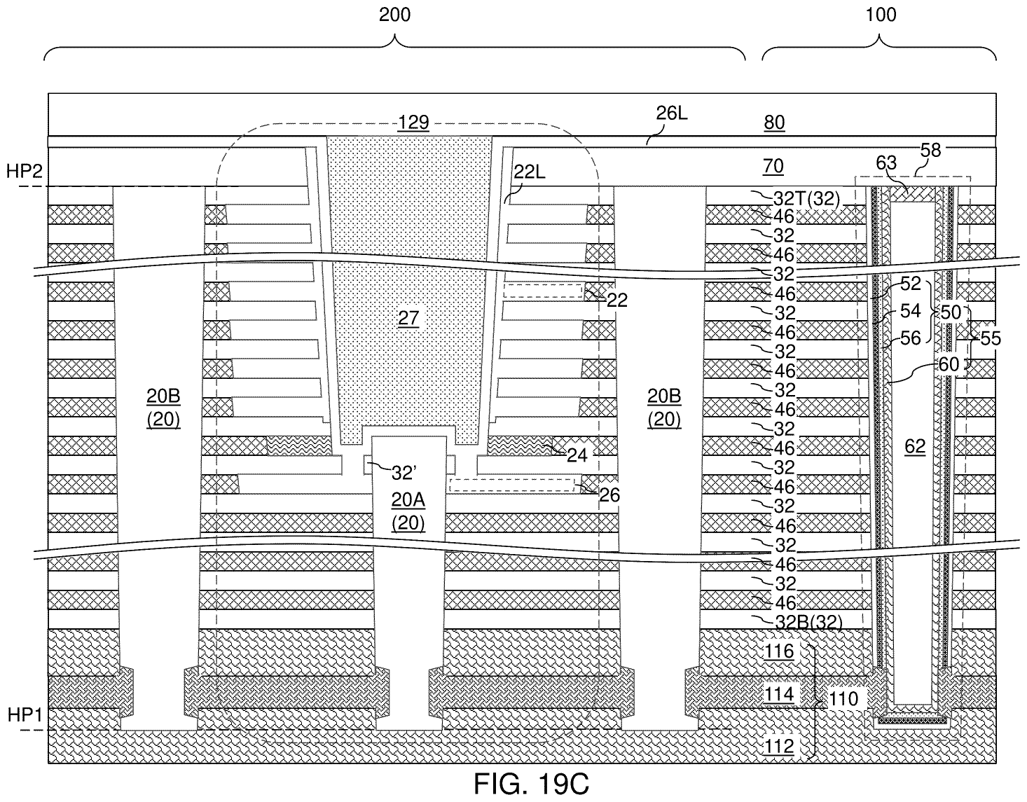

Referring to FIGS. 19A-19C, the second exemplary structure is illustrated after formation of the isolation trench fill structures 76.

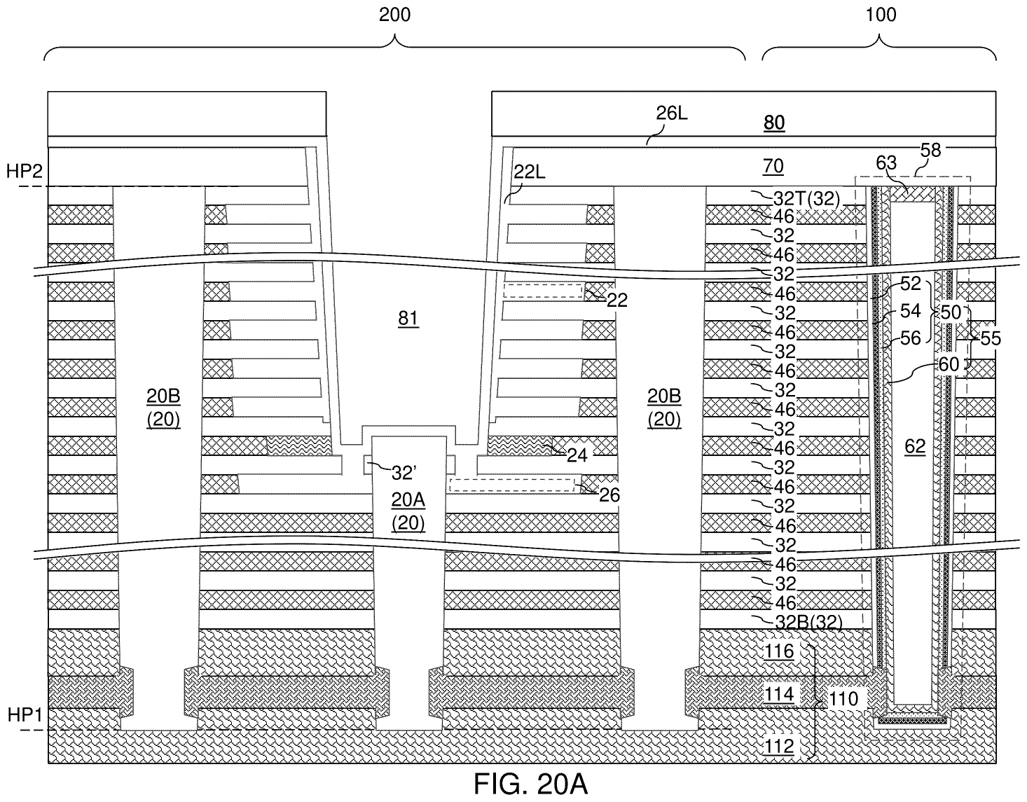

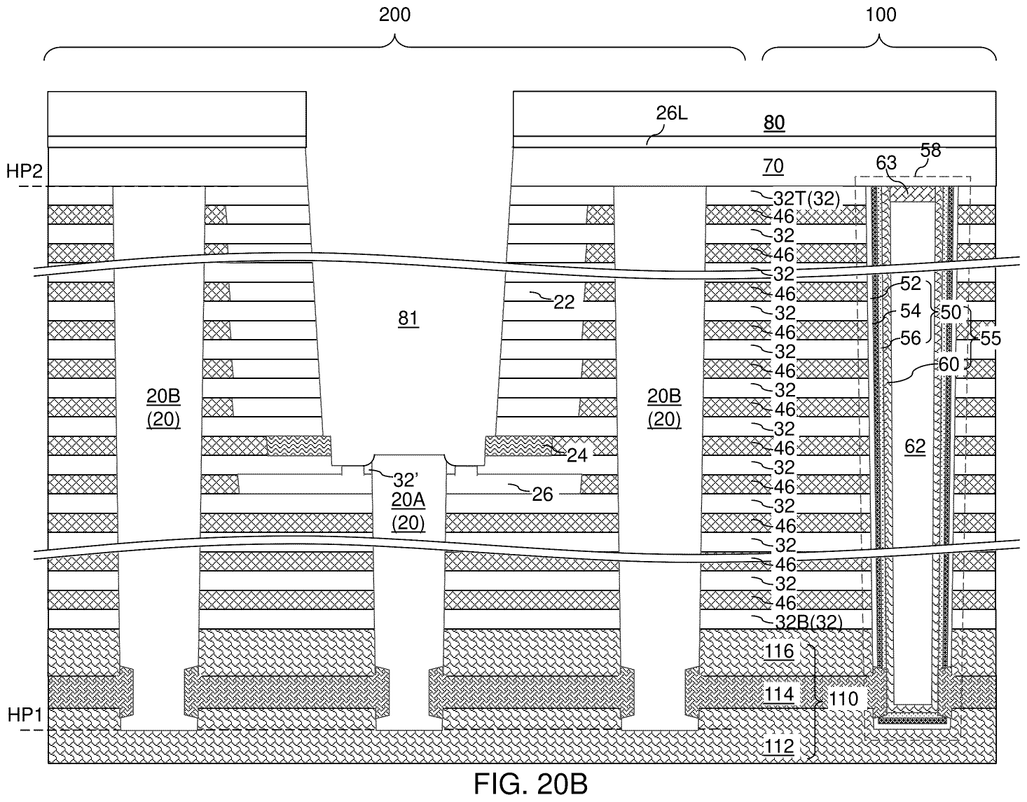

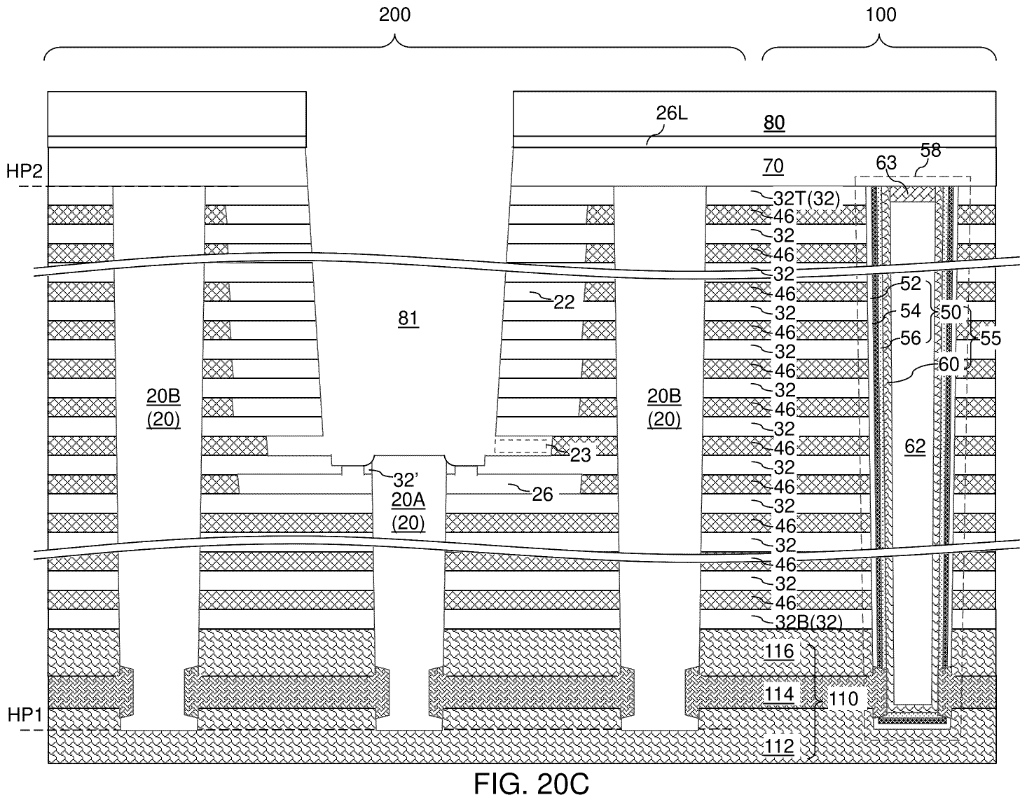

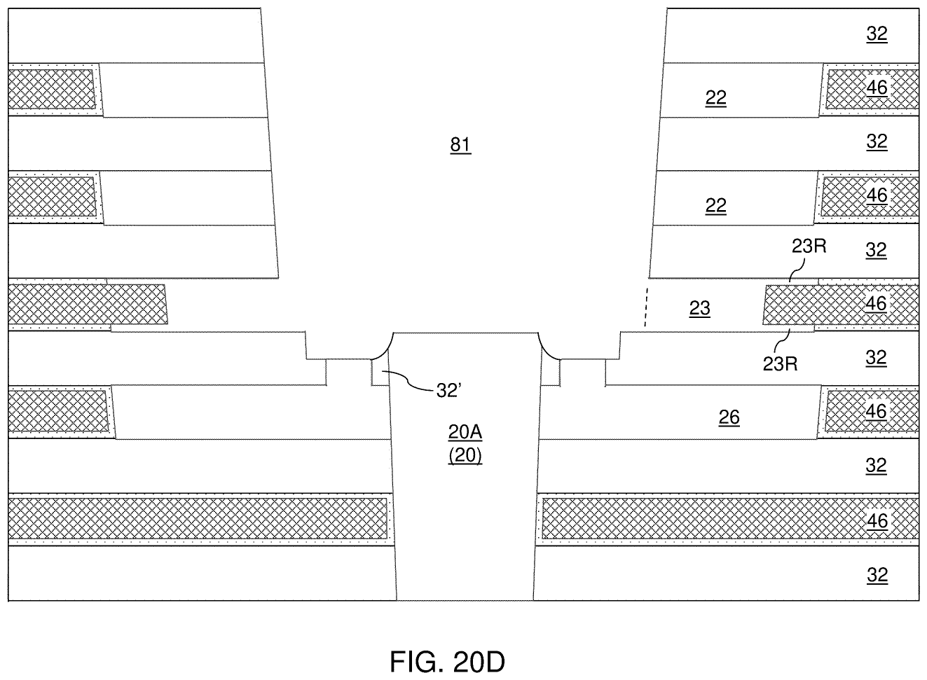

Referring to FIG. 20A, a photoresist layer (not shown) can be applied over the contact-level dielectric layer 80, and can be lithographically patterned to form openings within the areas of the in-process layer contact assemblies 129. In one embodiment, areas of the openings in the photoresist layer may be the same as the areas of the sacrificial via fill material portions 27 in a plan view such as a see-through top-down view. An anisotropic etch process can be performed to remove portions of the contact-level dielectric layer 80 that are not covered by the photoresist layer. Top surfaces of the sacrificial via fill material portions 27 can be exposed underneath the openings in the contact-level dielectric layer 80.

Subsequently, the sacrificial via fill material portions 27 can be removed selective to the materials of the contact-level dielectric layer 80 and the second insulating liner 26L. For example, a selective etch process or an ashing process (if the sacrificial via fill material portions 27 comprise a carbon-based material) may be employed to remove the sacrificial via fill material portions 27. If a selective etch process is employed, the selective etch process may comprise an isotropic etch process or an anisotropic etch process. A replacement contact via cavity 81 is formed in each combination of a volume from which a sacrificial via fill material portion 27 is removed and a volume of an overlying opening through the contact-level dielectric layer 80.

Referring to FIG. 20B, any insulating liner, such as the second insulating liner 26L and the first insulating liner 22L, that is the present around the replacement contact via cavity 81 can be removed by performing an isotropic etch process. For example, if the second insulating liner 26L and the first insulating liner 22L comprise a respective silicon oxide material, a wet etch process employing dilute hydrofluoric acid may be performed to isotropically etch physically exposed portions of the second insulating liner 26L and the first insulating liner 22L around the replacement contact via cavities 81. Inner cylindrical surfaces of the first annular insulating fins 22 and inner cylindrical surfaces of the sacrificial fin structures 24 can be exposed around the replacement contact via cavities 81. An annular top surface of a vertically protruding portion of a second annular insulating fin 26 may be exposed underneath the replacement contact via cavities 81.

Referring to FIGS. 20C and 20D, the sacrificial fin structures 24 can be removed selective to the materials of the insulating layers 32, the first annular insulating fins 22, the second annular insulating fins 26, the insulating cap layer 70, and the contact-level dielectric layer 80. If the sacrificial fin structures 24 comprise amorphous silicon, a wet etch process employing hot trimethyl-2 hydroxyethyl ammonium hydroxide (“hot TMY”) or tetramethyl ammonium hydroxide (TMAH) may be performed to remove the sacrificial fin structures 24.

In summary, the replacement contact via cavity 81 may be formed by sequentially removing the sacrificial via fill material portions 27, portions of an insulating liner (such as the second insulating liner 26L), and the sacrificial fin structures 24. Voids are formed in each volume of the second fin cavities 23. In one embodiment, a cylindrical surface of a backside blocking dielectric layer can be physically exposed around the each second fin cavity 23.

As shown in FIG. 20D, a selective isotropic etch process may be performed to remove portions of the backside blocking dielectric layers 44 that are proximal to the second fin cavities 23. The selective isotropic etch process and etches the material of the backside blocking dielectric layers 44 selective to the materials of the electrically conductive layers 46, the insulating layers 32, the first annular insulating fins 22, the second annular insulating fins 26, the insulating cap layer 70, and the contact-level dielectric layer 80. For example, if the backside blocking dielectric layers 44 comprise aluminum oxide, a wet etch process employing hot phosphoric acid may be employed as the selective isotropic etch process. The isotropic etch process etches portions of the backside blocking dielectric layers 44 that are proximal to the replacement contact via cavities 81. For each backside blocking dielectric layer 44 that is exposed to a respective second fin cavity 23, the selective isotropic etch process may remove a cylindrical portion of the backside blocking dielectric layer 44, a top annular portion of the backside blocking dielectric layer 44 that is joined to a top periphery of the cylindrical portion, and the bottom annular portion of the backside blocking dielectric layer 44 that is adjoined to a bottom periphery of the cylindrical portion.

Each second fin cavity 23 can be expanded to include volumes of a pair of annular rim-shaped voids 23R having a respective height that is the same as the thickness of a backside blocking dielectric layer 44. Each replacement contact via cavity 81 comprises a respective second fin cavity 23 to which a respective first electrically conductive layer 46 is physically exposed. For each replacement contact via cavity 81 including a respective second fin cavity 23 located at a level other than the level of the topmost electrically conductive layer 46 or the level of the bottommost electrically conductive layer 46, at least one first annular insulating fin 22 overlies the respective second fin cavity 23 and a second annular insulating fin 26 underlies the respective second fin cavity 23. Each first annular insulating fin 22 is laterally surrounded by a respective second electrically conductive layer 46, and is laterally spaced from the respective second electrically conductive layer 46 by a respective backside blocking dielectric layer 44. Each second annular insulating fin 26 is laterally surrounded by a respective third electrically conductive layer 46, and is laterally spaced from the respective third electrically conductive layer 46 by a respective backside blocking dielectric layer 44.

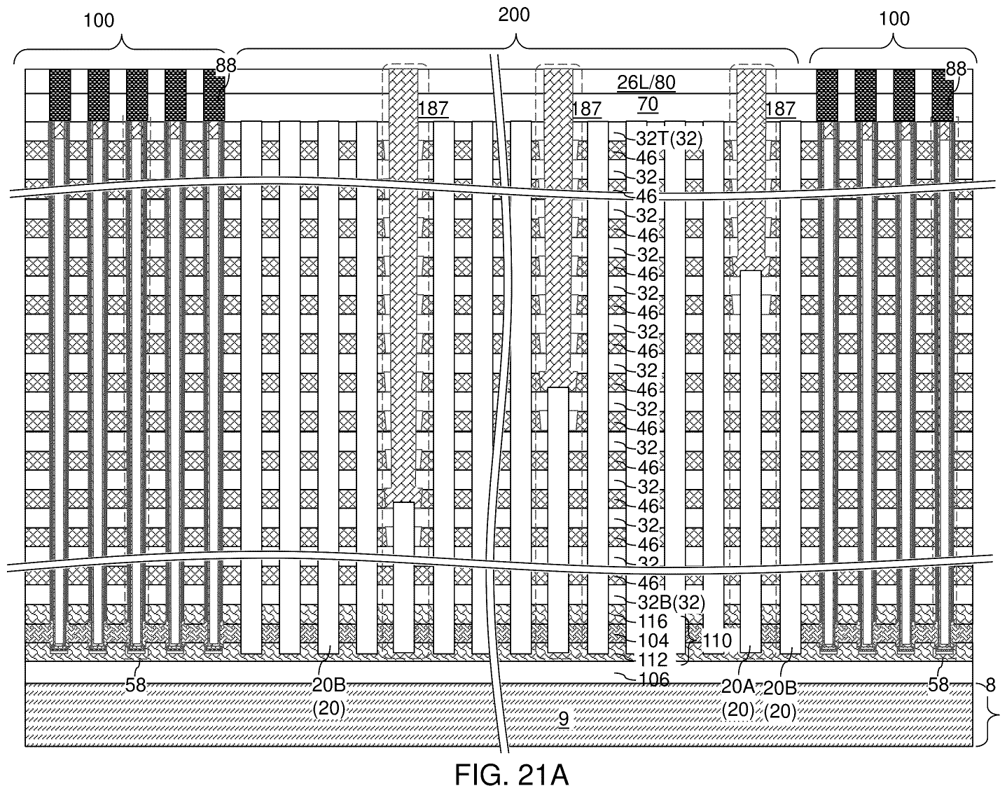

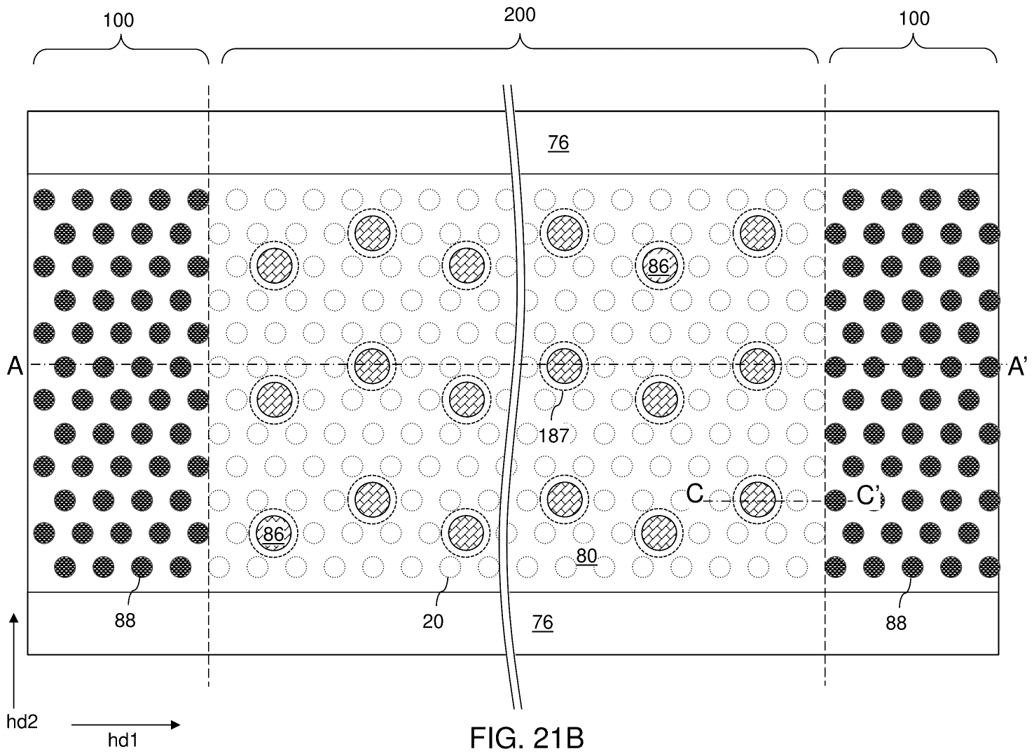

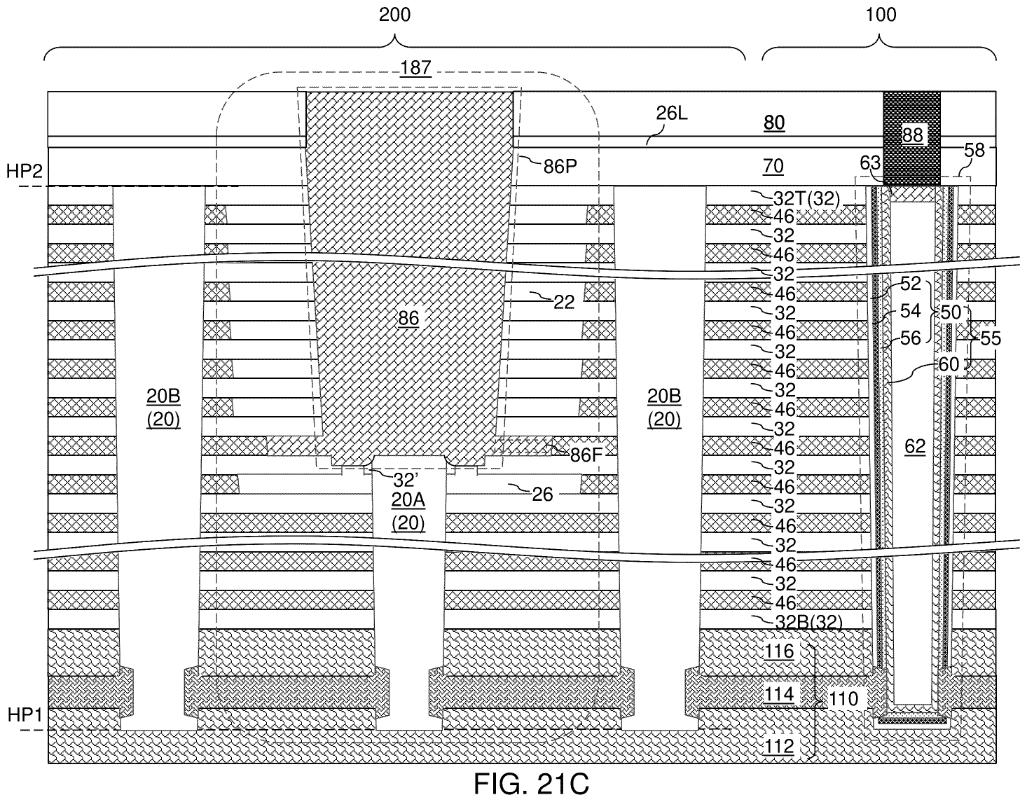

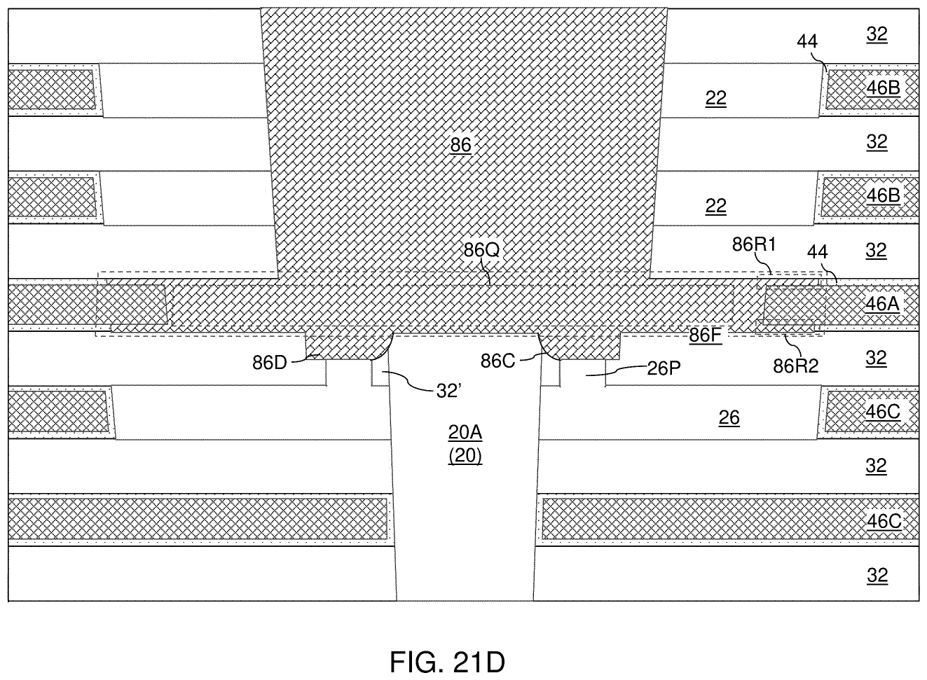

Referring to FIGS. 21A-21D, a photoresist layer (not shown) can be applied to over the second exemplary structure, and can be lithographically patterned to form openings over the memory opening fill structures 58. An anisotropic etch process can be performed to transfer the pattern of the openings in the photoresist layer through the contact-level dielectric layer 80, the second insulating liner 26L, and the insulating cap layer 70. Drain contact via cavities are formed through the contact-level dielectric layer 80. The photoresist layer can be subsequently removed, for example, by ashing.

At least one conductive material can be deposited in the replacement contact via cavities 81 and the drain contact via cavities. The at least one conductive material may comprise a metallic barrier material and a metallic fill material. The metallic barrier material may comprise a metallic nitride material such as TiN, TaN, and/or WN and/or a metallic carbide material such as TiC, TaC, and/or WC. The metallic fill material may comprise W, Ti, Ta, Ru, Co, Mo, Cu, etc. The at least one conductive material may be deposited by chemical vapor deposition, physical vapor deposition, electroplating, electroless plating, or combinations thereof. Excess portions of the at least one conductive material can be removed from above the horizontal plane including the top surface of the contact-level dielectric layer 80 by performing a planarization process, which may employ a chemical mechanical polishing (CMP) process or a recess etch process. Each remaining portion of the at least one conductive material filling a respective replacement contact via cavity 81 constitutes a layer contact via structure 86 that contacts top surface a respective first electrically conductive layer 46. Each remaining portion of the at least one conductive material filling a respective drain contact via cavity constitutes a drain contact via structure 88 that contacts top surface a respective drain region 63.

As shown in FIG. 21D, each layer contact via structure 86 is formed directly on a respective first electrically conductive layer 46A of the electrically conductive layers 46. Each electrically conductive layer 46 within the alternating stack (32, 46) may be contacted by a respective layer contact via structure 86. Generally, each combination of a sacrificial via fill material portion 27 and a sacrificial fin structure 24 can be replaced with a layer contact via structure 86.

An array of layer contact assemblies 187 can be formed in the contact region 200 between each neighboring pair of isolation trench fill structures 76 that are spaced along the second horizontal direction hd2. Each layer contact assembly 187 comprises a layer contact via structure 86 vertically extending through each layer within the alternating stack (32, 46) and laterally contacting a cylindrical surface of the first electrically conductive layer 46.

Referring to FIGS. 21A-21D, in the second embodiment, a three-dimensional memory device comprises: an alternating stack (32, 46) of insulating layers 32 and electrically conductive layers 46, wherein the electrically conductive layers 46 comprise a first electrically conductive layer 46A, second electrically conductive layers 46B that overlie the first electrically conductive layer 46A, and third electrically conductive layers 46C that underlie the first electrically conductive layer 46A, as shown in FIG. 21D. A memory opening 49 vertically extends through the alternating stack (32, 46), and a memory opening fill structure 58 is located in memory opening 49 and comprises a vertical stack of memory elements (e.g., portions of the memory film 50) located at levels of the electrically conductive layers 46 and a vertical semiconductor channel 60. The memory device also includes a layer contact assembly 187 comprising a layer contact via structure 86 vertically extending through each of the second electrically conductive layers 46B and laterally contacting a cylindrical surface of the first electrically conductive layer 46A, a dielectric support pillar structure 20 (such as a first-type dielectric support pillar structure 20A) vertically extending through each of the third electrically conductive layers 46C and contacting a bottom surface of the layer contact via structure 86, first annular insulating fins 22 laterally surrounding the layer contact via structure 86 and located at each level of the second electrically conductive layers 46B, and a second annular insulating fin 26 having an inner cylindrical sidewall surface that contacts a first cylindrical surface segment of the dielectric support pillar structure 20.

In one embodiment, the second annular insulating fin 26 is located at a level of a topmost third electrically conductive layer 46C of the third electrically conductive layers 46. In one embodiment, each of the third electrically conductive layers 46 except the topmost third electrically conductive layer 46 is in direct contact with the dielectric support pillar structure 20 (e.g., 20A), or is laterally spaced from the dielectric support pillar structure 20 (e.g., 20A) by a respective backside blocking dielectric layer 44 which contacts a respective cylindrical surface segment of the memory opening fill structure 58.

In one embodiment shown in FIG. 21D, the second annular insulating fin 26 comprises an annular upward protrusion 26P that protrudes above an annular top surface of the second annular insulating fin 26 and contacts the layer contact via structure 86.

In one embodiment shown in FIG. 21C, the layer contact via structure 86 comprises: a pillar portion 86P that vertically extends through each of the second electrically conductive layers 46B and the first electrically conductive layer 46A; and a fin portion 86F located at a level of the first electrically conductive layer 46A and adjoined to and laterally protruding from a bottom portion of the pillar portion 86P, and having an outer sidewall that contacts the cylindrical (i.e., edge) surface of the first electrically conductive layer 46A.

In one embodiment shown in FIG. 21D, the fin portion 86F comprises: a plate portion 86Q; a first annular rim 86R1 extending outward from the plate portion 86Q and having a top surface within a horizontal plane including a top surface of the plate portion 86Q; and a second annular rim 86R2 extending outward from the plate portion 86Q and having a bottom surface within a horizontal plane including a bottom surface of the plate portion 86Q. The plate portion 86Q includes an annular downward protruding portion 86D that contacts the annular upward protrusion 26P of the second annular insulating fin 26.

In one embodiment, the first electrically conductive layer 46A is embedded within a backside blocking dielectric layer 44 that contacts a cylindrical surface segment of the memory opening fill structure 58; and each of the first annular rim 86R1 and the second annular rim 86R2 has a thickness that equals a thickness of the backside blocking dielectric layer 44.

In one embodiment, an annular bottom surface segment of the first annular rim 86R1 contacts an annular top surface segment of the first electrically conductive layer 46A; and an annular top surface segment of the second annular rim 86R2 contacts an annular bottom surface segment of the first electrically conductive layer 46A. In one embodiment, a cylindrical (i.e., edge) surface of the plate portion 86Q vertically extends between the first annular rim 86R1 and the second annular rim 86R2; and an entirety of the cylindrical (i.e., edge) surface of the plate portion 86Q is in contact with a cylindrical (i.e., edge) surface segment of the first electrically conductive layer 46A.

In one embodiment, the layer contact via structure 86 comprises an annular downward protruding portion 86D that protrudes downward from a horizontal plane including an annular bottom surface of the fin portion 86F and laterally surrounding an upper portion of the dielectric support pillar structure 20 (e.g., 20A). In one embodiment, a convex inner sidewall 86C of the annular downward protruding portion 86D contacts an annular concave surface segment of the dielectric support pillar structure 20.

In one embodiment, each of the first annular insulating fins 22 contacts or is laterally spaced by a respective backside blocking dielectric layer 44 from a respective one of the second electrically conductive layers 46B. In one embodiment, at least one additional dielectric support pillar structure 20 (such as at least one second-type dielectric support pillar structure 20B) may be provided, each of which may have a same material composition as the dielectric support pillar structure 20 (i.e., 20A), may have a bottom surface located within a horizontal plane including a bottom surface of the dielectric support pillar structure 20, and may have a top surface located within a horizontal plane including a topmost surface of the alternating stack (32, 46).

The device of the second embodiment includes additional dielectric support pillar structures 20A located below the respective layer contact via structures 86. This provides compact lengths of portions of the insulating layers 32 that extend between the dielectric support pillar structures 20A and 20B in the contact region 200. This prevents or reduces buckling of the portions of the insulating layers 32 located in the contact region 200 into the laterally-extending cavities 43 during replacement of the sacrificial material layers 42 with the electrically conductive layers 46.

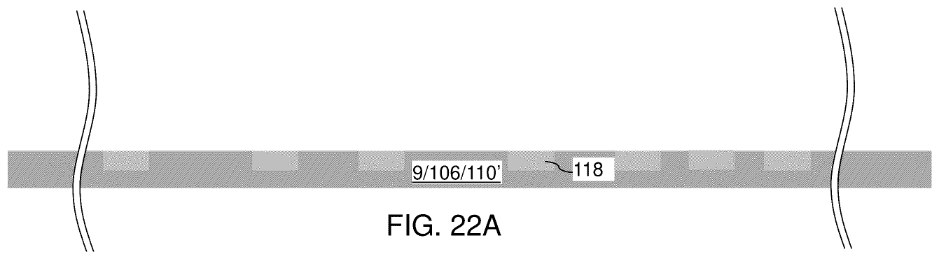

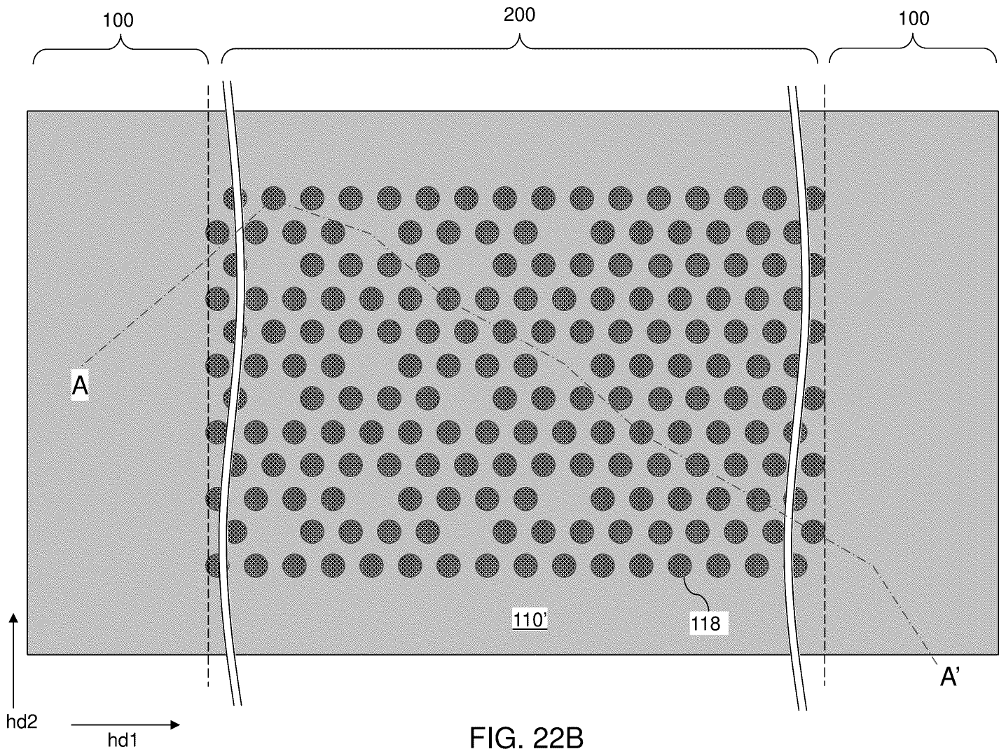

Referring to FIGS. 22A and 22B, a third exemplary structure according to a third embodiment of the present disclosure is illustrated. The etch-stop plates formed within the third exemplary structure are herein referred to as first etch-stop plates 118. The third exemplary structure may be derived from the first exemplary structure illustrated in FIGS. 1A and 1B by modifying the pattern of the first etch-stop plates 118. The pattern of the first etch-stop plates 118 may have the pattern of a periodic two-dimensional array of support pillar structures, such as a pattern of a hexagonal array or a rectangular array.

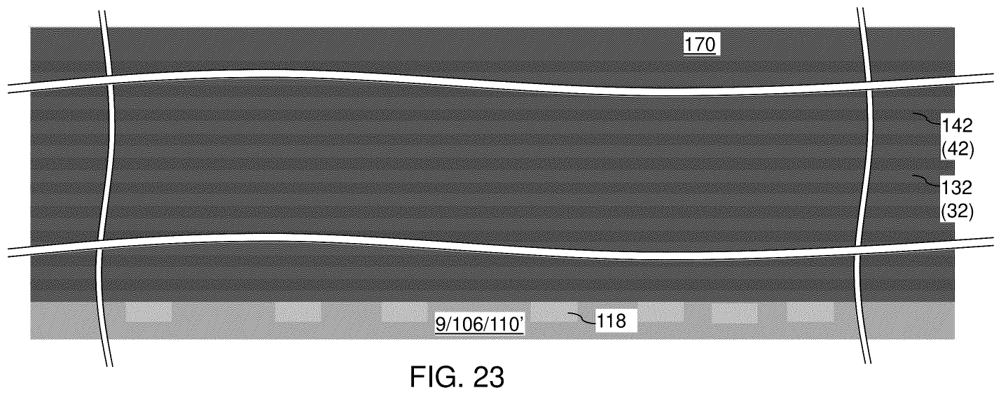

Referring to FIG. 23, the processing steps described with reference to FIG. 2 can be performed to form a first alternating stack (132, 142) of first insulating layers 132 and first sacrificial material layers 142. The first insulating layers 132 are a subset of all insulating layers 32 that will be formed in the first alternating stack and a subsequently formed second alternating stack. The first sacrificial material layers 142 are a subset of all sacrificial material layers 42 that will be formed in the first alternating stack and the subsequently formed second alternating stack. As such, the first insulating layers 132 may be the same as the insulating layers 32 described with reference to the first exemplary structure and the second exemplary structure, and the first sacrificial material layers 142 may be the same as the sacrificial material layers 42 described with reference to the first exemplary structure and the second exemplary structure. In one embodiment, each of the first insulating layers 132 may have a first thickness, and each of the first sacrificial material layers 142 may have a second thickness. An additional insulating layer can be formed on the top surface of the topmost first sacrificial material layer 142, which is herein referred to as a first insulating cap layer 170.

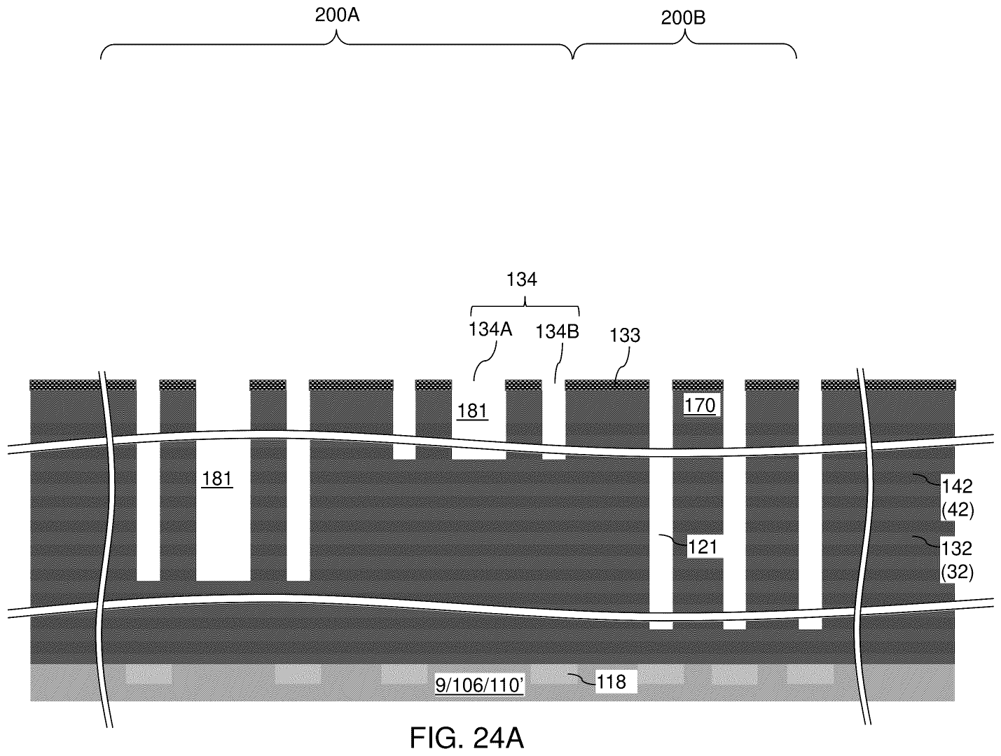

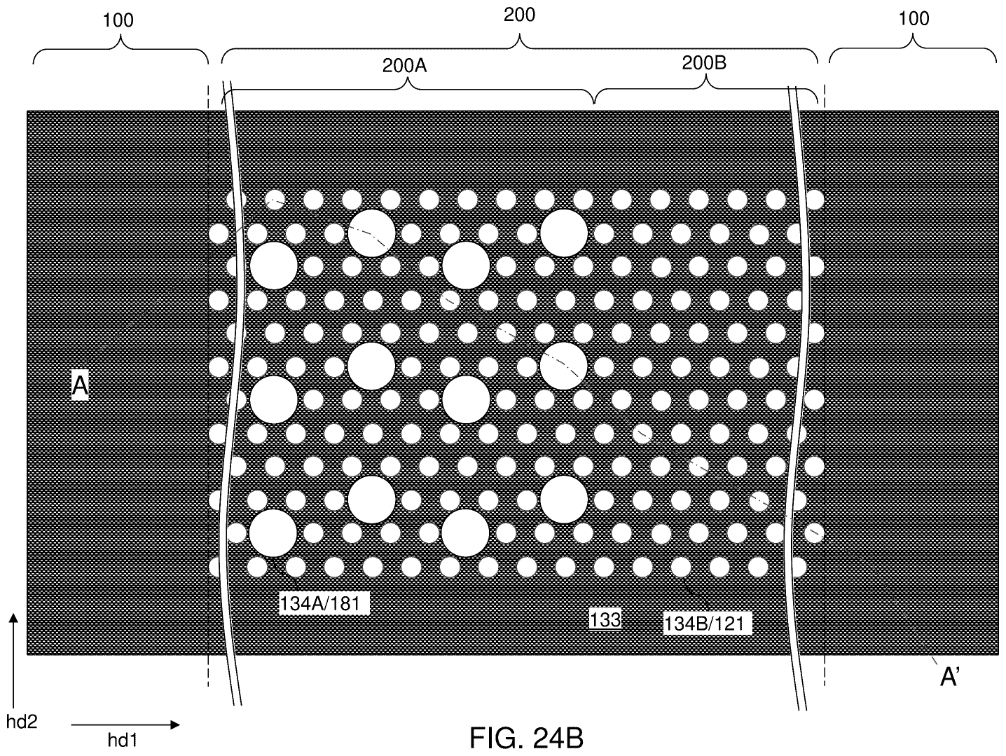

Referring to FIGS. 24A and 24B, a first patterned hard mask layer 133 may be formed over the first insulating cap layer 170. The first patterned hard mask layer 133 may comprise any etch mask material that can withstand ashing processes that are subsequently employed to remove patterned photoresist material layers. The first patterned hard mask layer 133 may comprise a metallic material (such as TiN), a dielectric metal oxide material, or a semiconductor material, such as amorphous silicon, polysilicon or silicon carbide. The first patterned hard mask layer 133 may be formed by depositing a blanket (unpatterned) hard mask material layer, by forming a photoresist material layer (not illustrated) over the blanket hard mask material layer, by lithographically patterning the photoresist material layer to form openings in areas in which first contact via cavities 181 and first support via cavities 121 are to be subsequently formed, and by transferring the pattern in the patterned photoresist layer through the blanket hard mask material layer by performing an anisotropic etch process. The anisotropic etch process may be extended to transfer the pattern of the openings in the first patterned hard mask layer 133 through the first insulating cap layer 170. An array of openings 134 is formed through the first patterned hard mask layer 133. The photoresist material can be subsequently removed.

The openings 134 in the first patterned hard mask layer 133 can be formed in the areas of the first etch-stop plate 118. In one embodiment, openings 134 in the first patterned hard mask layer 133 can be formed over each first etch-stop plate 118 and at locations at which first layer contact via structures are to be subsequently formed. In one embodiment, the openings 134 in the first patterned hard mask layer 133 may comprise first-type openings 134A having a larger area and formed at a location at which a respective first layer contact via structure is to be subsequently formed in a plan view (such as a top-down view), and second-type openings 134B having a smaller area and formed at a location at which a respective first-tier dielectric support structure is to be subsequently formed. Alternatively, the areas of the first and second-type openings may be the same.

In one embodiment, each first-type opening 134A in the first patterned hard mask layer 133 may be laterally surrounded by a plurality of second-type openings 134 in the first patterned hard mask layer 133. Each combination of a first-type opening 134A in the first patterned hard mask layer 133 and a neighboring set of second-type openings 134B in the first patterned hard mask layer 133 constitutes a cluster of openings 134 in the first patterned hard mask layer 133. The total number of clusters of openings 134 through the first patterned hard mask layer 133 may be the same as or may be greater than the total number of first sacrificial material layers 142 in the first alternating stack (132, 142). In a non-limiting illustrative example, for each first-type opening 134A in the first patterned hard mask layer 133, a hexagonal arrangement of six second-type openings 134B or a rectangular arrangement of four second-type openings 134B may be provided through the first patterned hard mask layer 133.

In one embodiment, a subset of the second-type openings 134B in the first patterned hard mask layer 133 may be formed as a periodic array of second-type openings 134B in an area 200B in which second layer contact via structures for electrically conductive layers in a second-tier structure to be subsequently formed over the first insulating cap layer 170. In a non-limiting illustrative example, the subset of the second-type openings 134B in the first patterned hard mask layer 133 may be arranged as a periodic hexagonal array or as a periodic rectangular array.

A series photoresist layers, in combination with a series of anisotropic etch processes can be subsequently employed to sequentially cover a respective subset of the openings in the first patterned hard mask layer 133 and to extend the pattern of the openings 134 in the first patterned hard mask layer 133 through a respective number of pairs of a first insulating layer 132 and a first sacrificial material layer 142, as described above with respect to the first embodiment.

For each first contact via cavity 181 having a respective depth, a plurality of first support via cavities 121 having the same depth may laterally surround the first contact via cavity 181 in the first area 200A of the contact region 200. In the second area 200B of the contact region 200 in which the first patterned hard mask layer 133 includes a periodic array of second-type openings 134B, an array of first support via cavities 121 can be formed. The array of first support via cavities 121 may have the same depth as a cluster of a first contact via cavity 181 and a respective set of first support via cavities 121 laterally surrounding the first contact via cavity 181 and having the greatest depth among the clusters of first contact via cavities 181 and first support via cavity 121. In one embodiment, the bottom surfaces of the array of first support via cavities 121 may be formed on a second-from-bottom first insulating layer 132, i.e., a first insulating layer 132 that overlies the bottommost first insulating layer 132 and is most proximal to the bottommost first insulating layer 132.

A plurality of contact via cavities 181 may vertically extend through a respective subset of the sacrificial material layers 42. In one embodiment, each first insulating layer 132 other than the bottommost first insulating layer 132 may have a respective top surface segment that is physically exposed to a respective one of the contact via cavities 181. The diameter of each first contact via cavity 181 may be in a range from 200 nm to 600 nm, and the diameter of each first support via cavity 121 may be in a range from 100 nm to 500 nm, although lesser and greater diameters may also be employed.

Clusters of first via cavities (181, 121) can be formed in the first alternating stack (132, 142). Each cluster of first via cavities (181, 121) comprises a respective first contact via cavity 181 and a respective set of first support via cavities 121 laterally surrounding the respective first contact via cavity 181. Each first via cavity (181, 121) within a same cluster of first via cavities (181, 121) may have a same depth. The depths of the clusters of first via cavities (181, 121) differ from cluster to cluster. Each cluster of first via cavities (181, 121) can be formed through a respective first subset of the first sacrificial material layers 142.

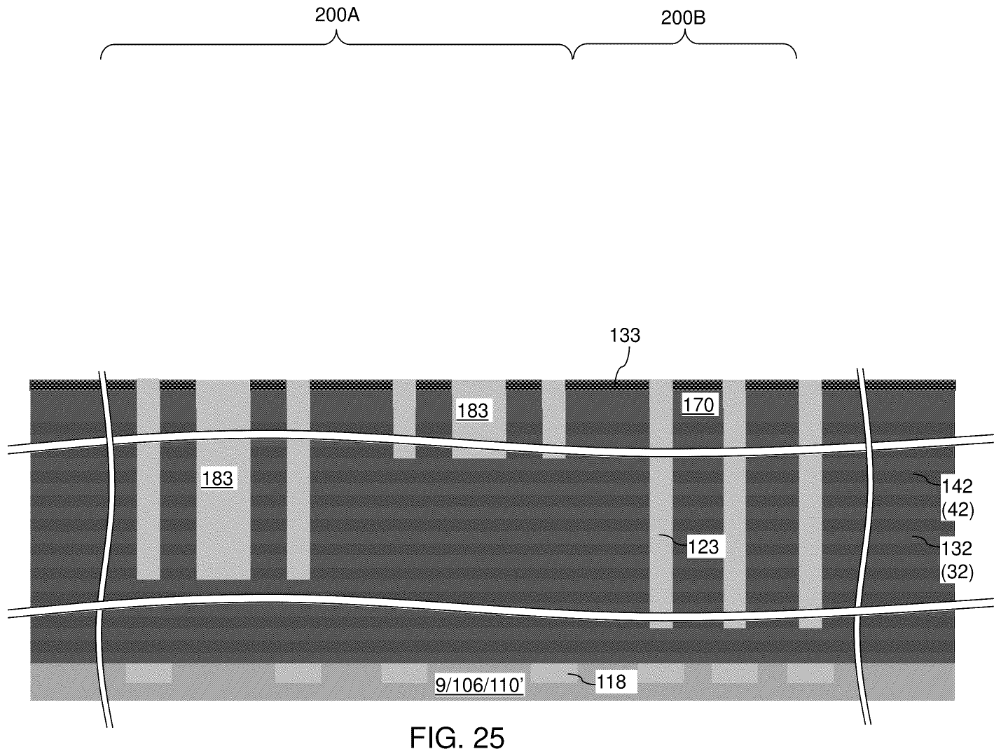

Referring to FIG. 25, a first sacrificial fill material can be deposited in the voids within the first via cavities (181, 121), i.e., within the first contact via cavities 181 and within he first support via cavities 121. The first sacrificial fill material comprises a material that can be subsequently removed selective to material of the first alternating stack (132, 142). For example, the first sacrificial fill material may comprise a carbon-based material, such as amorphous carbon or diamond-like carbon, a semiconductor material, such as amorphous silicon, polysilicon, or silicon-germanium, or a dielectric material, such as borosilicate glass or organosilicate glass.

Excess portions of the first sacrificial fill material may be removed from above the horizontal plane including the top surface of the first patterned hard mask layer 133 employing a planarization process. The planarization process may comprise a recess etch process or a chemical mechanical polishing process. Each remaining portion of the first sacrificial fill material that fills a respective first contact via cavity 181 constitutes a first sacrificial contact via fill material portion 183. Each remaining portion of the first sacrificial fill material that fills a respective first support via cavity 121 constitutes a first sacrificial support via fill material portion 123. Each first sacrificial via fill material portion (183, 123) may have a respective top surface located within the horizontal plane including the top surface of the first patterned hard mask layer 133.

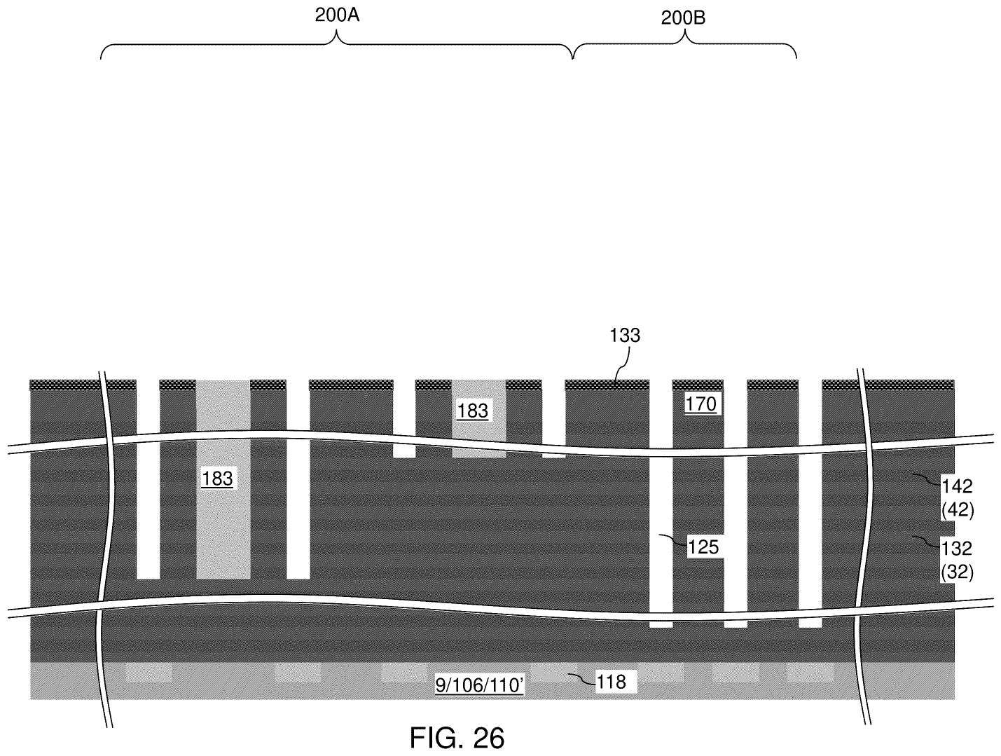

Referring to FIG. 26, a photoresist layer (not shown) can be applied over the first patterned hard mask layer 133, and can be lithographically patterned to cover the first sacrificial contact via fill material portions 183 without covering the first sacrificial support via fill material portions 123. A selective etch process or an ashing process can be performed to remove the first sacrificial support via fill material portions 123 from within the first support via cavities 121. For example, if the first sacrificial support via fill material portions 123 comprise silicon, a wet etch process using hot trimethyl-2 hydroxyethyl ammonium hydroxide (“hot TMY”) or tetramethyl ammonium hydroxide (TMAH) may be used to remove the first sacrificial support via fill material portions 123 selective to the materials of the first alternating stack (132, 142) and the first patterned hard mask layer 133. The portions of the sacrificial fill material that are present in the first support via cavities 121 are removed without removing the first sacrificial contact via fill material portions 183. A void is formed within the entire volume of each first support via cavity 121.

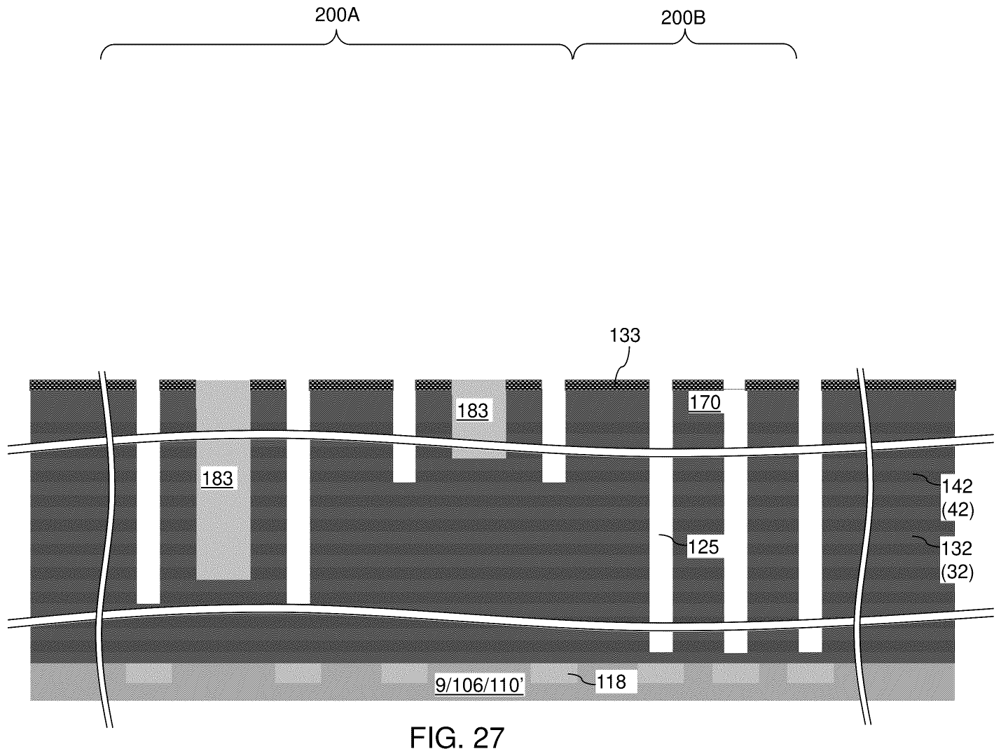

Referring to FIG. 27, a first via extension process can be performed to vertically extend the first support via cavities 121. The first via extension process comprises an anisotropic etch process, and vertically extends each first support via cavity 121 by a vertical extension distance that is greater than the thickness of one of the first sacrificial material layers 142 within the first alternating stack (132, 142) (i.e., the second thickness), and is less than twice the sum of the thickness of one of the first insulating layers 132 within the first alternating stack (132, 142) (i.e., the first thickness) and the thickness of one of the first sacrificial material layers within the first alternating stack (132, 142) (i.e., the second thickness). In one embodiment, the first via extension process may etch through a first insulating layer 132 and a first sacrificial material layer 142 underneath each of the first support via cavities 121.

The first via extension process is performed while the first contact via cavities 181 are filled with first sacrificial contact via fill material portions 183. The array of first support via cavities 121 underlying the array of second-type openings 134B in the first patterned hard mask layer 133 can be vertically extended such that the array of first support via cavities 121 vertically extends through each first sacrificial material layer 142 within the first alternating stack (132, 142) after the first via extension process. The photoresist layer can be removed, for example, by ashing.

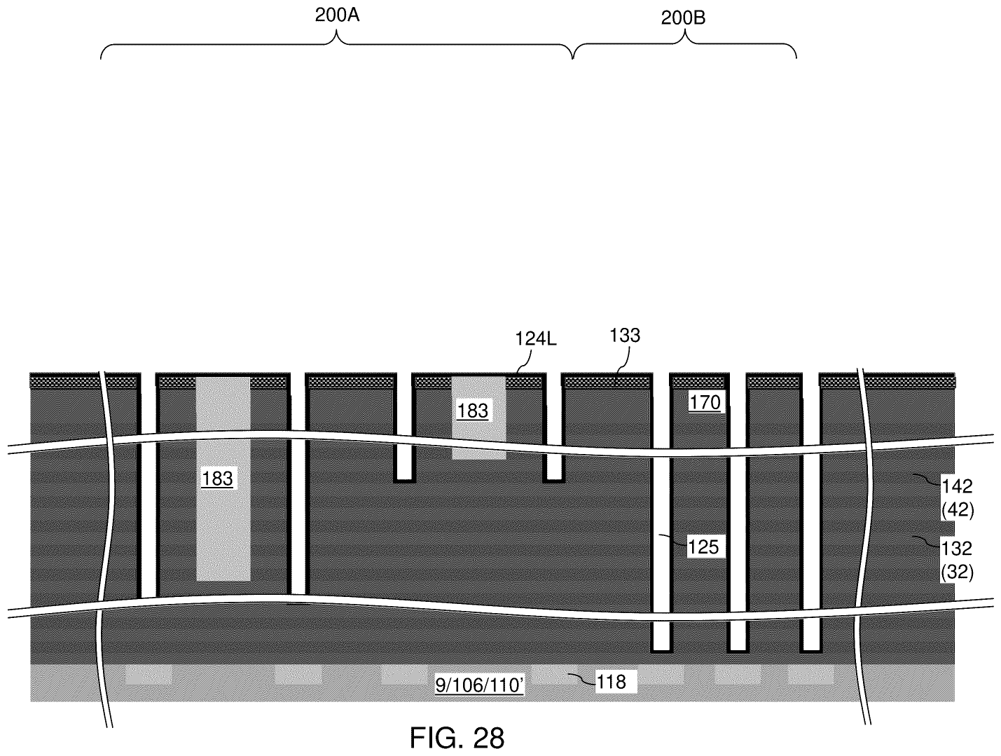

Referring to FIG. 28, a first insulating liner 124L can be conformally deposited in peripheral portions of the first support via cavities 121 and over the first patterned hard mask layer 133. The first insulating liner 124L comprises an insulating material such as a dielectric metal oxide, silicon carbide nitride (i.e., silicon carbonitride), or silicon oxide, and may have a thickness in a range from 5 nm to 60 nm, such as from 10 nm to 30 nm, although lesser and greater thicknesses may also be employed.

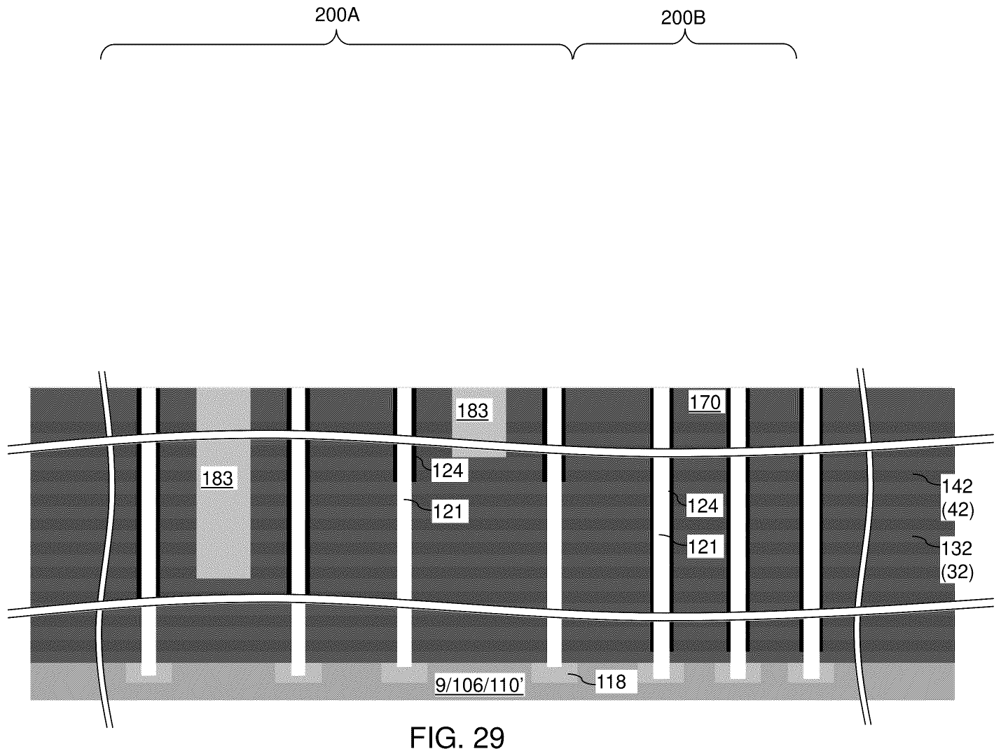

Referring to FIG. 29, an anisotropic etch process can be performed to etch horizontally-extending portions of the first insulating liner 124L from above the first patterned hard mask layer 133 and at the bottom of each first support via cavity 121. Each remaining tubular portion of the first insulating liner 124L comprises a first tubular insulating liner 124 located in a peripheral portion of a respective first support via cavity 121. For an array of first support via cavities 121 in the second area 200B that is formed outside the first area 200A occupied by the first sacrificial contact via fill material portions 183, each first tubular insulating liner 124 may vertically extend through and may contact all of the first sacrificial material layers 142. Each first tubular insulating liner 124 is formed in a peripheral portion of a respective first support via cavity 121, and vertically extends through and laterally contacts a respective subset of the first sacrificial material layers 142 within the first alternating stack (132, 142). Some or all of the first tubular insulating liners 124 may contact the topmost first sacrificial material layer 142. The first tubular insulating liners 124 in different first support via cavities 121 have different heights.

A second via extension process can be performed to vertically extend the first support via cavities 121. The second via extension process comprises an anisotropic etch process, and etches portions of the first alternating stack (132, 142) that underlie the first support via cavities 121. The first etch-stop plates 118 function as etch-stop structures for the second via extension process. Each first support via cavity 121 vertically extends through each layer within the first alternating stack (132, 142) after the second via extension process. In one embodiment, a surface of a first etch-stop plate 118 may be physically exposed at the bottom of each first support via cavity 121. A first tubular insulating liner 124 may contact a respective first subset of the first sacrificial material layers 142, and each first sacrificial material layer 142 in a second subset of the first sacrificial material layers 142 that underlies the first subset may laterally surround and may be exposed to a first support via cavity 121. In other words, the first tubular insulating liner 124 covers sidewalls of a respective upper first subset but not of a respective lower second subsect of first sacrificial material layers 142. The sidewalls of the respective lower second subsect of first sacrificial material layers 142 are exposed in the respective first support via cavity 121. The first patterned hard mask layer 133 can be subsequently removed, for example, by performing a selective etch process such as a wet etch process.

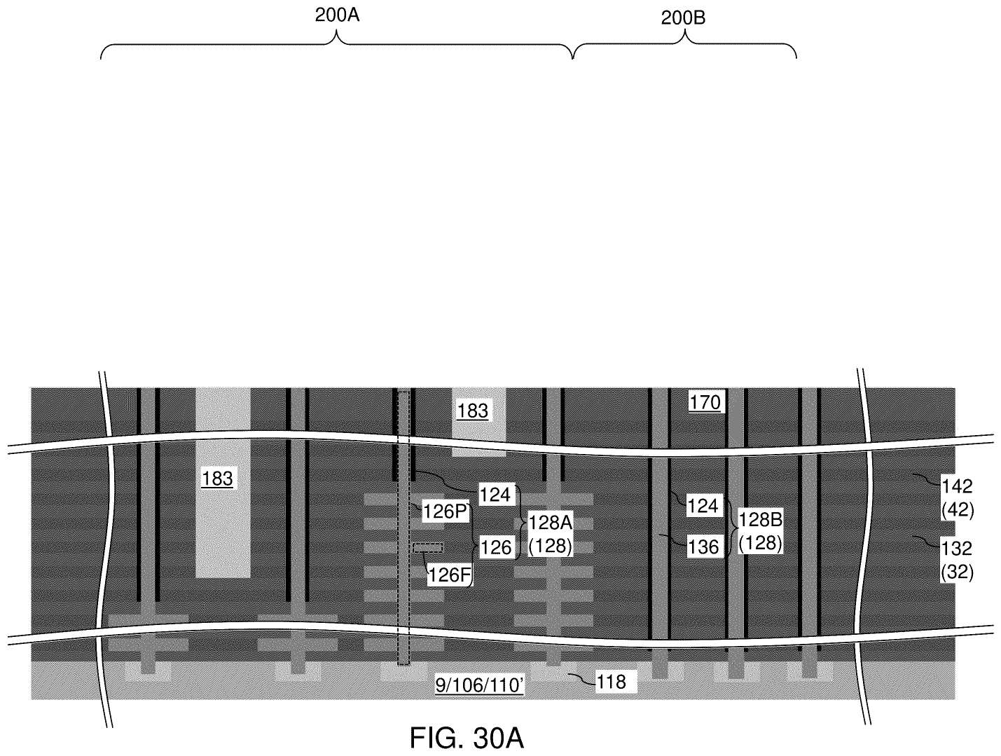

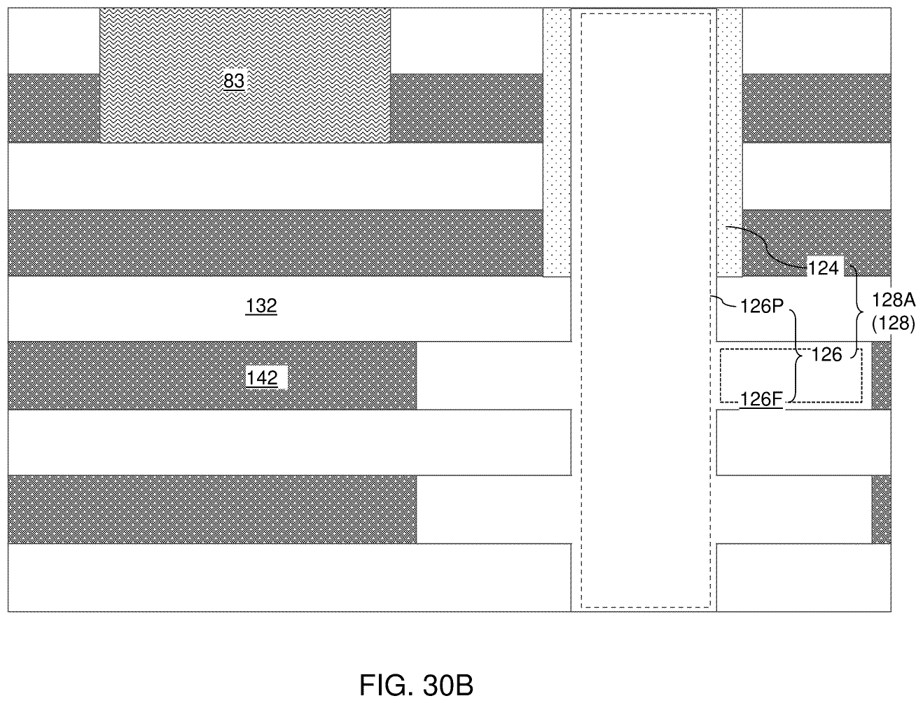

Referring to FIGS. 30A and 30B, a selective isotropic etch process can be performed to isotropically etch portions of the exposed lower second subset of the first sacrificial material layers 142 that are proximal to the first support via cavities 121 selective to the materials of the first insulating layers 132, the first etch-stop plates 118, the first tubular insulating liners 124, and the first insulating cap layer 170. For example, if the first sacrificial material layers 142 comprise silicon nitride, a wet etch process employing hot phosphoric acid may be performed to isotropically etch portions of the first sacrificial material layers 142 that are proximal to the first support via cavities 121 and are not covered by a first tubular insulating liner 124. The lateral recess distance of the selective isotropic etch process may be in a range from 20 nm to 300 nm, such as from 40 nm to 200 nm, although lesser and greater lateral recess distances may also be employed.

Annular fin cavities can be formed in the volumes from which the material of the first to sacrificial material layers 142 is removed by the selective isotropic etch process. A subset of the first support via cavities 121 located in the first area 200A adjacent to a respective subset of the first sacrificial contact via fill material portions 183 can be converted into finned first support via cavities including a respective set of at least one annular fin cavity. The array of first support via cavities 121 located in the second area 200B in which each first tubular insulating liner 124 vertically extends through each first sacrificial material layer 142 in the first alternating stack (132, 142) is not modified during the selective isotropic etch process.

In one embodiment, for each first support via cavity 121 that is formed in the first area 200A adjacent to a respective one of the first sacrificial contact via fill material portions 183, a first tubular insulating liner 124 is present within the first support via cavity 121. The first tubular insulating liner 124 contacts sidewalls of a respective first subset of the first sacrificial material layers 142. A respective second subset of the first sacrificial material layers 142 underlie the respective first subset of the first sacrificial material layers 142. The respective second subset of the first sacrificial material layers 142 underlies a horizontal plane including an annular bottom surface of the first tubular insulating liner 124. Annular cavities are formed around the first support via cavity 121 by removing proximal portions of the second subset of the first sacrificial material layers 142 selective to the first tubular insulating liner 124 and the first insulating layers 132.

A dielectric fill material, such as undoped silicate glass or a doped silicate glass, can be deposited into finned first support via cavities and the first support via cavities 121 that do not include any annular fin cavity. In one embodiment, a first finned dielectric material portion 126 can be formed in the first area 200A in a finned first support via cavity, which comprises a combination of a first support via cavity 121 and at least one annular cavity. The first finned dielectric material portion 126 comprises a first dielectric pillar 126P that vertically extends through each layer within the first alternating stack (132, 142) and laterally extending first dielectric fins 126F surrounding the first dielectric pillar 126. A contiguous combination of a first tubular insulating liner 124 and a first finned dielectric material portion 126 constitutes a first finned dielectric support pillar structure 128A, which is a first dielectric support pillar structure 128 of a first type.

A first cylindrical dielectric material portion 136 can be formed within a volume of a void in a first support via cavity 121 in the second area 200B in which a first tubular insulating liner 124 vertically extends through each first sacrificial material layer 142. A contiguous combination of a first tubular insulating liner 124 and a first cylindrical dielectric material portion 136 constitutes a first finless dielectric support pillar structure 128B, which is a first dielectric support pillar structure 128 of a second type. The first finned dielectric material portions 126 and the first cylindrical dielectric material portions 136 may be formed simultaneously by deposition and planarization of a same dielectric fill material.

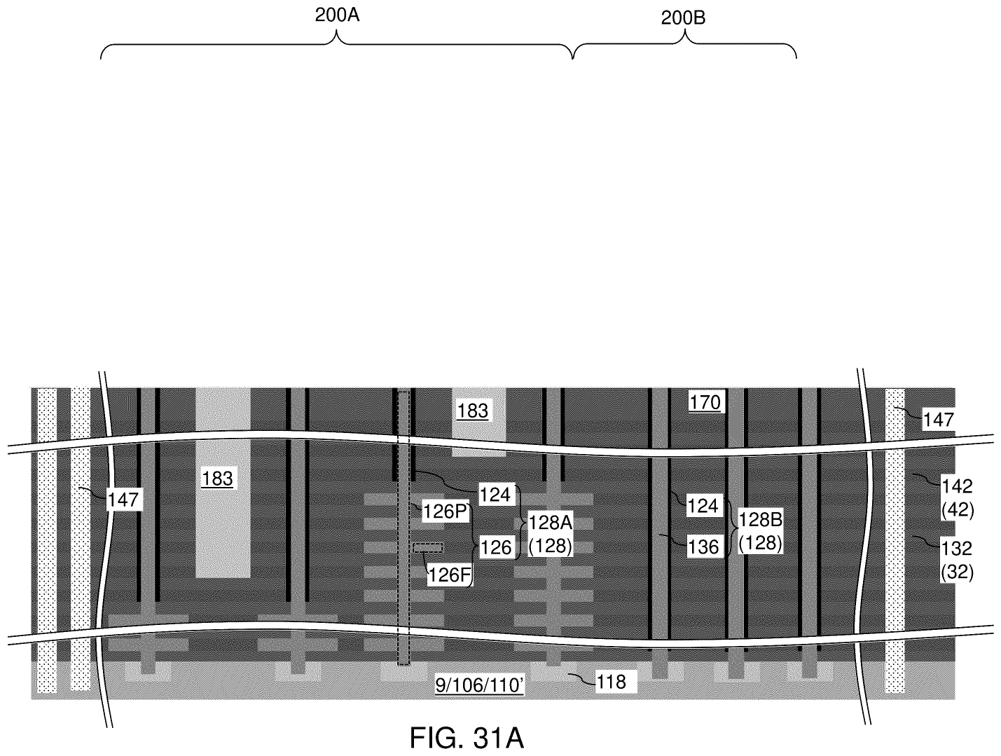

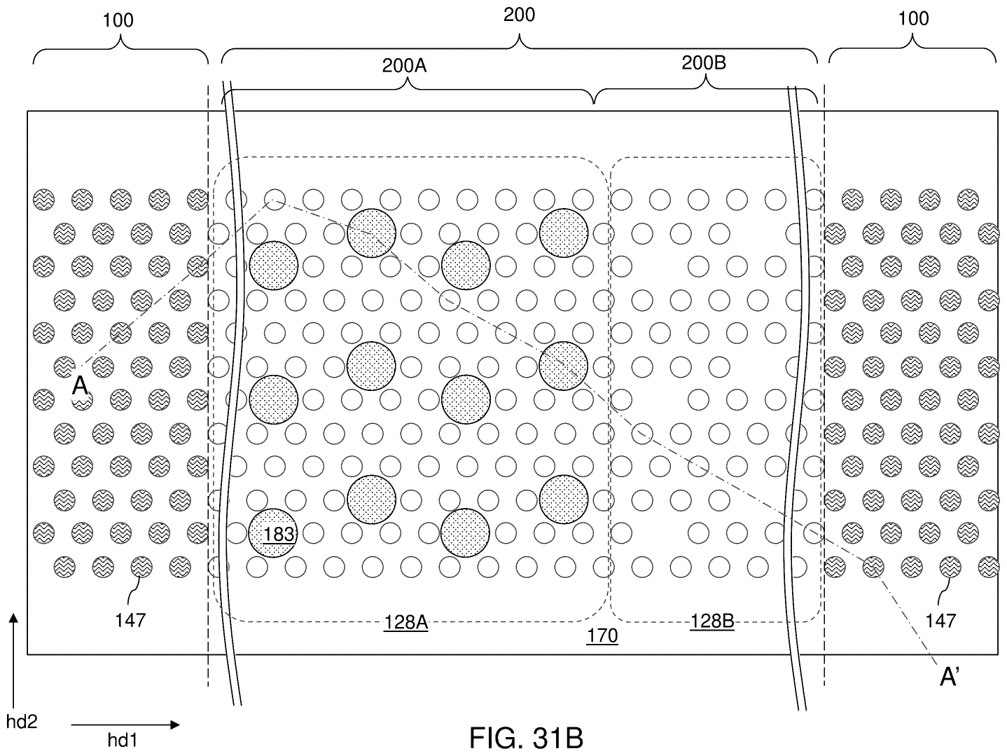

Referring to FIGS. 31A and 31B, first-tier memory openings can be formed through the first alternating stack (132, 142) in memory array regions 100. The first-tier memory openings can be formed in the same manner as formation of the memory openings 49 in the first and second exemplary structure. A sacrificial fill material, such as amorphous silicon or a carbon-based material can be deposited in the first-tier memory openings to form first-tier sacrificial memory opening fill structures 147.

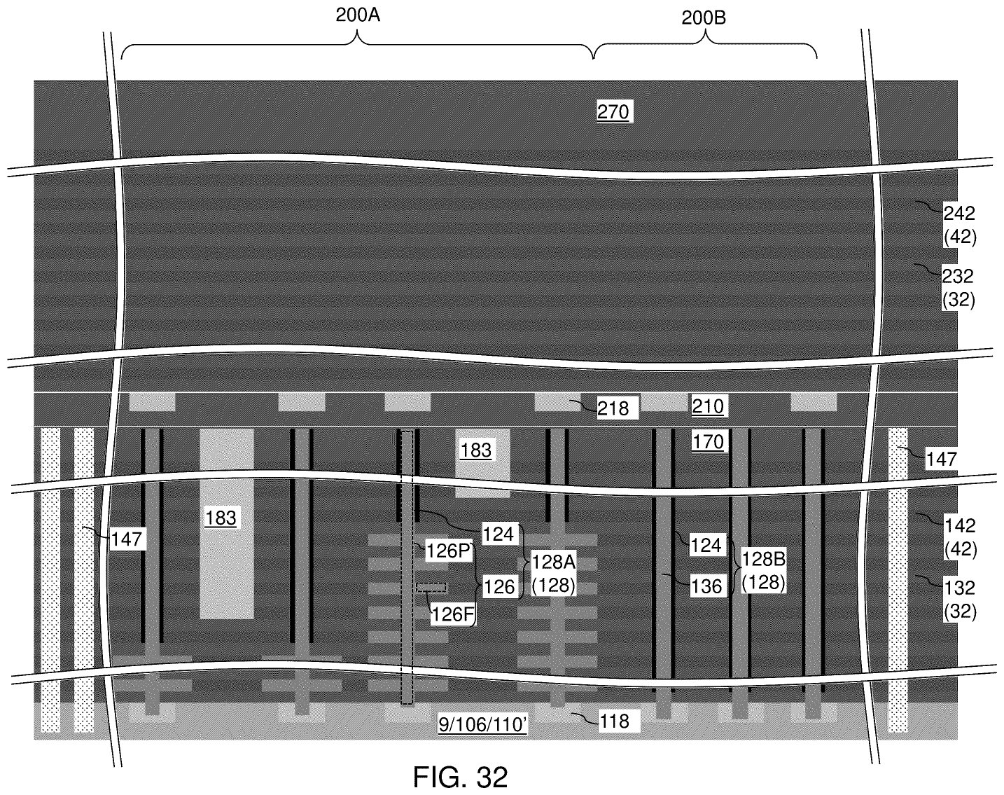

Referring to FIG. 32, an inter-tier dielectric layer 210 can be deposited over the first insulating cap layer 170. The inter-tier dielectric layer 210 comprises a dielectric material such as silicon oxide, and may have a thickness in a range from 50 nm to 300 nm, although lesser and greater thicknesses may also be employed.

Second etch-stop plates 218 may be formed in the inter-tier dielectric layer 210. The second etch-stop plates 218 may comprise any material that may be employed for the first etch-stop plates 118. The second etch-stop plates 218 may be have top surfaces within a horizontal plane including the top surface of the inter-tier dielectric layer 210. The pattern of the second etch-stop plates 218 may be derived from the pattern of the first etch-stop plates 118 by not forming the second etch-stop plates 218 at locations at which second layer contact via structures are to be subsequently formed. The sites at which the second layer contact via structures are to be subsequently formed may be located at a subset of the lattice sites of the pattern of the two-dimensional array of first etch-stop plates 118. Each site from which a second etch-stop plate 218 is omitted is laterally surrounded by sites at which second etch-stop plates 218 are present.

A second alternating stack (232, 242) of second insulating layers 232 and second sacrificial material layers 242 can be formed above the inter-tier dielectric layer 210. The second insulating layers 232 are a subset of the insulating layers 32. The second sacrificial material layers 242 are a subset of the sacrificial material layers 42. The second alternating stack (232, 242) may be the same as the first alternating stack (132, 142) except that the total number of repetitions of a pair of a second insulating layer 232 and a second sacrificial material layer 242 in the second alternating stack (232, 242) may be different from the total number of repetitions of a pair of a first insulating layer 132 and a first sacrificial material layer 142 in the first alternating stack (132, 142). A second insulating cap layer 270 may be formed over the second alternating stack (232, 242). The second insulating cap layer 270 may have the same material composition and the same thickness range as the first insulating cap layer 170.

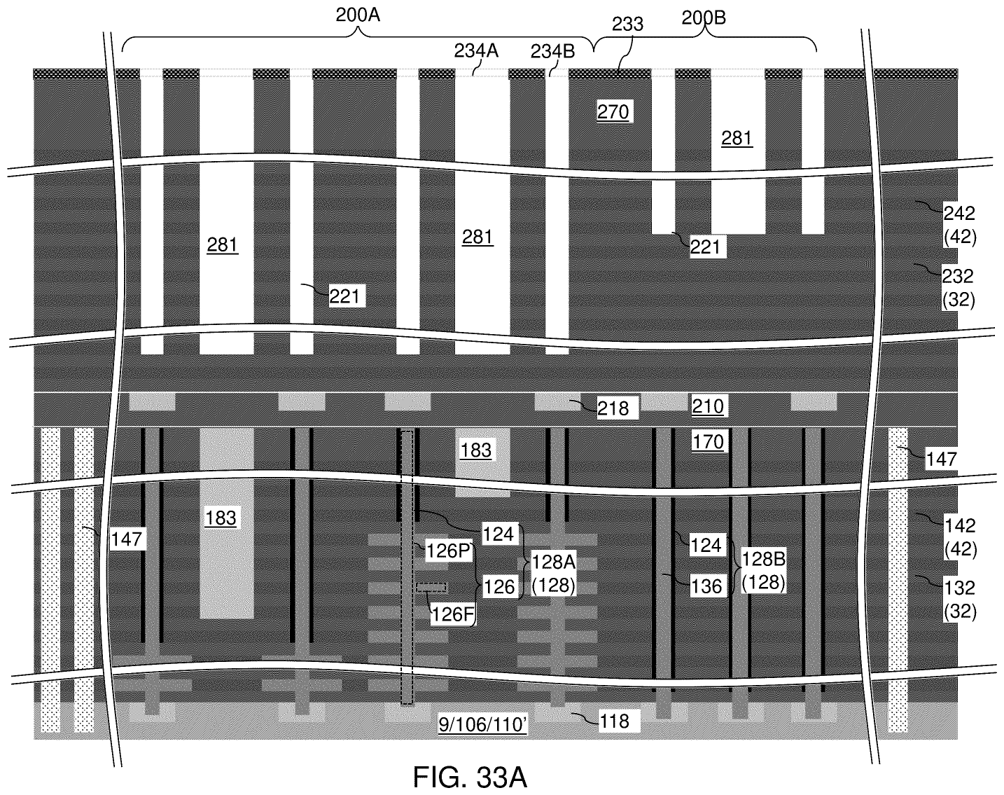

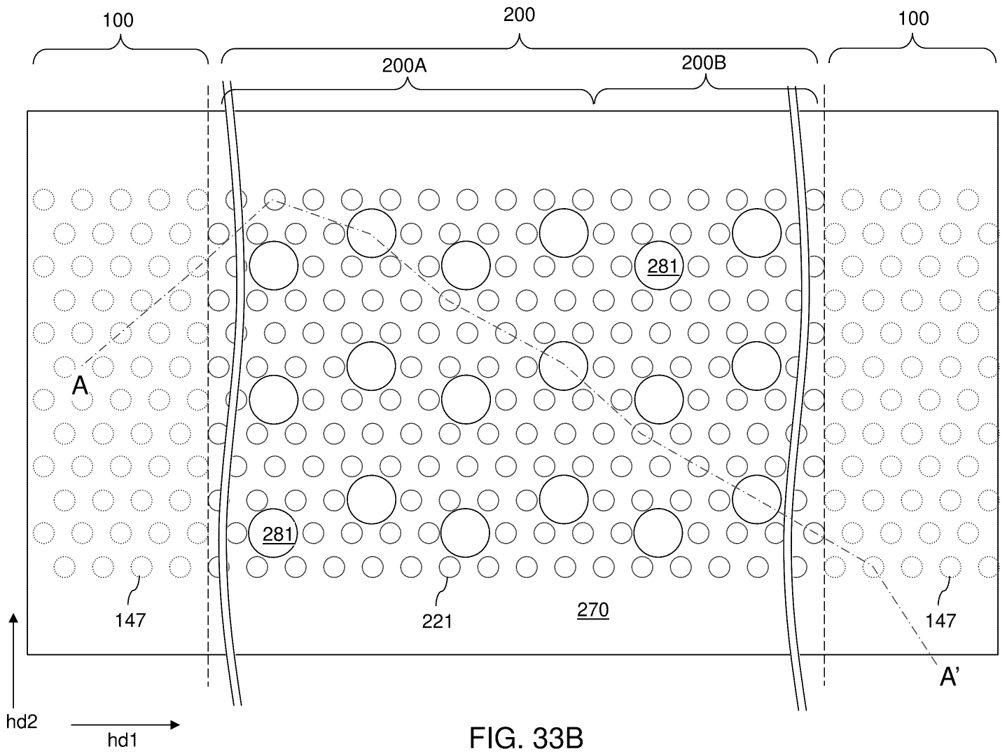

Referring to FIGS. 33A and 33B, a second patterned hard mask layer 233 may be formed over the second insulating cap layer 270. The second patterned hard mask layer 233 may comprise any etch mask material that may be employed as the first patterned hard mask layer 133. An array of openings 234 is formed through the second patterned hard mask layer 233 using the same method as described above for the array of openings 134. The photoresist material can be subsequently removed.

The openings 234 in the second patterned hard mask layer 233 can be formed in the areas of the first sacrificial contact via fill material portions 183 and the first dielectric support pillar structures 128. In one embodiment, the openings 234 in the second patterned hard mask layer 233 may comprise first-type openings 234A having a larger area and formed at a location at which a respective second layer contact via structure is to be subsequently formed in a plan view (such as a top-down view), and second-type openings 234B having a smaller area and formed at a location at which a respective second-tier dielectric support structure is to be subsequently formed. Alternatively, both types of openings (234A, 234B) may have the same area.

In one embodiment, each first-type opening 234A in the second patterned hard mask layer 233 may be laterally surrounded by a plurality of second-type openings 234B in the second patterned hard mask layer 233. Each combination of a first-type opening 234A in the second patterned hard mask layer 233 and a neighboring set of second-type openings 234B in the second patterned hard mask layer 233 constitutes a cluster of openings 234 in the second patterned hard mask layer 233. The total number of clusters of openings through the second patterned hard mask layer 233 may be the same as or may be greater than the sum of the total number of first sacrificial material layers 142 in the first alternating stack (132, 142) and the total number of second sacrificial material layers 242 in the second alternating stack (132, 242). In a non-limiting illustrative example, for each first-type opening 234A in the second patterned hard mask layer 233, a hexagonal arrangement of six second-type openings 234B or a rectangular arrange of fourth second-type openings 234B may be provided through the second patterned hard mask layer 233. In one embodiment, a subset of the clusters of openings 234B in the second area 200B in the second patterned hard mask layer 233 may overlie and may have an areal overlap in a plan view with the periodic array of first finless dielectric support pillar structure 128B embedded in the first alternating stack (132, 142).

A series photoresist layers, in combination with a series of anisotropic etch processes can be subsequently employed to sequentially cover a respective subset of the openings in the second patterned hard mask layer 233 and to extend the pattern of the openings in the second patterned hard mask layer 233 through a respective number of pairs of a second insulating layer 232 and a second sacrificial material layer 242. For example, the scheme described with reference to formation of the first contact via cavities 181 and the first support via cavities 121 may be employed to form second contact via cavities 281 and second support via cavities 221.

Clusters of second via cavities (281, 221) can be formed in the second alternating stack (132, 242). Each cluster of second via cavities (281, 221) comprises a respective second contact via cavity 281 and a respective set of second support via cavities 221 laterally surrounding the respective second contact via cavity 281. Each second via cavity (281, 221) within a same cluster of second via cavities (281, 221) may have a same depth. The depths of the clusters of second via cavities (281, 221) differ from cluster to cluster. Each cluster of second via cavities (281, 221) can be formed through a respective first subset of the second sacrificial material layers 242. In one embodiment, each clusters of second via cavities (281, 221) having an areal overlap with a respective first sacrificial contact via fill material portion 183 may have a bottom surface located at a second-from-bottom second insulating layer 232, i.e., a second insulating layer 232 that overlies the bottommost second insulating layer 232 and is most proximal to the bottommost second insulating layer 232.

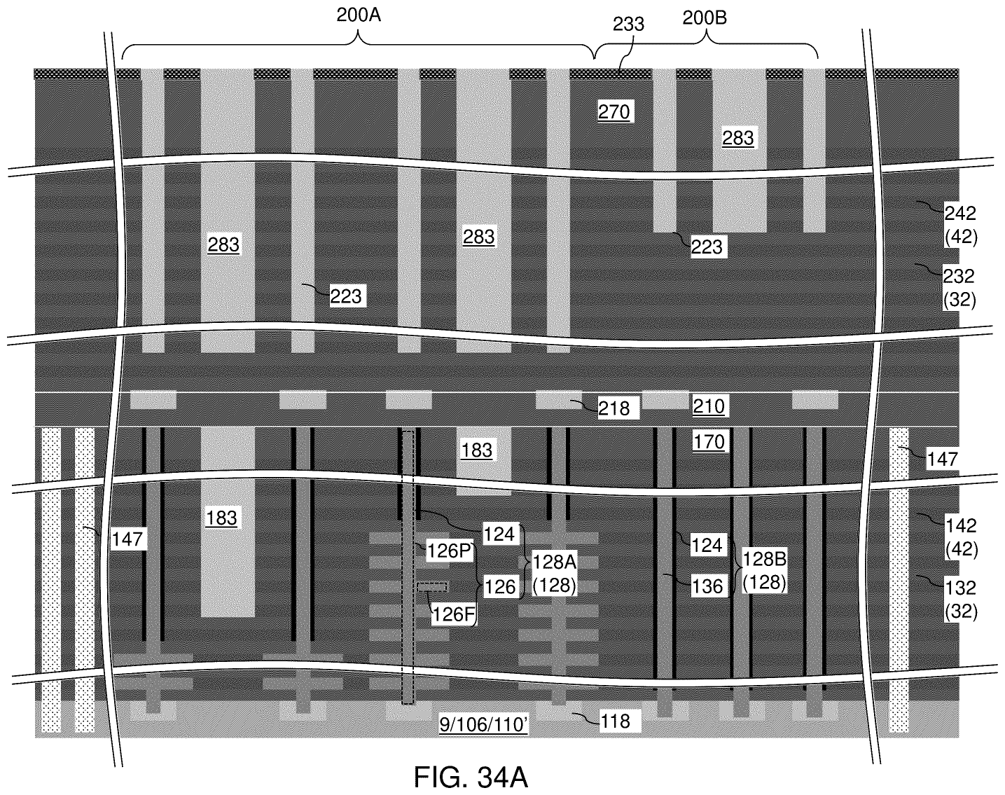

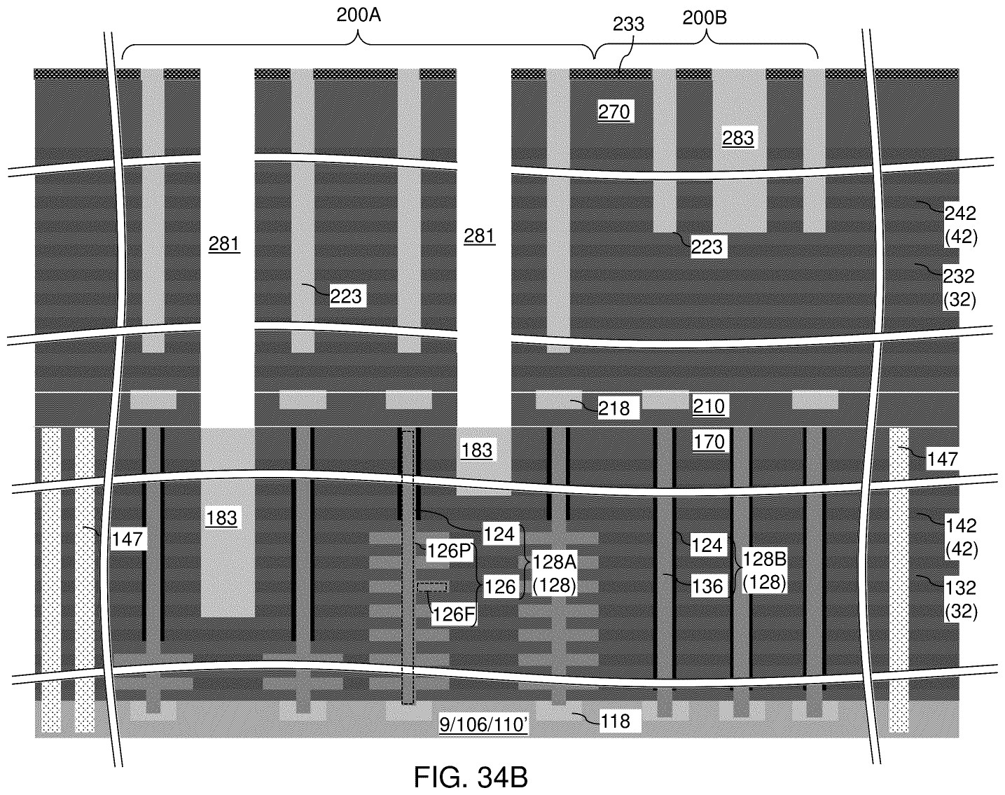

Referring to FIG. 34A, a second sacrificial fill material can be deposited in the voids within the second via cavities (281, 221), i.e., within the second contact via cavities 281 and within he second support via cavities 221. The second sacrificial fill material comprises a material that can be subsequently removed selective to material of the second alternating stack (132, 242). For example, the second sacrificial fill material may comprise a semiconductor material, such as amorphous silicon, polysilicon, or silicon-germanium, or a dielectric material, such as borosilicate glass or organosilicate glass.

Excess portions of the second sacrificial fill material may be removed from above the horizontal plane including the top surface of the second patterned hard mask layer 233 employing a planarization process. The planarization process may comprise a recess etch process or a chemical mechanical polishing process. Each remaining portion of the second sacrificial fill material that fills a respective second contact via cavity 281 constitutes a second sacrificial contact via fill material portion 283. Each remaining portion of the second sacrificial fill material that fills a respective second support via cavity 221 constitutes a second sacrificial support via fill material portion 223. Each second sacrificial via fill material portion (283, 223) may have a respective top surface located within the horizontal plane including the top surface of the second patterned hard mask layer 233.

Referring to FIG. 34B, a photoresist layer (not shown) can be applied over the second patterned hard mask layer 233, and can be lithographically patterned to cover all second sacrificial via fill material portions (283, 223) except the second sacrificial contact via fill material portion 283 having an areal overlap with the first sacrificial contact via fill material portions 183. The second sacrificial contact via fill material portion 283 having the areal overlap with the first sacrificial contact via fill material portions 183 are then removed by selective etching to reopen the second contact via cavities 281 having the areal overlap with the first sacrificial contact via fill material portions 183.

An anisotropic etch process can be performed to vertically extend the reopened subset of the second contact via cavities 281. The reopened subset of the second contact via cavities 281 are vertically extended through underlying material layers of the second alternating stack (232, 242), the inter-tier dielectric layer 210, and the first insulating cap layer 170. Top surfaces of the first sacrificial contact via fill material portions 183 can be physically exposed underneath the vertically extended subset of the second contact via cavities 281. The photoresist layer can be subsequently removed, for example, by ashing.

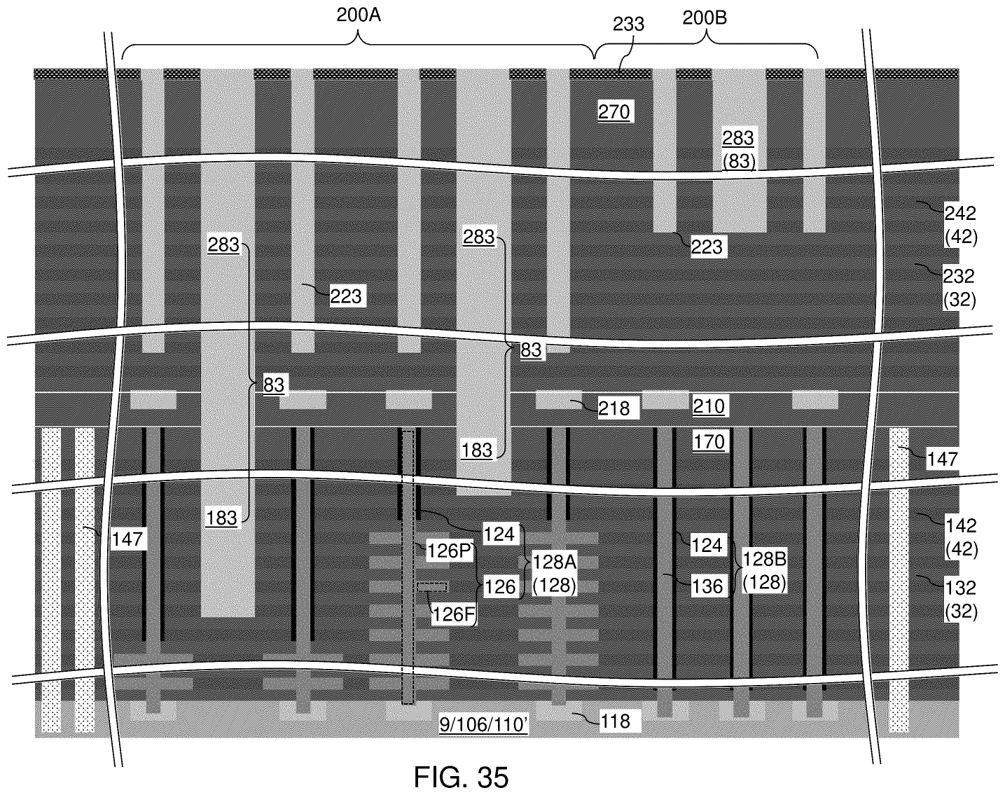

Referring to FIG. 35, the second sacrificial contact via fill material portions 283 are reformed in the vertically extended subset of the second contact via cavities 281. The reformed second sacrificial contact via fill material portions 283 contact the respective underlying first sacrificial contact via fill material portions 183. The first sacrificial contact via fill material portions 183 and the second sacrificial contact via fill material portions 283 are collectively referred to as sacrificial contact via fill material portions 83.

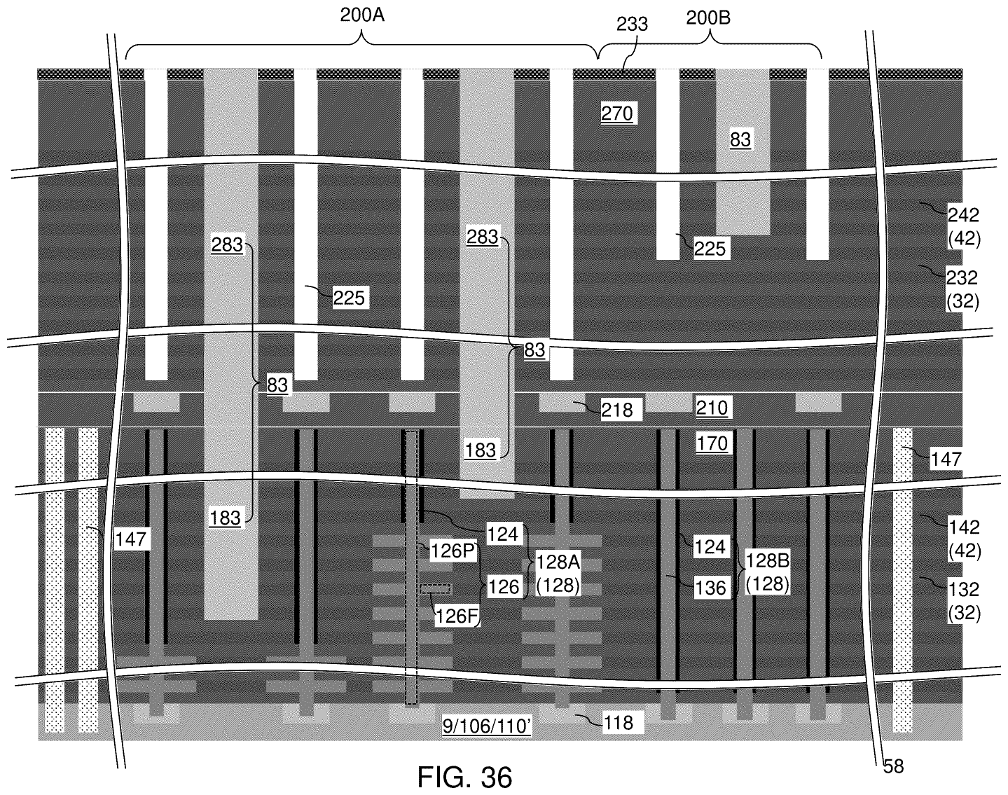

Referring to FIG. 36, a photoresist layer (not shown) can be applied over the second patterned hard mask layer 233, and can be lithographically patterned to cover the second sacrificial contact via fill material portions 283 without covering the second sacrificial support via fill material portions 223. A selective etch process can be performed to remove the second sacrificial support via fill material portions 223 from within the second support via cavities 221. For example, if the second sacrificial support via fill material portions 223 comprise silicon, a wet etch process using hot trimethyl-2 hydroxyethyl ammonium hydroxide (“hot TMY”) or tetramethyl ammonium hydroxide (TMAH) may be used to remove the second sacrificial support via fill material portions 223 selective to the materials of the second alternating stack (132, 242) and the second patterned hard mask layer 233. The portions of the sacrificial fill material that are present in the second support via cavities 221 are removed without removing the second sacrificial contact via fill material portions 283. A void is formed within the entire volume of each second support via cavity 221.

A first via extension process can be performed to vertically extend the second support via cavities 221. The first via extension process comprises an anisotropic etch process, and vertically extends each second support via cavity 221 by a vertical extension distance that is greater than the thickness of one of the second sacrificial material layers 242 within the second alternating stack (232, 242) (i.e., the second thickness), and is less than twice the sum of the thickness of one of the second insulating layers 232 within the second alternating stack (132, 246) (i.e., the first thickness) and the thickness of one of the second sacrificial material layers within the second alternating stack (232, 242) (i.e., the second thickness). In one embodiment, the first via extension process may etch through a second insulating layer 232 and a second sacrificial material layer 242 underneath each of the second support via cavities 221.

The first via extension process is performed while the second contact via cavities 281 are filled with second sacrificial contact via fill material portions 283. A subset of the second support via cavities 221 overlying the first finned dielectric support pillar structures 128A can be vertically extended through each second sacrificial material layer 242 within the second alternating stack (232, 242) after the first via extension process. The photoresist layer can be removed, for example, by ashing.

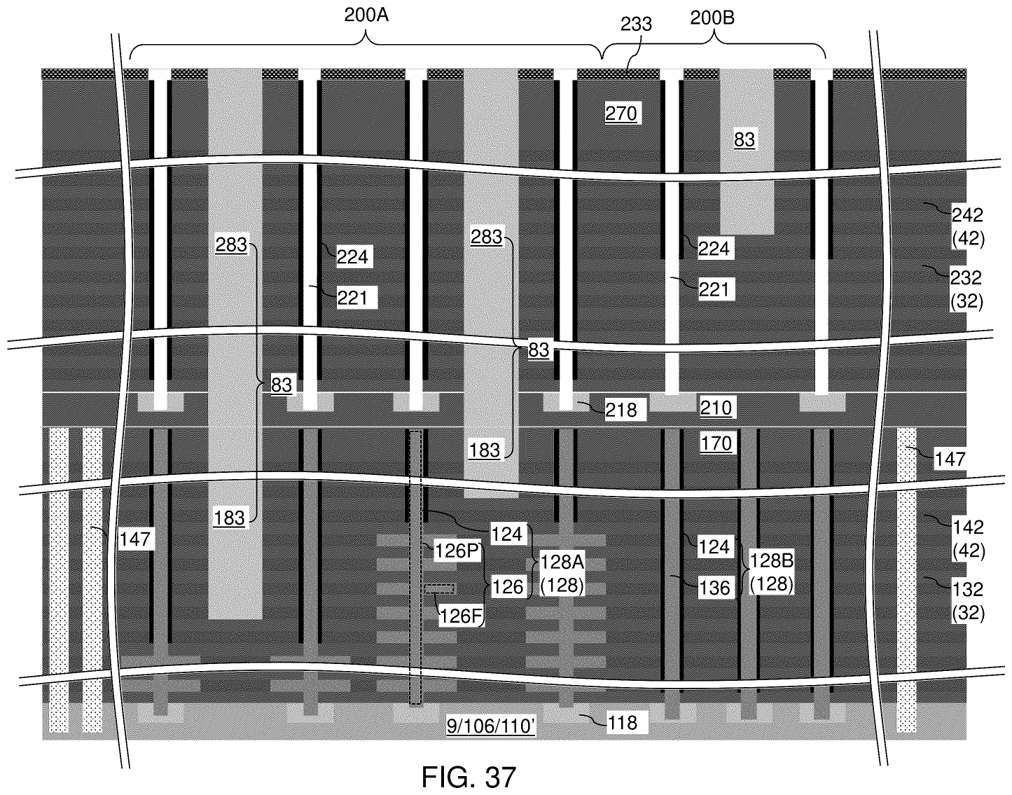

Referring to FIG. 37, a second insulating liner can be conformally deposited in peripheral portions of the second support via cavities 221 and over the second patterned hard mask layer 233. The second insulating liner comprises an insulating material, such as a dielectric metal oxide, silicon carbide nitride, or silicon oxide, and may have a thickness in a range from 5 nm to 60 nm, such as from 20 nm to 30 nm, although lesser and greater thicknesses may also be employed.

An anisotropic etch process can be performed to etch horizontally-extending portions of the second insulating liner from above the second patterned hard mask layer 233 and at the bottom of each second support via cavity 221. Each remaining tubular portion of the second insulating liner comprises a second tubular insulating liner 224 located in a peripheral portion of a respective second support via cavity 221. For each second support via cavity 221 that is formed above and has an areal overlap in a plan view with a respective first finned dielectric support pillar structure 128A, a second tubular insulating liner 224 therein may vertically extend through and may contact all of the second sacrificial material layers 242. For each second support via cavities 221 that is formed above and having an areal overlap with a respective first finless dielectric support pillar structure 128B, a second tubular insulating liner 224 therein may vertically extends through and laterally contact a respective first subset of the second sacrificial material layers 242 within the second alternating stack (232, 242), and overlie a respective second subset of the second sacrificial material layers 242.

A second via extension process can be performed to vertically extend the second support via cavities 221. The second via extension process comprises an anisotropic etch process, and etches portions of the second alternating stack (232, 242) that underlie the second support via cavities 221. The second etch-stop plates 218 function as etch-stop structures for the second via extension process. Each second support via cavity 221 vertically extends through each layer within the second alternating stack (132, 242) after the second via extension process. In one embodiment, a surface of a second etch-stop plate 218 may be physically exposed at the bottom of each second support via cavity 221. A second tubular insulating liner 224 may contact a respective first subset of the second sacrificial material layers 242, and each second sacrificial material layer 242 in a second subset of the second sacrificial material layers 242 that underlies the second subset may laterally surround and may be exposed to a second support via cavity 221 that is enclosed by the second tubular insulating liner 224. The second tubular insulating liners 224 extend to different heights in the respective second support via cavities 221. The second patterned hard mask layer 233 can be subsequently removed, for example, by performing a selective etch process. such as a wet etch process.

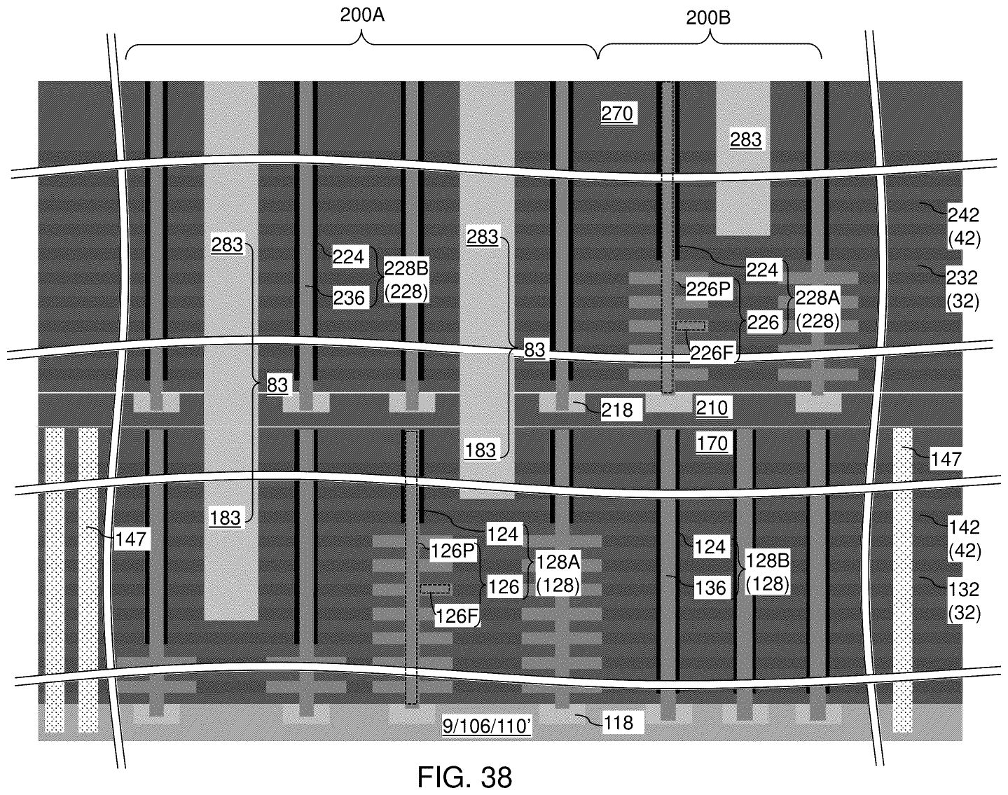

Referring to FIG. 38, a selective isotropic etch process can be performed to isotropically etch portions of the second sacrificial material layers 242 that are exposed in the second support via cavities 221 selective to the materials of the second insulating layers 232, the second etch-stop plates 218, the second tubular insulating liners 224, and the second insulating cap layer 270. For example, if the second sacrificial material layers 242 comprise silicon nitride, a wet etch process employing hot phosphoric acid may be performed to isotropically etch portions of the second sacrificial material layers 242 that are exposed in the second support via cavities 221 and are not covered by a second tubular insulating liner 224. The lateral recess distance of the selective isotropic etch process may be in a range from 20 nm to 300 nm, such as from 40 nm to 200 nm, although lesser and greater lateral recess distances may also be employed.

Annular fin cavities can be formed in the volumes from which the material of the second to sacrificial material layers 242 is removed by the selective isotropic etch process. A subset of the second support via cavities 221 located in the second area 200B adjacent to a respective subset of the second sacrificial contact via fill material portions 283 can be converted into finned second support via cavities including a respective set of at least one annular fin cavity. A subset of second support via cavities 221 in the first area 200A in which each second tubular insulating liner 224 vertically extends through each second sacrificial material layer 242 in the second alternating stack (232, 242) is not modified during the selective isotropic etch process.

In one embodiment, for each second support via cavity 221 that does not extend into the inter-tier dielectric layer 210 and is formed adjacent to a respective one of the second sacrificial contact via fill material portions 283, a second tubular insulating liner 224 is present within the second support via cavity 221. The second tubular insulating liner 224 contacts sidewalls of a respective first subset of the second sacrificial material layers 242. A respective second subset of the second sacrificial material layers 242 underlies the respective first subset of the second sacrificial material layers 242. The respective second subset of the second sacrificial material layers 242 underlies a horizontal plane including an annular bottom surface of the second tubular insulating liner 224. Annular cavities are formed around the second support via cavity 221 by removing proximal portions of the second subset of the second sacrificial material layers 242 selective to the second tubular insulating liner 224 and the second insulating layers 232.

A dielectric fill material, such as undoped silicate glass or a doped silicate glass, can be deposited into finned second support via cavities and the second support via cavities 221 that do not include any annular fin cavity. In one embodiment, a second finned dielectric material portion 226 can be formed in a finned second support via cavity, which comprises a combination of a second support via cavity 221 and at least one annular cavity. The second finned dielectric material portion 226 comprises a second dielectric pillar 226P that vertically extends through each layer within the second alternating stack (232, 242) and laterally extending second dielectric fins 226F surrounding the second dielectric pillar 226. A contiguous combination of a second tubular insulating liner 224 and a second finned dielectric material portion 226 located in the second area 200B constitutes a second finned dielectric support pillar structure 228A, which is a second dielectric support pillar structure 228 of a first type.

A second cylindrical dielectric material portion 236 can be formed in the first area 200A within a volume of a void in a second support via cavity 221 in which a second tubular insulating liner 224 vertically extends through each second sacrificial material layer 242. A contiguous combination of a second tubular insulating liner 224 and a second cylindrical dielectric material portion 236 located in the first area 200A constitutes a second finless dielectric support pillar structure 228B, which is a second dielectric support pillar structure 228 of a second type. The second finned dielectric material portions 226 and the second cylindrical dielectric material portions 236 may be formed simultaneously by deposition and planarization of a same dielectric fill material.

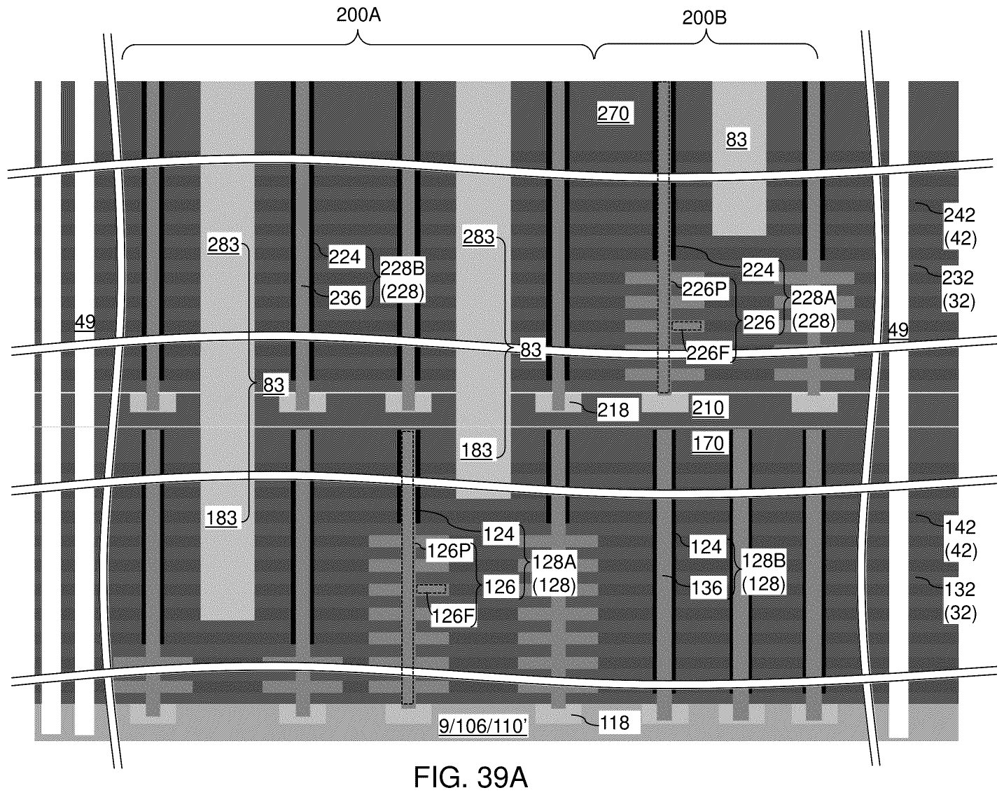

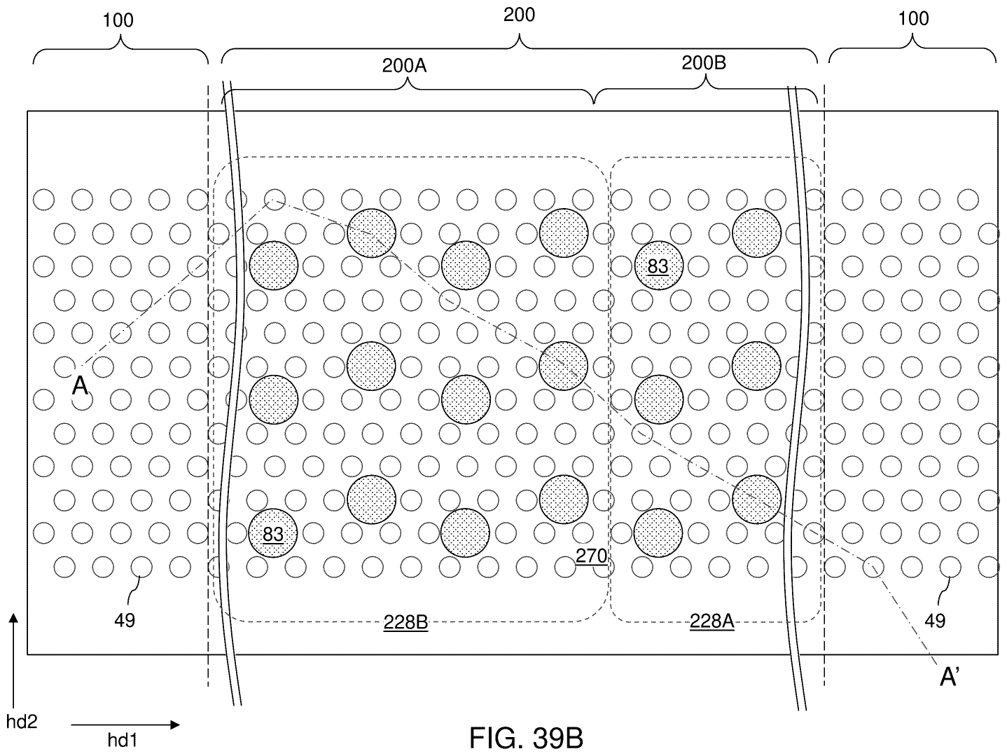

Referring to FIGS. 39A and 39B, second-tier memory openings can be formed through the second alternating stack (232, 242) in memory array regions 100. Each second-tier memory opening can be formed directly on a top surface of a respective one of the first-tier sacrificial memory opening fill structures 147. A selective etch process can be performed to remove the first-tier sacrificial memory opening fill structures 147 from inside the volumes of the first-tier memory openings. Memory openings 49 are formed through the first alternating stack (132, 142) and through the second alternating stack (232, 242). The memory openings 49 comprise voids including the volumes of the first-tier memory openings and the second-tier memory openings. A surface of a lower source-level semiconductor layer 112 may be physically exposed at the bottom of each memory opening 49.

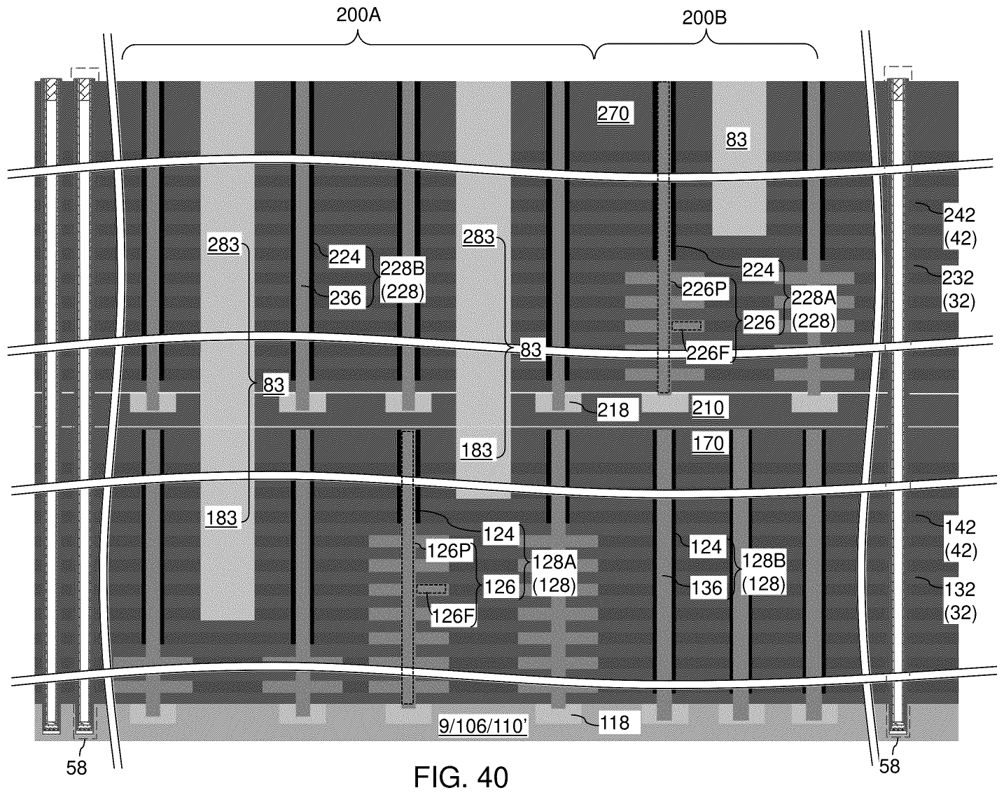

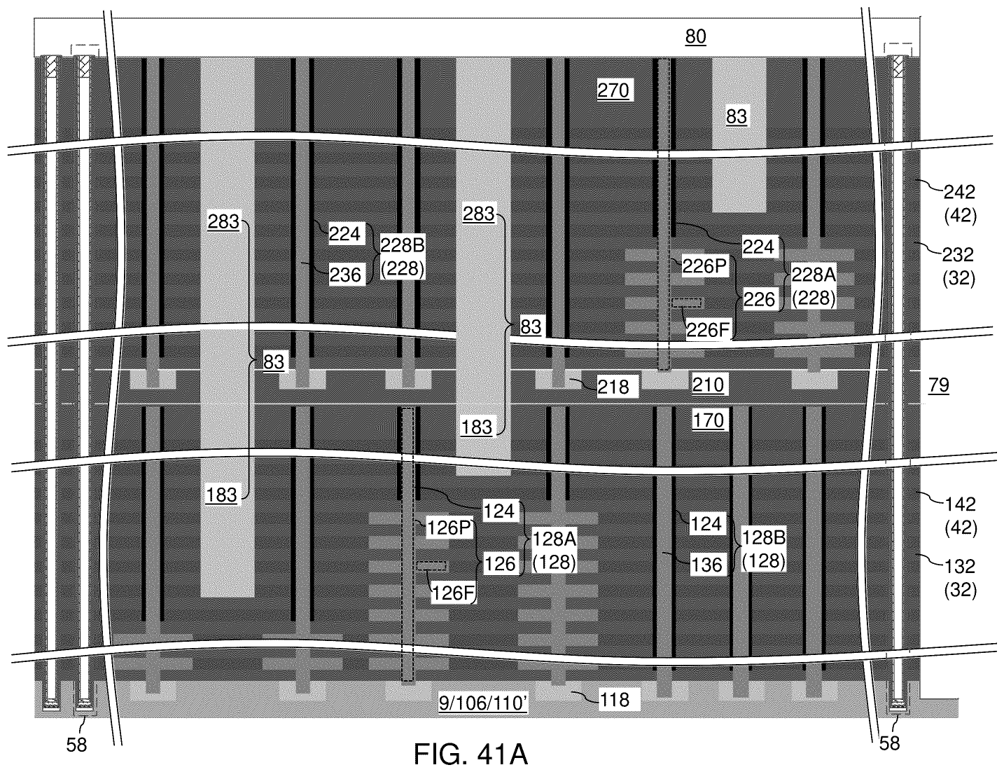

Referring to FIG. 40, the processing steps described with reference to FIG. 4E may be performed to form a memory opening fill structure 58 within each memory opening 49. An array of memory opening fill structures 58 can be formed within each memory array region 100.

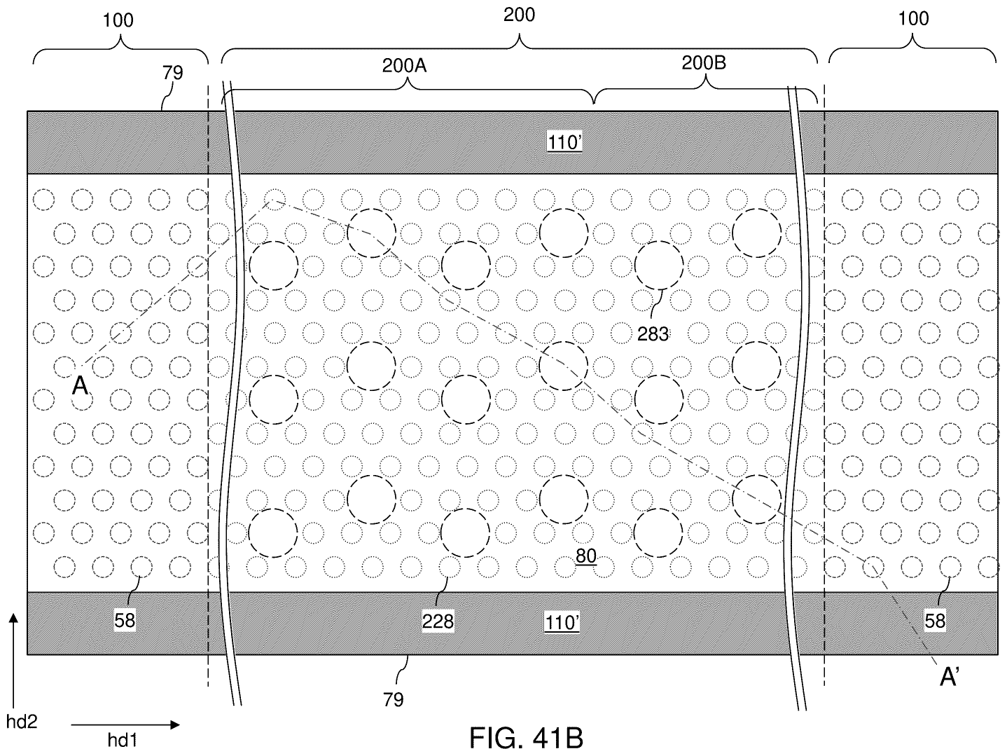

Referring to FIGS. 41A and 41B, a contact-level dielectric layer 80 can be formed above the second insulating cap layer 270. The contact-level dielectric layer 80 comprises a dielectric material such as undoped silicate glass or a doped silicate glass, and may have a thickness in a range from 100 nm to 800 nm, such as from 200 nm to 500 nm, although lesser and greater thicknesses may also be employed.

A photoresist layer (not shown) can be applied over the contact-level dielectric layer 80, and is lithographically patterned to form elongated openings in areas between clusters of memory opening fill structures 58. The elongated openings can be formed over areas that are free of any memory opening fill structures 58, any dielectric support pillar structures (128, 228), and any sacrificial contact via fill material portions 83. The pattern in the photoresist layer can be transferred through the contact-level dielectric layer 80, the second insulating cap layer 270, the second alternating stack (232, 242), the inter-tier dielectric layer 210, the first insulating cap layer 170, the first alternating stack (132, 142), and an upper portion of the in-process source-level material layers 110′ employing an anisotropic etch process. Lateral isolation trenches 79 are formed in the volumes from which materials of the contact-level dielectric layer 80, the second insulating cap layer 270, the second alternating stack (232, 242), the inter-tier dielectric layer 210, the first insulating cap layer 170, the first alternating stack (132, 142), and the in-process source-level material layers 110′ are etched. The lateral isolation trenches 79 vertically extend from the top surface of the contact-level dielectric layer 80 to the source-level sacrificial layer 104 (if present) or to the top surface of a semiconductor substrate 8 (if the in-process source-level material layers 110′ are omitted). The lateral isolation trenches 79 laterally extend along the first horizontal direction hd1 between neighboring memory blocks of memory opening fill structures 58.

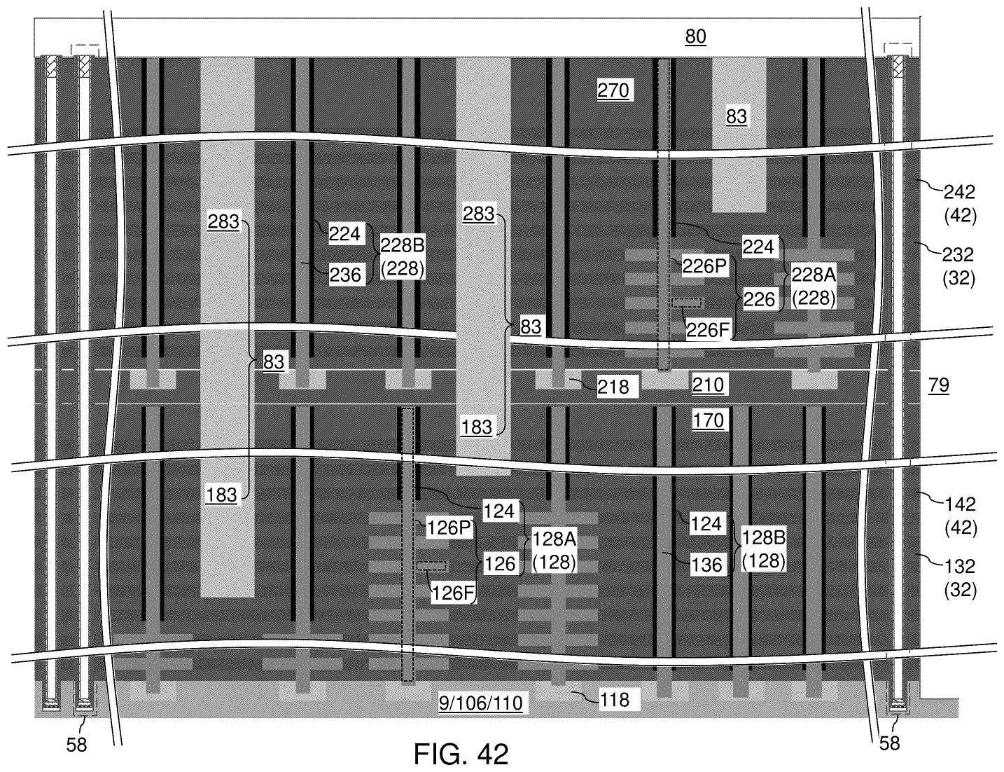

Referring to FIG. 42, the processing steps described with reference to FIGS. 8A and 8B may be performed to replace the in-process source-level material layers 110′ with source-level material layers 110.

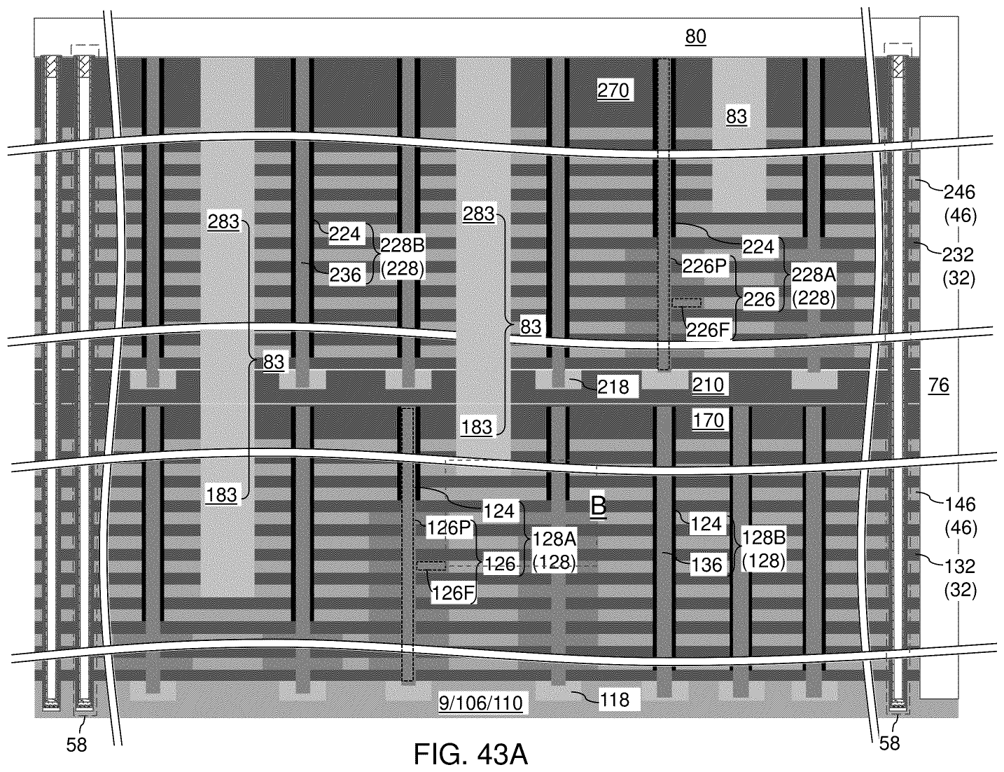

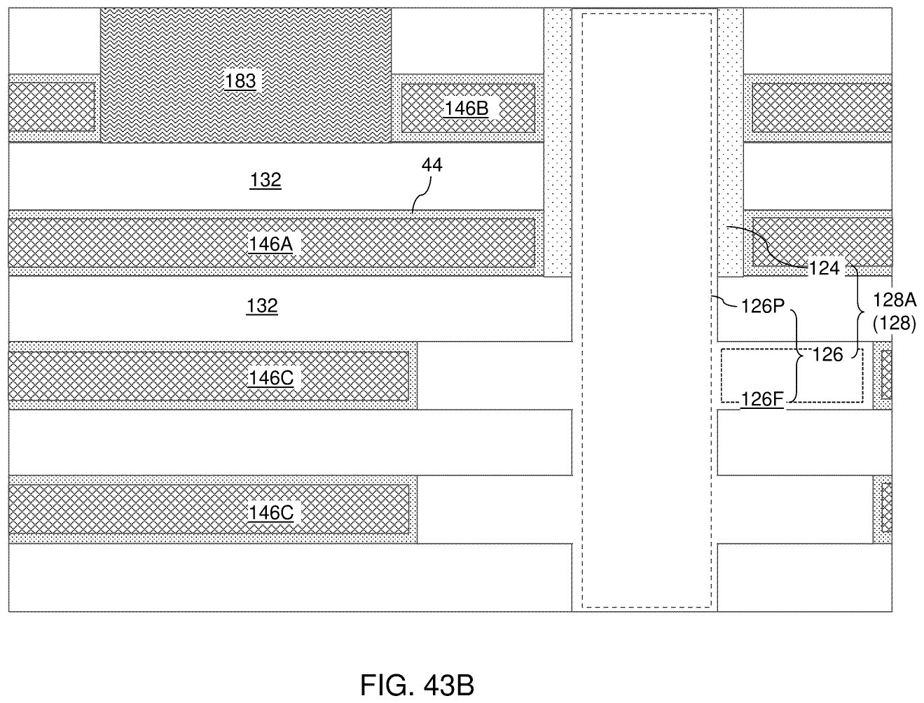

Referring to FIGS. 43A and 43B, the processing steps described with reference to FIGS. 8C, 8D, and 8E may be performed to replace the sacrificial material layers 42 with electrically conductive layers 46 and to form isolation trench fill structures 76 in the lateral isolation trenches 79. The electrically conductive layers 46 comprise first electrically conductive layers 146 and second electrically conductive layers 246. Each first sacrificial material layer 142 may be replaced with a respective combination of a backside blocking dielectric layer 44 and a first electrically conductive layer 146. Each second sacrificial material layer 242 may be replaced with a respective combination of a backside blocking dielectric layer 44 and a second electrically conductive layer 246.

Referring to FIG. 43B, for each combination of a first sacrificial contact via fill material portion 183 and an adjacent first finned dielectric support pillar structure 128A including a first tubular insulating liner 124 that does not vertically extend through each level of the first electrically conductive layers 146, one of the first electrically conductive layers 146A underlies the first sacrificial contact via fill material portion 183 and laterally surrounds the first tubular insulating liner 124. The first tubular insulating liner 124 vertically extends through a first subset of the first electrically conductive layers 146B that overlies the one of the first electrically conductive layers 146A, and through the one of the first electrically conductive layers 146A. A second subset of the first electrically conductive layers 146C may underlie the one of the first electrically conductive layers 146A, and may laterally surround a respective first dielectric fin 126F within the first finned dielectric support pillar structure 128A.

For each combination of a second sacrificial contact via fill material portion 283 and an adjacent second finned dielectric support pillar structure 228A including a second tubular insulating liner 224 that does not vertically extend through each level of the second electrically conductive layers 246, one of the second electrically conductive layers 246 underlies the second sacrificial contact via fill material portion 283 and laterally surrounds the second tubular insulating liner 224. The second tubular insulating liner 224 vertically extends through a first subset of the second electrically conductive layers 246 that overlies the one of the second electrically conductive layers 246, and through the one of the second electrically conductive layers 246. A second subset of the second electrically conductive layers 246 may underlie the one of the second electrically conductive layers 246, and may laterally surround a respective second dielectric fin 226F within the second finned dielectric support pillar structure 228A.

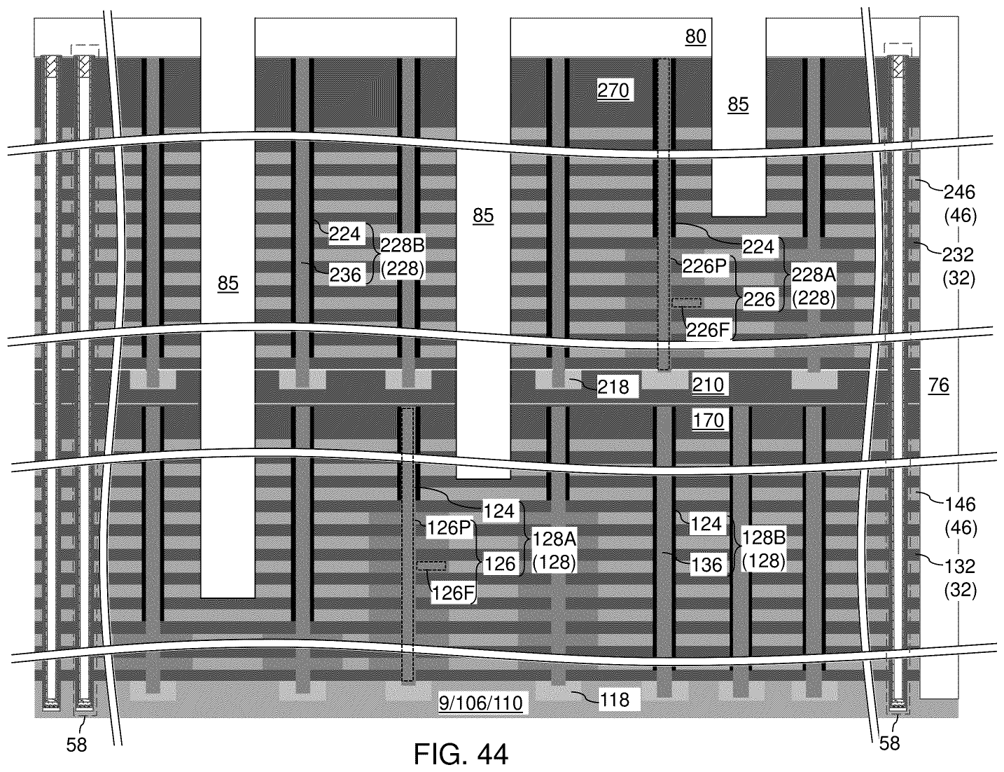

Referring to FIG. 44, a photoresist layer (not shown) can be applied over the contact-level dielectric layer 80, and can be lithographically patterned to form openings within the areas of the sacrificial contact via fill material portions 83. In one embodiment, areas of the openings in the photoresist layer may be the same as the areas of the second sacrificial contact via fill material portion 283 in a plan view such as a see-through top-down view. An anisotropic etch process can be performed to remove portions of the contact-level dielectric layer 80 that are not covered by the photoresist layer. Top surfaces of the second sacrificial contact via fill material portions 283 can be exposed underneath the openings in the contact-level dielectric layer 80.

Subsequently, the sacrificial contact via fill material portions 83 can be removed selective to the materials of the insulating layers (132, 232), the insulating cap layers (170, 270), the contact-level dielectric layer 80, and the backside blocking dielectric layers 44, and selective to the electrically conductive layers (146, 246). For example, a selective etch process (for example, if the sacrificial contact via fill material portions 83 comprise a semiconductor material) or an ashing process (for example, if the sacrificial contact via fill material portions 83 comprise a carbon-based material) may be employed to remove the sacrificial contact via fill material portions 83. If a selective etch process is employed, the selective etch process may comprise an isotropic etch process or an anisotropic etch process.

A replacement contact via cavity 85 is formed in each volume from which at least one sacrificial contact via fill material portion 83 is removed. In one embodiment, each replacement contact via cavity 85 may comprise a cylindrical via cavity that vertically extends from the horizontal plane including a top surface of the contact-level dielectric layer 80 to a top surface of a respective one of the insulating layers (132, 232).

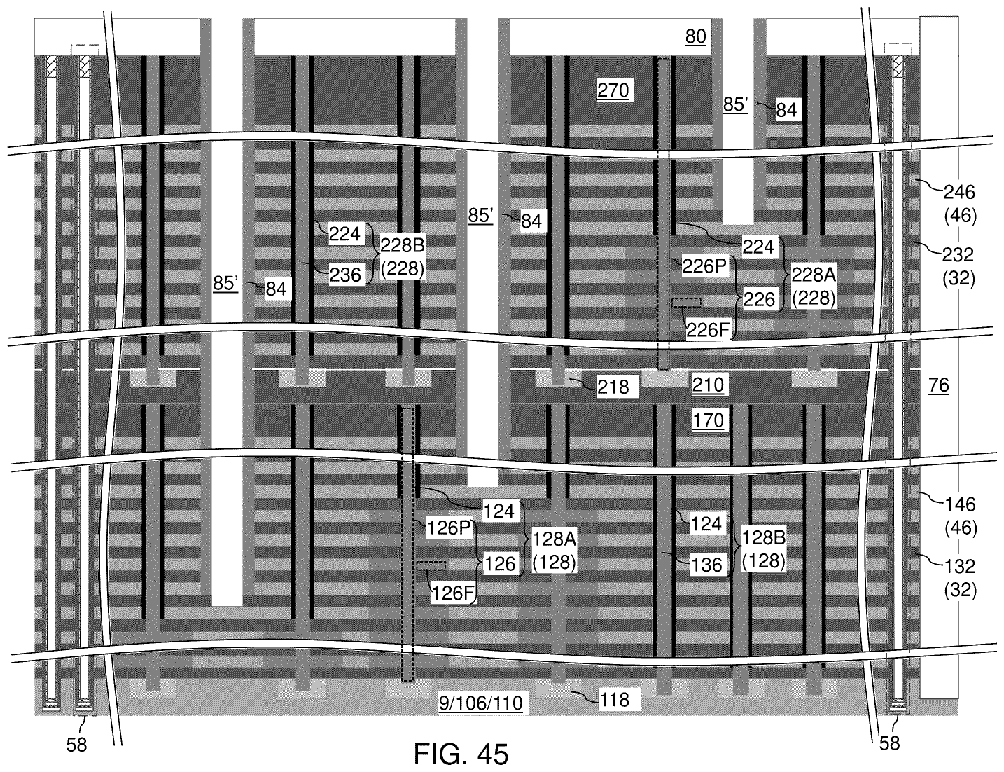

Referring to FIG. 45, an insulating material layer can be conformally deposited in peripheral portions of the replacement contact via cavities 85 and over the contact-level dielectric layer 80. The insulating material layer comprises an insulating material such as silicon oxide, and has a thickness in a range from 30 nm to 100 nm, although lesser and greater thicknesses may also be employed. An anisotropic etch process can be performed to remove horizontally-extending portions of the insulating material layer, and to etch through a respective insulating layer (132, 232) and a horizontally-extending portion of a respective backside blocking dielectric layer 44 that underlies a respective replacement contact via cavity 85. Each remaining cylindrical portion of the insulating material layer located in a respective replacement contact via cavity 85 comprises a tubular insulating spacer 84. A circular top surface segment of an electrically conductive layer (146, 246) may be physically exposed underneath each void 85′ that is laterally surrounded by a respective tubular insulating spacer 84.

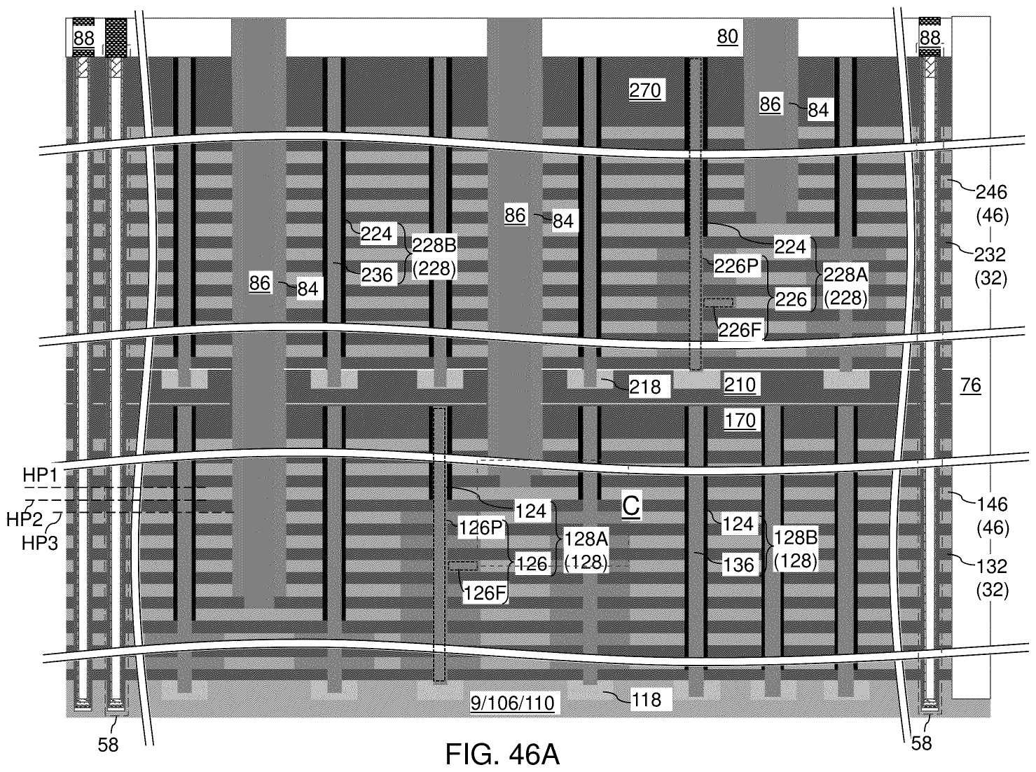

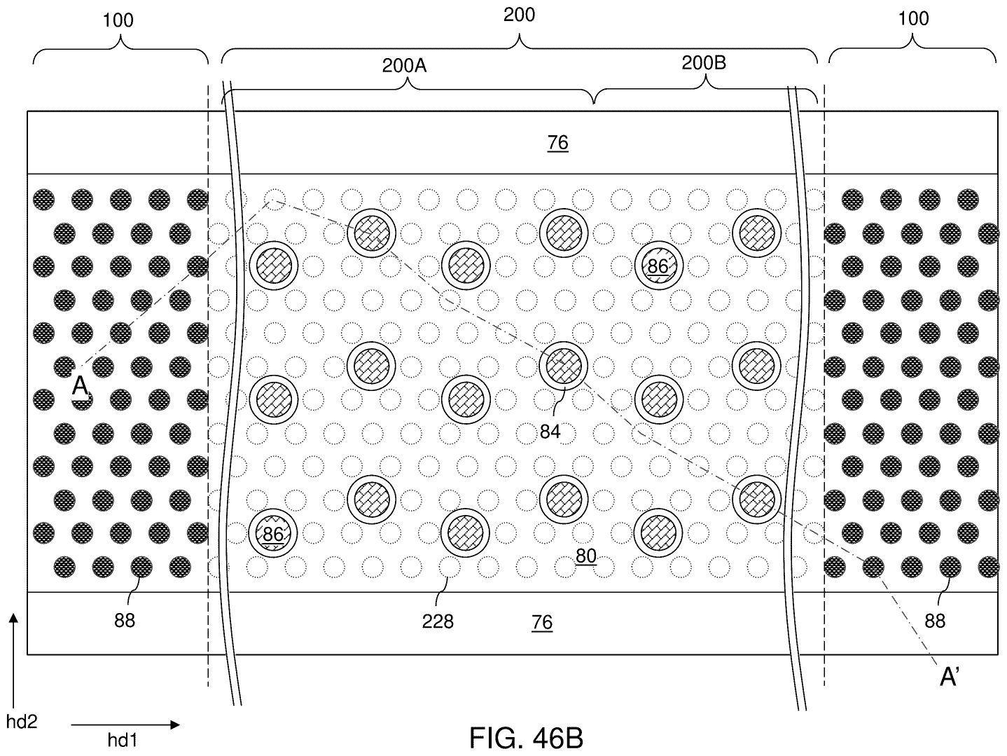

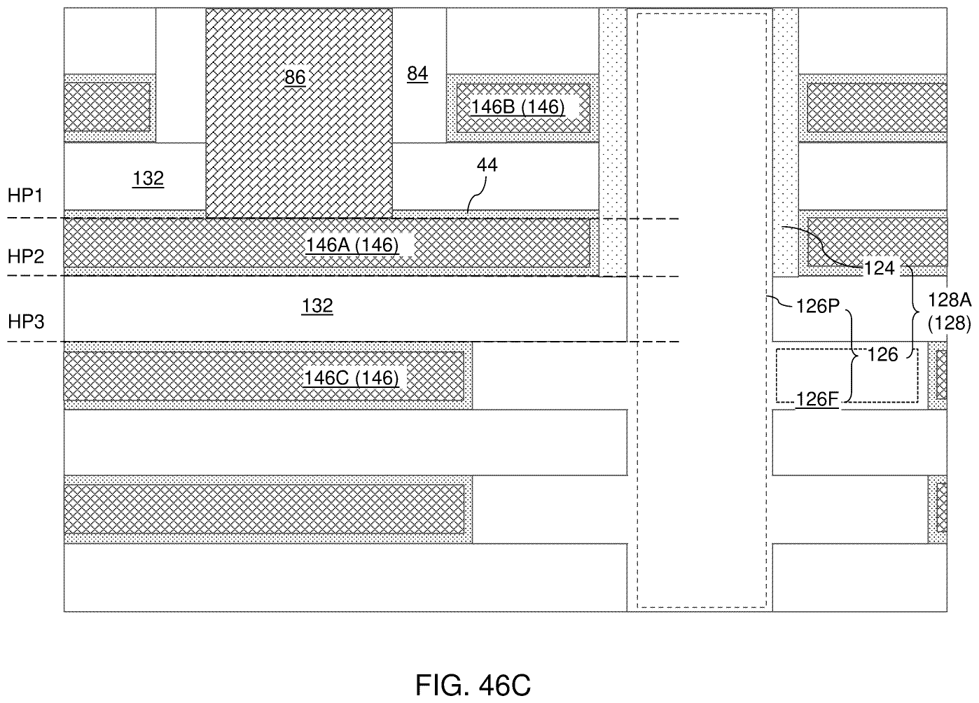

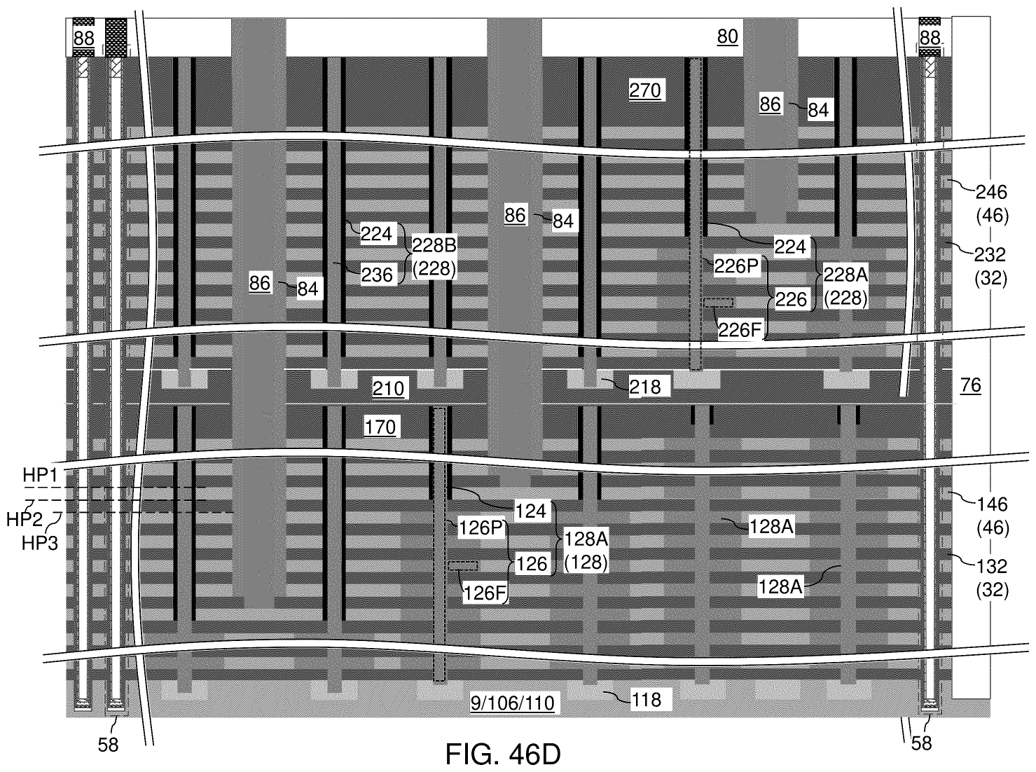

Referring to FIGS. 46A-46D, a photoresist layer (not shown) can be applied to over the contact-level dielectric layer 80, and can be lithographically patterned to form openings over the memory opening fill structures 58. An anisotropic etch process can be performed to transfer the pattern of the openings in the photoresist layer through the contact-level dielectric layer 80. Drain contact via cavities are formed through the contact-level dielectric layer 80. The photoresist layer can be subsequently removed, for example, by ashing.

At least one conductive material can be deposited in the replacement contact via cavities 81 and the drain contact via cavities. The at least one conductive material may comprise a metallic barrier material and a metallic fill material. The metallic barrier material may comprise a metallic nitride material such as TiN, TaN, MoN and/or WN and/or a metallic carbide material such as TiC, TaC, and/or WC. The metallic fill material may comprise W, Ti, Ta, Ru, Co, Mo, Cu, etc. The at least one conductive material may be deposited by chemical vapor deposition, physical vapor deposition, electroplating, electroless plating, or combinations thereof. Excess portions of the at least one conductive material can be removed from above the horizontal plane including the top surface of the contact-level dielectric layer 80 by performing a planarization process, which may employ a chemical mechanical polishing (CMP) process or a recess etch process. Each remaining portion of the at least one conductive material filling a respective replacement contact via cavity 85 constitutes a layer contact via structure 86 that contacts top surface a respective electrically conductive layer 46. Each remaining portion of the at least one conductive material filling a respective drain contact via cavity constitutes a drain contact via structure 88 that contacts top surface a respective drain region 63.

In one embodiment, each sacrificial contact via fill material portion 83 may be replaced with material portions comprising a layer contact via structure 86 such that the layer contact via structure 86 contacts a top surface of a respective one of the electrically conductive layers 46 within a respective horizontal plane, such as the first horizontal plane HP1 illustrated in FIG. 46C.

FIG. 46A illustrates a configuration of the third exemplary structure in which the first finless dielectric support pillar structures 128B are present. FIG. 46D illustrates an alternative configuration of the third exemplary structure in which the first finless dielectric support pillar structure 128B are omitted. Instead, additional first finned dielectric support pillar structures 128A are formed instead of the first finless dielectric support pillar structure 128B,

In the third embodiment, the finned dielectric support pillar structures (128A, 228A) include fins only below the layer contact via structures 86. By enlarging the width of the support pillar structures only below the bottom of the layer contact via structures, bottom over etching of cavities 85 does not occur. The electrically conductive layers 46 function as etch stop layers during the etching step that forms the voids 85′, as shown in FIG. 45. Thus, the short circuits and/or leakage current are avoided or reduced between the layer contact via structures 86 and electrically conductive layers 46C underlying the electrically conductive layer 46A which is intentionally contacted by the layer contact via structure 86.

Referring to FIGS. 46A-46D, the third exemplary structure may comprise a three-dimensional memory device. The three-dimensional memory device may comprise: a first alternating stack (132, 146) of first insulating layers 132 and first electrically conductive layers 146; a memory opening 49 vertically extending through the first alternating stack (132, 146); a memory opening fill structure 58 located in the memory opening 49 and comprising a vertical stack of memory elements (e.g., portions of the memory film 50) and a vertical semiconductor channel 60; a first layer contact via structure 86 vertically extending through a first subset of the first electrically conductive layers 146B and contacting a top surface of one 146A of the first electrically conductive layers 146 within a first horizontal plane HP1; and a first finned dielectric support pillar structure 128A located in proximity to the first layer contact via structure 86 and comprising: a first tubular insulating liner 124 vertically extending through each of the first subset of the first electrically conductive layers 146B and through said one 146A of the first electrically conductive layers 146, and a first finned dielectric material portion 126 comprising a first dielectric pillar 126P that vertically extends through each layer within the first alternating stack (132, 146) and further comprising first dielectric fins 126F that are located below the first horizontal plane HP1.

In one embodiment, the first tubular insulating liner 124 has an annular bottom surface located within a second horizontal plane HP2 that underlies the first horizontal plane HP1. In one embodiment, a topmost horizontal surface of the first dielectric fins 126F is located within a third horizontal plane HP3 that underlies the second horizontal plane HP2. In one embodiment, a vertical spacing between the second horizontal plane HP2 and the third horizontal plane HP3 is not greater than a thickness of one of the first insulating layers 132 located between said one 146A of the first electrically conductive layers 146 and another 146C of the first electrically conductive layers 146 that is most proximal to said one 146A of the first electrically conductive layers 146 and located underneath the second horizontal plane HP2. In one embodiment, a vertical spacing between the first horizontal plane HP1 and the second horizontal plane HP2 is not less than a sum of a thickness of said one 146A of the first electrically conductive layers 146 and a thickness of a backside blocking dielectric layer 44 in contact with said one 146A of the first electrically conductive layers 146.

In one embodiment, the first dielectric fins 126F are located at levels of a second subset of the first electrically conductive layers 146 that underlie the second horizontal plane HP2. In one embodiment, the second subset of the first electrically conductive layers 146 comprise each of the first electrically conductive layers 146 within the first alternating stack (132, 146) which underlies said one 146A of the first electrically conductive layers 146.

In one embodiment, each of the first dielectric fins 126F is laterally spaced from a respective first electrically conductive layer 146 within the second subset of the first electrically conductive layers 146 by tubular portion of a respective backside blocking dielectric layer 44 that contacts a respective cylindrical surface segment of the memory opening fill structure 58. In one embodiment, each of the first subset of the first electrically conductive layers 146 is laterally spaced from the first tubular insulating liner 124 by a respective backside blocking dielectric layer 44 that contacts a respective cylindrical surface segment of the memory opening fill structure 58. In one embodiment, said one 146A of the first electrically conductive layers 146 is laterally spaced from the first tubular insulating liner 124 by a backside blocking dielectric layer 44 that contacts a cylindrical surface segment of the memory opening fill structure 58.

In one embodiment, the first dielectric pillar 126P comprises a straight sidewall that vertically extends from an inner periphery of a topmost surface of the first dielectric fins 126F at least to a topmost surface of the first alternating stack (132, 146). In one embodiment, the three-dimensional memory device comprises a first finless dielectric support pillar structure 128B comprising: an additional tubular insulating liner 124 comprising a same material as the first tubular insulating liner 124 and vertically extending through each of the first electrically conductive layers 146 in the first alternating stack (132, 146), and an additional dielectric pillar (which is embodied as a first cylindrical dielectric material portion 136) comprising a same material as the first dielectric pillar 126P, laterally surrounded by the additional tubular insulating liner 124, and having a straight sidewall that vertically extends through each layer within the first alternating stack (132, 146).

In one embodiment, the three-dimensional memory device comprises: a second alternating stack (232, 246) of second insulating layers 232 and second electrically conductive layers 246 located over the first alternating stack (132, 146), wherein the memory opening 49, the memory opening fill structure 58, the first layer contact via structure 86, and the first finned dielectric support pillar structure 128A vertically extend through each layer within the second alternating stack (232, 246); and a second finned dielectric support pillar structure 228A vertically extending through the second alternating stack (232, 246) and not extending into the first alternating stack (132, 146) and comprising: a second tubular insulating liner 224 vertically extending through each of a first subset of the second electrically conductive layers 246 and through one of the second electrically conductive layers 246 that underlies the first subset of the second electrically conductive layers 246, and a second finned dielectric material portion 226 comprising a second dielectric pillar 226P that vertically extends through each layer within the second alternating stack (232, 246) and further comprising second dielectric fins 226F that underlie said one of the second electrically conductive layers 246.

In one embodiment, the three-dimensional memory device comprises a second layer contact via structure 86 located in proximity to the second finned dielectric support pillar structure 228A and vertically extending through the first subset of the second electrically conductive layers 246 and contacting a top surface of said one of the second electrically conductive layers 246. In one embodiment, the three-dimensional memory device comprises an etch-stop plate (such as a second etch-stop plate 218) embedded within an inter-tier dielectric layer located between the first alternating stack (132, 146) and the second alternating stack (232, 246), wherein a bottom surface of the second finned dielectric support pillar structure 228A contacts the etch-stop plate (such as the second etch-stop plate 218).

The various embodiments of the present disclosure can be employed to provide layer contact via structures 86 for electrically conductive layers 46 in a three-dimensional memory device without forming any staircase region in an alternating stack of insulating layers 32 and electrically conductive layers 46. Sacrificial via fill material portions (27, 83) are employed during replacement of sacrificial material layers 42 with electrically conductive layers 46 in regions in which the layer contact via structures 86 are to be formed. Structural support features are located below the contact via structures 86 which enhance the mechanical strength of the region below the sacrificial via fill material portions (27, 83) during replacement of the sacrificial material layers 42 with electrically conductive layers 46.

In the first embodiment, a layer contact via structures 86 may vertically extend through each layer within the alternating stack (32, 46), and annular insulating fins (22, 26) may be provided at each level of the electrically conductive layers 46 except the level of the electrically conductive layer 46 that is contacted by the layer contact via structure 86. The bottom portion of the layer contact via structure 86 and the second annular insulating fins 26 function as the structural support features.

In the second embodiment, a dielectric support pillar structure 20 function as the structural support feature below the layer contact via structure 86. First annular insulating fins 22 may be provided at each level of overlying electrically conductive layers 46, and second annular insulating fins 26 may underlie the electrically conductive layer 46 and may laterally surround and may contact the dielectric support pillar structure 20.

In the third embodiment, finned dielectric support pillar structures (128A, 228A) are provided around a layer contact via structure 86. The finned dielectric support pillar structures (128A, 228A) comprise dielectric fins (126F, 226F) which function as the structural support features which are located only at levels that underlie the layer contact via structure 86.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device comprising:
an alternating stack of insulating layers and electrically conductive layers, wherein the electrically conductive layers comprise a first electrically conductive layer, second electrically conductive layers that overlie the first electrically conductive layer, and third electrically conductive layers that underlie the first electrically conductive layer;
a memory opening vertically extending through the alternating stack;
a memory opening fill structure located in memory opening and comprising a vertical stack of memory elements located at levels of the electrically conductive layers and a vertical semiconductor channel; and
a layer contact assembly comprising:
a layer contact via structure vertically extending through each of the second electrically conductive layers and laterally contacting a cylindrical surface of the first electrically conductive layer;
a dielectric support pillar structure vertically extending through each of the third electrically conductive layers and contacting a bottom surface of the layer contact via structure; first annular insulating fins laterally surrounding the layer contact via structure and located at each level of the second electrically conductive layers; and
a second annular insulating fin having an inner cylindrical sidewall surface that contacts a first cylindrical surface segment of the dielectric support pillar structure.

2. The three-dimensional memory device of claim 1, wherein the second annular insulating fin is located at a level of a topmost third electrically conductive layer of the third electrically conductive layers.

3. The three-dimensional memory device of claim 2, wherein each of the third electrically conductive layers except the topmost third electrically conductive layer is in direct contact with the dielectric support pillar structure, or is laterally spaced from the dielectric support pillar structure by a respective backside blocking dielectric layer which contacts a respective cylindrical surface segment of the memory opening fill structure.

4. The three-dimensional memory device of claim 1, wherein the second annular insulating fin comprises an annular upward protrusion that protrudes above an annular top surface of the second annular insulating fin and contacts the layer contact via structure.

5. The three-dimensional memory device of claim 1, wherein the layer contact via structure comprises:
a pillar portion that vertically extends through each of the second electrically conductive layers and the first electrically conductive layer; and
a fin portion located at a level of the first electrically conductive layer and adjoined to and laterally protruding from a bottom portion of the pillar portion and having an outer sidewall that contacts the cylindrical surface of the first electrically conductive layer.

6. The three-dimensional memory device of claim 5, wherein the fin portion comprises:
a plate portion;
a first annular rim extending outward from the plate portion and having a top surface within a horizontal plane including a top surface of the plate portion; and
a second annular rim extending outward from the plate portion and having a bottom surface within a horizontal plane including a bottom surface of the plate portion.

7. The three-dimensional memory device of claim 6, wherein:
the first electrically conductive layer is embedded within a backside blocking dielectric layer that contacts a cylindrical surface segment of the memory opening fill structure; and
each of the first annular rim and the second annular rim has a thickness that equals a thickness of the backside blocking dielectric layer.

8. The three-dimensional memory device of claim 6, wherein:
an annular bottom surface segment of the first annular rim contacts an annular top surface segment of the first electrically conductive layer; and
an annular top surface segment of the second annular rim contacts an annular bottom surface segment of the first electrically conductive layer.

9. The three-dimensional memory device of claim 6, wherein:
a cylindrical surface of the plate portion vertically extends between the first annular rim and the second annular rim; and
an entirety of the cylindrical surface of the plate portion is in contact with a cylindrical surface segment of the first electrically conductive layer.

10. The three-dimensional memory device of claim 6, wherein the plate portion includes an annular downward protruding portion that contacts an annular upward protrusion of the second annular insulating fin.

11. The three-dimensional memory device of claim 10, wherein the annular downward protruding portion protrudes downward from a horizontal plane including an annular bottom surface of the fin portion and laterally surrounds an upper portion of the dielectric support pillar structure.

12. The three-dimensional memory device of claim 11, wherein a convex inner sidewall of the annular downward protruding portion contacts an annular concave surface segment of the dielectric support pillar structure.

13. The three-dimensional memory device of claim 1, wherein each of the first annular insulating fins contacts, or is laterally spaced by a respective backside blocking dielectric layer from, a respective one of the second electrically conductive layers.

14. The three-dimensional memory device of claim 1, further comprising an additional dielectric support pillar structure having a same material composition as the dielectric support pillar structure, has a bottom surface located within a horizontal plane including a bottom surface of the dielectric support pillar structure, and has a top surface located within a horizontal plane including a topmost surface of the alternating stack.

15. A method of forming a three-dimensional memory device, comprising:
forming an alternating stack of insulating layers and sacrificial material layers over a substrate;
forming a memory opening through the alternating stack;
forming a memory opening fill structure in the memory opening, wherein the memory opening fill structure comprises a vertical stack of memory elements located at levels of the sacrificial material layers and a vertical semiconductor channel;
forming a dielectric support pillar structure through the alternating stack;
forming a contact via cavity through a first subset of the sacrificial material layers by etching an upper portion of the dielectric support pillar structure to reduce a height of the dielectric support pillar structure and to expose sidewalls of the first subset of the sacrificial material layers;
replacing portions of the first subset of the sacrificial material layers that are proximal to the contact via cavity with first annular insulating fins;
performing a first via extension process that vertically extends the contact via cavity;
replacing a portion of a first sacrificial material layer that underlies the first subset of the sacrificial material layers with a sacrificial fin structure;
forming a sacrificial via fill material portion in the contact via cavity;
replacing remaining portions of the sacrificial material layer in the alternating stack with electrically conductive layers; and
replacing at least the sacrificial via fill material portion and the sacrificial fin structure with an electrically conductive layer contact via structure.

16. The method of claim 15, further comprising:
performing a second via extension process that vertically extends the contact via cavity; and
replacing an annular portion of a topmost sacrificial material layer of a second subset of the sacrificial material layers that underlies the sacrificial fin structure with a second annular insulating fin, wherein the sacrificial via fill material portion is formed after formation of the second annular insulating fin.

17. The method of claim 16, wherein a bottommost surface of the contact via cavity is located above a horizontal plane including a top surface of a bottommost sacrificial material layer within the alternating stack after performing the second via extension process.

18. The method of claim 16, further comprising:
forming an annular cavity by removing the annular portion of the topmost sacrificial material layer of the second subset of the sacrificial material layers; and
depositing an insulating liner in the contact via cavity and in the annular cavity, wherein the second annular insulating fin comprises a portion of the insulating liner that is deposited in the annular cavity, and wherein the sacrificial via fill material portion is formed in a void within a volume of the contact via cavity that remains after deposition of the insulating liner.

19. The method of claim 15, further comprising:
forming lateral isolation trenches through the alternating stack;
forming laterally-extending cavities by etching the sacrificial material layers selective to the insulating layers and the sacrificial fin structure; and
forming a combination of a respective backside blocking dielectric layer and a respective one of the electrically conductive layers within each of the laterally-extending cavities.

20. The method of claim 19, further comprising:
forming a replacement contact via cavity by removing the sacrificial via fill material portion and the sacrificial fin structure, wherein one of the backside blocking dielectric layers is physically exposed; and
removing proximal portions of said one of the backside blocking dielectric layers to expose a first electrically conductive layer of the electrically conductive layers to the replacement contact via cavity, wherein the layer contact via structure is formed directly on the first electrically conductive layer.
